(19) United States
(12) Patent Application Publication
(10) Pub. No.: US 2025/0127042 A1
(43) Pub. Date: Apr. 17, 2025

(54) ORGANIC ELECTRIC ELEMENT USING COMPOUND FOR ORGANIC ELECTRIC ELEMENT, AND ELECTRONIC DEVICE THEREOF

(71) Applicants: DUK SAN NEOLUX CO., LTD., Chungcheongnam-do (KR); SAMSUNG DISPLAY CO., LTD., Gyeonggi-do (KR)

(72) Inventors: MI KYUNG KIM, Gyeonggi-do (KR); JI HYUN SEO, Gyeonggi-do (KR); BYUNG HEE PARK, Gyeonggi-do (KR); SANG WON SEO, Gyeonggi-do (KR); NAM WOO KIM, Gyeonggi-do (KR); SUNG MO KOO, Gyeonggi-do (KR); HYUN WOO LEE, Gyeonggi-do (KR); KI HO SO, Chungcheongnam-do (KR); HYUNG DONG LEE, Chungcheongnam-do (KR); SUN HEE LEE, Chungcheongnam-do (KR); YONG WOOK PARK, Chungcheongnam-do (KR); SOUNG YUN MUN, Chungcheongnam-do (KR)

(21) Appl. No.: 18/832,069

(22) PCT Filed: Dec. 29, 2022
(86) PCT No.: PCT/KR2022/021655

§ 371 Date: Jul. 22, 2024

(30) Foreign Application Priority Data
Jan. 20, 2022 (KR) 10-2022-0008541
Jul. 26, 2022 (KR) 10-2022-0092529

(51) Int. Cl. H10K 85/60; H10K 50/13

(52) U.S. Cl. CPC H10K 85/636; H10K 85/633; H10K 50/13; H10K 85/615; H10K 85/622; H10K 85/626; H10K 85/6572; H10K 85/6574; H10K 85/6576

(57) ABSTRACT

An organic electric element includes a first electrode, a second electrode, and an organic material layer between the first electrode and the second electrode. The organic material layer includes a light-emitting layer, a hole transport layer between the first electrode and the light-emitting layer, and a plurality of light-emitting auxiliary layers between the hole transport layer and the light-emitting layer. The plurality of light-emitting auxiliary layers include a first light-emitting auxiliary layer adjacent to the hole transport layer and a second light-emitting auxiliary layer adjacent to the light-emitting layer, and the first light-emitting auxiliary layer includes a compound represented by Formula 1 and the second light-emitting auxiliary layer includes a compound represented by Formula 2.

### CROSS REFERENCE TO RELATED APPLICATIONS AND CLAIM OF PRIORITY

This application claims benefit under 35 U.S.C. 119, 120, 121, or 365(c), and is a National Stage entry from International Application No. PCT/KR2022/021655 filed on Dec. 29, 2022, which claims priority to the benefit of Korean Patent Application Nos. 10-2022-0008541 filed on Jan. 20, 2022 and 10-2022-0092529 file on Jul. 26, 2022 in the Korean Intellectual Property Office, the entire contents of which are incorporated herein by reference.

### BACKGROUND

### 1. Technical Field

The present invention relates to an organic electric element using compound for an organic electric element and an electronic device thereof.

### 2. Background Art

In general, an organic light emitting phenomenon refers to a phenomenon in which electric energy is converted into light energy of an organic material. An organic electric element utilizing the organic light emitting phenomenon usually has a structure including an anode, a cathode, and an organic material layer interposed therebetween. In many cases, the organic material layer has a multi-layered structure having respectively different materials in order to improve efficiency and stability of an organic electric element, and for example, may comprise a hole injection layer, a hole transport layer, a light-emitting layer, an electron transport layer, an electron injection layer, or the like.

The most important issues in organic electroluminescent element are life and efficiency, and as the display becomes larger, these efficiency and life problems must be solved.

Efficiency, life span, driving voltage, and the like are correlated with each other. If efficiency is increased, then driving voltage is relatively lowered, and the crystallization of an organic material due to Joule heating generated during operation is reduced as driving voltage is lowered, as a result of which life span shows a tendency to increase. However, efficiency cannot be maximized only by simply improving the organic material layer. This is because long life span and high efficiency can be simultaneously achieved when energy levels and T1 values among the respective layers included in the organic material layer, inherent material properties (mobility, interfacial properties, etc.) and the like are optimal combination.

Therefore, in order to fully demonstrate the excellent characteristics of organic electric element, it is necessary to develop materials that form the organic layer of the element, in particular, research and development on the composition and constituent materials of a light-emitting auxiliary layer is necessary, taking into account the thickness of the light-emitting auxiliary layer and the hole mobility in a light-emitting auxiliary layer.

### SUMMARY

The object of the present invention is to provide an organic electric element and its electronic device employing compound that can lower the driving voltage of the element and improve the luminous efficiency and life time as material for a light-emitting auxiliary layer.

In an aspect of the present invention, the present invention provides an organic electric element employing compounds of the following Formulas 1 and 2 to a light-emitting auxiliary layer.

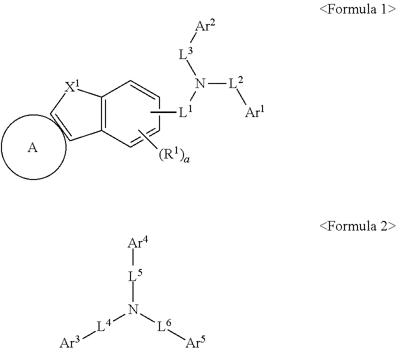

In another aspect of the present invention, the present invention provides an electronic device including the organic electric element.

According to the present invention, a driving voltage of an organic electric element can be lowered and the luminous efficiency and lifetime of the element can be improved.

### BRIEF DESCRIPTION OF THE DRAWINGS

FIGS. 1 to 3 illustrate examples of organic electroluminescent element according to the present invention.

### DETAILED DESCRIPTION

Unless otherwise stated, the term “aryl group” or “arylene group” as used herein has, but not limited to, 6 to 60 carbon atoms. The aryl group or arylene group in the present invention may comprise a monocyclic ring, ring assemblies, a fused polycyclic system, spiro compound and the like.

As used herein, the term “fluorenyl group” refers to a substituted or unsubstituted fluorenyl group, and “fluorenylene group” refers to a substituted or unsubstituted fluorenylene group. The fluorenyl group or fluorenylene group used in the present invention comprises a spiro compound formed by combining R and R′ with each other in the following structure, and also comprises compound formed by linking adjacent R″s to each other. “Substituted fluorenyl group”, “substituted fluorenylene group” means that at least one of R, R′, R″ in the following structure is a substituent other than hydrogen, and R″ may be 1 to 8 in the following formula. In this specification, a fluorenyl group and a fluoreneylene group may be referred to as a fluorene group or fluorene regardless of the valence.

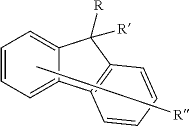

The term “spiro compound” as used herein has a spiro union which means union having one atom as the only common member of two rings. The common atom is designated as ‘spiro atom’. The compounds are defined as ‘monospiro-’, ‘dispiro-’ or ‘trispiro-’ depending on the number of spiro atoms in one compound.

The term “heterocyclic group” used in the specification comprises a non-aromatic ring as well as an aromatic ring like “heteroaryl group” or “heteroarylene group”. Unless otherwise stated, the term “heterocyclic group” means, but not limited to, a ring containing one or more heteroatoms and having 2 to 60 carbon atoms. Unless otherwise stated, the term “heteroatom” as used herein represents, for example, N, O, S, P or Si and may comprise a heteroatom group such as SO₂, P═O etc. instead of carbon forming a ring such as the following compound. In the specification, “heterocyclic group” comprises a monocyclic, ring assemblies, fused polycyclic system, a spiro-compound and the like.

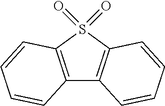 [SMILES: O=S1(=O)c2ccccc2-c2ccccc21]

The term “aliphatic ring group” as used herein refers to a cyclic hydrocarbon except for aromatic hydrocarbons, and comprises a monocyclic ring, ring assemblies, a fused polycyclic system, a spiro-compound and the like, and unless otherwise specified, it means a ring of 3 to 60 carbon atoms, but not limited thereto. For example, a fused ring of benzene being an aromatic ring and cyclohexane being a non-aromatic ring corresponds to aliphatic ring group.

In this specification, a ‘group name’ corresponding to an aryl group, an arylene group, a heterocyclic group, and the like exemplified for each symbol and its substituent may be written in the name of functional group reflecting the valence, and may also be described as the name of a parent compound. For example, in the case of phenanthrene which is a kind of aryl group, it may be described by distinguishing valence such as ‘phenanthryl (group)’ when it is ‘monovalent group’, and ‘phenanthrylene (group)’ when it is ‘divalent group’, and it may also be described as a parent compound name, ‘phenanthrene’, regardless of its valence. Similarly, in the case of pyrimidine, it may be described as ‘pyrimidine’ regardless of its valence, and it may also be described as the name of corresponding functional group such as pyrimidinyl (group) when it is ‘monovalent group’, and ‘pyrimidylene (group)’ when it is ‘divalent group’.

In addition, in the present specification, the numbers and alphabets indicating a position may be omitted when describing a compound name or a substituent name. For example, pyrido[4,3-d]pyrimidine, benzofuro[2,3-d]pyrimidine and 9,9-dimethyl-9H-fluorene can be described as pyridopyrimidine, benzofuropyrimidine and dimethylfluorene, respectively. Therefore, both benzo[g]quinoxaline and benzo[f]quinoxaline can be described as benzoquinoxaline.

In addition, unless otherwise expressed, where any formula of the present invention is represented by the following formula, the substituent according to the index may be defined as follows.

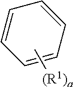

In the above formula, where a is an integer of zero, the substituent R¹ is absent. This means the case where hydrogen atoms are bonded to all the carbon constituting the benzene ring and this is the same as the case where R¹ is hydrogen and a is an integer of 1 to 5. Here, chemical formulas or compounds may be written without explicitly describing the hydrogen.

In addition, one substituent R¹ is bonded to any carbon of the carbons forming the benzene ring when “a” is an integer of 1. Similarly, where “a” is an integer of 2 or 3, substituents R¹s may be bonded to the carbon of the benzene ring, for example, as followings. Also, where “a” is an integer of 4 to 6, substituents R¹s are bonded to the carbon of the benzene ring in a similar manner. Further, where “a” is an integer of 2 or more, R¹s may be the same or different from each other.

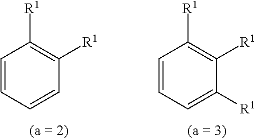

In addition, unless otherwise specified in the present specification, when referring to a condensed/fused ring, the number in the ‘number-condensed/fused ring’ indicates the number of condensed/fused rings. For example, a form in which three rings are condensed/fused with each other, such as anthracene, phenanthrene, and benzoquinazoline, may be represented by a 3-condensed/fused ring.

In addition, unless otherwise described herein, in the case of expressing a ring in the form of a ‘number-membered’ such as a 5-membered ring or a 6-membered ring, the number in the ‘number-membered’ represents the number of atoms forming the ring. For example, thiophene or furan may correspond to a 5-membered ring, and benzene or pyridine may correspond to a 6-membered ring.

In addition, unless otherwise specified in the present specification, when adjacent groups are linked to each other to form a ring, the ring may be selected from the group consisting of a C₆-C₆₀ aromatic ring group, a fluorenyl group, a C₂-C₆₀ heterocyclic group containing at least one heteroatom selected from the group consisting of O, N, S, Si and P, and a C₃-C₆₀ aliphatic ring.

Unless otherwise stated, the term “between adjacent groups”, for example, in case of the following Formulas, comprises not only “between R₁ and R₂”, “between R₂ and R₃”, “between R₃ and R₄”, “between R₅ and R₆”, but also “between R₇ and R₈” sharing one carbon, and may comprise “between substituents” attached to atom (carbon or nitrogen) consisting different ring, such as “between R₁ and R₇”, “between R₁ and R₈”, or “between R₄ and R₅” and the like. That is, where there are substituents bonded to adjacent elements constituting the same ring, the substituents may be correspond “adjacent groups”, and even if there are no adjacent substituents on the same ring, substituents attached to the adjacent ring may correspond to “adjacent groups”. In the following Formula, when the substituents bonded to the same carbon, such as R₇ and R₈, are linked to each other to form a ring, a compound containing a spiro-moiety may be formed.

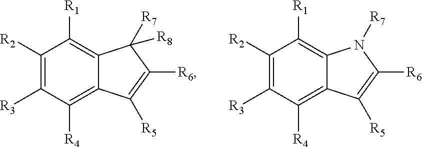

In addition, in the present specification, the expression ‘adjacent groups may be linked to each other to form a ring’ is used in the same sense as ‘adjacent groups are linked selectively to each other to form a ring’, and a case where at least one pair of adjacent groups may be bonded to each other to form a ring.

In addition, unless otherwise specified in the present specification, an aryl group, an arylene group, a fluorenyl group, a fluorenylene group, a heterocyclic group, an aliphatic ring group, an alkyl group, an alkenyl group, an alkynyl group, an alkoxyl group, an aryloxyl group, and a ring formed by adjacent groups may be each optionally substituted with one or more substituents selected from the group consisting of deuterium, halogen, an amino group unsubstituted or substituted with a C₁-C₂₀ alkyl group or a C₆-C₂₀ aryl group, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si and P, and a C₃-C₂₀ aliphatic ring group.

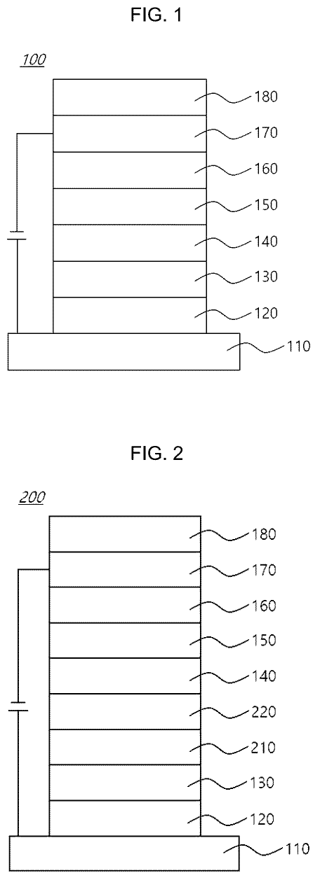

Hereinafter, referring to FIGS. 1 to 3, a lamination structure of an organic electric element including the compound of the present invention will be described.

In designation of reference numerals to components in respective drawings, it should be noted that the same elements will be designated by the same reference numerals although they are shown in different drawings. In addition, in the following description of the present invention, a detailed description of known functions and configurations incorporated herein will be omitted when it may make the subject matter of the present invention rather unclear.

Terms, such as first, second, A, B, (a), (b) or the like may be used herein when describing components of the present invention. Each of these terminologies is not used for defining an essence, order or sequence of a corresponding component but used merely to distinguish the corresponding component from other component(s). It will be understood that the expression ‘one component is “connected,” “coupled” or “joined” to another component’ comprises the case where a third component may be “connected,” “coupled” or “joined” between a first component and a second component as well as the case where the first component may be directly connected, coupled or joined to the second component.

In addition, it will be understood that when an element such as a layer, film, region or substrate is referred to as being “on” or “over” another element, it can be directly on the other element or intervening elements may also be present. In contrast, when an element is referred to as being “directly on” another element, there are no intervening elements present.

The FIGS. 1 to 3 show examples of an organic electric element according to an embodiment of the present invention, respectively.

Referring to the FIG. 1, an organic electric element 100 according to an embodiment of the present invention includes a first electrode 110 formed on a substrate (not shown), a second electrode 170, and an organic material layer between the first electrode 110 and the second electrode 170.

The first electrode 110 may be an anode (positive electrode), and the second electrode 170 may be a cathode (negative electrode). In the case of an inverted organic electric element, the first electrode may be a cathode, and the second electrode may be an anode.

The organic material layer may include a hole transport zone, a light-emitting layer, and an electron transport zone sequentially formed on the first electrode 110, and the hole transport zone includes a hole injection layer 120, a hole transport layer 130, and a light-emitting auxiliary layer (not shown), etc., and the electron transport zone may include an electron transport layer 150 and an electron injection layer 160.

In addition, a layer for improving the luminous efficiency 180 may be formed one side of sides of the first electrode 110 and the second electrode 170, wherein one side is not facing the organic material layer, as a result the luminous efficiency of an organic electric element can be improved.

For example, the light efficiency improving layer 180 may be formed on the second electrode 170, as a result, in the case of a top emission organic light emitting element, the optical energy loss due to Surface Plasmon Polaritons (SPPs) at the second electrode 170 may be reduced and in the case of a bottom emission organic light emitting element, the light efficiency improving layer 180 may serve as a buffer for the second electrode 170.

A buffer layer 210 or a light-emitting auxiliary layer 220 may be further formed between a hole transport layer 130 and a light-emitting layer 140, which will be described with reference to FIG. 2.

Referring to FIG. 2, the organic electric element 200 according to another embodiment of the present invention may comprise a hole injection layer 120, a hole transport layer 130, a buffer layer 210, a light-emitting auxiliary layer 220, a light-emitting layer 140, the electron transport layer 150, the electron injection layer 160, and a second electrode 170 formed on a first electrode 110 in sequence, and a layer for improving light efficiency 180 may be formed on the second electrode, and although not shown in FIG. 2, an electron transport auxiliary layer may be further formed between the light-emitting layer 140 and the electron transport layer 150.

The light-emitting auxiliary layer 220 may be formed of a single layer or a plurality of two or more layers, and preferably a plurality of layers consisting of/including a first light-emitting auxiliary layer adjacent to a hole transport layer and a second light-emitting auxiliary layer adjacent to a light-emitting layer. When the light-emitting auxiliary layer is formed of multiple layers, the hole mobility and T1 energy level in each light-emitting auxiliary layer are taken into consideration, and the thickness of each layer is appropriately considered to form each light-emitting auxiliary layer, thereby improving the characteristics of an organic electric element.

The thickness of the light-emitting auxiliary layer varies depending on the color. In the case of a top emission device, the light generated in the light-emitting layer passes through the hole transport region and is reflected at the anode. The reflected light passes through the hole transport region and combines with the light generated in the light-emitting layer to transmit light to the outside through the electron transport layer. At this time, if a top emission device is designed to use constructive interference being a microcavity phenomenon, light efficiency, color purity and lifespan of the device are improved.

In other words, since the wavelength is different for each color, a microcavity phenomenon must be used by adjusting the thickness of the hole transport region between the anode and the light-emitting layer to suit the color. To use this, the thickness of the hole transport region is changed. For example, when the sum of the thicknesses of the hole transport region except for the light-emitting auxiliary layer is 1,000 to 1,500 Å, it is preferable that the thickness of the light-emitting auxiliary layer is 600 to 900 Å for red, 300 to 500 Å for green, and 50 to 100 Å for blue. The hole transport region may include a hole injection layer, a hole transport layer, and an light-emitting auxiliary layer.

As described above, a light-emitting auxiliary layer may be formed of a plurality of layers including/composed of a first light-emitting auxiliary layer adjacent to a hole transport layer and a second light-emitting auxiliary layer adjacent to a light-emitting layer. In this case, it appears that the first light-emitting auxiliary layer mainly plays the role of injecting holes from the hole transport layer to the light-emitting auxiliary layer and transporting the injected holes, and the second light-emitting auxiliary layer mainly plays the role of injecting holes from the light-emitting auxiliary layer to the host and blocking electrons.

In this way, the charge balance of the device can be appropriately adjusted by appropriately adjusting the hole injection characteristics in a first and a second light-emitting auxiliary layers, which can affect the efficiency and lifespan of an element.

In addition, the hole mobility of a first light-emitting auxiliary layer affects the hole transport role of the first light-emitting auxiliary layer and can play a significant role in improving the driving voltage characteristics of the element, and a second light-emitting auxiliary layer can play the role of electron blocking to the host based on high LUMO and high T1 and minimize damage to a hole transport layer, which can affect the lifespan. Since a second light-emitting auxiliary layer should be designed so as not to affect the hole transport role of a first light-emitting auxiliary layer as much as possible, it is preferable that the thickness of a second light-emitting auxiliary layer is thin.

For example, the thickness of the first light-emitting auxiliary layer is preferably 25 to 900 Å, 25 to 75 Å, preferably 25 to 50 Å for a blue organic electric element, 100 to 450 Å, preferably 250 to 450 Å for a green organic electric element, and 500 to 900 Å, preferably 650 to 850 Å for a red organic electric element, and the thickness of the second light-emitting auxiliary layer is 10 to 300 Å, preferably 20 to 100 Å, and more preferably 25 to 75 Å.

The hole mobility of the first light-emitting auxiliary layer can be confirmed through HOD (Hole Only Device), and HOD can be confirmed through the element configuration as follows.

After a hole injection layer is formed by vacuum depositing 1,4,5,8,9,11-hexaazatriphenylenehexacarbonitrile (hereinafter referred to as HAT-CN) to a thickness of 5 nm on the ITO layer (anode) formed on the glass substrate, a hole transport zone layer is formed by vacuum depositing a hole transport compound (target compound) to a thickness of 300 nm on the hole injection layer. Then, HAT-CN is vacuum deposited to a thickness of 1 nm on the hole transport zone layer to form a hole blocking layer, and then Al is deposited to a thickness of 100 nm on the hole blocking layer to form a cathode.

HOD of the element manufactured as described above can be measured by the J-V Curve (Current Density-Voltage Curve) using I-V-L measurement equipment manufactured by Mc Science.

At this time, the hole mobility can be checked by calculating based on SCLC (Space Charge Limited Current) in the J-V Curve. SCLC is the point where the main emission begins and refers to the section in dynamic balance (space charge) where the charge is filled in the trap.

The hole mobility (μ) can be calculated through Child's Law and Poole-Frenkel Emission equation.

Equation 1 below is Child's Law, and Equation 2 below is the equation for Poole-Frenkel Emission.

$$J = \frac{9}{8} εμ \frac{{V}^{2}}{{d}^{3}} \qquad [ Equation 1 ]$$

$$J : current density ( A / {Cm}^{2} )$$

$$ε : dielectric constant of organic material ( 2.655 \times {10}^{- 13} A \cdot s / V \cdot cm )$$

$$d : thickness of thin film ( cm )$$

$$V : applied voltage ( V )$$

$$μ ( E ) = {μ}_{0} exp ( β \sqrt{E} ) \qquad [ Equation 2 ]$$

$$E : electric field ( V / cm )$$

$${μ}_{o} : mobility of Poole - frenkel ( {cm}^{2} / V \cdot s )$$

$$β : constant of Poole - frenkel$$

$$Combining Equation 1 and Equation 2 above gives Equation 3 below .$$

$$ln \frac{J}{{E}^{2}} = β \sqrt{E} + ln ( \frac{9}{8} ε \frac{{μ}_{0}}{d} ) \qquad [ Equation 3 ]$$

Here, β and μ₀ can be calculated by referring to the J-V Curve since they are different for each material of an element and a configuration of an element. Therefore, by introducing the calculated β and μ₀ into Equation 2, the hole mobility (μ) can be calculated. At this time, the hole mobility for the material can be calculated by calculating the range of hole mobility for the section of the SCLC or by calculating the hole mobility (μ₀) of the zero field (i.e., the case where E is 0). In this specification, the hole mobility of the compound means the hole mobility of the zero field.

The hole mobility of a first light-emitting auxiliary layer according to the present invention is 5.1×10⁻⁵ to 1.3×10⁻³ cm/V·S, preferably, 1.6×10⁻⁴ to 1.3×10⁻³ cm/V·S.

In addition, it is preferable that the HOMO energy levels of a first light-emitting auxiliary layer and a second light-emitting auxiliary layer satisfy Equation 4 below.

HOMO_{P1}>HOMO_{P2} [Equation 4]

HOMO_{P1} is the HOMO of a first light-emitting auxiliary layer, and HOMO_{P2} is the HOMO of a second light-emitting auxiliary layer.

When the HOMO energy levels of a first emission auxiliary layer and a second emission auxiliary layer satisfy Equation 4 above, hole injection and hole transport from the hole transport layer to the host are performed well as a cascade structure. In particular, when the HOMO energy level of a second light-emitting auxiliary layer is low, hole injection into the host occurs smoothly, which may affect the increase in efficiency.

The T1 energy level of a second light-emitting auxiliary layer according to the present invention is preferably 2.3 to 3.0, for a red organic electric element, 2.3 to 2.9, preferably 2.5 to 2.8, and for a green organic electric element, 2.6 to 2.8. 2.9, preferably 2.7 to 2.9.

When the T1 energy level of a second light-emitting auxiliary layer is within the above range, triplet electrons can be effectively prevented from moving from the dopant to the hole transport layer, which can have an effect on improving the efficiency and lifespan of the element.

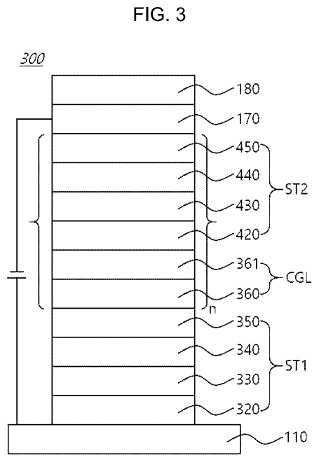

According to another embodiment of the present invention, an organic material layer may be a form consisting of multiple stacks, wherein the stacks comprise a hole transport layer, a light-emitting layer, and an electron transport layer, respectively. This will be described with reference to FIG. 3.

Referring to FIG. 3, two or more sets of stacks of the organic material layers ST1 and ST2 may be formed between the first electrode 110 and the second electrode 170 in the organic electric element 300 according to another embodiment of the present invention, wherein the organic material layers are consisted of multiple layers, respectively, and the charge generation layer CGL may be formed between the stacks of the organic material layer.

Specifically, the organic electric element according to the embodiment of the present invention may comprise a first electrode 110, a first stack ST1, a charge generation layer CGL, a second stack ST2, and a second electrode 170 and a layer for improving light efficiency 180.

The first stack ST1 is an organic layer formed on the first electrode 110, and the first stack ST1 may comprise the first hole injection layer 320, the first hole transport layer 330, a light-emitting auxiliary layer (not shown), the first light-emitting layer 340 and the first electron transport layer 350 and the second stack ST2 may comprise a second hole injection layer 420, a second hole transport layer 430, a light-emitting auxiliary layer (not shown), a second light-emitting layer 440 and a second electron transport layer 450. As such, the first stack and the second stack may be the organic layers having the same or different stacked structures.

The charge generation layer CGL may be formed between the first stack ST1 and the second stack ST2. The charge generation layer CGL may comprise a first charge generation layer 360 and a second charge generation layer 361. The charge generating layer CGL is formed between the first light-emitting layer 340 and the second light-emitting layer 440 to increase the current efficiency generated in each light-emitting layer and to smoothly distribute charges.

The first light-emitting layer 340 may comprise a light emitting material comprising a blue host doped with a blue fluorescent dopant and the second light-emitting layer 440 may comprise a light emitting material comprising a green host doped with a greenish yellow dopant and a red dopant together.

In FIG. 3, n may be an integer of 1 to 5 and the charge generation layer CGL and the third stack may be further stacked on the second stack ST2 when n is 2.

When multiple light-emitting layers are formed in a multi-layer stack structure as shown in FIG. 3, it is possible to manufacture an organic electroluminescent element that emits not only white light but also various colors, wherein the white light is emitted by the mixing effect of light emitted from each light-emitting layer.

The organic electric element according to an embodiment of the present invention may be manufactured using various deposition methods. The organic electric element according to an embodiment of the present invention may be manufactured using a PVD (physical vapor deposition) method or CVD (chemical vapor deposition) method. For example, the organic electric element may be manufactured by depositing a metal, a conductive metal oxide, or a mixture thereof on the substrate to form the anode 110, forming the organic material layer comprising the hole injection layer 120, the hole transport layer 130, the light-emitting layer 140, the electron transport layer 150, and the electron injection layer 160 thereon, and then depositing a material, which can be used as the cathode 170, thereon. Also, an emission-auxiliary layer 220 may be formed between a hole transport layer 130 and a light-emitting layer 140, and an electron transport auxiliary layer (not shown) may be further formed between a light-emitting layer 140 and an electron transport layer 150 and, as described above, a stack structure may be formed.

Also, the organic material layer may be manufactured in such a manner that the fewer layers are formed using various polymer materials by a soluble process or solvent process, for example, spin coating, nozzle printing, inkjet printing, slot coating, dip coating, roll-to-roll, doctor blading, screen printing, or thermal transfer, instead of deposition. Since the organic material layer according to the present invention may be formed in various ways, the scope of protection of the present invention is not limited by a method of forming the organic material layer.

The organic electric element according to an embodiment of the present invention may be of a top emission type, a bottom emission type, or a dual emission type depending on the material used.

In addition, the organic electric element according to an embodiment of the present invention may be selected from the group consisting of an organic electroluminescent element, an organic solar cell, an organic photo conductor, an organic transistor, an element for monochromatic illumination and an element for quantum dot display.

Another embodiment of the present invention provides an electronic device including a display device which includes the above described organic electric element, and a control unit for controlling the display device. Here, the electronic device may be a wired/wireless communication terminal which is currently used or will be used in the future, and covers all kinds of electronic devices including a mobile communication terminal such as a cellular phone, a navigation unit, a game player, various kinds of TVs, and various kinds of computers.

Hereinafter, an organic electric element according to one aspect of the present invention will be described.

An organic electric element according to one aspect of the present invention includes a first electrode, a second electrode, and an organic material layer formed between the first electrode and the second electrode, wherein the organic material layer includes a light-emitting layer, a hole transport layer formed between the light-emitting layer and the first electrode, and a plurality of light-emitting auxiliary layers formed between the hole transport layer and the light-emitting layer, and the plurality of light-emitting auxiliary layers include a first light-emitting auxiliary layer adjacent to the hole transport layer and a second light-emitting auxiliary layer adjacent to the light-emitting layer. Here, the first light-emitting auxiliary layer includes a compound represented by the following Formula 1, and the second light-emitting auxiliary layer includes a compound represented by the following Formula 2.

Hereinafter, Formula 1 and Formula 2 will be described.

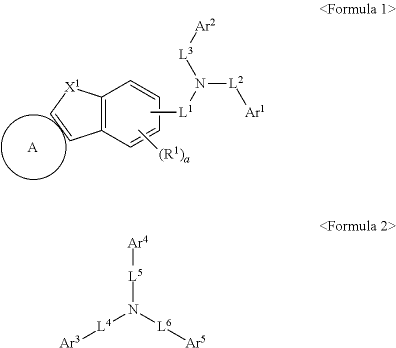

In Formulas 1 and 2, each of symbols may be defined as follows.

A ring is a C₆-C₆₀ aromatic hydrocarbon ring group, and may be substituted with the same or different R.

X¹ is O, S or C(R′)(R″).

Ar¹ to Ar⁵ are each independently selected from the group consisting of a C₆-C₆₀ aryl group, a fluorenyl group, a C₂-C₆₀ heterocyclic group containing at least one heteroatom of O, N, S, Si and P, and a C₃-C₆₀ aliphatic ring group.

L¹ to L⁶ are each independently selected from the group consisting of a single bond, a C₆-C₆₀ arylene group, a fluorenylene group, a C₂-C₆₀ heterocyclic group containing at least one heteroatom of O, N, S, Si and P, and a C₃-C₆₀ aliphatic ring group.

R¹, R, R′ and R″ are each independently selected from the group consisting of hydrogen, deuterium, halogen, a cyano group, a nitro group, a C₆-C₆₀ aryl group, a fluorenyl group, a C₂-C₆₀ heterocyclic group containing at least one heteroatom of O, N, S, Si and P, a C₃-C₆₀ aliphatic ring group, a C₁-C₂₀ alkyl group, a C₂-C₂₀ alkenyl group, a C₂-C₂₀ alkynyl group, a C₁-C₂₀ alkoxyl group, and a C₆-C₂₀ aryloxy group, and adjacent R¹s may be bonded to each other to form a ring, and R′ and R″ may be bonded to each other to form a ring.

With the proviso that when A ring is a C₆ aromatic hydrocarbon ring group, i) the A ring is substituted with R that is a substituent other than hydrogen, ii) R¹ is a substituent other than hydrogen, iii) adjacent R's form a ring, or iv) at least one of Ar¹ and Ar² is a C₃-C₆₀ aliphatic ring group when X¹ is C(R′)(R″). That is, when A ring is a C₆ aromatic hydrocarbon ring group, i) the case where both R and R¹ are hydrogen is excluded when X¹ is O or S, ii) at least one of Ar¹ and Ar² is a C₃-C₆o aliphatic ring group when X¹ is C(R′)(R″).

a is an integer of 1 to 3, and when a is an integer of 2 or more, each of R¹s is the same as or different from each other, and adjacent groups may be bonded to each other to form a ring.

When a ring is formed by adjacent R¹ groups and/or R′ and R″, the ring may be selected from the group consisting of a C₆-C₆₀ aromatic ring group, a fluorene group, a C₂-C₆₀ heterocyclic group containing at least one heteroatom of O, N, S, Si and P, and a C₃-C₆₀ aliphatic ring group.

For example, when an aromatic ring group is formed by adjacent R¹ groups and/or R′ and R″, the aromatic ring group may be a C₆-C₃₀, a C₆-C₂₀, a C₆-C₁₆, a C₆-C₁₄, a C₆-C₁₀ or a C₆ aromatic ring group, specifically, benzene, naphthalene, phenanthrene or the like.

When a ring is formed by R′ and R″, a spiro compound may be formed. For example, the spiro compound is 9,9′-spirobifluorene, spiro[benzo[b]fluorene-11,9′-fluorene], (1r,5R,7S)-spiro[adamantane-2,9′-fluorene], etc.

When at least one of Ar¹ to Ar⁵, R¹, R, R′ and R″ is an aryl group, the aryl group may be, for example, a C₆-C₃₀, a C₆-C₂₉, a C₆-C₂₈, a C₆-C₂₇, a C₆-C₂₆, a C₆-C₂₅, a C₆-C₂₄, a C₆-C₂₃, a C₆-C₂₂, a C₆-C₂₁, a C₆-C₂₀, a C₆-C₁₉, a C₆-C₁₈, a C₆-C₁₇, a C₆-C₁₆, a C₆-C₁₅, a C₆-C₁₄, a C₆-C₁₃, a C₆-C₁₂, a C₆-C₁₁, a C₆-C₁₀, a C₆, a C₁₀, a C₁₂, a C₁₃, a C₁₄, a C₁₅, a C₁₆, a C₁₇, a C₁₈, a C₁₉, a C₂₀, a C₂₁, a C₂₂, a C₂₃, a C₂₄, a C₂₅, a C₂₆, a C₂₇, a C₂₈, a C₂₉, a C₃₀ aryl group, specifically, phenyl, biphenyl, naphthyl, terphenyl, phenanthrene, triphenylene or the like.

When at least one of L¹ to L⁶ is an arylene group, the arylene group may be, for example, a C₆-C₃₀, a C₆-C₂₉, a C₆-C₂₈, a C₆-C₂₇, a C₆-C₂₆, a C₆-C₂₅, a C₆-C₂₄, a C₆-C₂₃, a C₆-C₂₂, a C₆-C₂₁, a C₆-C₂₀, a C₆-C₁₉, a C₆-C₁₈, a C₆-C₁₇, a C₆-C₁₆, a C₆-C₁₅, a C₆-C₁₄, a C₆-C₁₃, a C₆-C₁₂, a C₆-C₁₁, a C₆-C₁₀, a C₆, a C₁₀, a C₁₂, a C₁₃, a C₁₄, a C₁₅, a C₁₆, a C₁₇, a C₁₈, a C₁₉, a C₂₀, a C₂₁, a C₂₂, a C₂₃, a C₂₄, a C₂₅, a C₂₆, a C₂₇, a C₂₈, a C₂₉, a C₃₀ arylene group, specifically, phenylene, biphenyl, naphthylene, terphenyl, phenanthrene, triphenylene or the like.

When at least one of Ar¹ to Ar⁵, R¹, R, R′, R″, L¹ to L⁶ is a heterocyclic group, the heterocyclic group may be, for example, a C₂-C₃₀, a C₂-C₂₉, a C₂-C₂₈, a C₂-C₂₇, a C₂-C₂₆, a C₂-C₂₅, a C₂-C₂₄, a C₂-C₂₃, a C₂-C₂₂, a C₂-C₂₁, a C₂-C₂₀, a C₂-C₁₉, a C₂-C₁₈, a C₂-C₁₇, a C₂-C₁₆, a C₂-C₁₅, a C₂-C₁₄, a C₂-C₁₃, a C₂-C₁₂, a C₂-C₁₁, a C₂-C₁₀, a C₂-C₉, a C₂-C₈, a C₂-C₇, a C₂-C₆, a C₂-C₅, a C₂-C₄, a C₂-C₃, a C₂, a C₃, a C₄, a C₅, a C₆, a C₇, a C₈, a C₉, a C₁₀, a C₁₁, a C₁₂, a C₁₃, a C₁₄, a C₁₅, a C₁₆, a C₁₇, a C₁₈, a C₁₉, a C₂₀, a C₂₁, a C₂₂, a C₂₃, a C₂₄, a C₂₅, a C₂₆, a C₂₇, a C₂₈, a C₂₉ or C₃₀ heterocyclic group, specifically, pyridine, pyrimidine, pyrazine, pyridazine, triazine, furan, pyrrole, silole, indene, indole, phenyl-indole, benzoindole, phenyl-benzoindole, pyrazinoindol, quinoline, isoquinoline, benzoquinoline, pyridoquinoline, quinazoline, benzoquinazoline, dibenzoquinazoline, phenanthroquinazoline, quinoxaline, benzoquinoxaline, dibenzoquinoxaline, benzofuran, naphthobenzofuran, dibenzofuran, dinaphthofuran, thiophene, benzothiophene, dibenzothiophene, naphthobenzothiophene, dinaphthothiophene, carbazole, phenyl-carbazole, benzocarbazole, phenyl-benzocarbazole, naphthyl-benzocarbazole, dibenzocarbazole, indolocarbazole, benzofuropyridine, benzothienopyridine, benzofuropyridine, benzothienopyrimidine, benzofuropyrimidine, benzothienopyrazine, benzofuropyrazine, benzoimidazole, benzothiazole, benzooxazole, benzosiloe, phenanthroline, dihydro-phenylphenazine, 10-phenyl-10H-phenoxazine, phenoxazine, phenothiazine, dibenzodioxin, benzodibenzodioxin, thianthrene, 9,9-dimethyl-9H-xantene, 9,9-dimethyl-9H-thioxantene, dihydrodimethylphenylacridine, spiro[fluorene-9,9′-xanthene] and the like.

When at least one of Ar¹ to Ar⁵, R¹, R, R′ and R″ is a fluorenyl group or at least one of L¹ to L⁶ is a fluorenylene group, the fluorenyl group or the fluorenylene group may be, for example, 9,9-dimethyl-9H-fluorene, 9,9-diphenyl-9H-fluorene, 9,9′-spirobifluorene, spiro[benzo[b]fluorene-11,9′-fluorene], benzo[b]fluorene, 11,11-diphenyl-11H-benzo[b]fluorene, 9-(naphthalen-2-yl)9-phenyl-9H-fluorene, (1r,5R,7S)-spiro[adamantane-2,9′-fluorene] and the like.

When at least one of Ar¹ to Ar⁵, R¹, R, R′, R″, L¹ to L⁶ is an aliphatic ring group, the aliphatic ring group may be, for example, a C₃-C₃₀, a C₃-C₂₉, a C₃-C₂₈, a C₃-C₂₇, a C₃-C₂₆, a C₃-C₂₅, a C₃-C₂₄, a C₃-C₂₃, a C₃-C₂₂, a C₃-C₂₁, a C₃-C₂₀, a C₃-C₁₉, a C₃-C₁₈, a C₃-C₁₇, a C₃-C₁₆, a C₃-C₁₅, a C₃-C₁₄, a C₃-C₁₃, a C₃-C₁₂, a C₃-C₁₁, a C₃-C₁₀, a C₃, a C₄, a C₅, a C₆, a C₇, a C₈, a C₉, a C₁₀, a C₁₁, a C₁₂, a C₁₃, a C₁₄, a C₁₅, a C₁₆, a C₁₇, a C₁₈, a C₁₉, a C₂₀, a C₂₁, a C₂₂, a C₂₃, a C₂₄, a C₂₅, a C₂₆, a C₂₇, a C₂₈, a C₂₉ or a C₃₀ aliphatic ring group, specifically, cyclohexyl group, norbornyl group, adamantyl group, etc.

When at least one of R¹, R, R′ and R″ is an alkyl group, the alkyl group may be, for example, a C₁-C₂₀, a C₁-C₁₀, a C₁-C₄, a C₁, a C₂, a C₃ and a C₄ alkyl group, specifically, methyl, ethyl, propyl, butyl, t-butyl, etc.

The aryl group, the arylene group, the fluorenyl group, the fluorenylene group, the heterocyclic group, the aliphatic ring group, the alkyl group, the alkenyl group, the alkynyl group, the alkoxyl group, the aryloxyl group, and the ring formed by adjacent groups may be each optionally substituted with one or more substituents selected from the group consisting of deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and -L′-N(Rₐ)(R_{b}).

L′ is selected from the group consisting of a single bond, a C₆-C₃₀ arylene group, a fluorenylene group, a C₂-C₃₀ heterocyclic group containing at least one heteroatom of O, N, S, Si and P, and a C₃-C₃₀ aliphatic ring group.

Rₐ and R_{b} are each independently selected from the group consisting of a C₆-C₃₀ aryl group, a fluorenyl group, a C₂-C₃₀ heterocyclic group containing at least one heteroatom of O, N, S, Si and P, and a C₃-C₃₀ aliphatic ring group.

When at least one of the aryl group, the fluorenyl group, the heterocyclic group, the aliphatic ring group, the aromatic ring group, the fluorene group, the alkyl group, the alkenyl group, the alkynyl group, the alkoxyl group, the aryloxyl group, the arylene group, the fluorenylene group, and the ring formed by adjacent groups is substituted with an aryl group or when at least one of Rₐ and R_{b} is an aryl group, the aryl group may be, for example, a C₆-C₃₀, a C₆-C₂₉, a C₆-C₂₈, a C₆-C₂₇, a C₆-C₂₆, a C₆-C₂₅, a C₆-C₂₄, a C₆-C₂₃, a C₆-C₂₂, a C₆-C₂₁, a C₆-C₂₀, a C₆-C₁₉, a C₆-C₁₈, a C₆-C₁₇, a C₆-C₁₆, a C₆-C₁₅, a C₆-C₁₄, a C₆-C₁₃, a C₆-C₁₂, a C₆-C₁₁, a C₆-C₁₀, a C₆, a C₁₀, a C₁₂, a C₁₃, a C₁₄, a C₁₅, a C₁₆, a C₁₇, a C₁₈, a C₁₉, a C₂₀, a C₂₁, a C₂₂, a C₂₃, a C₂₄, a C₂₅, a C₂₆, a C₂₇, a C₂₈, a C₂₉, a C₃₀ aryl group.

When L′ is an arylene group, the arylene group may be, for example, a C₆-C₃₀, a C₆-C₂₉, a C₆-C₂₈, a C₆-C₂₇, a C₆-C₂₆, a C₆-C₂₅, a C₆-C₂₄, a C₆-C₂₃, a C₆-C₂₂, a C₆-C₂₁, a C₆-C₂₀, a C₆-C₁₉, a C₆-C₁₈, a C₆-C₁₇, a C₆-C₁₆, a C₆-C₁₅, a C₆-C₁₄, a C₆-C₁₃, a C₆-C₁₂, a C₆-C₁₁, a C₆-C₁₀, a C₆, a C₁₀, a C₁₂, a C₁₃, a C₁₄, a C₁₅, a C₁₆, a C₁₇, a C₁₈, a C₁₉, a C₂₀, a C₂₁, a C₂₂, a C₂₃, a C₂₄, a C₂₅, a C₂₆, a C₂₇, a C₂₈, a C₂₉, a C₃₀ arylene group.

When at least one of the aryl group, the fluorenyl group, the heterocyclic group, the aliphatic ring group, the aromatic ring group, the fluorene group, the alkyl group, the alkenyl group, the alkynyl group, the alkoxyl group, the aryloxyl group, the arylene group, the fluorenylene group, and the ring formed by adjacent groups is substituted with a heterocyclic group, or when at least one of Rₐ, R_{b} and L′ is a heterocyclic group, the heterocyclic group may be, for example, a C₂-C₃₀, a C₂-C₂₉, a C₂-C₂₈, a C₂-C₂₇, a C₂-C₂₆, a C₂-C₂₅, a C₂-C₂₄, a C₂-C₂₃, a C₂-C₂₂, a C₂-C₂₁, a C₂-C₂₀, a C₂-C₁₉, a C₂-C₁₈, a C₂-C₁₇, a C₂-C₁₆, a C₂-C₁₅, a C₂-C₁₄, a C₂-C₁₃, a C₂-C₁₂, a C₂-C₁₁, a C₂-C₁₀, a C₂-C₉, a C₂-C₈, a C₂-C₇, a C₂-C₆, a C₂-C₅, a C₂-C₄, a C₂-C₃, a C₂, a C₃, a C₄, a C₅, a C₆, a C₇, a C₈, a C₉, a C₁₀, a C₁₁, a C₁₂, a C₁₃, a C₁₄, a C₁₅, a C₁₆, a C₁₇, a C₁₈, a C₁₉, a C₂₀, a C₂₁, a C₂₂, a C₂₃, a C₂₄, a C₂₅, a C₂₆, a C₂₇, a C₂₈, a C₂₉ or a C₃₀ heterocyclic group.

When at least one of the aryl group, the fluorenyl group, the heterocyclic group, the aliphatic ring group, the aromatic ring group, the fluorene group, the alkyl group, the alkenyl group, the alkynyl group, the alkoxyl group, the aryloxyl group, the arylene group, the fluorenylene group, and the ring formed by adjacent groups is substituted with a fluorenyl group or when at least one of Rₐ and R_{b} is a fluorenyl group or when L′ is a fluorenylene group, the fluorenyl group or the fluorenylene group may be, for example, 9,9-dimethyl-9H-fluorene, 9,9-diphenyl-9H-fluorene, 9,9′-spirobifluorene, spiro[benzo[b]fluorene-11,9′-fluorene], benzo[b]fluorene, 11,11-diphenyl-11H-benzo[b]fluorene, 9-(naphthalen-2-yl)9-phenyl-9H-fluorene, (1r,5R,7S)-spiro[adamantane-2,9′-fluorene], etc.

When at least one of the aryl group, the fluorenyl group, the heterocyclic group, the aliphatic ring group, the aromatic ring group, the fluorene group, the alkyl group, the alkenyl group, the alkynyl group, the alkoxyl group, the aryloxyl group, the arylene group, the fluorenylene group, and the ring formed by adjacent groups is substituted with an alkyl group, the alkyl group may be, for example, a C₁-C₂₀, a C₁-C₁₀, a C₁-C₄, a C₁, a C₂, a C₃, a C₄ alkyl group.

When at least one of the aryl group, the fluorenyl group, the heterocyclic group, the aliphatic ring group, the aromatic ring group, the fluorene group, the alkyl group, the alkenyl group, the alkynyl group, the alkoxyl group, the aryloxyl group, the arylene group, the fluorenylene group, and the ring formed by adjacent groups is substituted with an aryloxyl group, the aryloxyl group may be, for example, a C₆-C₃₀, a C₆-C₂₉, a C₆-C₂₈, a C₆-C₂₇, a C₆-C₂₆, a C₆-C₂₅, a C₆-C₂₄, a C₆-C₂₃, a C₆-C₂₂, a C₆-C₂₁, a C₆-C₂₀, a C₆-C₁₉, a C₆-C₁₈, a C₆-C₁₇, a C₆-C₁₆, a C₆-C₁₅, a C₆-C₁₄, a C₆-C₁₃, a C₆-C₁₂, a C₆-C₁₁, a C₆-C₁₀, a C₆, a C₁₀, a C₁₂, a C₁₃, a C₁₄, a C₁₅, a C₁₆, a C₁₇, a C₁₈, a C₁₉, a C₂₀, a C₂₁, a C₂₂, a C₂₃, a C₂₄, a C₂₅, a C₂₆, a C₂₇, a C₂₈, a C₂₉, a C₃₀ aryloxy group.

When at least one of the aryl group, the fluorenyl group, the heterocyclic group, the aliphatic ring group, the aromatic ring group, the fluorene group, the alkyl group, the alkenyl group, the alkynyl group, the alkoxyl group, the aryloxyl group, the arylene group, the fluorenylene group, and the ring formed by adjacent groups is substituted with an aliphatic ring group, the aliphatic ring group may be, for example, a C₃-C₃₀, a C₃-C₂₉, a C₃-C₂₈, a C₃-C₂₇, a C₃-C₂₆, a C₃-C₂₅, a C₃-C₂₄, a C₃-C₂₃, a C₃-C₂₂, a C₃-C₂₁, a C₃-C₂₀, a C₃-C₁₉, a C₃-C₁₈, a C₃-C₁₇, a C₃-C₁₆, a C₃-C₁₅, a C₃-C₁₄, a C₃-C₁₃, a C₃-C₁₂, a C₃-C₁₁, a C₃-C₁₀, a C₃, a C₄, a C₅, a C₆, a C₇, a C₈, a C₉, a C₁₀, a C₁₁, a C₁₂, a C₁₃, a C₁₄, a C₁₅, a C₁₆, a C₁₇, a C₁₈, a C₁₉, a C₂₀, a C₂₁, a C₂₂, a C₂₃, a C₂₄, a C₂₅, a C₂₆, a C₂₇, a C₂₈, a C₂₉ or a C₃₀ aliphatic ring group, specifically, cyclohexyl group, norbornyl group, adamantyl group, etc.

Ring A of Formula 1 may be one of the following Formulas A-1 to A-3.

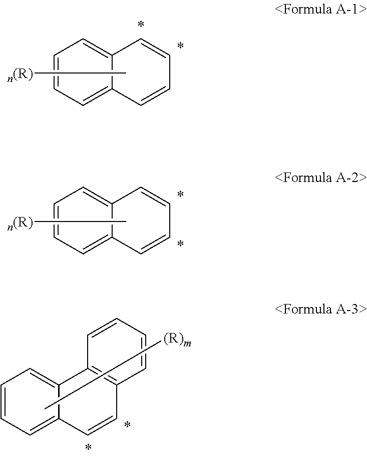

In Formula A-1 to Formula A-3, R is the same as defined for Formula 1, n is an integer of 0 to 6, m is an integer of 0 to 8, and when each of these is an integer of 2 or more, each of R is the same as or different from each other, and adjacent R may be bonded to each other to form a ring. * indicates the fused position.

When adjacent R groups are linked to each other to form a ring, the ring may be selected from the group consisting of a C₆-C₆₀ aromatic ring group, a fluorene group, a C₂-C₆₀ heterocyclic group containing at least one heteroatom selected from the group consisting of O, N, S, Si and P, and a C₃-C₆₀ aliphatic ring.

For example, when an aromatic ring is formed by adjacent R groups, the aromatic ring may be, for example, a C₆-C₃₀, a C₆-C₂₀, a C₆-C₁₆, a C₆-C₁₄, a C₆-C₁₀, or a C₆ aromatic ring, specifically, it may be an aromatic ring such as benzene, naphthalene, phenanthrene, etc.

Ar¹ in Formula 1 may be represented by the following Formula a.

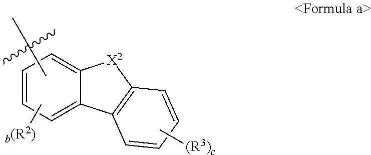

In Formula a, each of symbols may be defined as follows.

X² is O, S or C(R_{c})(R_{d}).

R², R³, R_{c} and R_{d} are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, and a C₃-C₃₀ aliphatic ring group, and adjacent groups may be bonded to each other to form a ring, R_{c} and R_{d} may be bonded to each other to form a ring.

b is an integer of 0 to 3, c is an integer of 0 to 4, and when each of these is an integer of 2 or more, each of R², each of R³ are the same as or different from each other.

The adjacent groups may be at least one pair of adjacent groups among adjacent R² groups and adjacent R³ groups, and when adjacent groups are linked to each other to form a ring, the ring may be selected from the group consisting of a C₆-C₆₀ aromatic ring group, a fluorene group, a C₂-C₆₀ heterocyclic group containing at least one heteroatom selected from the group consisting of O, N, S, Si and P, and a C₃-C₆₀ aliphatic ring.

For example, when an aromatic ring is formed by adjacent R² groups and/or adjacent R³ groups, the aromatic ring may be, for example, a C₆-C₃₀, a C₆-C₂₀, a C₆-C₁₆, a C₆-C₁₄, a C₆-C₁₀, or a C₆ aromatic ring, specifically, it may be an aromatic ring such as benzene, naphthalene, phenanthrene, etc.

When R_{c} and R_{d} are linked to each other to form a ring, the ring may be selected from the group consisting of a C₆-C₆₀ aromatic ring group, a fluorene group, a C₂-C₆₀ heterocyclic group containing at least one heteroatom selected from the group consisting of O, N, S, Si and P, and a C₃-C₆₀ aliphatic ring.

When R_{c} and R_{d} are linked to each other to form a ring, a spiro compound can be formed. For example, the spiro compound may be 9,9′-spirobifluorene, spiro[benzo[b]fluorene-11, 9′-fluorene], (1r,5R,7S)-spiro[adamantane-2,9′-fluorene], etc.

The Formula a may be one of the following Formula a-1 to Formula a-4.

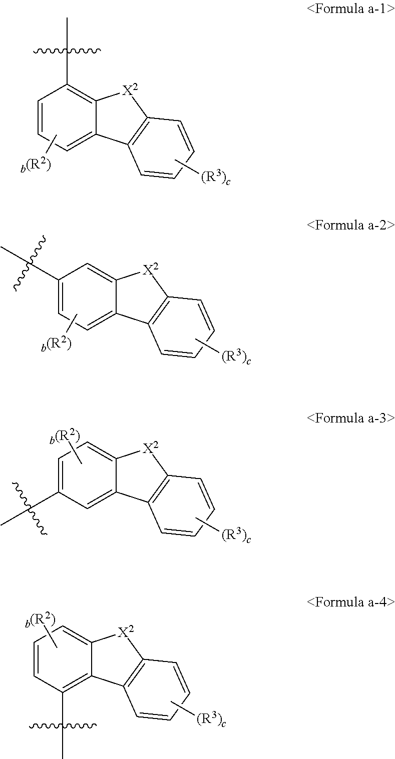

In Formula a-1 to Formula a-4, X², R², R³, b and c are the same as defined for Formula a.

Formula 1 may be represented by one of the following Formula 1-1 to Formula 1-17.

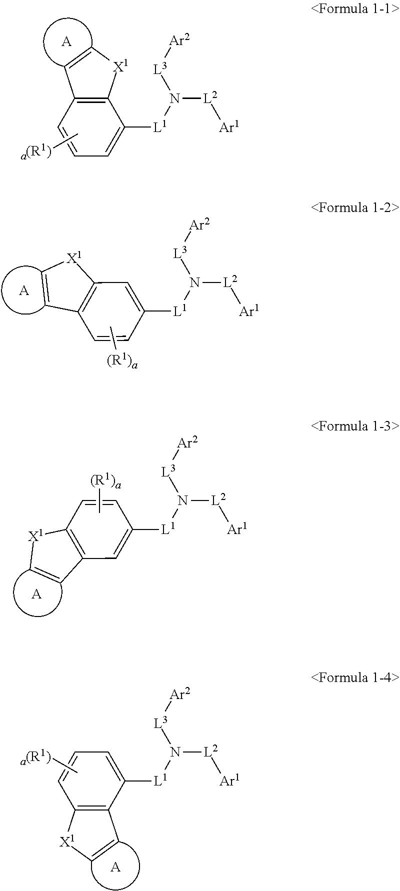

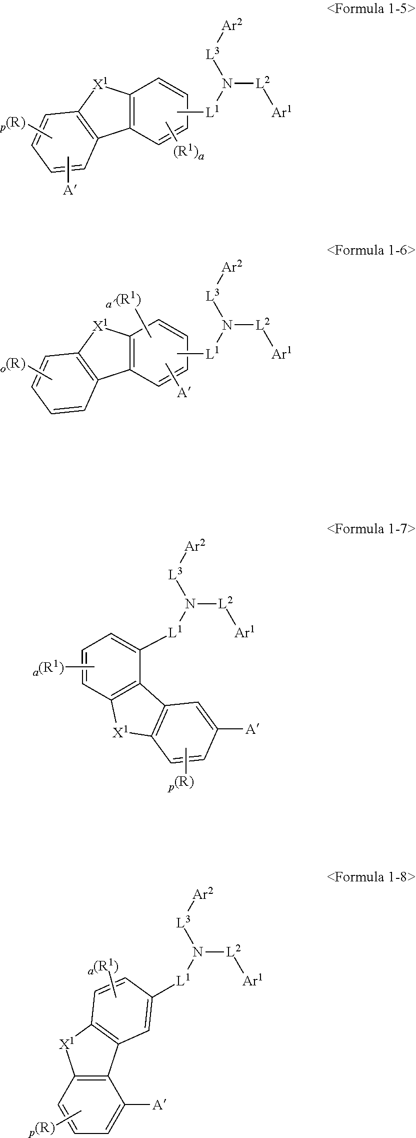

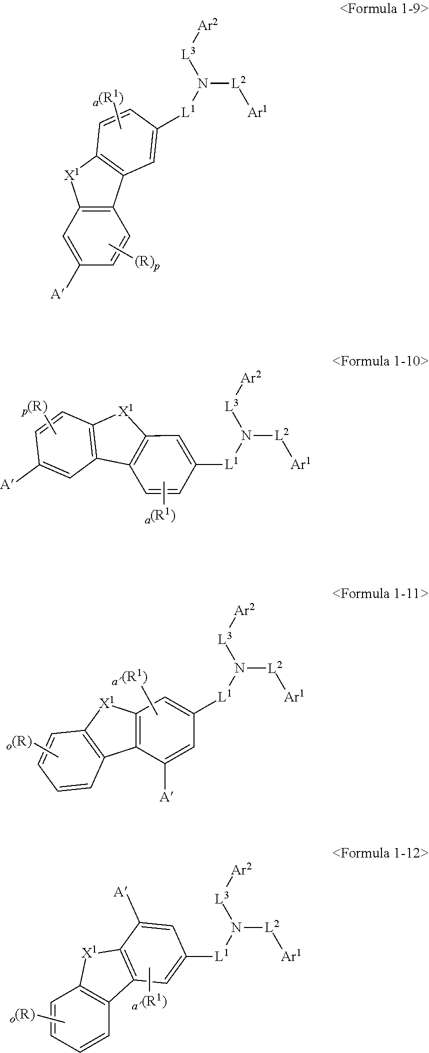

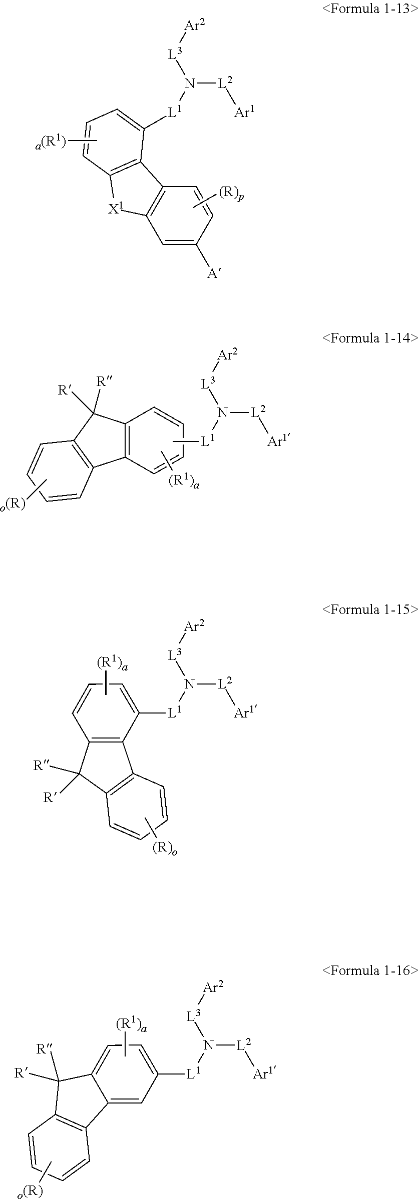

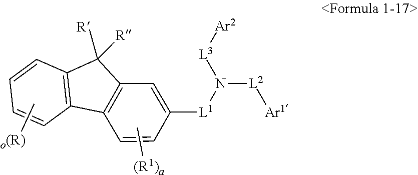

In Formula 1-1 to Formula 1-17, A ring, X¹, R, R¹, L¹-L³, Ar¹, Ar², R′, R″ and a are the same as defined for Formula 1.

A′ is selected from the group consisting of a C₁-C₂₀ alkyl group, a C₂-C₂₀ alkenyl group, a C₆-C₆₀ aryl group, a fluorenyl group, a C₂-C₆₀ heterocyclic group comprising at least one heteroatom selected from the group consisting of O, N, S, Si and P, and a C₃-C₆₀ aliphatic ring group, and Ar^{1′} is a C₃-C₆₀ aliphatic ring group.

p is an integer of 0 to 3, a′ is an integer of 0 to 2, o is an integer of 0 to 4, and when each of these is an integer of 2 or more, each of R, each of R¹ are the same as or different from each other, and adjacent groups may be bonded to each other to form a ring.

In Formula 1-5 to Formula 1-12, A′ may be represented by the following Formula A′-1 to Formula A′-5.

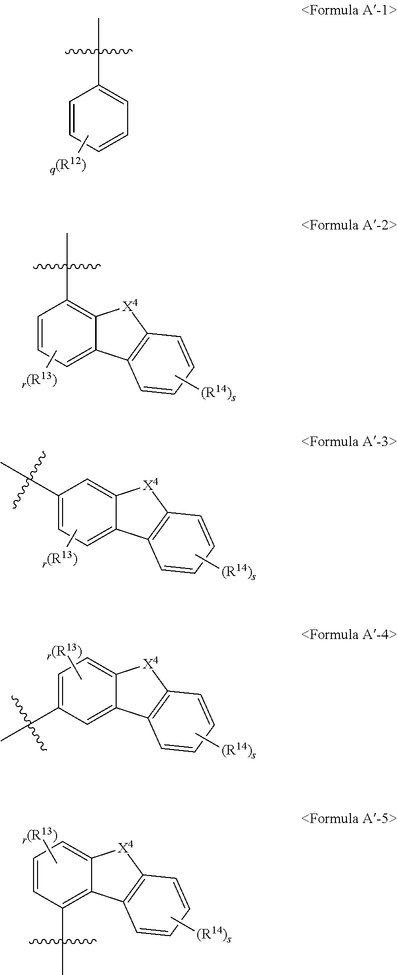

In Formula A′-1 to Formula A′-5, each of symbols may be defined as follows.

X⁴ is O or S.

R¹² to R¹⁴ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and adjacent groups may be bonded to each other to form a ring.

r is an integer of 0 to 3, s is an integer of 0 to 4, q is an integer of 0 to 5, and when each of these is an integer of 2 or more, each of R¹², each of R¹³, each of R¹⁴ are the same as or different from each other, and adjacent groups may be bonded to each other to form a ring.

When adjacent R¹² groups, adjacent R¹³ groups, adjacent R¹⁴ groups are linked to each other to form a ring, the ring may be selected from the group consisting of a C₆-C₆₀ aromatic ring group, a fluorene group, a C₂-C₆₀ heterocyclic group containing at least one heteroatom selected from the group consisting of O, N, S, Si and P, and a C₃-C₆₀ aliphatic ring. For example, when an aromatic ring is formed by adjacent groups, the aromatic ring may be, for example, a C₆-C₃₀, a C₆-C₂₀, a C₆-C₁₆, a C₆-C₁₄, a C₆-C₁₀, or a C₆ aromatic ring, specifically, it may be an aromatic ring such as benzene, naphthalene, phenanthrene, etc.

In Formula 1-14 to Formula 1-17, Ar^{1′} may be one of the following Formula Ar-1 to Formula Ar-7.

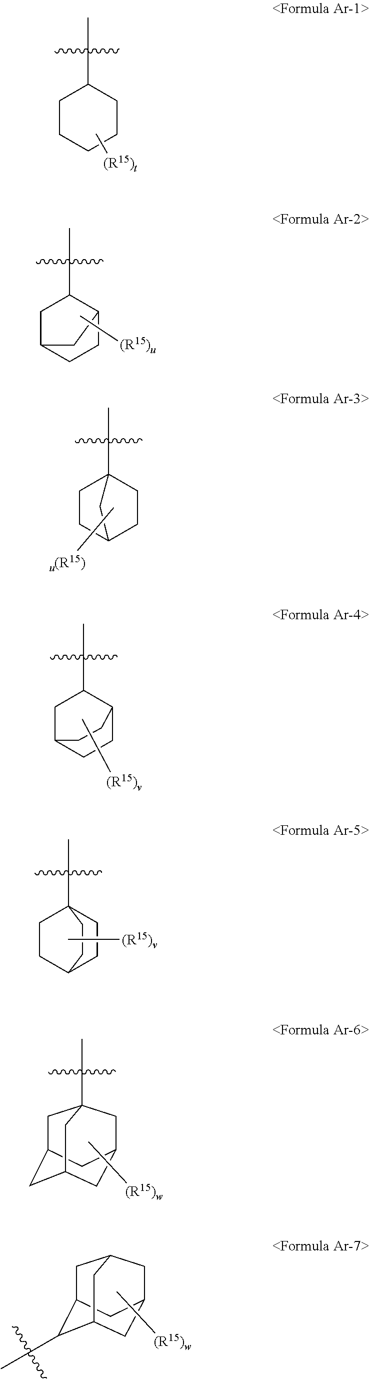

In Formula Ar-1 to Formula Ar-7, R¹⁵ is selected from the group consisting of deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and -L′-N(Rₐ)(R_{b}), t and u are each an integer of 0 to 11, v is an integer of 0 to 13, w is an integer of 0 to 15, and when each of these is an integer of 2 or more, each of R¹⁵ are the same as or different from each other, and adjacent groups may be bonded to each other to form a ring.

Ar³ in the Formula 2 may be represented by one of the following b to Formula d.

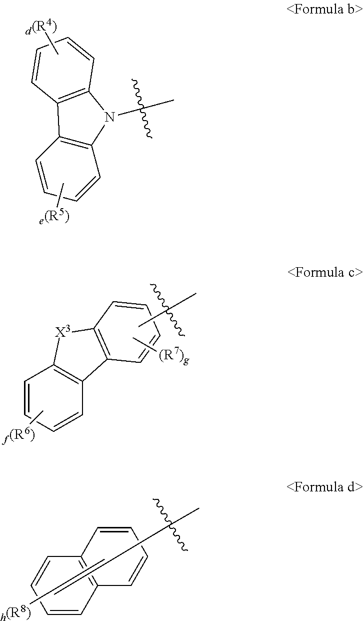

In Formula b to Formula d, each of symbols may be defined as follows.

X³ is O or S.

R⁴ to R⁸ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and -L′-N(Rₐ)(R_{b}), and adjacent groups may be bonded to each other to form a ring, and L′, Rₐ and R_{b} are the same as defined for Formula 2.

d, e and f are each an integer of 0 to 4, g is an integer of 0 to 3, h is an integer of 0 to 7, and when each of these is an integer of 2 or more, each of R⁴, each of R⁵, each of R⁶, each of R⁷, each of R⁸ are the same as or different from each other.

When adjacent R⁴ groups, adjacent R⁵ groups, adjacent R⁶ groups, adjacent R⁷ groups, adjacent R^{a} groups are linked to each other to form a ring, the ring may be selected from the group consisting of a C₆-C₆₀ aromatic ring group, a fluorene group, a C₂-C₆₀ heterocyclic group containing at least one heteroatom selected from the group consisting of O, N, S, Si and P, and a C₃-C₆₀ aliphatic ring.

For example, when an aromatic ring is formed by adjacent groups, the aromatic ring may be, for example, a C₆-C₃₀, a C₆-C₂₀, a C₆-C₁₆, a C₆-C₁₄, a C₆-C₁₀, or a C₆ aromatic ring, specifically, it may be an aromatic ring such as benzene, naphthalene, phenanthrene, etc.

Formula c may be one of the following Formula c-1 to Formula c-4.

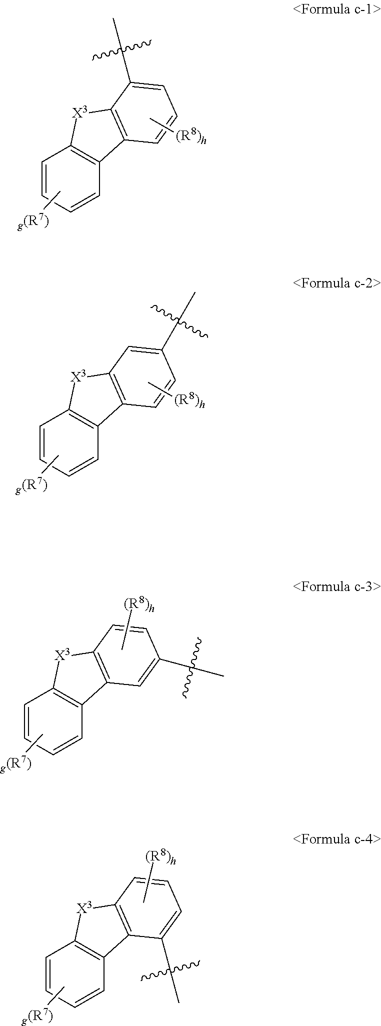

In Formula c-1 to Formula c-4, X³, R⁷, R⁸, g and h are the same as defined for Formula c.

Formula 2 may be represented by one of the following Formulas 2-1 to 2-5.

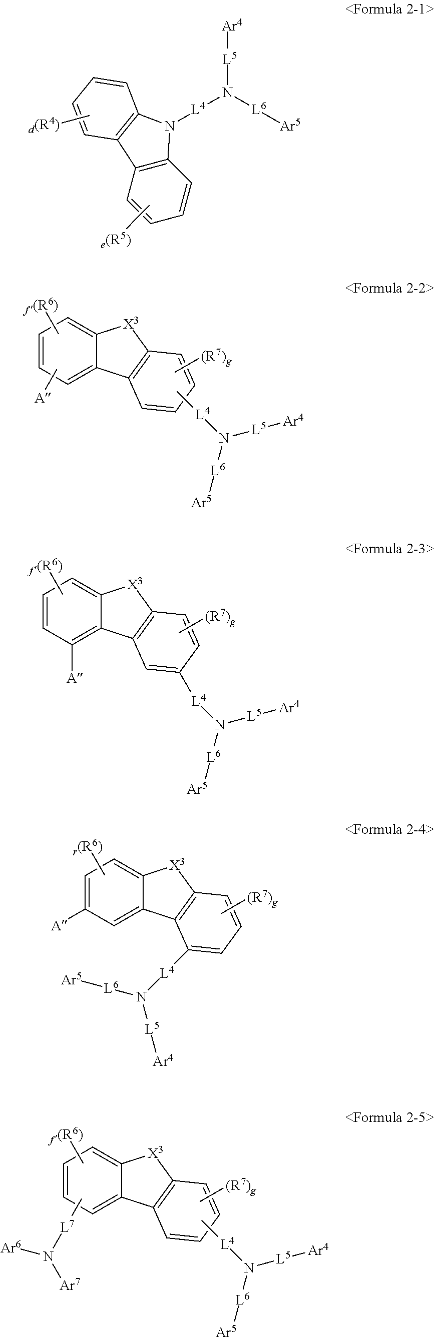

In Formulas 2-1 to 2-5, each of symbols may be defined as follows.

L⁴ to L⁶, Ar⁴ and Ar⁵ are the same as defined for Formula 2, X³ is O or S.

R⁴ to R⁷ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and -L′-N(Rₐ)(R_{b}), and adjacent groups may be bonded to each other to form a ring, and L′, Rₐ and R_{b} are the same as defined for Formula 2.

d and e are each an integer of 0 to 4, f′ is an integer of 0 to 3, and when each of these is an integer of 2 or more, each of R⁴, each of R⁵, each of R⁶, each of R⁷ are the same as or different from each other, and adjacent groups may be bonded to each other to form a ring.

When adjacent R⁴ groups, adjacent R⁵ groups, adjacent R⁶ groups, adjacent R⁷ groups are linked to each other to form a ring, the ring may be selected from the group consisting of a C₆-C₆₀ aromatic ring group, a fluorene group, a C₂-C₆₀ heterocyclic group containing at least one heteroatom selected from the group consisting of O, N, S, Si and P, and a C₃-C₆₀ aliphatic ring.

For example, when an aromatic ring is formed by adjacent groups, the aromatic ring may be, for example, a C₆-C₃₀, a C₆-C₂₀, a C₆-C₁₆, a C₆-C₁₄, a C₆-C₁₀, or a C₆ aromatic ring, specifically, it may be an aromatic ring such as benzene, naphthalene, phenanthrene, etc.

A″ is selected from the group consisting of a C₁-C₂₀ alkyl group, a C₂-C₂₀ alkenyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and -L′-N(Rₐ)(R_{b}), and wherein L′, Rₐ and R_{b} are the same as defined for Formula 2.

At least one of the L¹ to L⁶ may be one of the following Formula L-1 to Formula L-12.

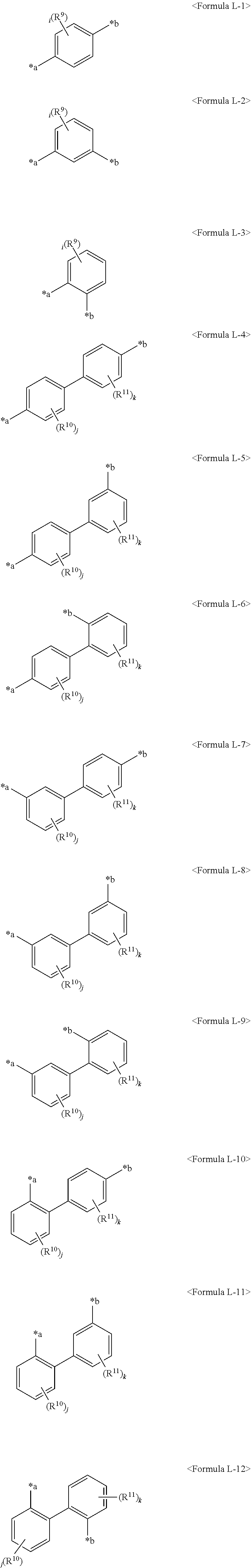

In Formula L-1 to Formula L-12, each of symbols may be defined as follows.

R⁹ to R¹¹ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and -L′-N(Rₐ)(R_{b}), and adjacent groups may be bonded to each other to form a ring, and L′, Rₐ and R_{b} are the same as defined for Formula 1 and Formula 2.

i, j and k are each an integer of 0 to 4, and when each of these is an integer of 2 or more, each of R⁹, each of R¹⁰, each of R¹¹ are the same as or different from each other, and adjacent groups may be bonded to each other to form a ring.

The ‘adjacent groups’ may be, for example, adjacent R⁹ groups, adjacent R¹⁰ groups, adjacent R¹¹ groups, and when at least one pair of adjacent groups are linked to each other to form a ring, the ring may be selected from the group consisting of a C₆-C₆₀ aromatic ring group, a fluorene group, a C₂-C₆₀ heterocyclic group containing at least one heteroatom selected from the group consisting of O, N, S, Si and P, and a C₃-C₆₀ aliphatic ring.

When an aromatic ring is formed by adjacent groups, the aromatic ring may be, for example, a C₆-C₃₀, a C₆-C₂₀, a C₆-C₁₆, a C₆-C₁₄, a C₆-C₁₀, or a C₆ aromatic ring, specifically, it may be an aromatic ring such as benzene, naphthalene, phenanthrene, etc.

*a and *b indicate the bonding positions. L¹ is a linker that connects N of the amine group and a benzene ring to which R¹ is bonded, L² to L⁶ are linkers that connect an amine group and one of Ar¹ to Ar⁵, and *a represents the position connected to the nitrogen of the amine group, and *b represents the position connected to the other side.

Therefore, when L¹ is one of the above Formula L-1 to formula L-12, *a represents the position bonded to the nitrogen of the amine group, and *b represents the position bonded to the benzene ring to which R¹ is bonded, and when at least one of L² to L⁶ is one of Formula L-1 to Formula L-12, *a represents the position bonded to the nitrogen of the amine group, and *b represents the position bonded to Ar¹ to Ar⁵.

Specifically, the compound represented by Formula 1 may be one of the following compounds, but there is no limitation thereto.

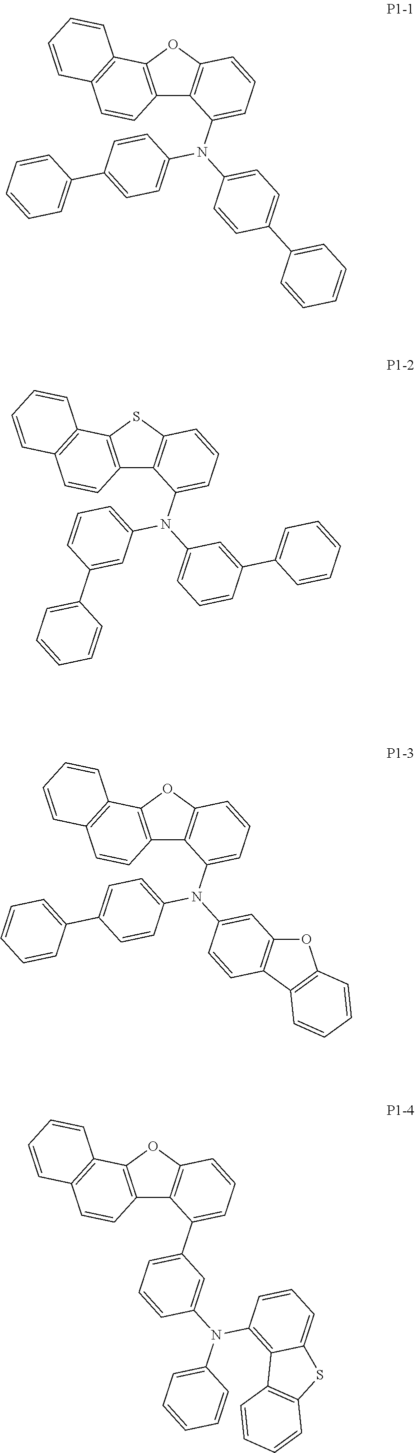 [SMILES: c1ccc(-c2ccc(N(c3ccc(-c4ccccc4)cc3)c3cccc4oc5c6ccccc6ccc5c34)cc2)cc1 ; c1ccc(-c2cccc(N(c3cccc(-c4ccccc4)c3)c3cccc4sc5c6ccccc6ccc5c34)c2)cc1 ; c1ccc(-c2ccc(N(c3ccc4c(c3)oc3ccccc34)c3cccc4oc5c6ccccc6ccc5c34)cc2)cc1 ; c1ccc(N(c2cccc(-c3cccc4oc5c6ccccc6ccc5c34)c2)c2cccc3sc4ccccc4c23)cc1]

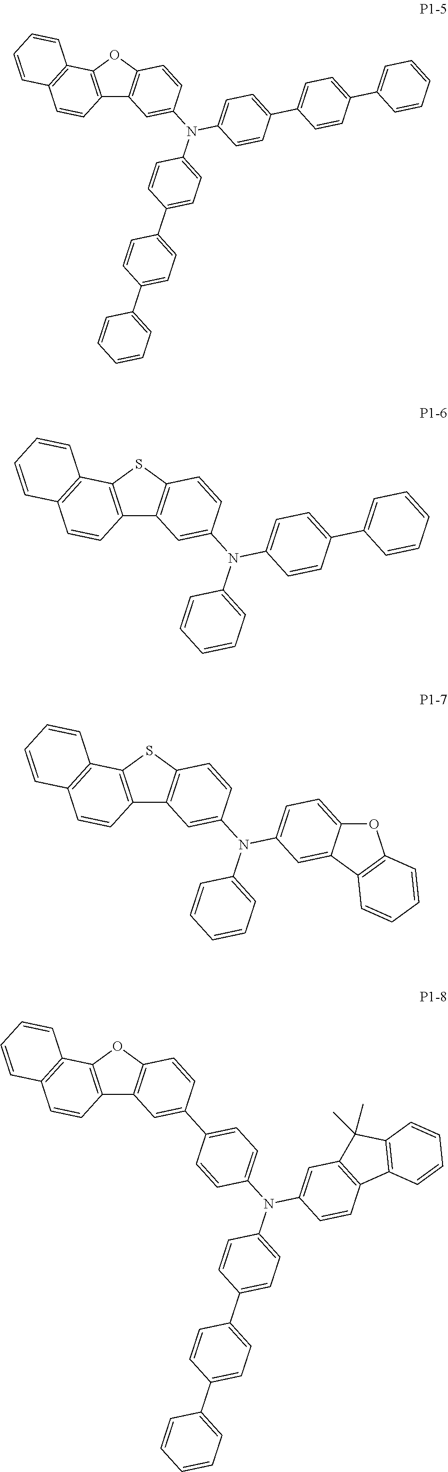 [SMILES: c1ccc(-c2ccc(-c3ccc(N(c4ccc(-c5ccc(-c6ccccc6)cc5)cc4)c4ccc5oc6c7ccccc7ccc6c5c4)cc3)cc2)cc1 ; c1ccc(-c2ccc(N(c3ccccc3)c3ccc4sc5c6ccccc6ccc5c4c3)cc2)cc1 ; c1ccc(N(c2ccc3oc4ccccc4c3c2)c2ccc3sc4c5ccccc5ccc4c3c2)cc1 ; CC1(C)c2ccccc2-c2ccc(N(c3ccc(-c4ccc(-c5ccccc5)cc4)cc3)c3ccc(-c4ccc5oc6c7ccccc7ccc6c5c4)cc3)cc21]

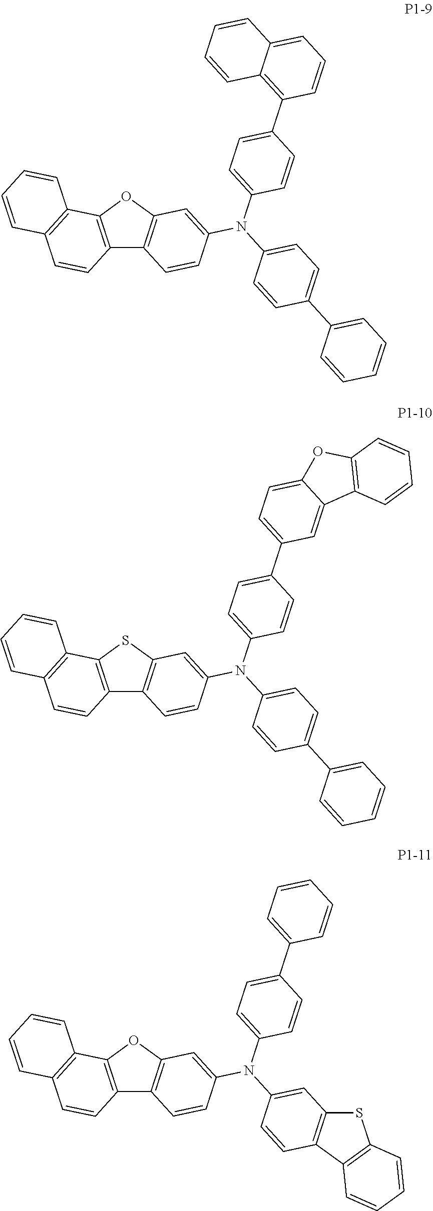 [SMILES: c1ccc(-c2ccc(N(c3ccc(-c4cccc5ccccc45)cc3)c3ccc4c(c3)oc3c5ccccc5ccc43)cc2)cc1 ; c1ccc(-c2ccc(N(c3ccc(-c4ccc5oc6ccccc6c5c4)cc3)c3ccc4c(c3)sc3c5ccccc5ccc43)cc2)cc1 ; c1ccc(-c2ccc(N(c3ccc4c(c3)oc3c5ccccc5ccc43)c3ccc4c(c3)sc3ccccc34)cc2)cc1]

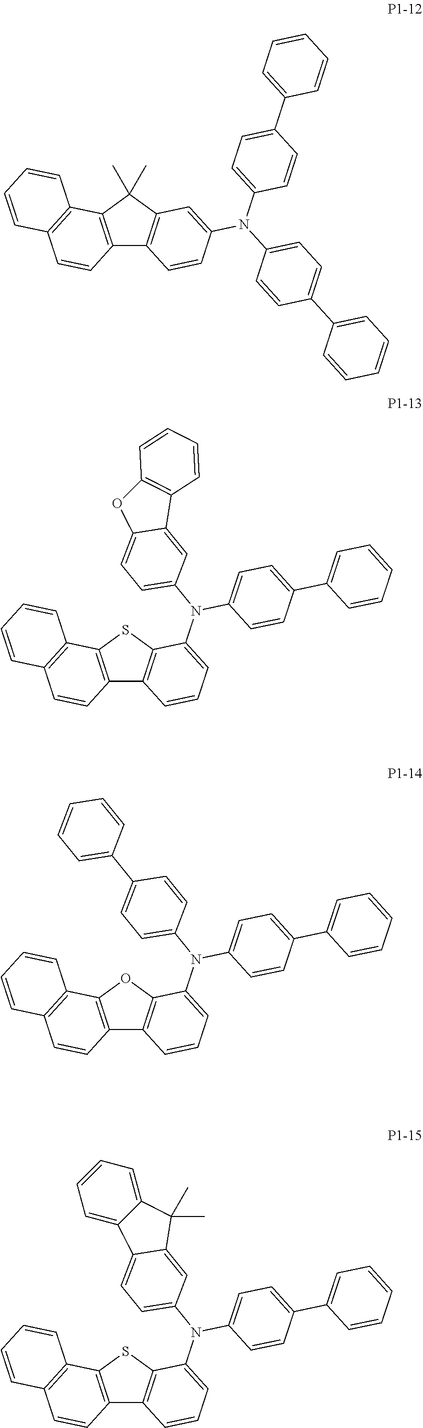 [SMILES: CC1(C)c2cc(N(c3ccc(-c4ccccc4)cc3)c3ccc(-c4ccccc4)cc3)ccc2-c2ccc3ccccc3c21 ; c1ccc(-c2ccc(N(c3ccc4oc5ccccc5c4c3)c3cccc4c3sc3c5ccccc5ccc43)cc2)cc1 ; c1ccc(-c2ccc(N(c3ccc(-c4ccccc4)cc3)c3cccc4c3oc3c5ccccc5ccc43)cc2)cc1 ; CC1(C)c2ccccc2-c2ccc(N(c3ccc(-c4ccccc4)cc3)c3cccc4c3sc3c5ccccc5ccc43)cc21]

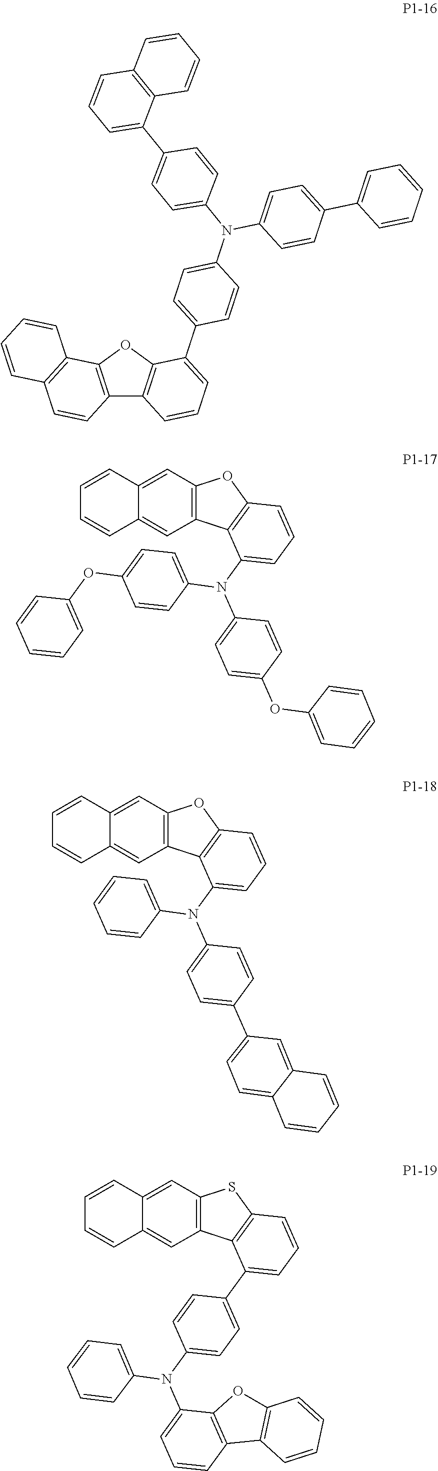 [SMILES: c1ccc(-c2ccc(N(c3ccc(-c4cccc5ccccc45)cc3)c3ccc(-c4cccc5c4oc4c6ccccc6ccc54)cc3)cc2)cc1 ; c1ccc(Oc2ccc(N(c3ccc(Oc4ccccc4)cc3)c3cccc4oc5cc6ccccc6cc5c34)cc2)cc1 ; c1ccc(N(c2ccc(-c3ccc4ccccc4c3)cc2)c2cccc3oc4cc5ccccc5cc4c23)cc1 ; c1ccc(N(c2ccc(-c3cccc4sc5cc6ccccc6cc5c34)cc2)c2cccc3c2oc2ccccc23)cc1]

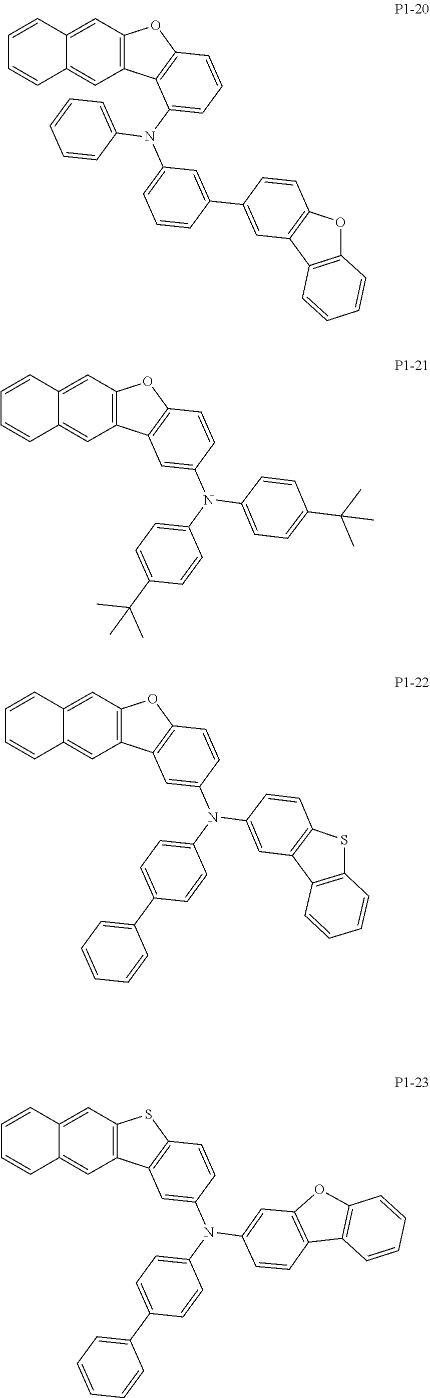 [SMILES: c1ccc(N(c2cccc(-c3ccc4oc5ccccc5c4c3)c2)c2cccc3oc4cc5ccccc5cc4c23)cc1 ; CC(C)(C)c1ccc(N(c2ccc(C(C)(C)C)cc2)c2ccc3oc4cc5ccccc5cc4c3c2)cc1 ; c1ccc(-c2ccc(N(c3ccc4oc5cc6ccccc6cc5c4c3)c3ccc4sc5ccccc5c4c3)cc2)cc1 ; c1ccc(-c2ccc(N(c3ccc4c(c3)oc3ccccc34)c3ccc4sc5cc6ccccc6cc5c4c3)cc2)cc1]

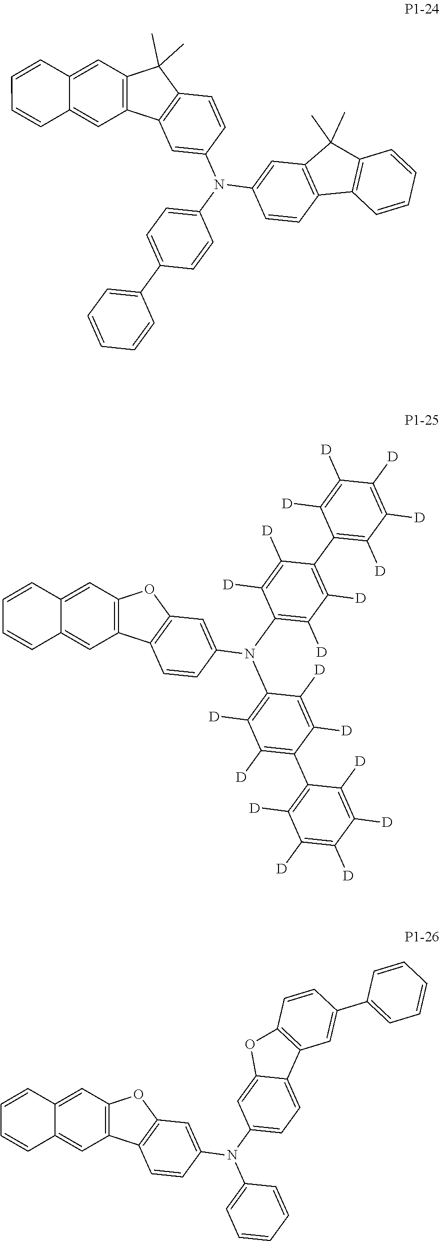 [SMILES: CC1(C)c2ccccc2-c2ccc(N(c3ccc(-c4ccccc4)cc3)c3ccc4c(c3)-c3cc5ccccc5cc3C4(C)C)cc21 ; [2H]c1c([2H])c([2H])c(-c2c([2H])c([2H])c(N(c3ccc4c(c3)oc3cc5ccccc5cc34)c3c([2H])c([2H])c(-c4c([2H])c([2H])c([2H])c([2H])c4[2H])c([2H])c3[2H])c([2H])c2[2H])c([2H])c1[2H] ; c1ccc(-c2ccc3oc4cc(N(c5ccccc5)c5ccc6c(c5)oc5cc7ccccc7cc56)ccc4c3c2)cc1]

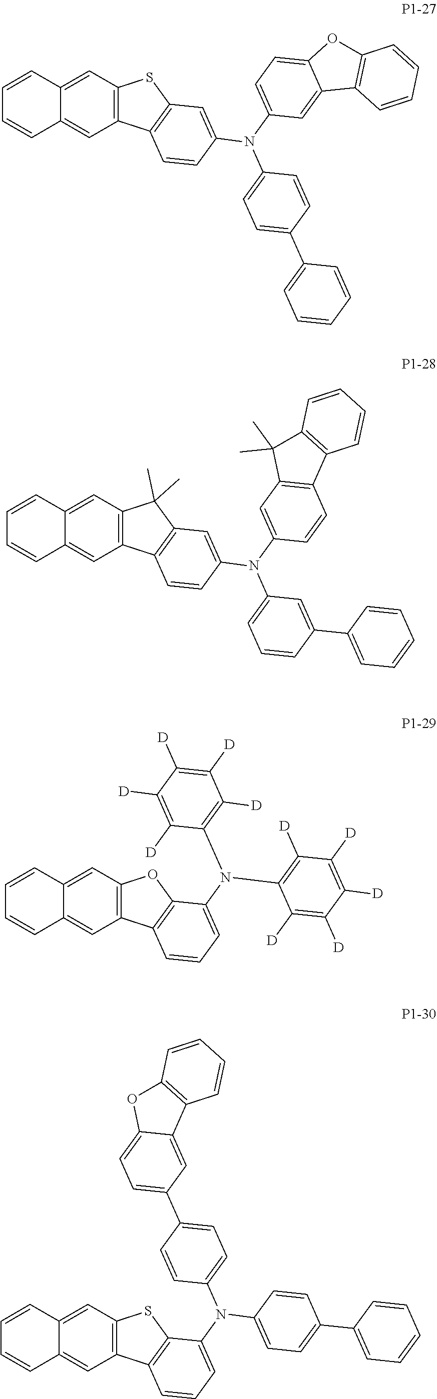 [SMILES: c1ccc(-c2ccc(N(c3ccc4c(c3)sc3cc5ccccc5cc34)c3ccc4oc5ccccc5c4c3)cc2)cc1 ; CC1(C)c2ccccc2-c2ccc(N(c3cccc(-c4ccccc4)c3)c3ccc4c(c3)C(C)(C)c3cc5ccccc5cc3-4)cc21 ; [2H]c1c([2H])c([2H])c(N(c2c([2H])c([2H])c([2H])c([2H])c2[2H])c2cccc3c2oc2cc4ccccc4cc23)c([2H])c1[2H] ; c1ccc(-c2ccc(N(c3ccc(-c4ccc5oc6ccccc6c5c4)cc3)c3cccc4c3sc3cc5ccccc5cc34)cc2)cc1]

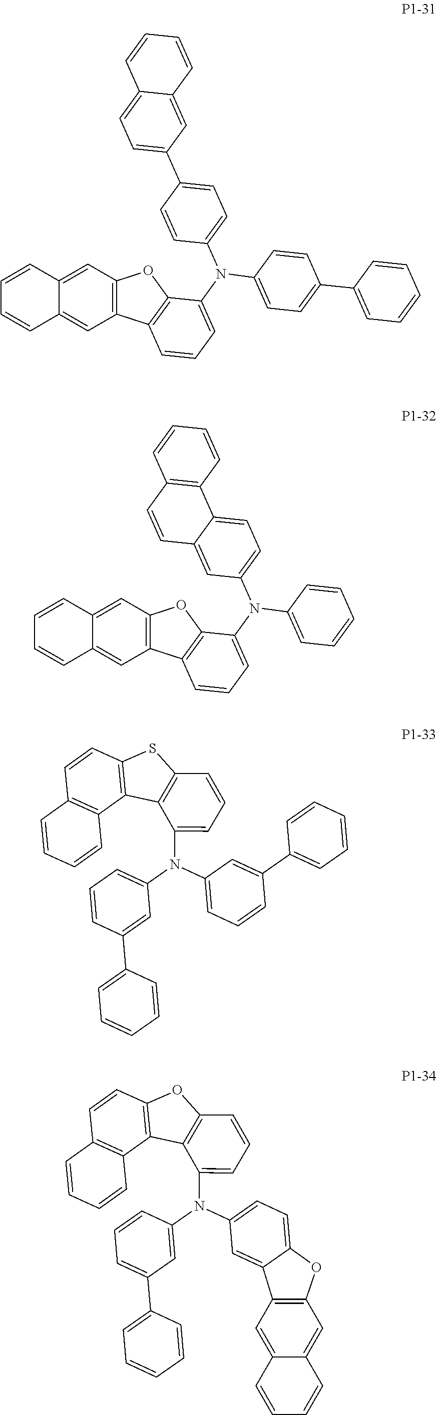 [SMILES: c1ccc(-c2ccc(N(c3ccc(-c4ccc5ccccc5c4)cc3)c3cccc4c3oc3cc5ccccc5cc34)cc2)cc1 ; c1ccc(N(c2ccc3c(ccc4ccccc43)c2)c2cccc3c2oc2cc4ccccc4cc23)cc1 ; c1ccc(-c2cccc(N(c3cccc(-c4ccccc4)c3)c3cccc4sc5ccc6ccccc6c5c34)c2)cc1 ; c1ccc(-c2cccc(N(c3ccc4oc5cc6ccccc6cc5c4c3)c3cccc4oc5ccc6ccccc6c5c34)c2)cc1]

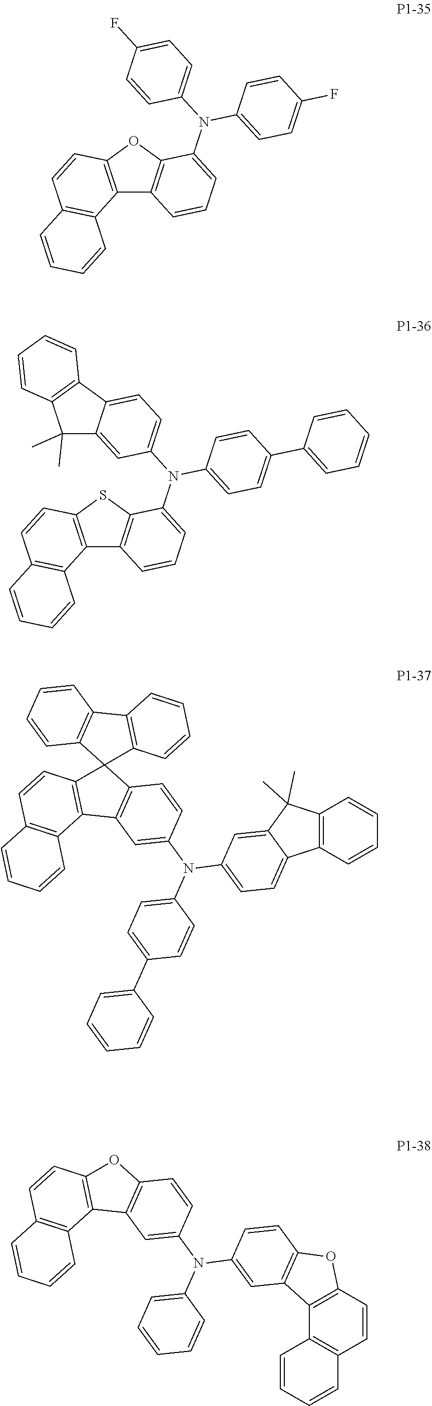 [SMILES: Fc1ccc(N(c2ccc(F)cc2)c2cccc3c2oc2ccc4ccccc4c23)cc1 ; CC1(C)c2ccccc2-c2ccc(N(c3ccc(-c4ccccc4)cc3)c3cccc4c3sc3ccc5ccccc5c34)cc21 ; CC1(C)c2ccccc2-c2ccc(N(c3ccc(-c4ccccc4)cc3)c3ccc4c(c3)-c3c(ccc5ccccc35)C43c4ccccc4-c4ccccc43)cc21 ; c1ccc(N(c2ccc3oc4ccc5ccccc5c4c3c2)c2ccc3oc4ccc5ccccc5c4c3c2)cc1]

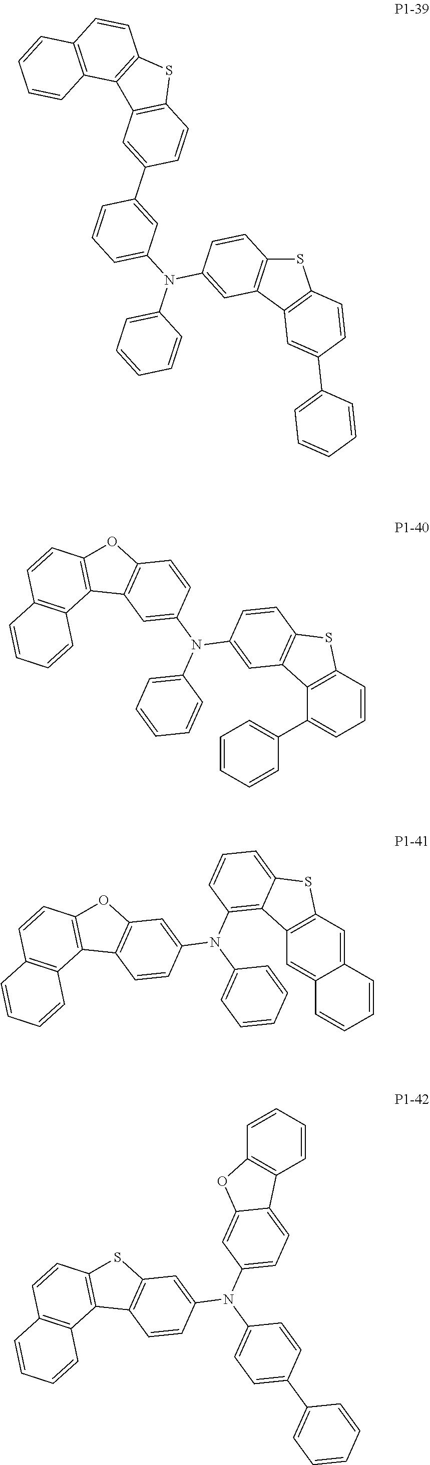 [SMILES: c1ccc(-c2ccc3sc4ccc(N(c5ccccc5)c5cccc(-c6ccc7sc8ccc9ccccc9c8c7c6)c5)cc4c3c2)cc1 ; c1ccc(-c2cccc3sc4ccc(N(c5ccccc5)c5ccc6oc7ccc8ccccc8c7c6c5)cc4c23)cc1 ; c1ccc(N(c2ccc3c(c2)oc2ccc4ccccc4c23)c2cccc3sc4cc5ccccc5cc4c23)cc1 ; c1ccc(-c2ccc(N(c3ccc4c(c3)oc3ccccc34)c3ccc4c(c3)sc3ccc5ccccc5c34)cc2)cc1]

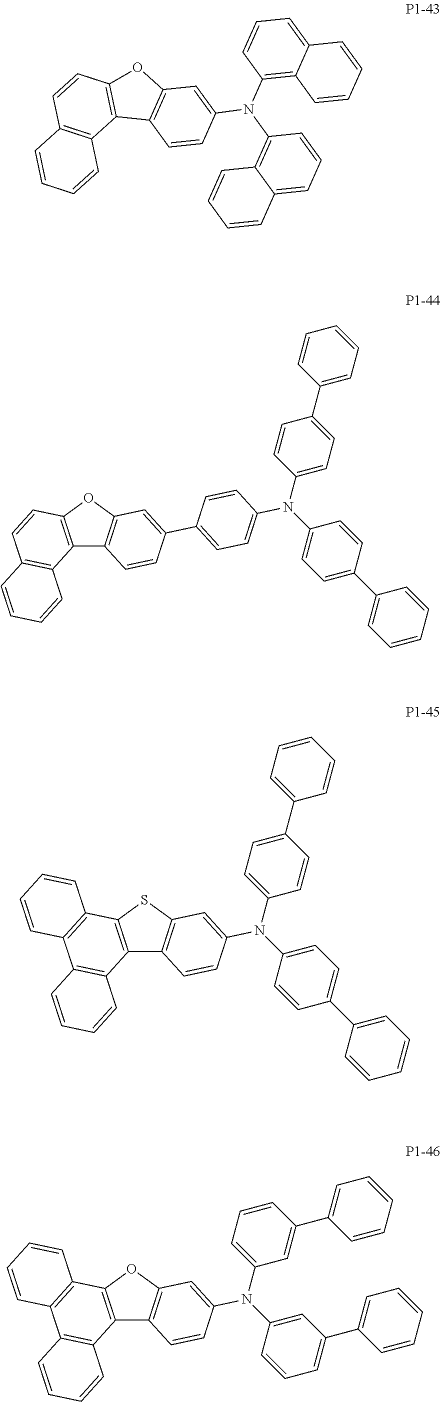 [SMILES: c1ccc2c(N(c3ccc4c(c3)oc3ccc5ccccc5c34)c3cccc4ccccc34)cccc2c1 ; c1ccc(-c2ccc(N(c3ccc(-c4ccccc4)cc3)c3ccc(-c4ccc5c(c4)oc4ccc6ccccc6c45)cc3)cc2)cc1 ; c1ccc(-c2ccc(N(c3ccc(-c4ccccc4)cc3)c3ccc4c(c3)sc3c5ccccc5c5ccccc5c43)cc2)cc1 ; c1ccc(-c2cccc(N(c3cccc(-c4ccccc4)c3)c3ccc4c(c3)oc3c5ccccc5c5ccccc5c43)c2)cc1]

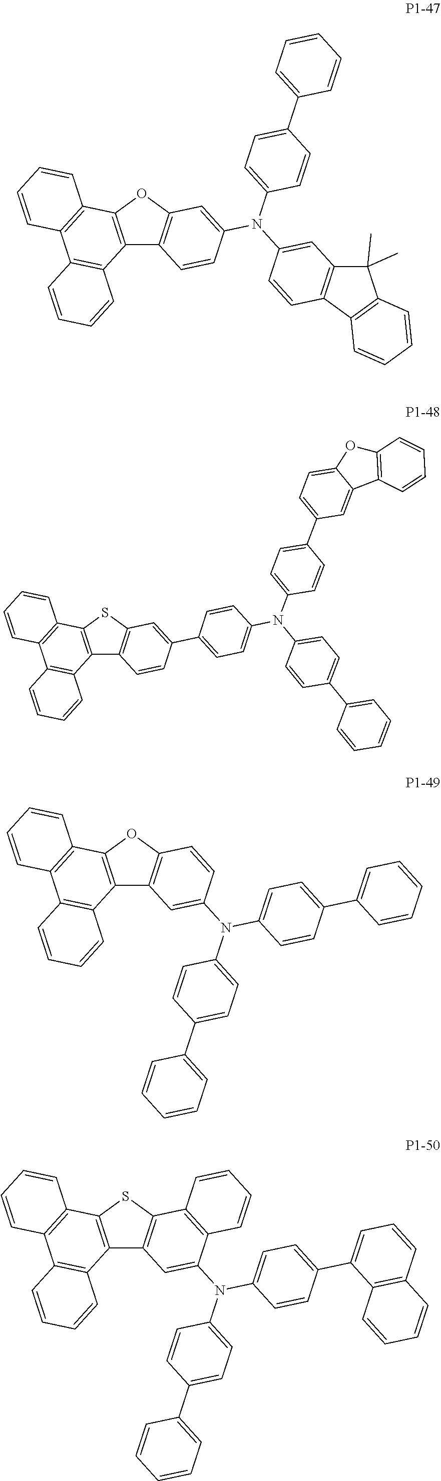 [SMILES: CC1(C)c2ccccc2-c2ccc(N(c3ccc(-c4ccccc4)cc3)c3ccc4c(c3)oc3c5ccccc5c5ccccc5c43)cc21 ; c1ccc(-c2ccc(N(c3ccc(-c4ccc5c(c4)sc4c6ccccc6c6ccccc6c54)cc3)c3ccc(-c4ccc5oc6ccccc6c5c4)cc3)cc2)cc1 ; c1ccc(-c2ccc(N(c3ccc(-c4ccccc4)cc3)c3ccc4oc5c6ccccc6c6ccccc6c5c4c3)cc2)cc1 ; c1ccc(-c2ccc(N(c3ccc(-c4cccc5ccccc45)cc3)c3cc4c(sc5c6ccccc6c6ccccc6c45)c4ccccc34)cc2)cc1]

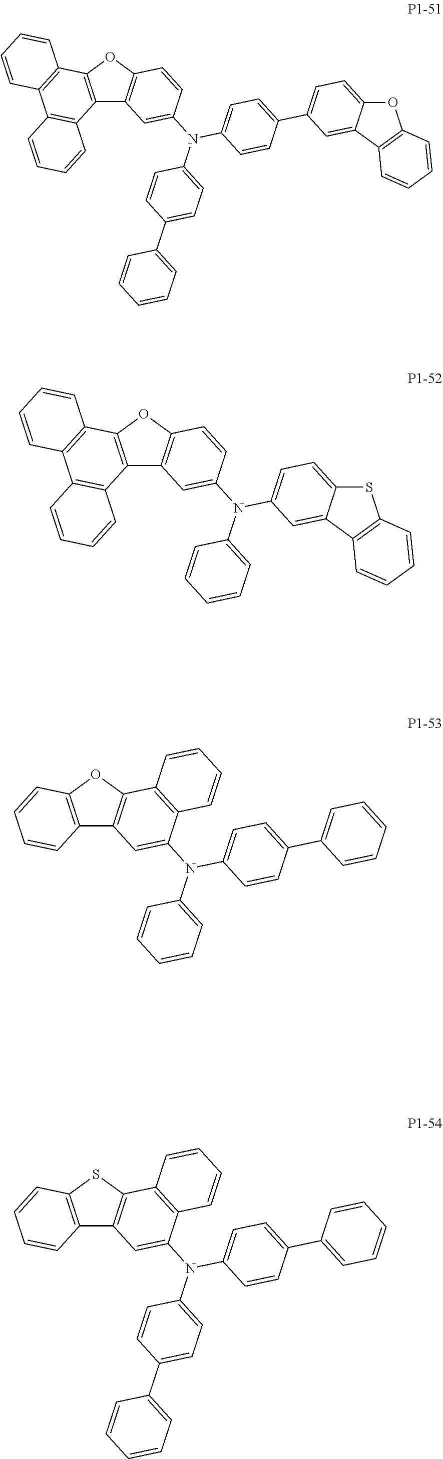 [SMILES: c1ccc(-c2ccc(N(c3ccc(-c4ccc5oc6ccccc6c5c4)cc3)c3ccc4oc5c6ccccc6c6ccccc6c5c4c3)cc2)cc1 ; c1ccc(N(c2ccc3sc4ccccc4c3c2)c2ccc3oc4c5ccccc5c5ccccc5c4c3c2)cc1 ; c1ccc(-c2ccc(N(c3ccccc3)c3cc4c5ccccc5oc4c4ccccc34)cc2)cc1 ; c1ccc(-c2ccc(N(c3ccc(-c4ccccc4)cc3)c3cc4c5ccccc5sc4c4ccccc34)cc2)cc1]

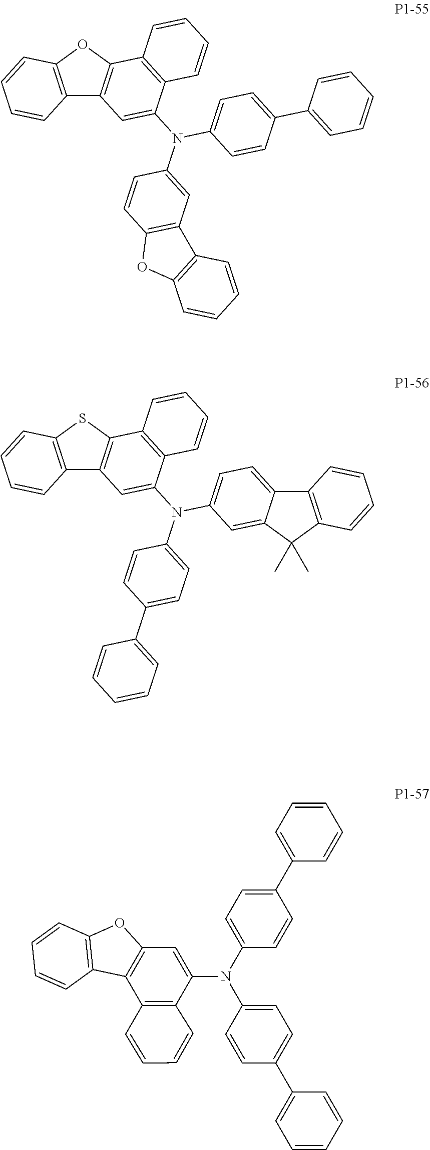 [SMILES: c1ccc(-c2ccc(N(c3ccc4oc5ccccc5c4c3)c3cc4c5ccccc5oc4c4ccccc34)cc2)cc1 ; CC1(C)c2ccccc2-c2ccc(N(c3ccc(-c4ccccc4)cc3)c3cc4c5ccccc5sc4c4ccccc34)cc21 ; c1ccc(-c2ccc(N(c3ccc(-c4ccccc4)cc3)c3cc4oc5ccccc5c4c4ccccc34)cc2)cc1]

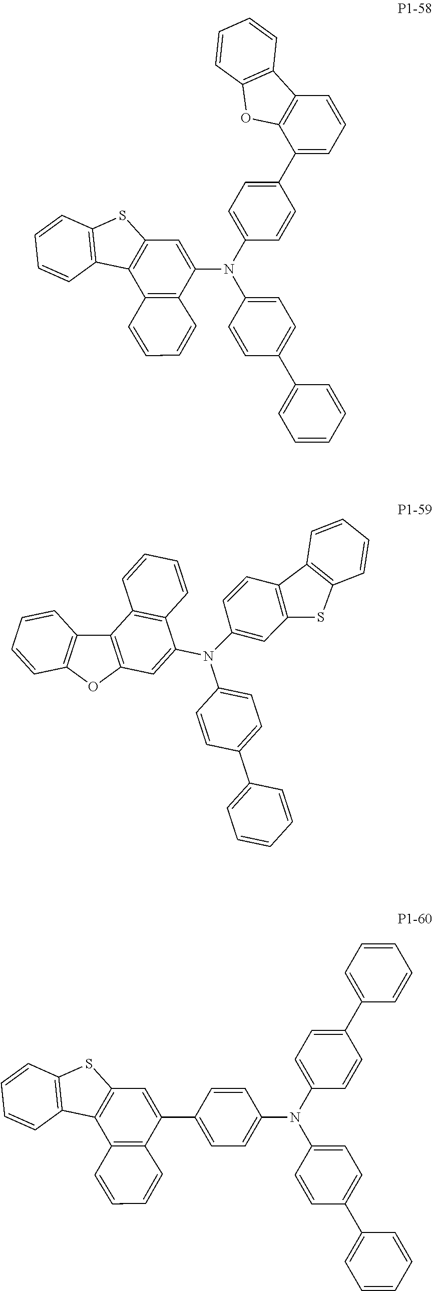 [SMILES: c1ccc(-c2ccc(N(c3ccc(-c4cccc5c4oc4ccccc45)cc3)c3cc4sc5ccccc5c4c4ccccc34)cc2)cc1 ; c1ccc(-c2ccc(N(c3ccc4c(c3)sc3ccccc34)c3cc4oc5ccccc5c4c4ccccc34)cc2)cc1 ; c1ccc(-c2ccc(N(c3ccc(-c4ccccc4)cc3)c3ccc(-c4cc5sc6ccccc6c5c5ccccc45)cc3)cc2)cc1]

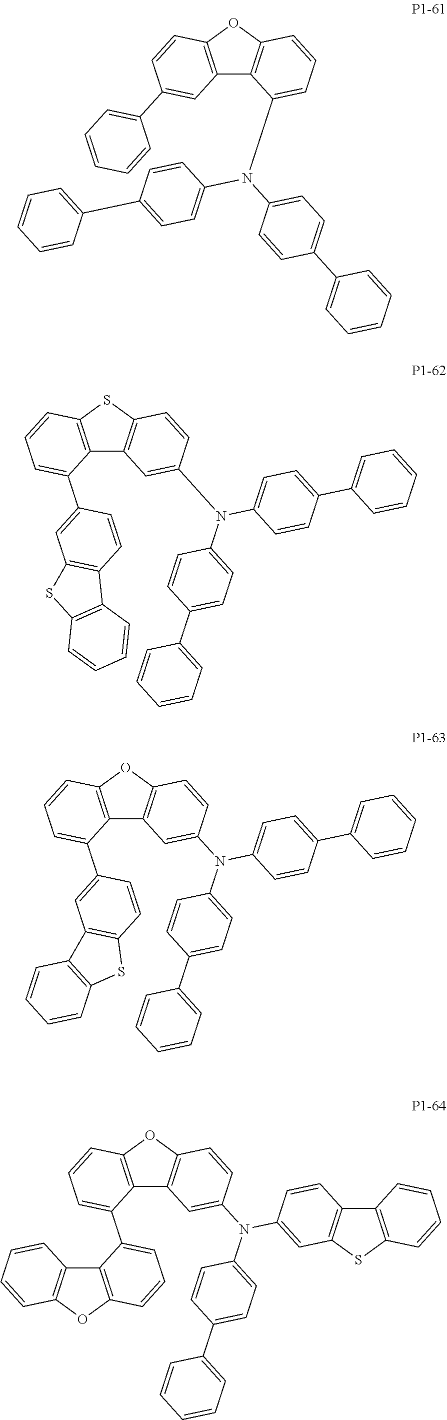 [SMILES: c1ccc(-c2ccc(N(c3ccc(-c4ccccc4)cc3)c3cccc4oc5ccc(-c6ccccc6)cc5c34)cc2)cc1 ; c1ccc(-c2ccc(N(c3ccc(-c4ccccc4)cc3)c3ccc4sc5cccc(-c6ccc7c(c6)sc6ccccc67)c5c4c3)cc2)cc1 ; c1ccc(-c2ccc(N(c3ccc(-c4ccccc4)cc3)c3ccc4oc5cccc(-c6ccc7sc8ccccc8c7c6)c5c4c3)cc2)cc1 ; c1ccc(-c2ccc(N(c3ccc4c(c3)sc3ccccc34)c3ccc4oc5cccc(-c6cccc7oc8ccccc8c67)c5c4c3)cc2)cc1]

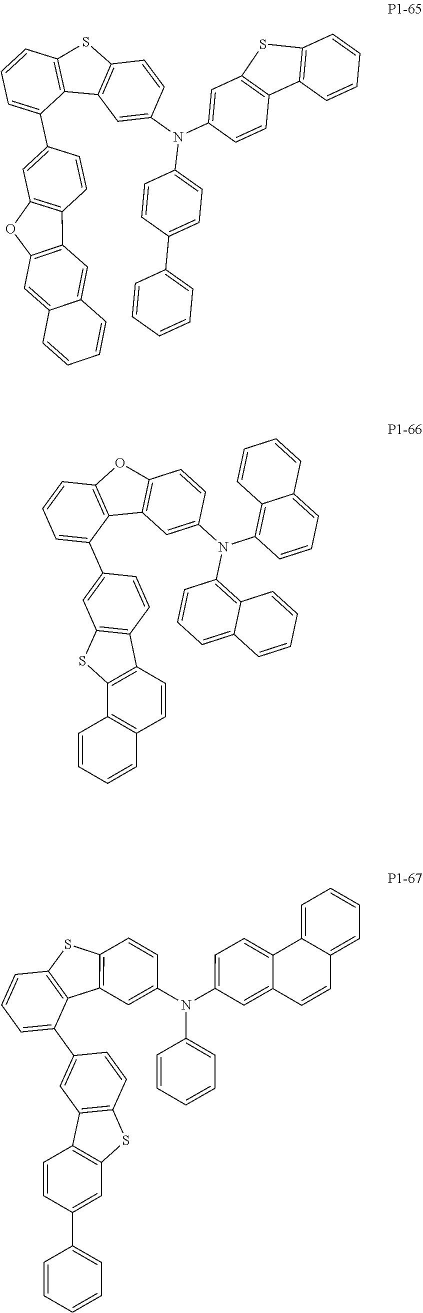 [SMILES: c1ccc(-c2ccc(N(c3ccc4c(c3)sc3ccccc34)c3ccc4sc5cccc(-c6ccc7c(c6)oc6cc8ccccc8cc67)c5c4c3)cc2)cc1 ; c1ccc2c(N(c3ccc4oc5cccc(-c6ccc7c(c6)sc6c8ccccc8ccc76)c5c4c3)c3cccc4ccccc34)cccc2c1 ; c1ccc(-c2ccc3c(c2)sc2ccc(-c4cccc5sc6ccc(N(c7ccccc7)c7ccc8c(ccc9ccccc98)c7)cc6c45)cc23)cc1]

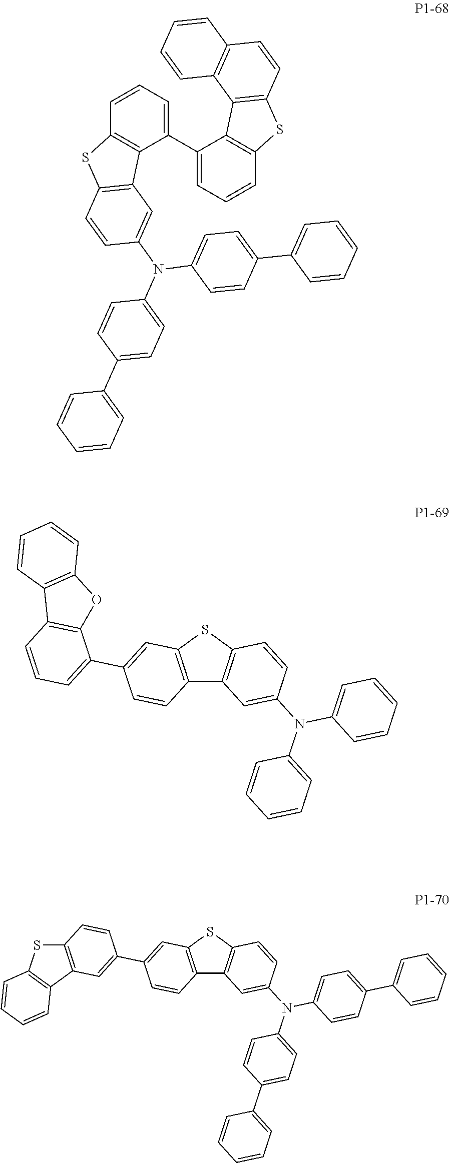 [SMILES: c1ccc(-c2ccc(N(c3ccc(-c4ccccc4)cc3)c3ccc4sc5cccc(-c6cccc7sc8ccc9ccccc9c8c67)c5c4c3)cc2)cc1 ; c1ccc(N(c2ccccc2)c2ccc3sc4cc(-c5cccc6c5oc5ccccc56)ccc4c3c2)cc1 ; c1ccc(-c2ccc(N(c3ccc(-c4ccccc4)cc3)c3ccc4sc5cc(-c6ccc7sc8ccccc8c7c6)ccc5c4c3)cc2)cc1]

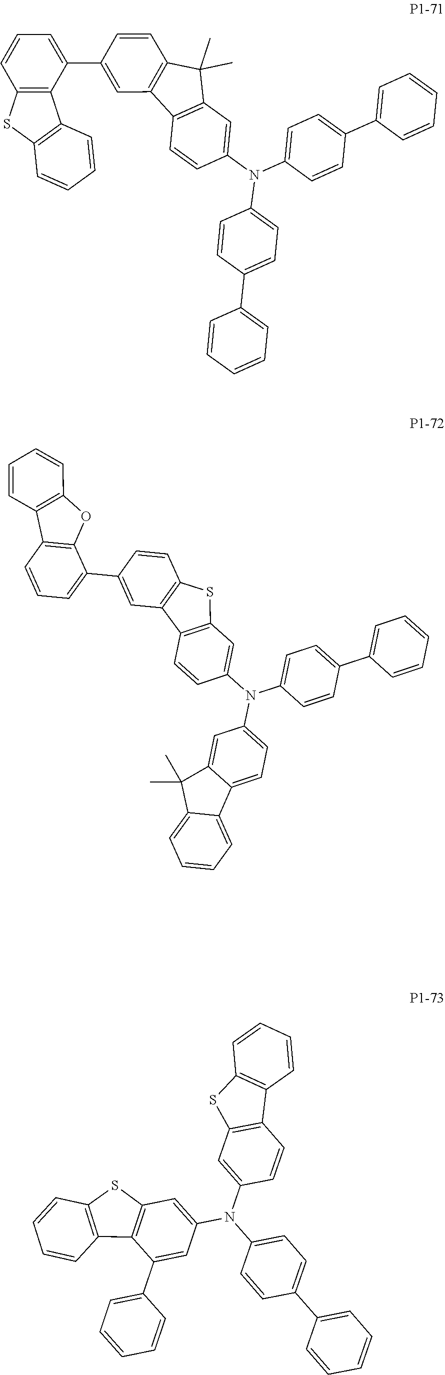 [SMILES: CC1(C)c2ccc(-c3cccc4sc5ccccc5c34)cc2-c2ccc(N(c3ccc(-c4ccccc4)cc3)c3ccc(-c4ccccc4)cc3)cc21 ; CC1(C)c2ccccc2-c2ccc(N(c3ccc(-c4ccccc4)cc3)c3ccc4c(c3)sc3ccc(-c5cccc6c5oc5ccccc56)cc34)cc21 ; c1ccc(-c2ccc(N(c3ccc4c(c3)sc3ccccc34)c3cc(-c4ccccc4)c4c(c3)sc3ccccc34)cc2)cc1]

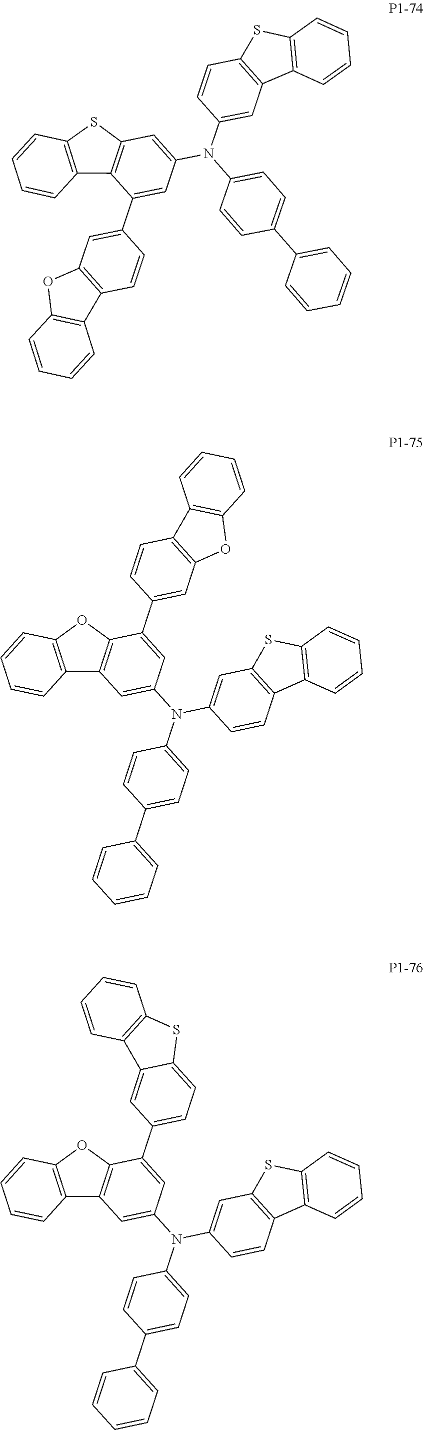 [SMILES: c1ccc(-c2ccc(N(c3cc(-c4ccc5c(c4)oc4ccccc45)c4c(c3)sc3ccccc34)c3ccc4sc5ccccc5c4c3)cc2)cc1 ; c1ccc(-c2ccc(N(c3ccc4c(c3)sc3ccccc34)c3cc(-c4ccc5c(c4)oc4ccccc45)c4oc5ccccc5c4c3)cc2)cc1 ; c1ccc(-c2ccc(N(c3ccc4c(c3)sc3ccccc34)c3cc(-c4ccc5sc6ccccc6c5c4)c4oc5ccccc5c4c3)cc2)cc1]

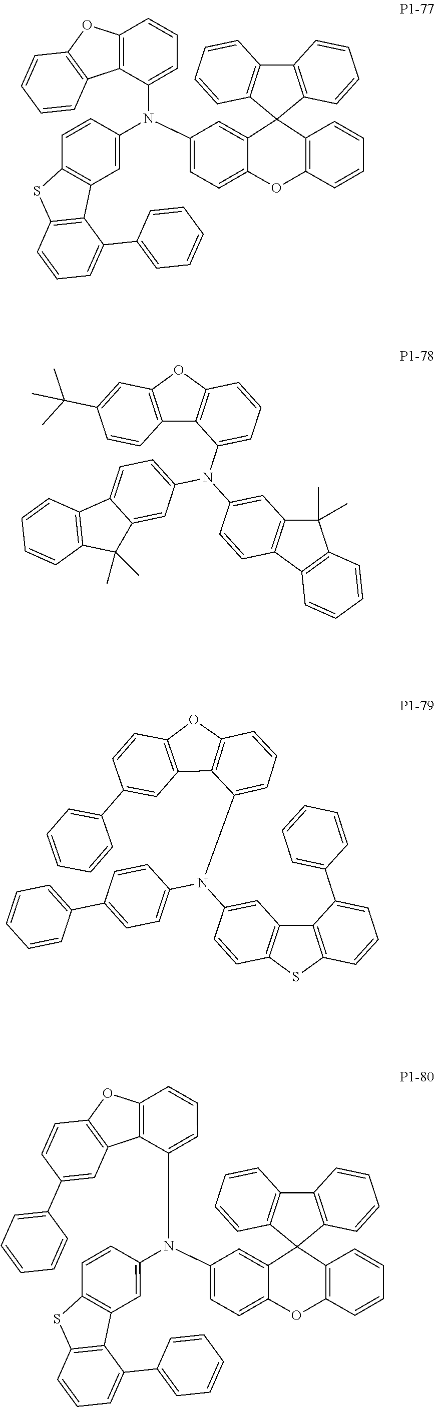 [SMILES: c1ccc(-c2cccc3sc4ccc(N(c5ccc6c(c5)C5(c7ccccc7O6)c6ccccc6-c6ccccc65)c5cccc6oc7ccccc7c56)cc4c23)cc1 ; CC(C)(C)c1ccc2c(c1)oc1cccc(N(c3ccc4c(c3)C(C)(C)c3ccccc3-4)c3ccc4c(c3)C(C)(C)c3ccccc3-4)c12 ; c1ccc(-c2ccc(N(c3ccc4sc5cccc(-c6ccccc6)c5c4c3)c3cccc4oc5ccc(-c6ccccc6)cc5c34)cc2)cc1 ; c1ccc(-c2ccc3oc4cccc(N(c5ccc6c(c5)C5(c7ccccc7O6)c6ccccc6-c6ccccc65)c5ccc6sc7cccc(-c8ccccc8)c7c6c5)c4c3c2)cc1]

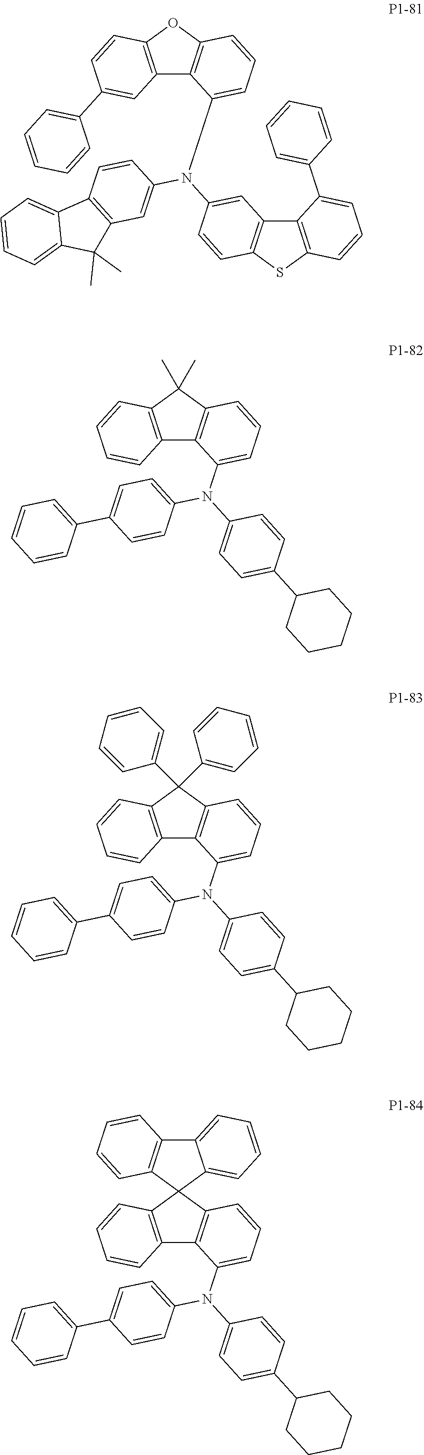 [SMILES: CC1(C)c2ccccc2-c2ccc(N(c3ccc4sc5cccc(-c6ccccc6)c5c4c3)c3cccc4oc5ccc(-c6ccccc6)cc5c34)cc21 ; CC1(C)c2ccccc2-c2c(N(c3ccc(-c4ccccc4)cc3)c3ccc(C4CCCCC4)cc3)cccc21 ; c1ccc(-c2ccc(N(c3ccc(C4CCCCC4)cc3)c3cccc4c3-c3ccccc3C4(c3ccccc3)c3ccccc3)cc2)cc1 ; c1ccc(-c2ccc(N(c3ccc(C4CCCCC4)cc3)c3cccc4c3-c3ccccc3C43c4ccccc4-c4ccccc43)cc2)cc1]

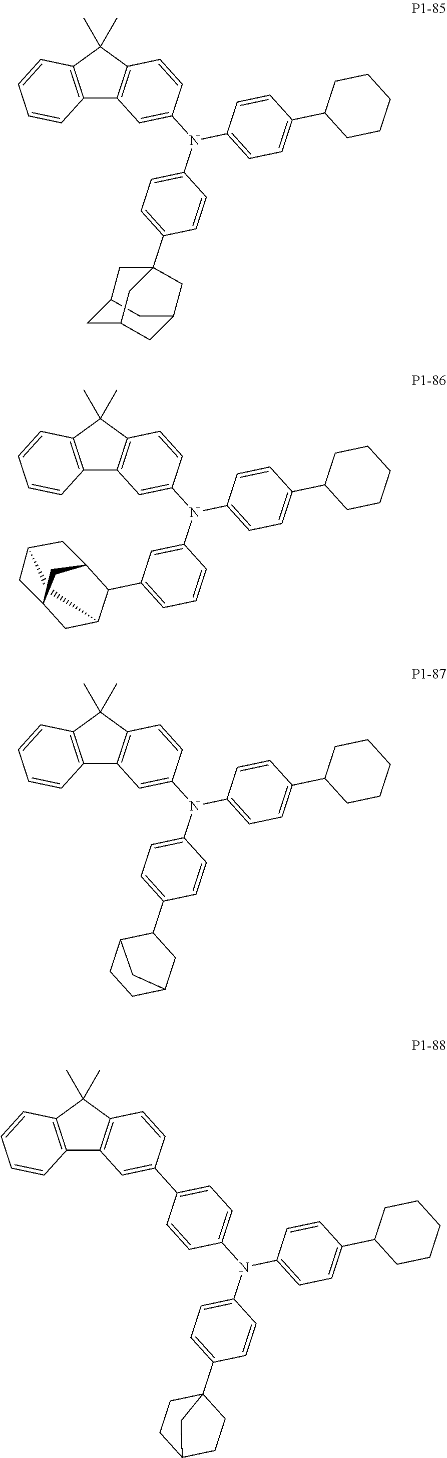 [SMILES: CC1(C)c2ccccc2-c2cc(N(c3ccc(C4CCCCC4)cc3)c3ccc(C45CC6CC(CC(C6)C4)C5)cc3)ccc21 ; CC1(C)c2ccccc2-c2cc(N(c3ccc(C4CCCCC4)cc3)c3cccc(C4[C@H]5C[C@H]6C[C@H](C5)C[C@H]4C6)c3)ccc21 ; CC1(C)c2ccccc2-c2cc(N(c3ccc(C4CCCCC4)cc3)c3ccc(C4CC5CCC4C5)cc3)ccc21 ; CC1(C)c2ccccc2-c2cc(-c3ccc(N(c4ccc(C5CCCCC5)cc4)c4ccc(C56CCC(CC5)C6)cc4)cc3)ccc21]

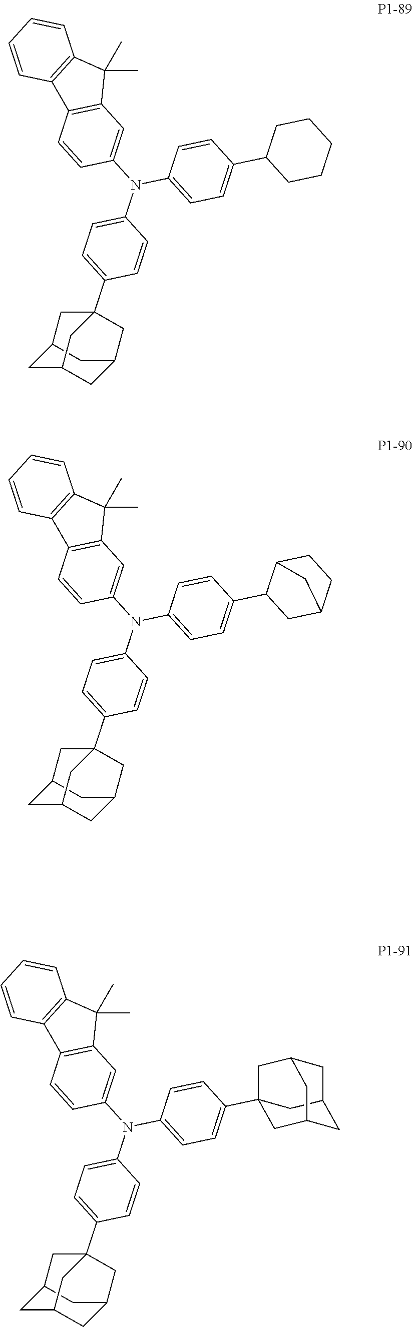 [SMILES: CC1(C)c2ccccc2-c2ccc(N(c3ccc(C4CCCCC4)cc3)c3ccc(C45CC6CC(CC(C6)C4)C5)cc3)cc21 ; CC1(C)c2ccccc2-c2ccc(N(c3ccc(C4CC5CCC4C5)cc3)c3ccc(C45CC6CC(CC(C6)C4)C5)cc3)cc21 ; CC1(C)c2ccccc2-c2ccc(N(c3ccc(C45CC6CC(CC(C6)C4)C5)cc3)c3ccc(C45CC6CC(CC(C6)C4)C5)cc3)cc21]

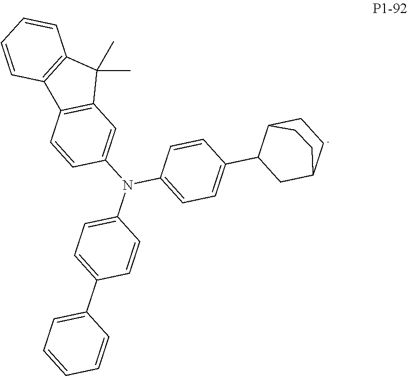 [SMILES: CC1(C)c2ccccc2-c2ccc(N(c3ccc(-c4ccccc4)cc3)c3ccc(C4CC5CCC4CC5)cc3)cc21]

Specifically, the compound represented by Formula 2 may be one of the following compounds, but there is no limitation thereto.

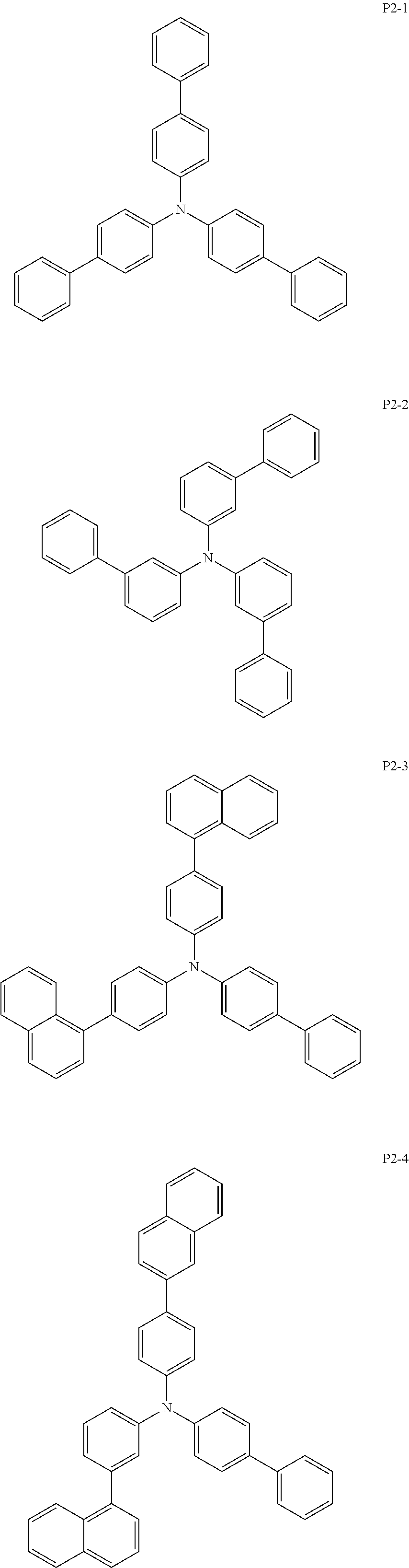 [SMILES: c1ccc(-c2ccc(N(c3ccc(-c4ccccc4)cc3)c3ccc(-c4ccccc4)cc3)cc2)cc1 ; c1ccc(-c2cccc(N(c3cccc(-c4ccccc4)c3)c3cccc(-c4ccccc4)c3)c2)cc1 ; c1ccc(-c2ccc(N(c3ccc(-c4cccc5ccccc45)cc3)c3ccc(-c4cccc5ccccc45)cc3)cc2)cc1 ; c1ccc(-c2ccc(N(c3ccc(-c4ccc5ccccc5c4)cc3)c3cccc(-c4cccc5ccccc45)c3)cc2)cc1]

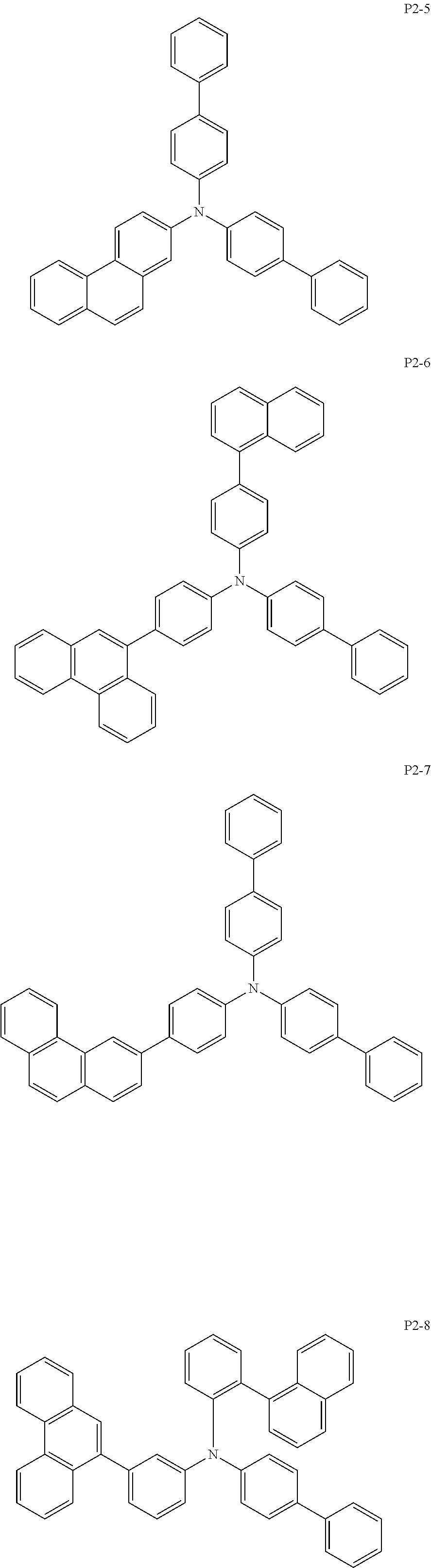 [SMILES: c1ccc(-c2ccc(N(c3ccc(-c4ccccc4)cc3)c3ccc4c(ccc5ccccc54)c3)cc2)cc1 ; c1ccc(-c2ccc(N(c3ccc(-c4cccc5ccccc45)cc3)c3ccc(-c4cc5ccccc5c5ccccc45)cc3)cc2)cc1 ; c1ccc(-c2ccc(N(c3ccc(-c4ccccc4)cc3)c3ccc(-c4ccc5ccc6ccccc6c5c4)cc3)cc2)cc1 ; c1ccc(-c2ccc(N(c3cccc(-c4cc5ccccc5c5ccccc45)c3)c3ccccc3-c3cccc4ccccc34)cc2)cc1]

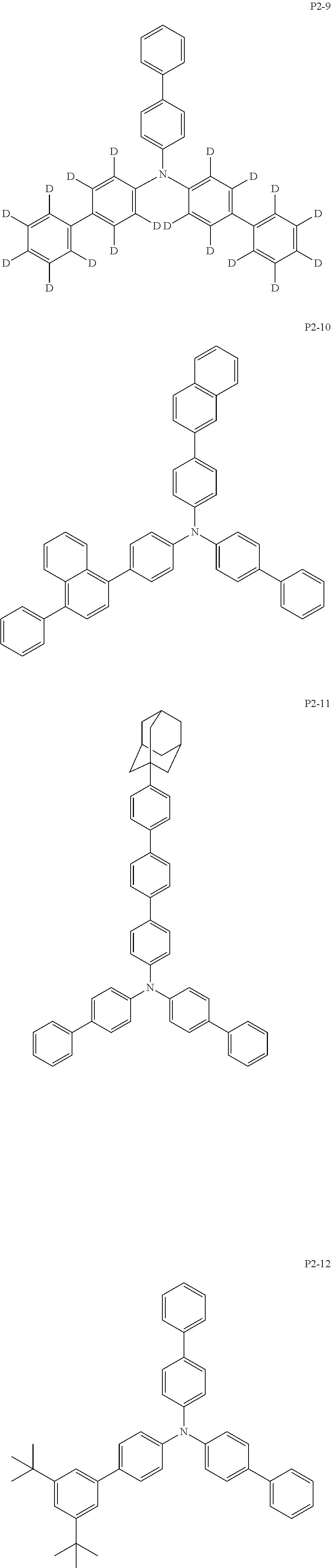 [SMILES: [2H]c1c([2H])c([2H])c(-c2c([2H])c([2H])c(N(c3ccc(-c4ccccc4)cc3)c3c([2H])c([2H])c(-c4c([2H])c([2H])c([2H])c([2H])c4[2H])c([2H])c3[2H])c([2H])c2[2H])c([2H])c1[2H] ; c1ccc(-c2ccc(N(c3ccc(-c4ccc5ccccc5c4)cc3)c3ccc(-c4ccc(-c5ccccc5)c5ccccc45)cc3)cc2)cc1 ; c1ccc(-c2ccc(N(c3ccc(-c4ccccc4)cc3)c3ccc(-c4ccc(-c5ccc(C67CC8CC(CC(C8)C6)C7)cc5)cc4)cc3)cc2)cc1 ; CC(C)(C)c1cc(-c2ccc(N(c3ccc(-c4ccccc4)cc3)c3ccc(-c4ccccc4)cc3)cc2)cc(C(C)(C)C)c1]

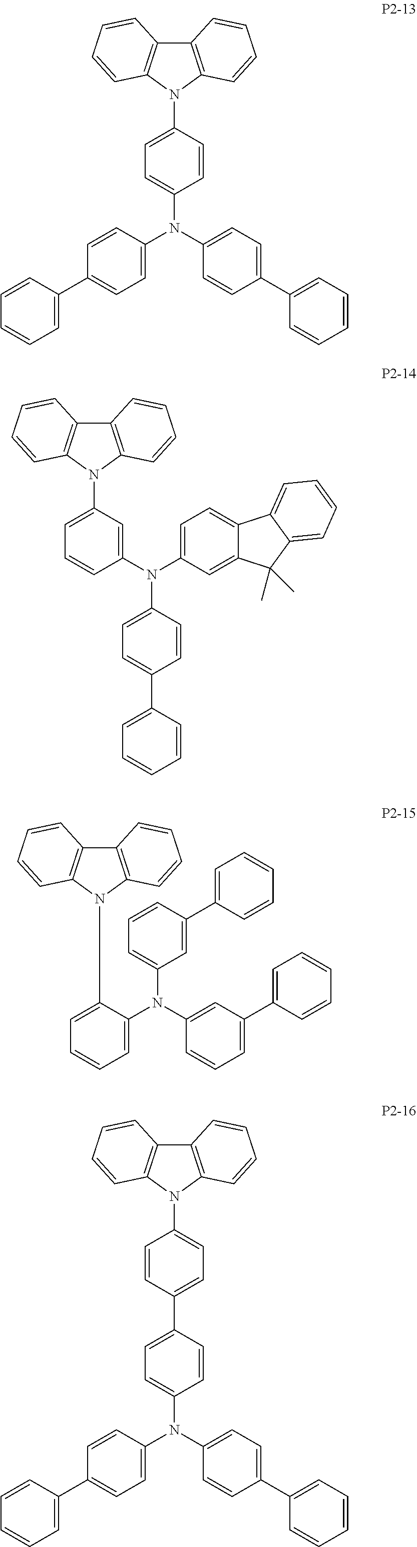 [SMILES: c1ccc(-c2ccc(N(c3ccc(-c4ccccc4)cc3)c3ccc(-n4c5ccccc5c5ccccc54)cc3)cc2)cc1 ; CC1(C)c2ccccc2-c2ccc(N(c3ccc(-c4ccccc4)cc3)c3cccc(-n4c5ccccc5c5ccccc54)c3)cc21 ; c1ccc(-c2cccc(N(c3cccc(-c4ccccc4)c3)c3ccccc3-n3c4ccccc4c4ccccc43)c2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

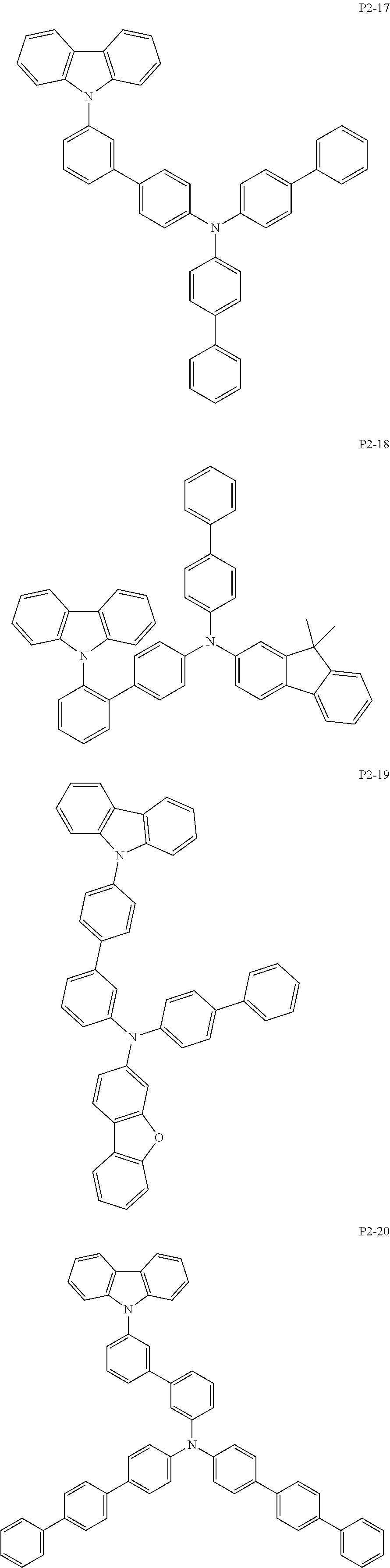 [SMILES: c1ccc(-c2ccc(N(c3ccc(-c4ccccc4)cc3)c3ccc(-c4cccc(-n5c6ccccc6c6ccccc65)c4)cc3)cc2)cc1 ; CC1(C)c2ccccc2-c2ccc(N(c3ccc(-c4ccccc4)cc3)c3ccc(-c4ccccc4-n4c5ccccc5c5ccccc54)cc3)cc21 ; c1ccc(-c2ccc(N(c3cccc(-c4ccc(-n5c6ccccc6c6ccccc65)cc4)c3)c3ccc4c(c3)oc3ccccc34)cc2)cc1 ; c1ccc(-c2ccc(-c3ccc(N(c4ccc(-c5ccc(-c6ccccc6)cc5)cc4)c4cccc(-c5cccc(-n6c7ccccc7c7ccccc76)c5)c4)cc3)cc2)cc1]

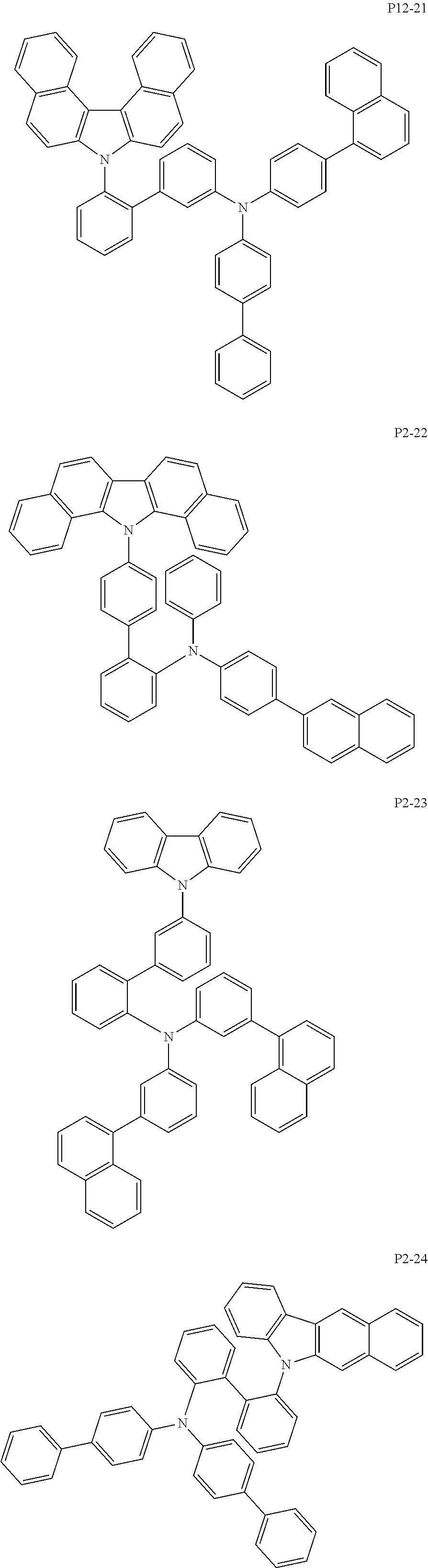 [SMILES: c1ccc(-c2ccc(N(c3ccc(-c4cccc5ccccc45)cc3)c3cccc(-c4ccccc4-n4c5ccc6ccccc6c5c5c6ccccc6ccc54)c3)cc2)cc1 ; c1ccc(N(c2ccc(-c3ccc4ccccc4c3)cc2)c2ccccc2-c2ccc(-n3c4c5ccccc5ccc4c4ccc5ccccc5c43)cc2)cc1 ; c1cc(-c2cccc3ccccc23)cc(N(c2cccc(-c3cccc4ccccc34)c2)c2ccccc2-c2cccc(-n3c4ccccc4c4ccccc43)c2)c1 ; c1ccc(-c2ccc(N(c3ccc(-c4ccccc4)cc3)c3ccccc3-c3ccccc3-n3c4ccccc4c4cc5ccccc5cc43)cc2)cc1]

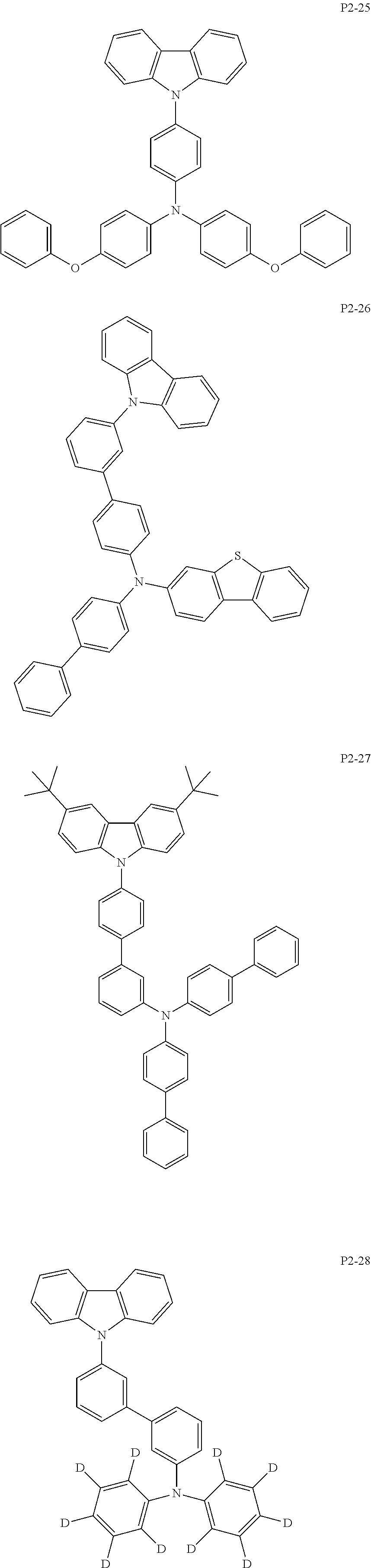 [SMILES: c1ccc(Oc2ccc(N(c3ccc(Oc4ccccc4)cc3)c3ccc(-n4c5ccccc5c5ccccc54)cc3)cc2)cc1 ; c1ccc(-c2ccc(N(c3ccc(-c4cccc(-n5c6ccccc6c6ccccc65)c4)cc3)c3ccc4c(c3)sc3ccccc34)cc2)cc1 ; CC(C)(C)c1ccc2c(c1)c1cc(C(C)(C)C)ccc1n2-c1ccc(-c2cccc(N(c3ccc(-c4ccccc4)cc3)c3ccc(-c4ccccc4)cc3)c2)cc1 ; [2H]c1c([2H])c([2H])c(N(c2cccc(-c3cccc(-n4c5ccccc5c5ccccc54)c3)c2)c2c([2H])c([2H])c([2H])c([2H])c2[2H])c([2H])c1[2H]]

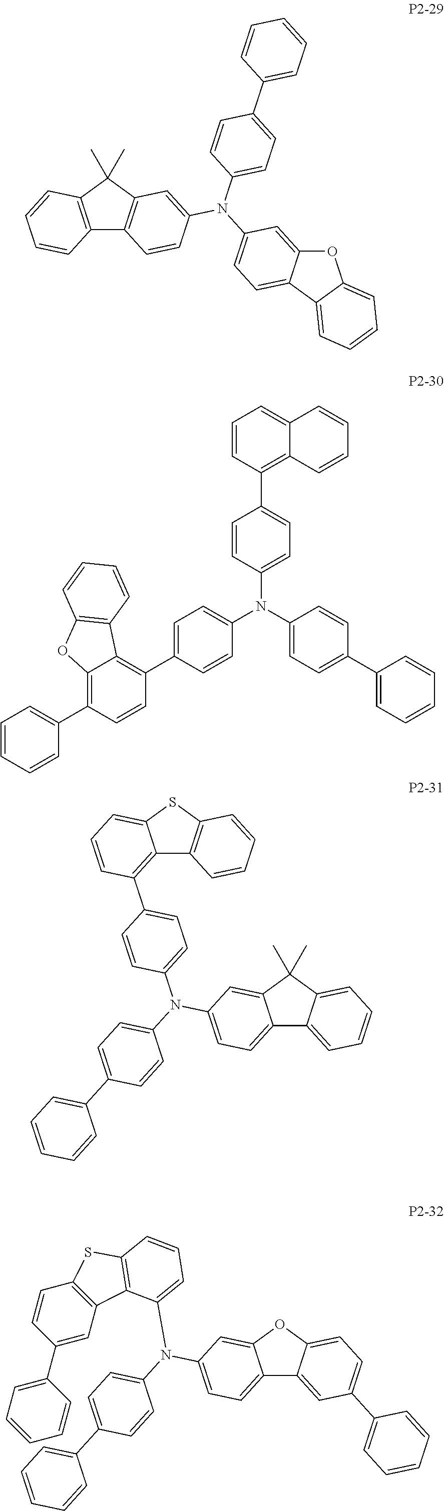 [SMILES: CC1(C)c2ccccc2-c2ccc(N(c3ccc(-c4ccccc4)cc3)c3ccc4c(c3)oc3ccccc34)cc21 ; c1ccc(-c2ccc(N(c3ccc(-c4cccc5ccccc45)cc3)c3ccc(-c4ccc(-c5ccccc5)c5oc6ccccc6c45)cc3)cc2)cc1 ; CC1(C)c2ccccc2-c2ccc(N(c3ccc(-c4ccccc4)cc3)c3ccc(-c4cccc5sc6ccccc6c45)cc3)cc21 ; c1ccc(-c2ccc(N(c3ccc4c(c3)oc3ccc(-c5ccccc5)cc34)c3cccc4sc5ccc(-c6ccccc6)cc5c34)cc2)cc1]

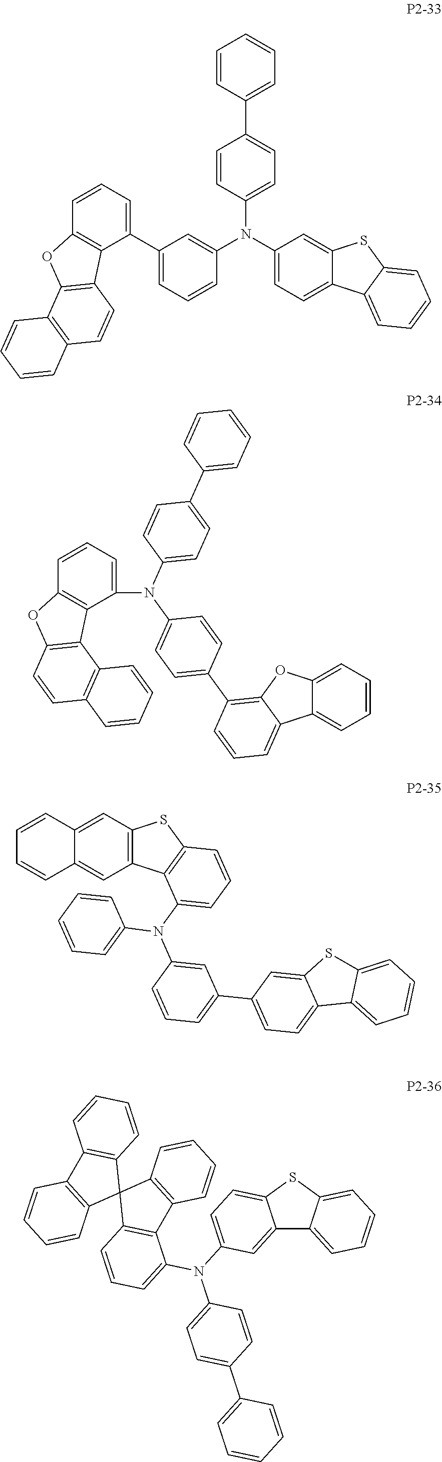 [SMILES: c1ccc(-c2ccc(N(c3cccc(-c4cccc5oc6c7ccccc7ccc6c45)c3)c3ccc4c(c3)sc3ccccc34)cc2)cc1 ; c1ccc(-c2ccc(N(c3ccc(-c4cccc5c4oc4ccccc45)cc3)c3cccc4oc5ccc6ccccc6c5c34)cc2)cc1 ; c1ccc(N(c2cccc(-c3ccc4c(c3)sc3ccccc34)c2)c2cccc3sc4cc5ccccc5cc4c23)cc1 ; c1ccc(-c2ccc(N(c3ccc4sc5ccccc5c4c3)c3cccc4c3-c3ccccc3C43c4ccccc4-c4ccccc43)cc2)cc1]

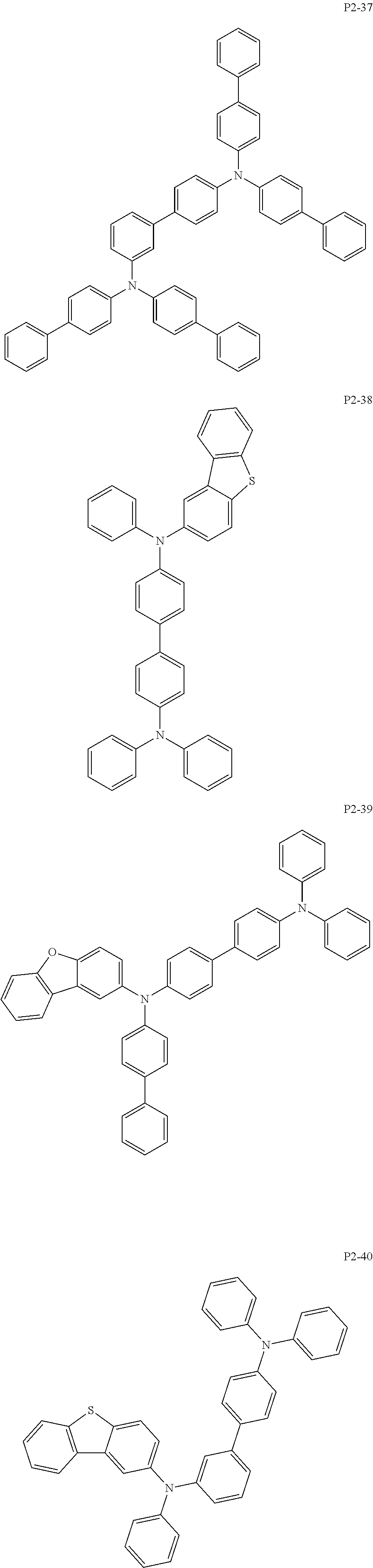 [SMILES: c1ccc(-c2ccc(N(c3ccc(-c4ccccc4)cc3)c3ccc(-c4cccc(N(c5ccc(-c6ccccc6)cc5)c5ccc(-c6ccccc6)cc5)c4)cc3)cc2)cc1 ; c1ccc(N(c2ccccc2)c2ccc(-c3ccc(N(c4ccccc4)c4ccc5sc6ccccc6c5c4)cc3)cc2)cc1 ; c1ccc(-c2ccc(N(c3ccc(-c4ccc(N(c5ccccc5)c5ccccc5)cc4)cc3)c3ccc4oc5ccccc5c4c3)cc2)cc1 ; c1ccc(N(c2ccccc2)c2ccc(-c3cccc(N(c4ccccc4)c4ccc5sc6ccccc6c5c4)c3)cc2)cc1]

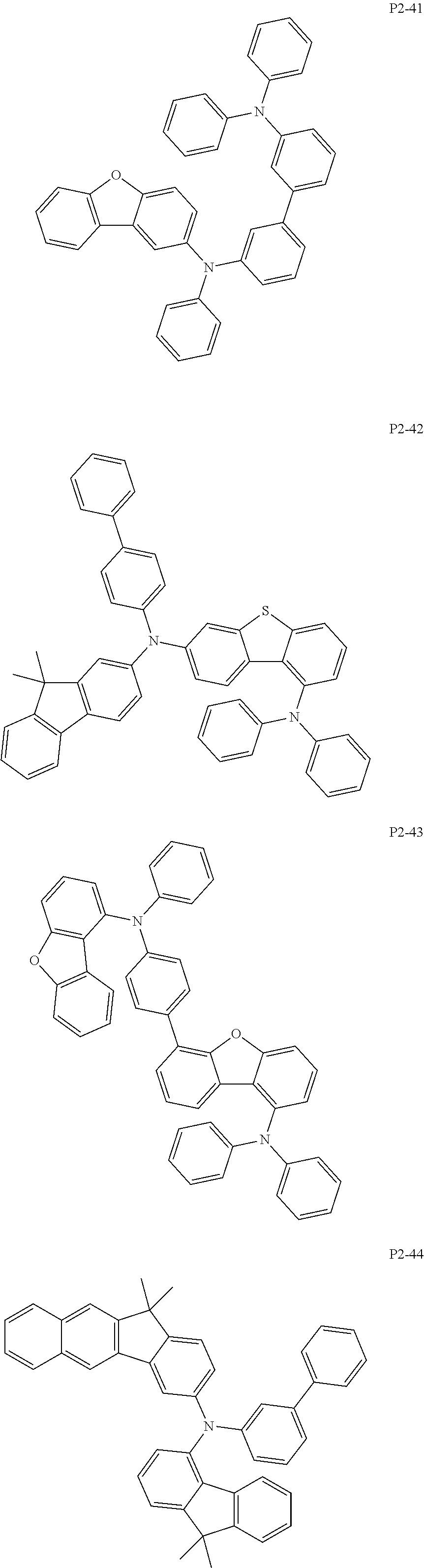 [SMILES: c1ccc(N(c2ccccc2)c2cccc(-c3cccc(N(c4ccccc4)c4ccc5oc6ccccc6c5c4)c3)c2)cc1 ; CC1(C)c2ccccc2-c2ccc(N(c3ccc(-c4ccccc4)cc3)c3ccc4c(c3)sc3cccc(N(c5ccccc5)c5ccccc5)c34)cc21 ; c1ccc(N(c2ccc(-c3cccc4c3oc3cccc(N(c5ccccc5)c5ccccc5)c34)cc2)c2cccc3oc4ccccc4c23)cc1 ; CC1(C)c2ccc(N(c3cccc(-c4ccccc4)c3)c3cccc4c3-c3ccccc3C4(C)C)cc2-c2cc3ccccc3cc21]

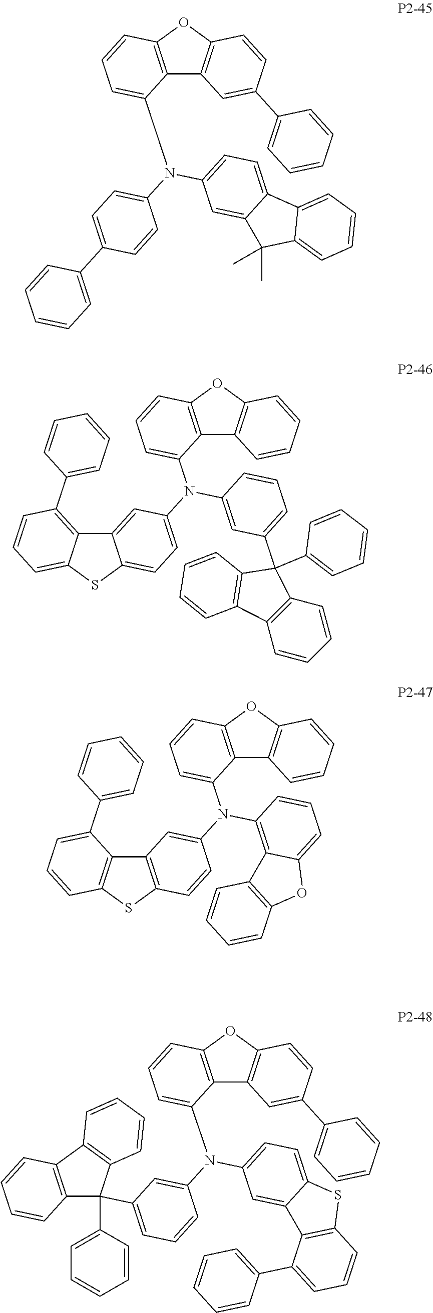 [SMILES: CC1(C)c2ccccc2-c2ccc(N(c3ccc(-c4ccccc4)cc3)c3cccc4oc5ccc(-c6ccccc6)cc5c34)cc21 ; c1ccc(-c2cccc3sc4ccc(N(c5cccc(C6(c7ccccc7)c7ccccc7-c7ccccc76)c5)c5cccc6oc7ccccc7c56)cc4c23)cc1 ; c1ccc(-c2cccc3sc4ccc(N(c5cccc6oc7ccccc7c56)c5cccc6oc7ccccc7c56)cc4c23)cc1 ; c1ccc(-c2ccc3oc4cccc(N(c5cccc(C6(c7ccccc7)c7ccccc7-c7ccccc76)c5)c5ccc6sc7cccc(-c8ccccc8)c7c6c5)c4c3c2)cc1]

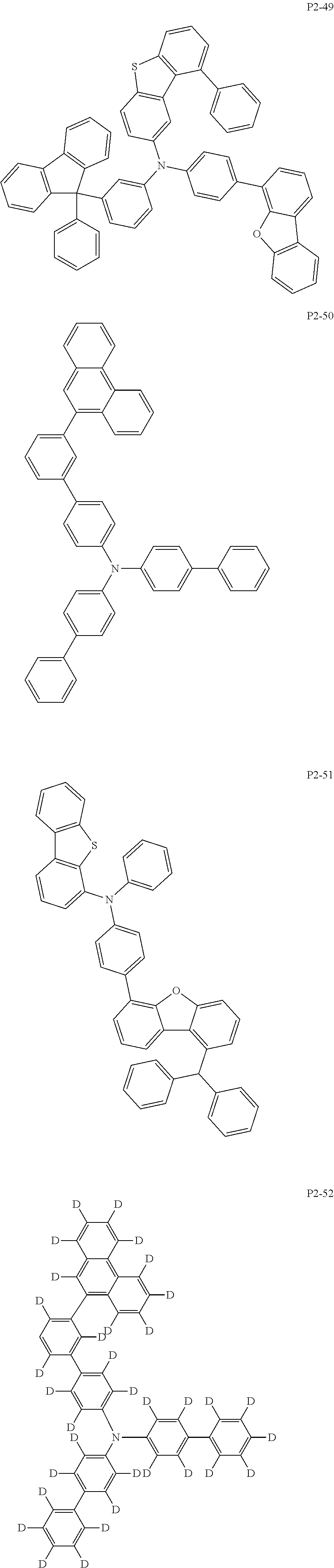

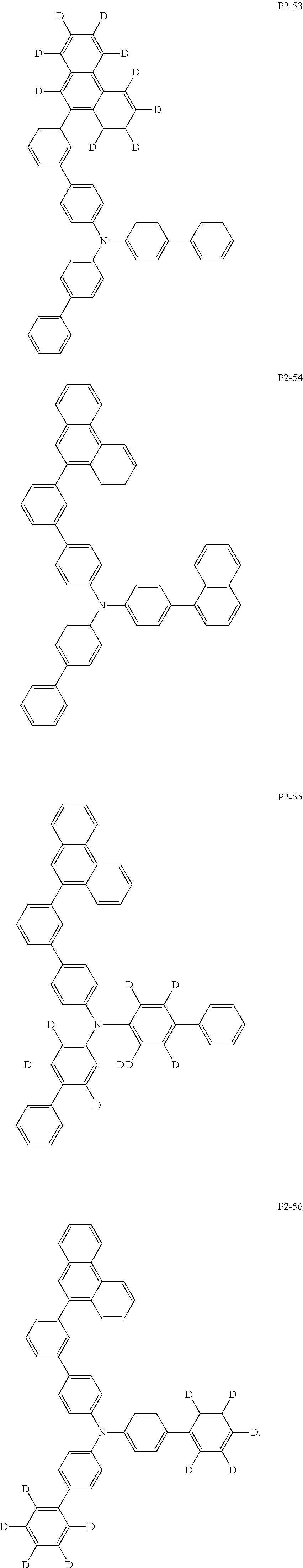

Hereinafter, synthesis example of the compound represented by Formula 1 and 2, and preparation method of an organic electroluminescent element will be described in detail by way of examples. However, the present invention is not limited to the following examples.

### SYNTHESIS EXAMPLE

### Synthesis Example of Formula 1

The compound represented by Formula 1 according to the present invention can be synthesized by reaction route of the following Reaction Scheme 1, but is not limited thereto.

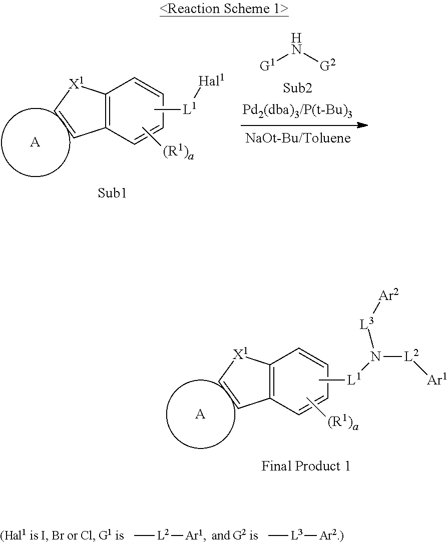

### Synthesis Example of Sub1

Sub 1 of the Reaction Scheme 1 can be synthesized according to the reaction route of the following Reaction Scheme 2-1 or 2-2. Sub 1 of the Reaction Scheme 1 can be synthesized according to the following Reaction Scheme 2-1 when X¹ is S, according to the following Reaction Scheme 2-2 when X¹ is O, and according to the following Reaction Scheme 2-3 when X¹ is C(R′)(R″), but is not limited thereto.

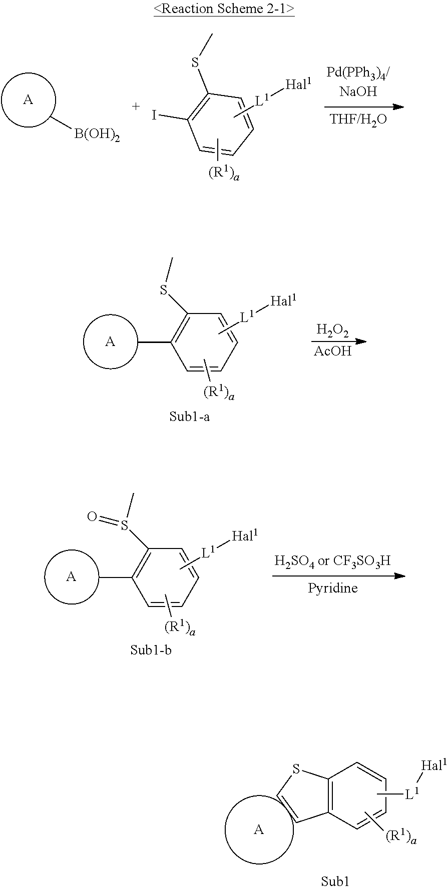

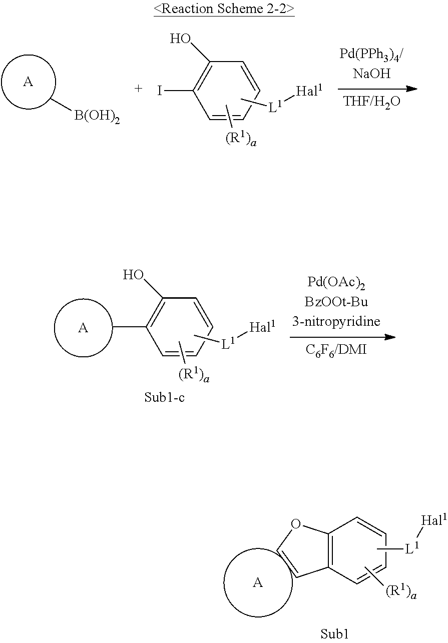

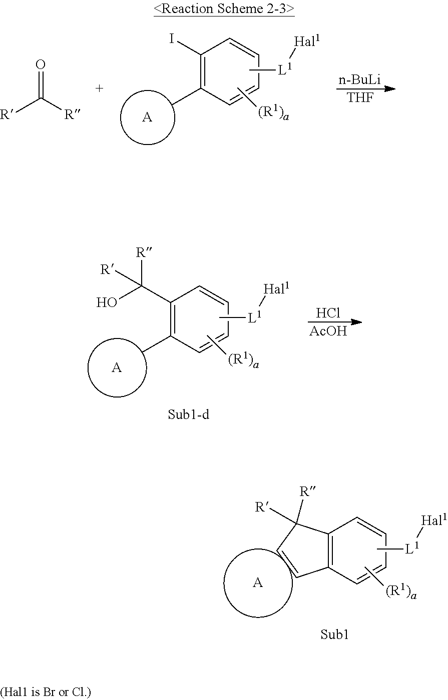

### Synthesis Example of Sub1

### 1. Synthesis Example of Sub1-1

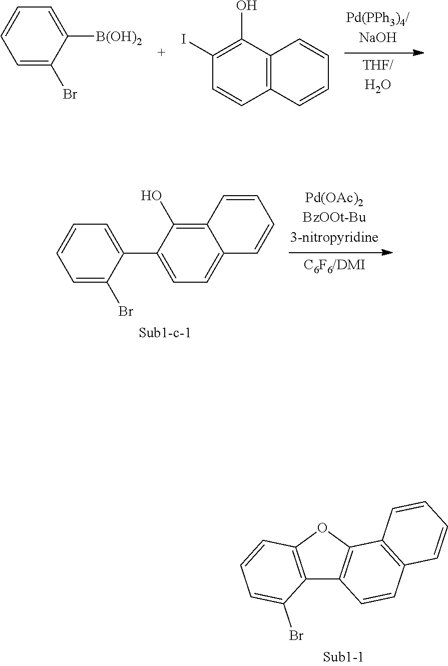 [SMILES: OB(O)c1ccccc1Br ; Oc1c(I)ccc2ccccc12 ; Oc1c(-c2ccccc2Br)ccc2ccccc12 ; Brc1cccc2oc3c4ccccc4ccc3c12]

### (1) Synthesis of Sub1-c-1

After dissolving 2-iodonaphthalen-1-ol (10.0 g, 37.0 mmol) in THF (185 mL), (2-bromophenyl)boronic acid (7.4 g, 37.0 mmol), Pd(PPh₃)₄ (2.57 g, 2.22 mmol), NaOH (4.4 g, 111 mmol) and H₂O (93 mL) were added to the solution and the mixture was stirred at 80° C. When the reaction was completed, the reaction product was extracted with CH₂Cl₂ and water, and then an organic layer was dried with MgSO₄ and concentrated. Then, the concentrate was separated through a silica gel column and recrystallized to obtain 9.1 g (yield: 82%) of the product.

### (2) Synthesis of Sub1-1

After putting Sub1-c-1 (9.1 g, 30.4 mmol), Pd(OAc)2 (0.34 g, 1.52 mmol) and 3-nitropyridine (0.188 g, 1.52 mmol) into a round bottom flask, the mixture was dissolved in C₆F₆ (45 mL) and DMI (30 mL). Then, tert-butylperoxybenzoate (11.8 g, 60.7 mmol) was added in the round bottom flask and the reaction mixture was stirred at 90° C. When the reaction was completed, the reaction product was extracted with CH₂Cl₂ and water, and then an organic layer was dried with MgSO₄ and concentrated. Then, the concentrate was separated through a silica gel column and recrystallized to obtain 5.8 g (yield: 64%) of the product.

### 2. Synthesis Example of Sub1-4

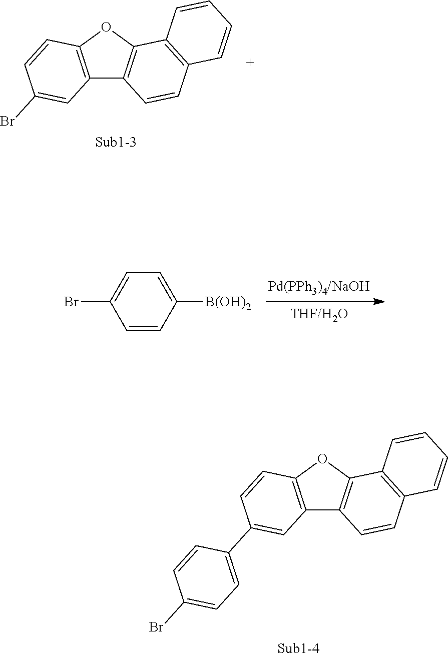 [SMILES: Brc1ccc2oc3c4ccccc4ccc3c2c1 ; OB(O)c1ccc(Br)cc1 ; Brc1ccc(-c2ccc3oc4c5ccccc5ccc4c3c2)cc1]

After dissolving Sub1-3 (5.0 g, 16.8 mmol) in THF (84 mL), (4-bromophenyl)boronic acid (3.4 g, 16.8 mmol), Pd(PPh₃)₄ (1.17 g, 1.01 mmol), NaOH (2.0 g, 50.5 mmol) and H₂O (42 mL) were added to the solution and the mixture was stirred at 80° C. When the reaction was completed, the reaction product was extracted with CH₂Cl₂ and water, and then an organic layer was dried with MgSO₄ and concentrated. Then, the concentrate was separated through a silica gel column and recrystallized to obtain 5.2 g (yield: 83%) of the product.

### 3. Synthesis Example of Sub1-9

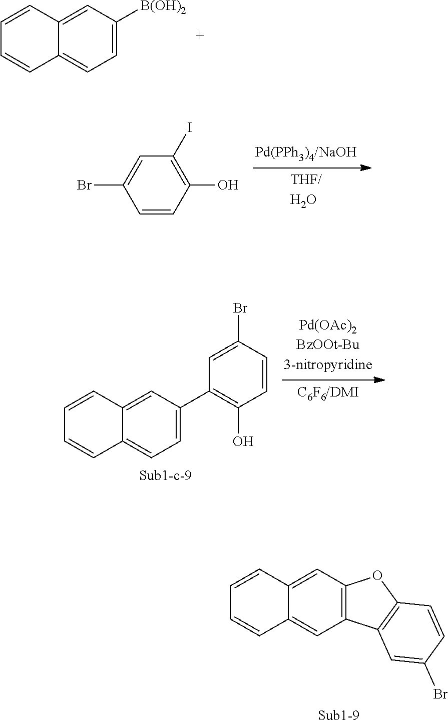 [SMILES: OB(O)c1ccc2ccccc2c1 ; Oc1ccc(Br)cc1I ; Oc1ccc(Br)cc1-c1ccc2ccccc2c1 ; Brc1ccc2oc3cc4ccccc4cc3c2c1]

### (1) Synthesis of Sub1-c-9

After dissolving 4-bromo-2-iodophenol (15.0 g, 50.2 mmol) in THF (250 mL), naphthalen-2-ylboronic acid (8.6 g, 50.2 mmol), Pd(PPh₃)₄ (3.48 g, 3.01 mmol), NaOH (6.0 g, 151 mmol) and H₂O (125 mL) were added to the solution, and then the synthesis was carried out in the same manner as in the synthesis method of Sub1-c-1 to obtain 12.6 g (yield: 84%) of the product.

### (2) Synthesis of Sub1-9

Sub1-c-9 (12.6 g, 42.2 mmol), Pd(OAc)₂ (0.47 g, 2.11 mmol), 3-nitropyridine (0.262 g, 2.11 mmol), C₆F₆ (63 mL), DMI (42 mL) and tert-butylperoxybenzoate (16.4 g, 84.3 mmol) were putted into a round bottom flask, and then the synthesis was carried out in the same manner as in the synthesis method of Sub1-1 to obtain 7.3 g (yield: 58%) of the product.

### 4. Synthesis Example of Sub1-18

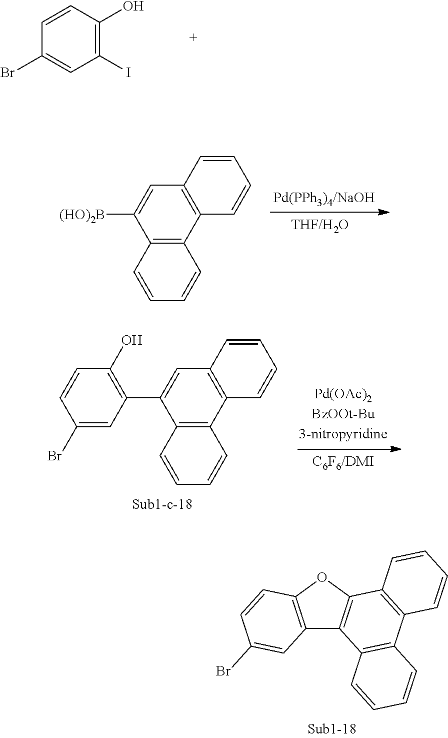

### (1) Synthesis of Sub1-c-18

After dissolving 4-bromo-2-iodophenol (10.0 g, 33.5 mmol) in THF (167 mL), phenanthren-9-ylboronic acid (7.4 g, 33.5 mmol), Pd(PPh₃)₄ (2.32 g, 2.01 mmol), NaOH (4.0 g, 100 mmol) and H₂O (84 mL) were added to the solution, and then the synthesis was carried out in the same manner as in the synthesis method of Sub1-c-1 to obtain 9.6 g (yield: 82%) of the product.

### (2) Synthesis of Sub1-18

Sub1-c-18 (9.6 g, 27.4 mmol), Pd(OAc)₂ (0.31 g, 1.37 mmol), 3-nitropyridine (0.170 g, 1.37 mmol), C₆F₆ (41 mL), DMI (27 mL), tert-butylperoxybenzoate (10.7 g, 54.9 mmol) were putted into a round bottom flask, and then the synthesis was carried out in the same manner as in the synthesis method of Sub1-1 to obtain 6.3 g (yield: 66%) of the product.

### 5. Synthesis Example of Sub1-31

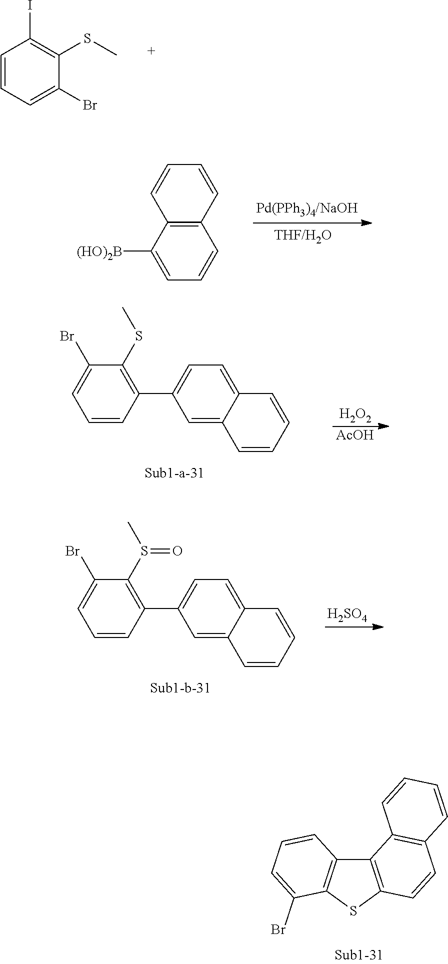

### (1) Synthesis of Sub1-a-31

After dissolving (2-bromo-6-iodophenyl)(methyl)sulfane (10.0 g, 30.4 mmol) in THF (152 mL), naphthalen-1-ylboronic acid (5.2 g, 30.4 mmol), Pd(PPh₃)₄ (2.11 g, 1.82 mmol), NaOH (3.65 g, 91.2 mmol) and H₂O (76 mL) were added to the solution, and then the synthesis was carried out in the same manner as in the synthesis method of Sub1-c-1 to obtain 8.1 g (yield: 81%) of the product.

### (2) Synthesis of Sub1-b-31

Sub1-a-31 (8.1 g, 24.6 mmol), H₂O₂ (7.0 mL) and acetic acid (98 mL) were added to a round bottom flask and stirred at room temperature. When the reaction was completed, acetic acid was removed and water was added to obtain a solid. The solid was dissolved in CH₂Cl₂, and the solution was separated through a silica gel column and concentrated to obtain 7.5 g (yield: 88%) of the product.

### (3) Synthesis of Sub1-31

Sub1-b-31 (7.5 g, 21.7 mmol) was dissolved in an excess of H₂SO₄ and stirred at room temperature for 6 hours. When the reaction was completed, the reaction product was neutralized with aqueous NaOH solution, and the organic layer extracted with CH₂Cl₂ was dried with MgSO₄ and concentrated. Afterwards, the concentrate was separated through a silica gel column and recrystallized to obtain 2.7 g (yield: 47%) of product.

### 6. Synthesis Example of Sub1-38

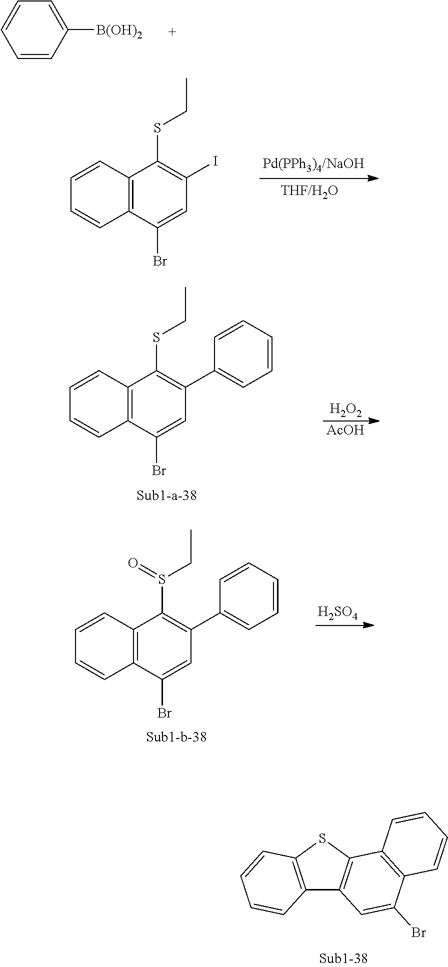

### (1) Synthesis of Sub1-a-38

After dissolving (4-bromo-2-iodonaphthalen-1-yl)(ethyl)sulfane (10.0 g, 25.4 mmol) in THF (127 mL), phenylboronic acid (3.1 g, 25.4 mmol), Pd(PPh₃)₄ (1.76 g, 1.53 mmol), NaOH (3.05 g, 76.3 mmol) and H₂O (64 mL) were added to the solution, and then the synthesis was carried out in the same manner as in the synthesis method of Sub1-c-1 to obtain 7.2 g (yield: 83%) of the product.

### (2) Synthesis of Sub1-b-38

Sub1-a-38 (7.2 g, 21.1 mmol), H₂O₂ (6.0 mL) and acetic acid (84 mL) were putted into a round bottom flask, and then the synthesis was carried out in the same manner as in the synthesis method of Sub1-b-31 to obtain 6.4 g (yield: 85%) of the product.

### (3) Synthesis of Sub1-38

Sub1-b-38 (6.4 g, 17.9 mmol) was dissolved in excess H₂SO₄, and then the synthesis was carried out in the same manner as in the synthesis method of Sub1-31 to obtain 5.2 g (yield: 92%) of the product.

### 7. Synthesis Example of Sub1-42

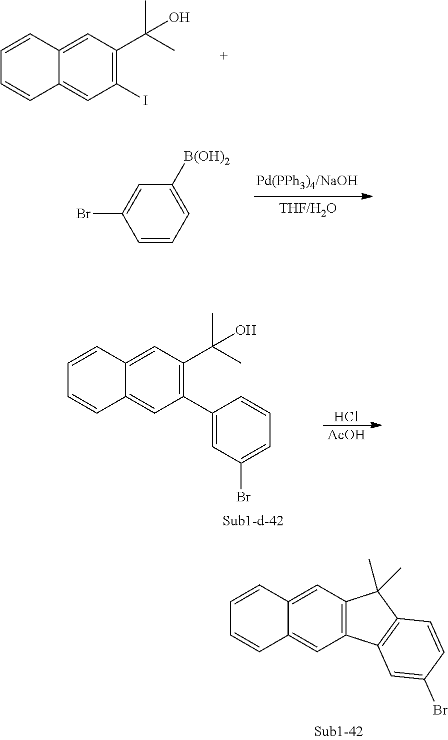

### (1) Synthesis of Sub1-d-42

After dissolving 2-(3-iodonaphthalen-2-yl)propan-2-ol (10.0 g, 32.0 mmol) in THF (160 mL), (3-bromophenyl)boronic acid (6.4 g, 32.0 mmol), Pd(PPh₃)₄ (2.22 g, 1.92 mmol), NaOH (3.8 g, 96.1 mmol) and H₂O (80 mL) were added to the solution, and then the synthesis was carried out in the same manner as in the synthesis method of Sub1-c-1 to obtain 9.5 g (yield: 87%) of the product.

### (2) Synthesis of Sub1-42

Sub1-d-42 (9.5 g, 27.9 mmol), acetic acid (70 mL) and concentrated hydrochloric acid (10 mL) were added to a round bottom flask and stirred at 80° C. for 3 hours under a nitrogen atmosphere. When the reaction was completed, the reaction product was extracted with CH₂Cl₂ and water, and then an organic layer was dried with MgSO₄ and concentrated. Then, the concentrate was separated through a silica gel column and recrystallized to obtain 6.6 g (yield: 73%) of the product.

### 8. Synthesis Example of Sub1-46

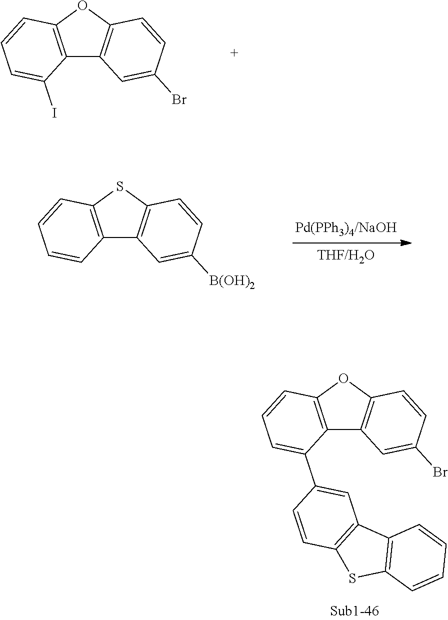 [SMILES: Brc1ccc2oc3cccc(I)c3c2c1 ; OB(O)c1ccc2sc3ccccc3c2c1 ; Brc1ccc2oc3cccc(-c4ccc5sc6ccccc6c5c4)c3c2c1]

After dissolving 8-bromo-1-iododibenzo[b,d]furan (10.0 g, 26.8 mmol) in THF (134 mL), dibenzo[b,d]thiophen-2-ylboronic acid (6.1 g, 26.8 mmol), Pd(PPh₃)₄ (1.86 g, 1.61 mmol), NaOH (3.2 g, 80.4 mmol), H₂O (67 mL) were added to the solution, and then the synthesis was carried out in the same manner as in the synthesis method of Sub1-4 to obtain 9.0 g (yield: 78%) of the product.

### 9. Synthesis Example of Sub1-49

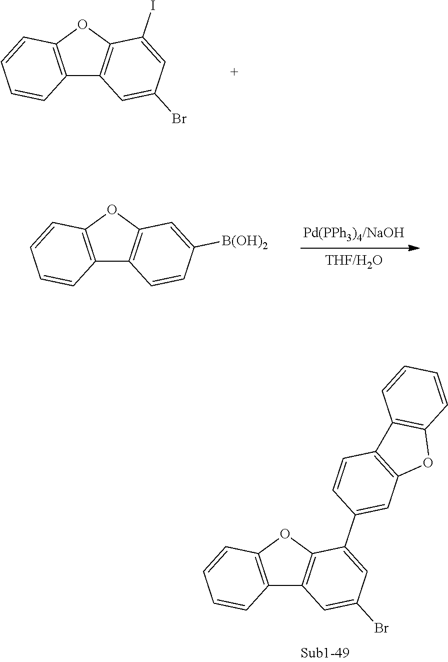 [SMILES: Brc1cc(I)c2oc3ccccc3c2c1 ; OB(O)c1ccc2c(c1)oc1ccccc12 ; Brc1cc(-c2ccc3c(c2)oc2ccccc23)c2oc3ccccc3c2c1]

After dissolving 2-bromo-4-iododibenzo[b,d]furan (10.0 g, 26.8 mmol) in THF (134 mL), dibenzo[b,d]furan-3-ylboronic acid (5.7 g, 26.8 mmol), Pd(PPh₃)₄ (1.86 g, 1.61 mmol), NaOH (3.2 g, 80.4 mmol) and H₂O (67 mL) were added to the solution, and then the synthesis was carried out in the same manner as in the synthesis method of Sub1-4 to obtain 9.2 g (yield: 83%) of the product.

### 10. Synthesis Example of Sub1-56

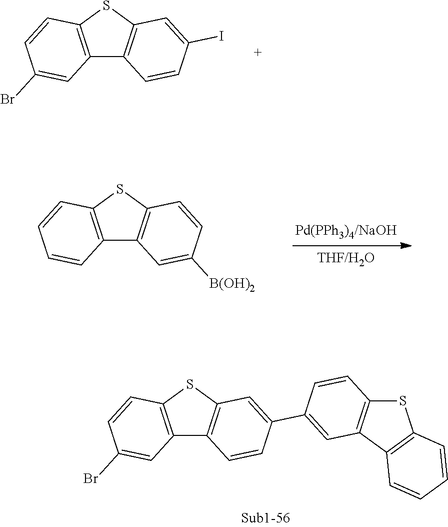 [SMILES: Brc1ccc2sc3cc(I)ccc3c2c1 ; OB(O)c1ccc2sc3ccccc3c2c1 ; Brc1ccc2sc3cc(-c4ccc5sc6ccccc6c5c4)ccc3c2c1]

After dissolving 2-bromo-7-iododibenzo[b,d]thiophene (10.0 g, 25.7 mmol) in THF (129 mL), dibenzo[b,d]thiophen-2-ylboronic acid (5.9 g, 25.7 mmol), Pd(PPh₃)₄ (1.78 g, 1.54 mmol), NaOH (3.1 g, 77.1 mmol) and H₂O (64 mL) were added to the solution, and then the synthesis was carried out in the same manner as in the synthesis method of Sub1-4 to obtain 9.8 g (yield: 86%) of the product.

### 11. Synthesis Example of Sub1-58

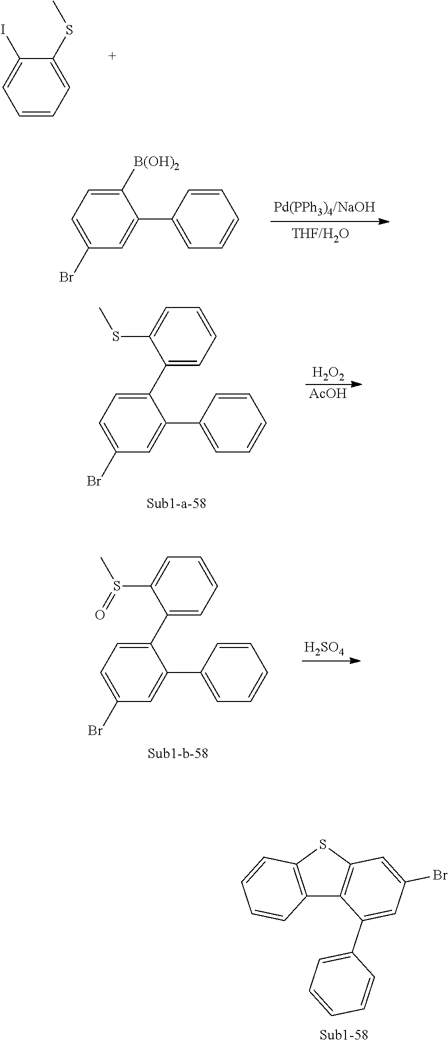

### (1) Synthesis of Sub1-a-58

After dissolving (2-iodophenyl)(methyl)sulfane (10.0 g, 40.0 mmol) in THF (200 mL), (5-bromo-[1,1′-biphenyl]-2-yl)boronic acid (11.1 g, 40.0 mmol), Pd(PPh₃)₄ (2.77 g, 2.40 mmol), NaOH (4.80 g, 120 mmol) and H₂O (100 mL) were added to the solution, and then the synthesis was carried out in the same manner as in the synthesis method of Sub1-c-1 to obtain 10.8 g (yield: 76%) of the product.

### (2) Synthesis of Sub1-b-58

Sub1-a-58 (10.8 g, 30.4 mmol), H₂O₂ (8.68 mL) and acetic acid (122 mL) were putted into a round bottom flask, and then the synthesis was carried out in the same manner as in the synthesis method of Sub1-b-31 to obtain 10.2 g (yield: 90%) of the product.

### (3) Synthesis of Sub1-58

Sub1-b-58 (10.2 g, 27.3 mmol) was dissolved in excess H₂SO₄, and then the synthesis was carried out in the same manner as in the synthesis method of Sub1-31 to obtain 8.3 g (yield: 89%) of the product.

Compounds belonging to Sub 1 may be, but not limited to, the following compounds, and Table 1 shows FD-MS (Field Desorption-Mass Spectrometry) values of the following compounds.

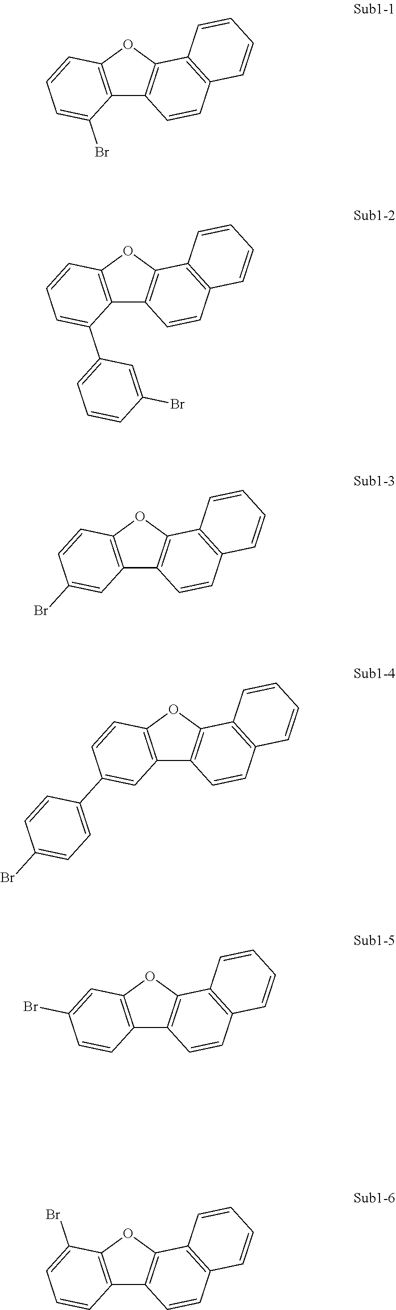 [SMILES: Brc1cccc2oc3c4ccccc4ccc3c12 ; Brc1cccc(-c2cccc3oc4c5ccccc5ccc4c23)c1 ; Brc1ccc2oc3c4ccccc4ccc3c2c1 ; Brc1ccc(-c2ccc3oc4c5ccccc5ccc4c3c2)cc1 ; Brc1ccc2c(c1)oc1c3ccccc3ccc21 ; Brc1cccc2c1oc1c3ccccc3ccc21]

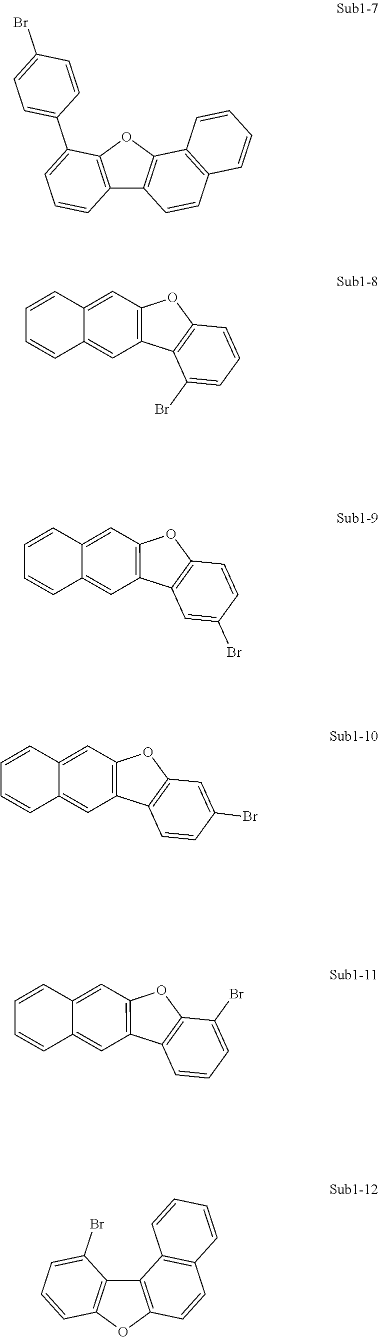 [SMILES: Brc1ccc(-c2cccc3c2oc2c4ccccc4ccc32)cc1 ; Brc1cccc2oc3cc4ccccc4cc3c12 ; Brc1ccc2oc3cc4ccccc4cc3c2c1 ; Brc1ccc2c(c1)oc1cc3ccccc3cc12 ; Brc1cccc2c1oc1cc3ccccc3cc12 ; Brc1cccc2oc3ccc4ccccc4c3c12]

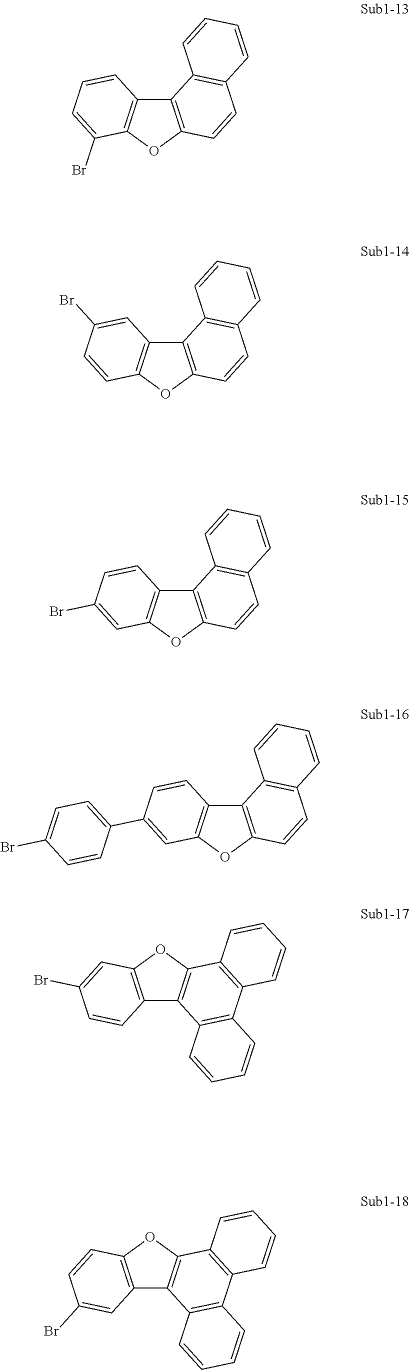 [SMILES: Brc1cccc2c1oc1ccc3ccccc3c12 ; Brc1ccc2oc3ccc4ccccc4c3c2c1 ; Brc1ccc2c(c1)oc1ccc3ccccc3c12 ; Brc1ccc(-c2ccc3c(c2)oc2ccc4ccccc4c23)cc1 ; Brc1ccc2c(c1)oc1c3ccccc3c3ccccc3c21 ; Brc1ccc2oc3c4ccccc4c4ccccc4c3c2c1]

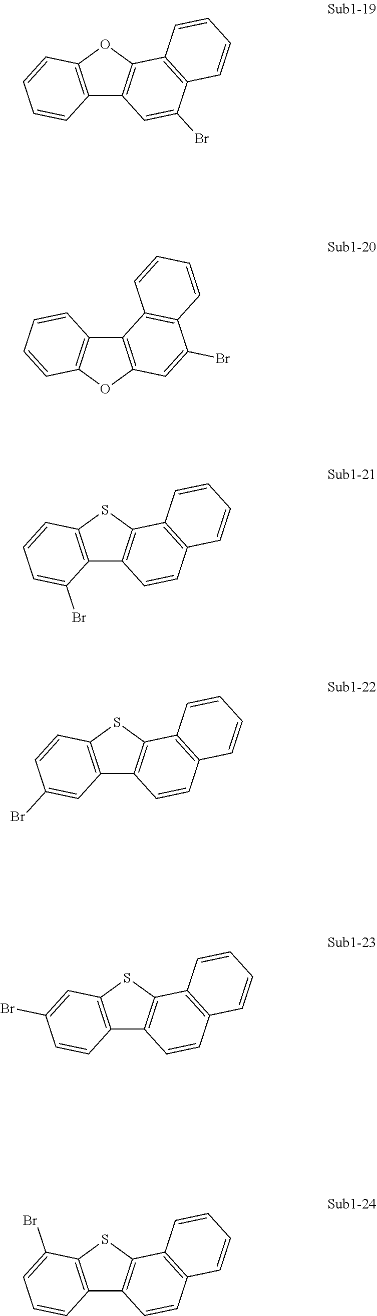 [SMILES: Brc1cc2c3ccccc3oc2c2ccccc12 ; Brc1cc2oc3ccccc3c2c2ccccc12 ; Brc1cccc2sc3c4ccccc4ccc3c12 ; Brc1ccc2sc3c4ccccc4ccc3c2c1 ; Brc1ccc2c(c1)sc1c3ccccc3ccc21 ; Brc1cccc2c1sc1c3ccccc3ccc21]

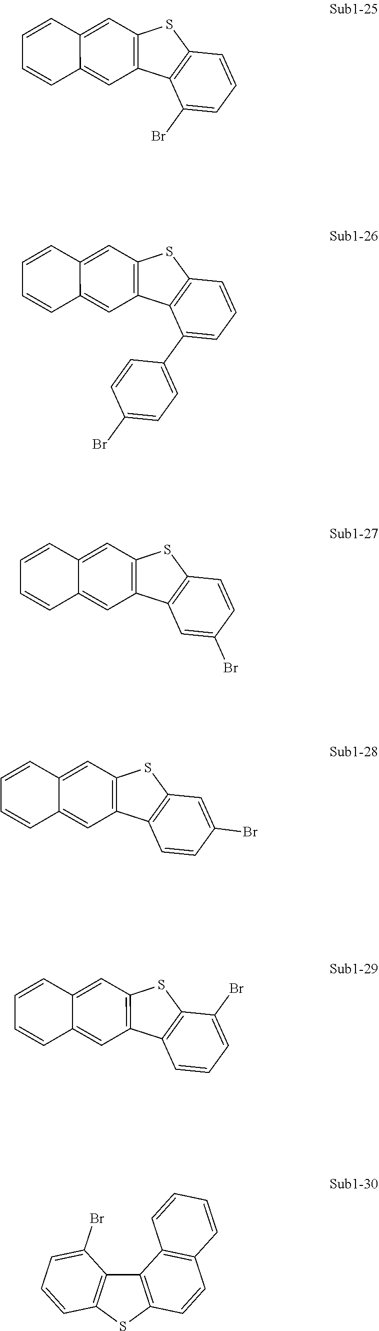 [SMILES: Brc1cccc2sc3cc4ccccc4cc3c12 ; Brc1ccc(-c2cccc3sc4cc5ccccc5cc4c23)cc1 ; Brc1ccc2sc3cc4ccccc4cc3c2c1 ; Brc1ccc2c(c1)sc1cc3ccccc3cc12 ; Brc1cccc2c1sc1cc3ccccc3cc12 ; Brc1cccc2sc3ccc4ccccc4c3c12]

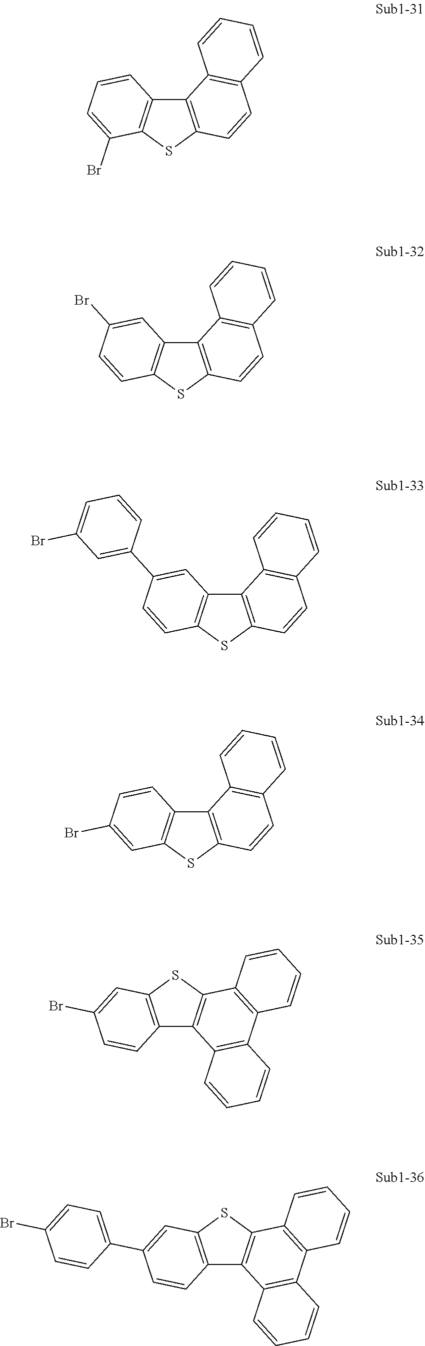 [SMILES: Brc1cccc2c1sc1ccc3ccccc3c12 ; Brc1ccc2sc3ccc4ccccc4c3c2c1 ; Brc1cccc(-c2ccc3sc4ccc5ccccc5c4c3c2)c1 ; Brc1ccc2c(c1)sc1ccc3ccccc3c12 ; Brc1ccc2c(c1)sc1c3ccccc3c3ccccc3c21 ; Brc1ccc(-c2ccc3c(c2)sc2c4ccccc4c4ccccc4c32)cc1]

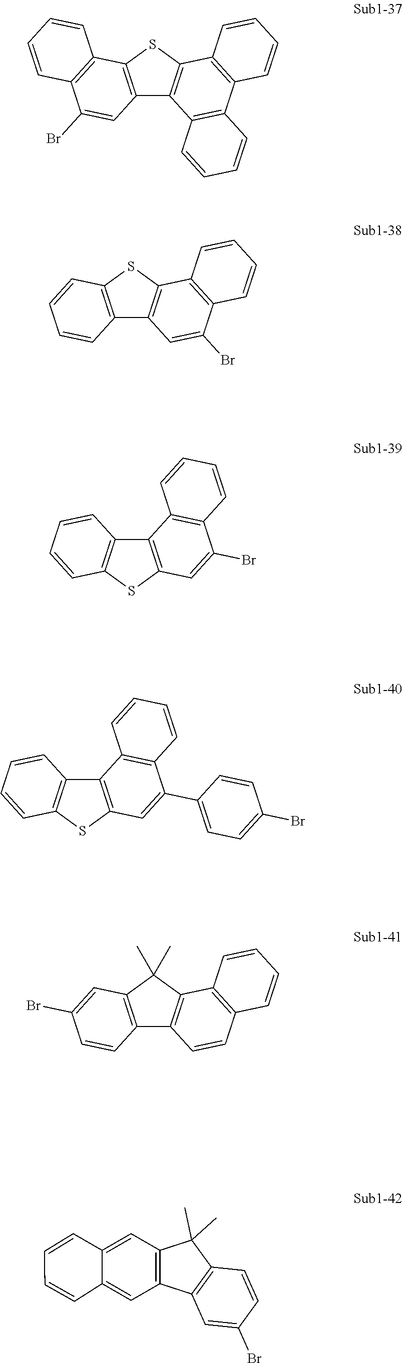 [SMILES: Brc1cc2c(sc3c4ccccc4c4ccccc4c23)c2ccccc12 ; Brc1cc2c3ccccc3sc2c2ccccc12 ; Brc1cc2sc3ccccc3c2c2ccccc12 ; Brc1ccc(-c2cc3sc4ccccc4c3c3ccccc23)cc1 ; CC1(C)c2cc(Br)ccc2-c2ccc3ccccc3c21 ; CC1(C)c2ccc(Br)cc2-c2cc3ccccc3cc21]

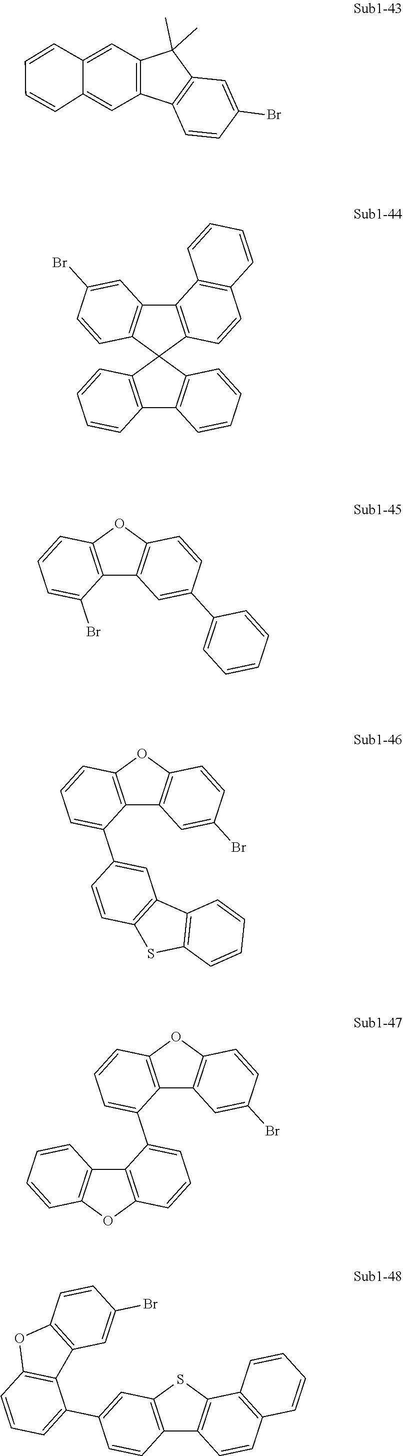 [SMILES: CC1(C)c2cc(Br)ccc2-c2cc3ccccc3cc21 ; Brc1ccc2c(c1)-c1c(ccc3ccccc13)C21c2ccccc2-c2ccccc21 ; Brc1cccc2oc3ccc(-c4ccccc4)cc3c12 ; Brc1ccc2oc3cccc(-c4ccc5sc6ccccc6c5c4)c3c2c1 ; Brc1ccc2oc3cccc(-c4cccc5oc6ccccc6c45)c3c2c1 ; Brc1ccc2oc3cccc(-c4ccc5c(c4)sc4c6ccccc6ccc54)c3c2c1]

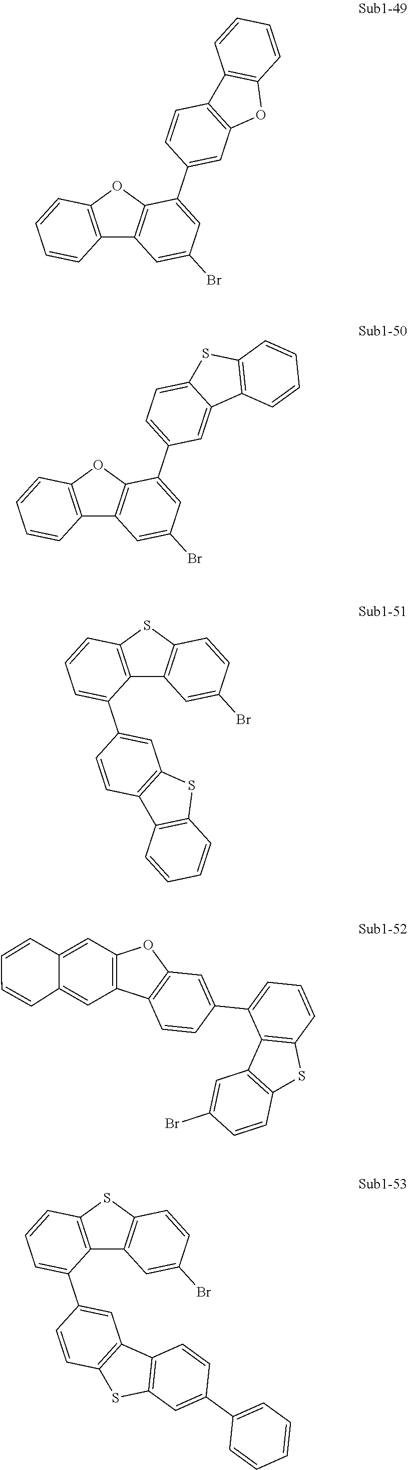 [SMILES: Brc1cc(-c2ccc3c(c2)oc2ccccc23)c2oc3ccccc3c2c1 ; Brc1cc(-c2ccc3sc4ccccc4c3c2)c2oc3ccccc3c2c1 ; Brc1ccc2sc3cccc(-c4ccc5c(c4)sc4ccccc45)c3c2c1 ; Brc1ccc2sc3cccc(-c4ccc5c(c4)oc4cc6ccccc6cc45)c3c2c1 ; Brc1ccc2sc3cccc(-c4ccc5sc6cc(-c7ccccc7)ccc6c5c4)c3c2c1]

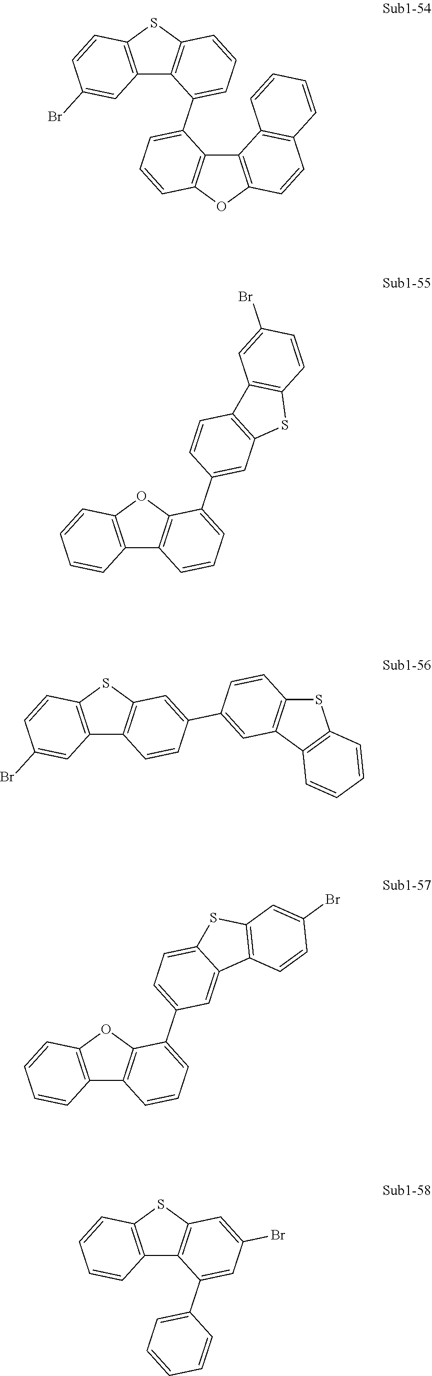 [SMILES: Brc1ccc2sc3cccc(-c4cccc5oc6ccc7ccccc7c6c45)c3c2c1 ; Brc1ccc2sc3cc(-c4cccc5c4oc4ccccc45)ccc3c2c1 ; Brc1ccc2sc3cc(-c4ccc5sc6ccccc6c5c4)ccc3c2c1 ; Brc1ccc2c(c1)sc1ccc(-c3cccc4c3oc3ccccc34)cc12 ; Brc1cc(-c2ccccc2)c2c(c1)sc1ccccc12]

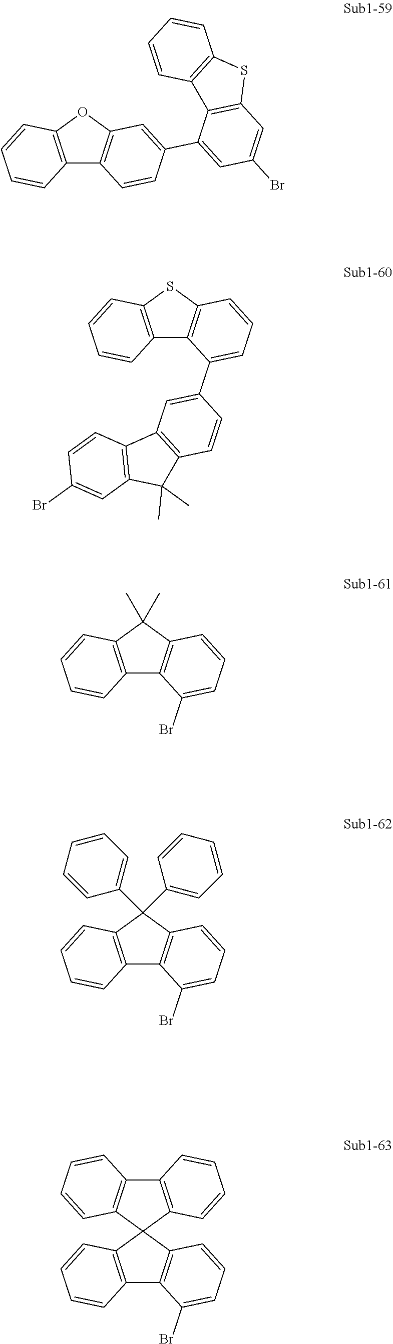 [SMILES: Brc1cc(-c2ccc3c(c2)oc2ccccc23)c2c(c1)sc1ccccc12 ; CC1(C)c2ccc(-c3cccc4sc5ccccc5c34)cc2-c2ccc(Br)cc21 ; CC1(C)c2ccccc2-c2c(Br)cccc21 ; Brc1cccc2c1-c1ccccc1C2(c1ccccc1)c1ccccc1 ; Brc1cccc2c1-c1ccccc1C21c2ccccc2-c2ccccc21]

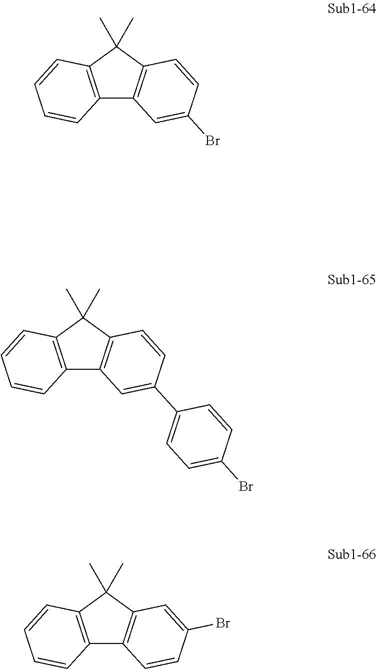 [SMILES: CC1(C)c2ccccc2-c2cc(Br)ccc21 ; CC1(C)c2ccccc2-c2cc(-c3ccc(Br)cc3)ccc21 ; CC1(C)c2ccccc2-c2ccc(Br)cc21]

TABLE 1

| Compound | FD-MS | Compound | FD-MS |
|---|---|---|---|
| Sub1-1 | m/z = 295.98(C₁₆H₉BrO = 297.15) | Sub1-2 | m/z = 372.01(C₂₂H₁₃BrO = 373.25) |
| Sub1-3 | m/z = 295.98(C₁₆H₉BrO = 297.15) | Sub1-4 | m/z = 372.01(C₂₂H₁₃BrO = 373.25) |
| Sub1-5 | m/z = 295.98(C₁₆H₉BrO = 297.15) | Sub1-6 | m/z = 295.98(C₁₆H₉BrO = 297.15) |
| Sub1-7 | m/z = 372.01(C₂₂H₁₃BrO = 373.25) | Sub1-8 | m/z = 295.98(C₁₆H₉BrO = 297.15) |
| Sub1-9 | m/z = 295.98(C₁₆H₉BrO = 297.15) | Sub1-10 | m/z = 295.98(C₁₆H₉BrO = 297.15) |
| Sub1-11 | m/z = 295.98(C₁₆H₉BrO = 297.15) | Sub1-12 | m/z = 295.98(C₁₆H₉BrO = 297.15) |
| Sub1-13 | m/z = 295.98(C₁₆H₉BrO = 297.15) | Sub1-14 | m/z = 295.98(C₁₆H₉BrO = 297.15) |
| Sub1-15 | m/z = 295.98(C₁₆H₉BrO = 297.15) | Sub1-16 | m/z = 372.01(C₂₂H₁₃BrO = 373.25) |
| Sub1-17 | m/z = 346(C₂₀H₁₁BrO = 347.21) | Sub1-18 | m/z = 346(C₂₀H₁₁BrO = 347.21) |
| Sub1-19 | m/z = 295.98(C₁₆H₉BrO = 297.15) | Sub1-20 | m/z = 295.98(C₁₆H₉BrO = 297.15) |
| Sub1-21 | m/z = 311.96(C₁₆H₉BrS = 313.21) | Sub1-22 | m/z = 311.96(C₁₆H₉BrS = 313.21) |
| Sub1-23 | m/z = 311.96(C₁₆H₉BrS = 313.21) | Sub1-24 | m/z = 311.96(C₁₆H₉BrS = 313.21) |
| Sub1-25 | m/z = 311.96(C₁₆H₉BrS = 313.21) | Sub1-26 | m/z = 387.99(C₂₂H₁₃BrS = 389.31) |
| Sub1-27 | m/z = 311.96(C₁₆H₉BrS = 313.21) | Sub1-28 | m/z = 311.96(C₁₆H₉BrS = 313.21) |
| Sub1-29 | m/z = 311.96(C₁₆H₉BrS = 313.21) | Sub1-30 | m/z = 311.96(C₁₆H₉BrS = 313.21) |
| Sub1-31 | m/z = 311.96(C₁₆H₉BrS = 313.21) | Sub1-32 | m/z = 311.96(C₁₆H₉BrS = 313.21) |
| Sub1-33 | m/z = 387.99(C₂₂H₁₃BrS = 389.31) | Sub1-34 | m/z = 311.96(C₁₆H₉BrS = 313.21) |
| Sub1-35 | m/z = 361.98(C₂₀H₁₁BrS = 363.27) | Sub1-36 | m/z = 438.01(C₂₆H₁₅BrS = 439.37) |
| Sub1-37 | m/z = 411.99(C₂₄H₁₃BrS = 413.33) | Sub1-38 | m/z = 311.96(C₁₆H₉BrS = 313.21) |
| Sub1-39 | m/z = 311.96(C₁₆H₉BrS = 313.21) | Sub1-40 | m/z = 387.99(C₂₂H₁₃BrS = 389.31) |
| Sub1-41 | m/z = 322.04(C₁₉H₁₅Br = 323.23) | Sub1-42 | m/z = 322.04(C₁₉H₁₅Br = 323.23) |
| Sub1-43 | m/z = 322.04(C₁₉H₁₅Br = 323.23) | Sub1-44 | m/z = 444.05(C₂₉H₁₇Br = 445.36) |
| Sub1-45 | m/z = 322(C₁₈H₁₁BrO = 323.19) | Sub1-46 | m/z = 427.99(C₂₄H₁₃BrOS = 429.33) |
| Sub1-47 | m/z = 412.01(C₂₄H₁₃BrO₂ = 413.27) | Sub1-48 | m/z = 478(C₂₈H₁₅BrOS = 479.39) |
| Sub1-49 | m/z = 412.01(C₂₄H₁₃BrO₂ = 413.27) | Sub1-50 | m/z = 427.99(C₂₄H₁₃BrOS = 429.33) |
| Sub1-51 | m/z = 443.96(C₂₄H₁₃BrS₂ = 445.39) | Sub1-52 | m/z = 478(C₂₈H₁₅BrOS = 479.39) |
| Sub1-53 | m/z = 520(C₃₀H₁₇BrS₂ = 521.49) | Sub1-54 | m/z = 493.98(C₂₈H₁₅BrS₂ = 495.45) |
| Sub1-55 | m/z = 427.99(C₂₄H₁₃BrOS = 429.33) | Sub1-56 | m/z = 443.96(C₂₄H₁₃BrS₂ = 445.39) |
| Sub1-57 | m/z = 427.99(C₂₄H₁₃BrOS = 429.33) | Sub1-58 | m/z = 337.98(C₁₈H₁₁BrS = 339.25) |
| Sub1-59 | m/z = 427.99(C₂₄H₁₃BrOS = 429.33) | Sub1-60 | m/z = 454.04(C₂₇H₁₉BrS = 455.41) |
| Sub1-61 | m/z = 272.02(C₁₅H₁₃Br = 273.17) | Sub1-62 | m/z = 396.05(C₂₅H₁₇Br = 397.32) |
| Sub1-63 | m/z = 394.04(C₂₅H₁₅Br = 395.3) | Sub1-64 | m/z = 272.02(C₁₅H₁₃Br = 273.17) |
| Sub1-65 | m/z = 348.05(C₂₁H₁₇Br = 349.27) | Sub1-66 | m/z = 272.02(C₁₅H₁₃Br = 273.17) |

### Synthesis Example of Sub 2

Sub 2 of Reaction Scheme 1 may be synthesized by the reaction route of Reaction Scheme 3 below (disclosed in Korean Patent No. 10-1251451 of the applicant of the present invention (registration notice dated Apr. 5, 2013)), but is not limited thereto.

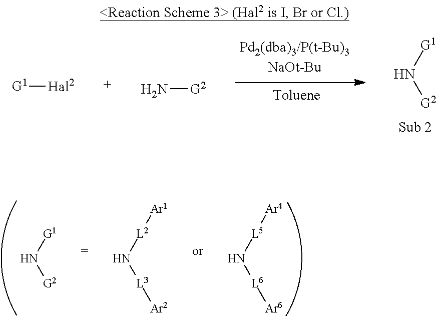

Compounds belonging to Sub 2 may be, but not limited to, the following compounds, and Table 2 shows FD-MS (Field Desorption-Mass Spectrometry) values of some compounds belonging to Sub 2.

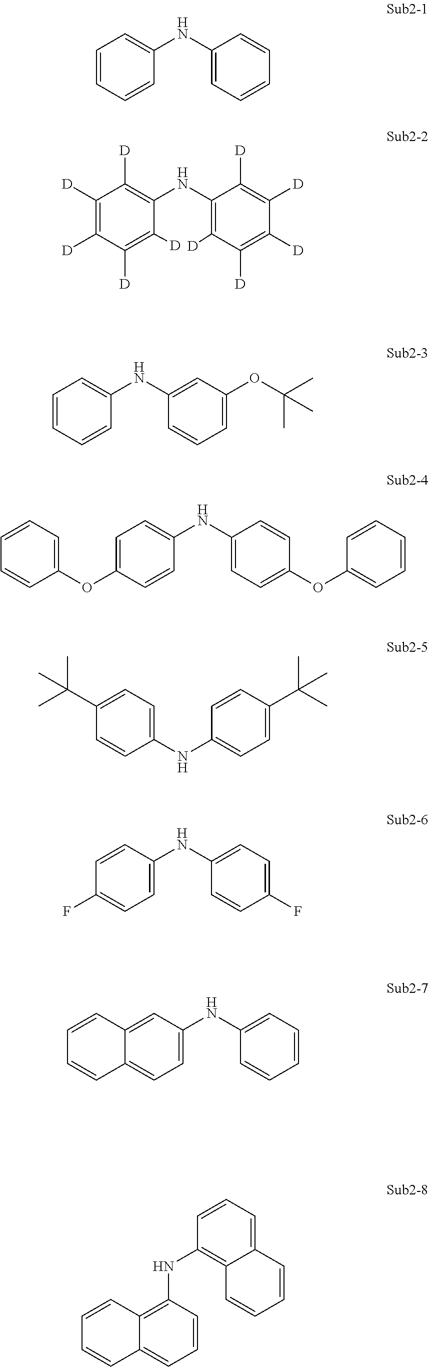

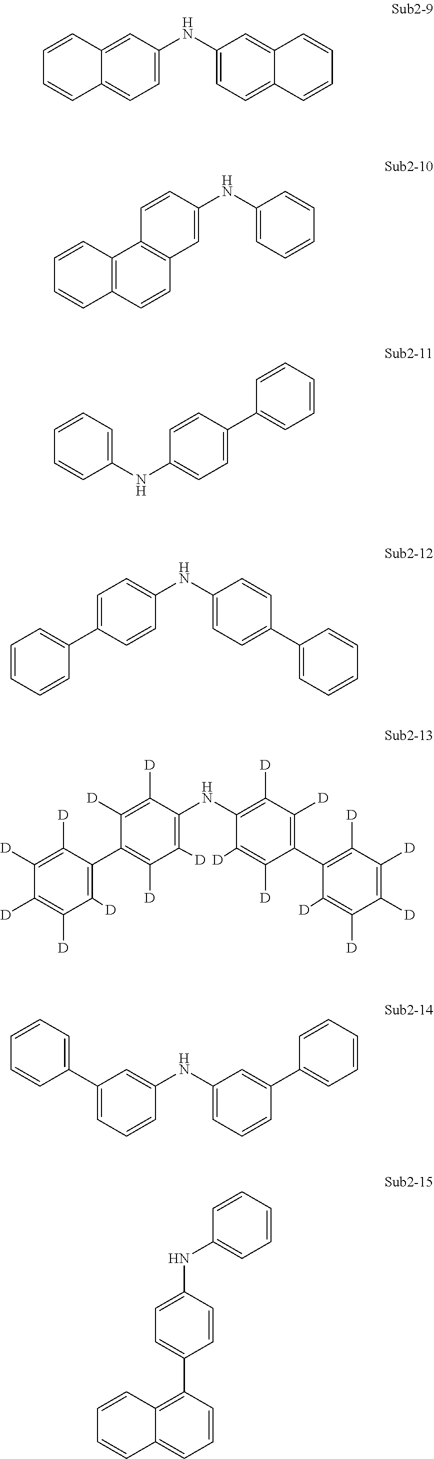

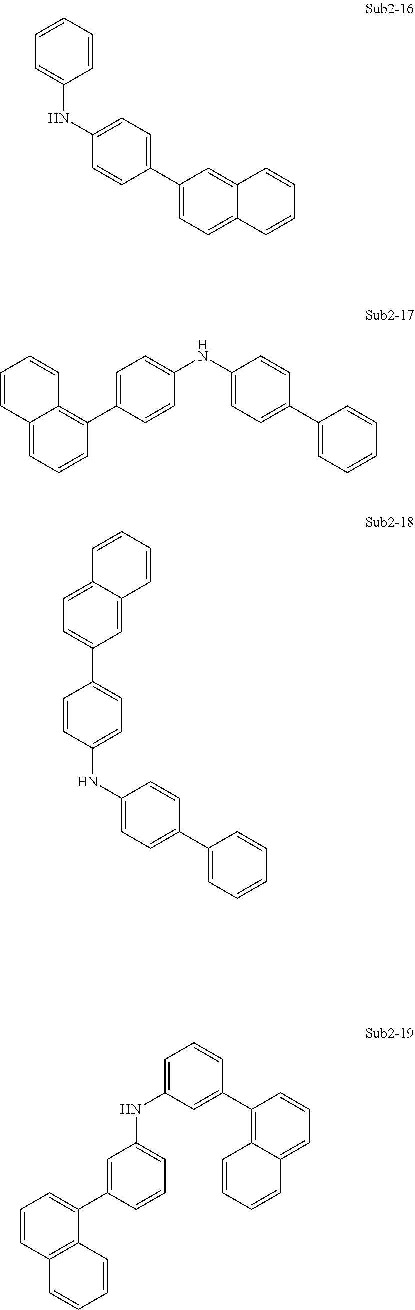 [SMILES: c1ccc(Nc2ccc(-c3ccc4ccccc4c3)cc2)cc1 ; c1ccc(-c2ccc(Nc3ccc(-c4cccc5ccccc45)cc3)cc2)cc1 ; c1ccc(-c2ccc(Nc3ccc(-c4ccc5ccccc5c4)cc3)cc2)cc1 ; c1cc(Nc2cccc(-c3cccc4ccccc34)c2)cc(-c2cccc3ccccc23)c1]

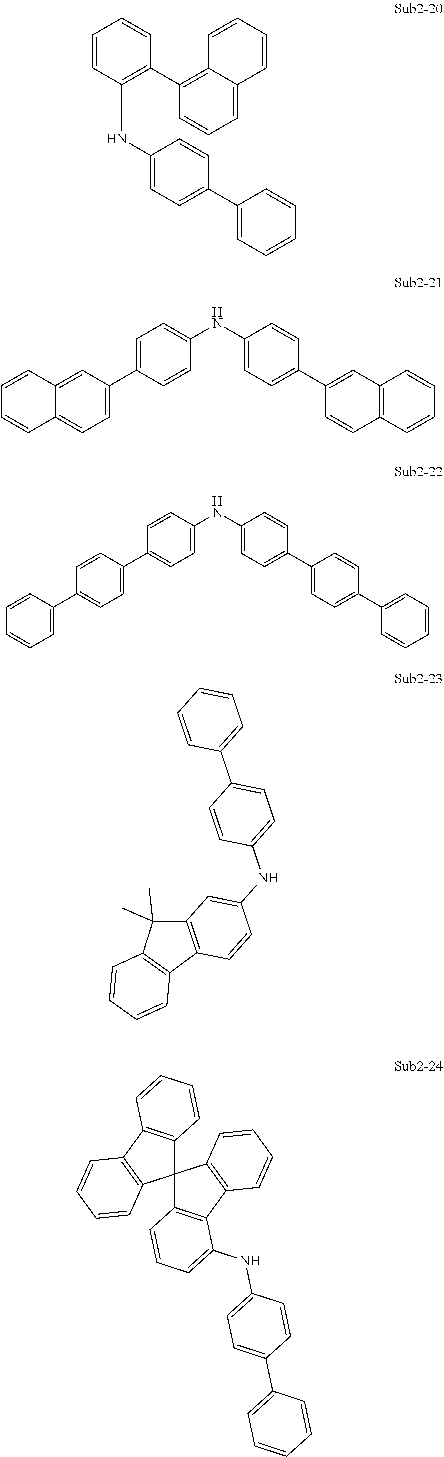 [SMILES: c1ccc(-c2ccc(Nc3ccccc3-c3cccc4ccccc34)cc2)cc1 ; c1ccc2cc(-c3ccc(Nc4ccc(-c5ccc6ccccc6c5)cc4)cc3)ccc2c1 ; c1ccc(-c2ccc(-c3ccc(Nc4ccc(-c5ccc(-c6ccccc6)cc5)cc4)cc3)cc2)cc1 ; CC1(C)c2ccccc2-c2ccc(Nc3ccc(-c4ccccc4)cc3)cc21 ; c1ccc(-c2ccc(Nc3cccc4c3-c3ccccc3C43c4ccccc4-c4ccccc43)cc2)cc1]

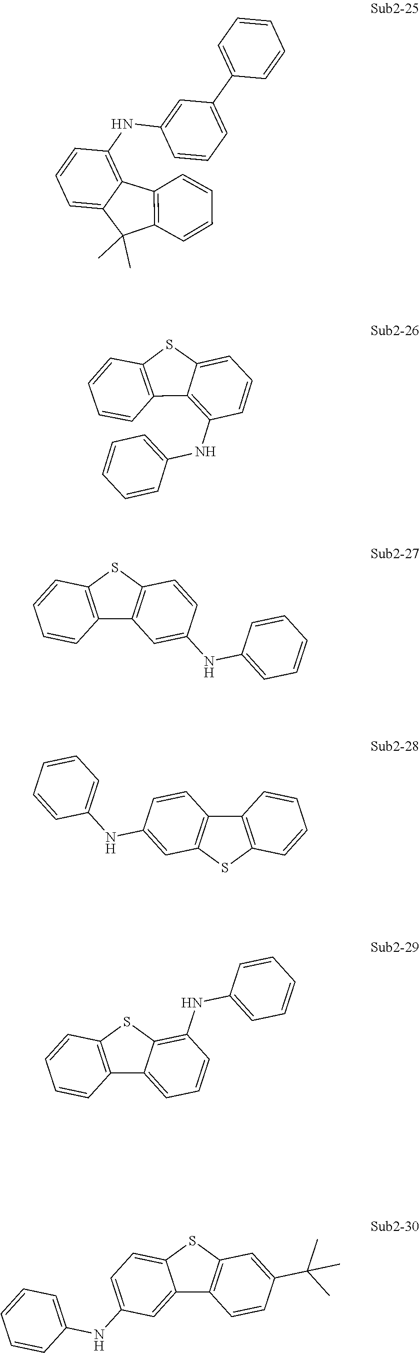 [SMILES: CC1(C)c2ccccc2-c2c(Nc3cccc(-c4ccccc4)c3)cccc21 ; c1ccc(Nc2cccc3sc4ccccc4c23)cc1 ; c1ccc(Nc2ccc3sc4ccccc4c3c2)cc1 ; c1ccc(Nc2ccc3c(c2)sc2ccccc23)cc1 ; c1ccc(Nc2cccc3c2sc2ccccc23)cc1 ; CC(C)(C)c1ccc2c(c1)sc1ccc(Nc3ccccc3)cc12]

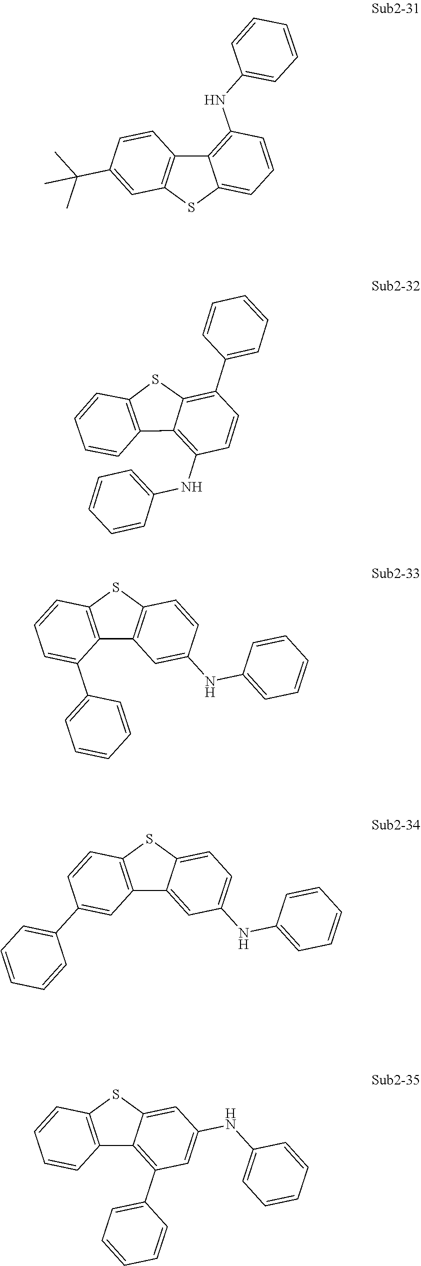 [SMILES: CC(C)(C)c1ccc2c(c1)sc1cccc(Nc3ccccc3)c12 ; c1ccc(Nc2ccc(-c3ccccc3)c3sc4ccccc4c23)cc1 ; c1ccc(Nc2ccc3sc4cccc(-c5ccccc5)c4c3c2)cc1 ; c1ccc(Nc2ccc3sc4ccc(-c5ccccc5)cc4c3c2)cc1 ; c1ccc(Nc2cc(-c3ccccc3)c3c(c2)sc2ccccc23)cc1]

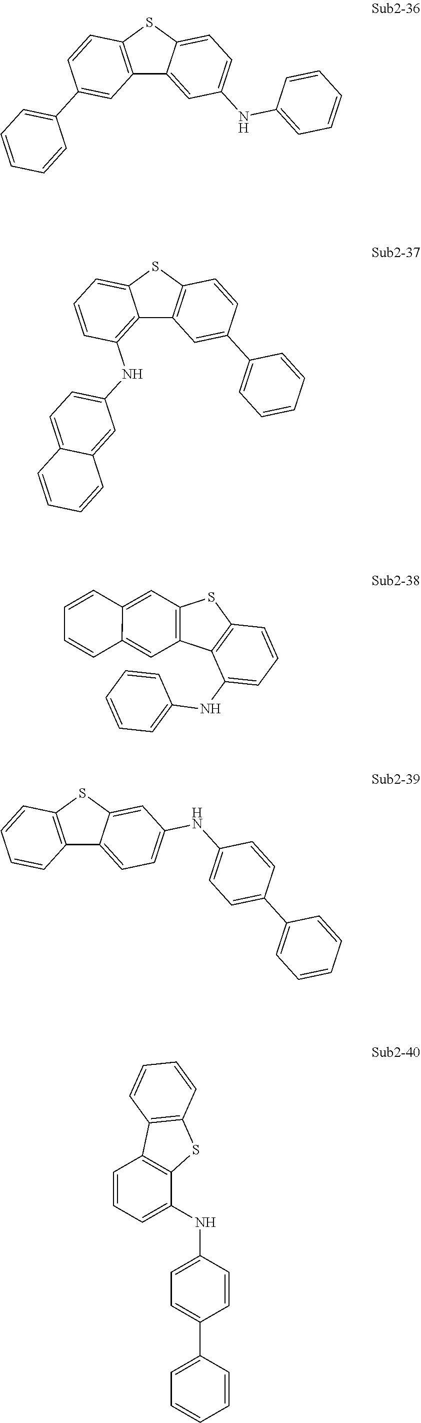 [SMILES: c1ccc(Nc2ccc3sc4ccc(-c5ccccc5)cc4c3c2)cc1 ; c1ccc(-c2ccc3sc4cccc(Nc5ccc6ccccc6c5)c4c3c2)cc1 ; c1ccc(Nc2cccc3sc4cc5ccccc5cc4c23)cc1 ; c1ccc(-c2ccc(Nc3ccc4c(c3)sc3ccccc34)cc2)cc1 ; c1ccc(-c2ccc(Nc3cccc4c3sc3ccccc34)cc2)cc1]

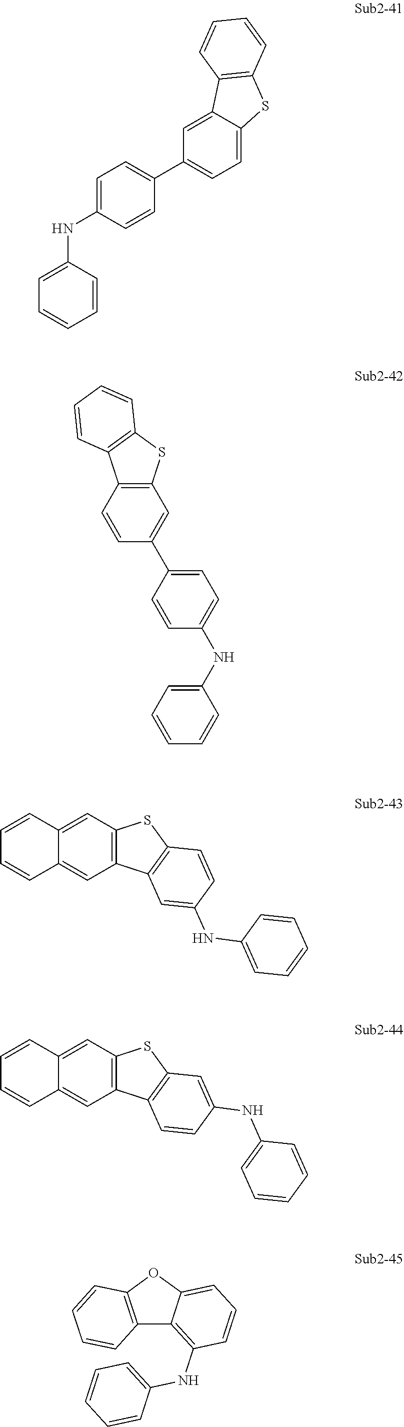 [SMILES: c1ccc(Nc2ccc(-c3ccc4sc5ccccc5c4c3)cc2)cc1 ; c1ccc(Nc2ccc(-c3ccc4c(c3)sc3ccccc34)cc2)cc1 ; c1ccc(Nc2ccc3sc4cc5ccccc5cc4c3c2)cc1 ; c1ccc(Nc2ccc3c(c2)sc2cc4ccccc4cc23)cc1 ; c1ccc(Nc2cccc3oc4ccccc4c23)cc1]

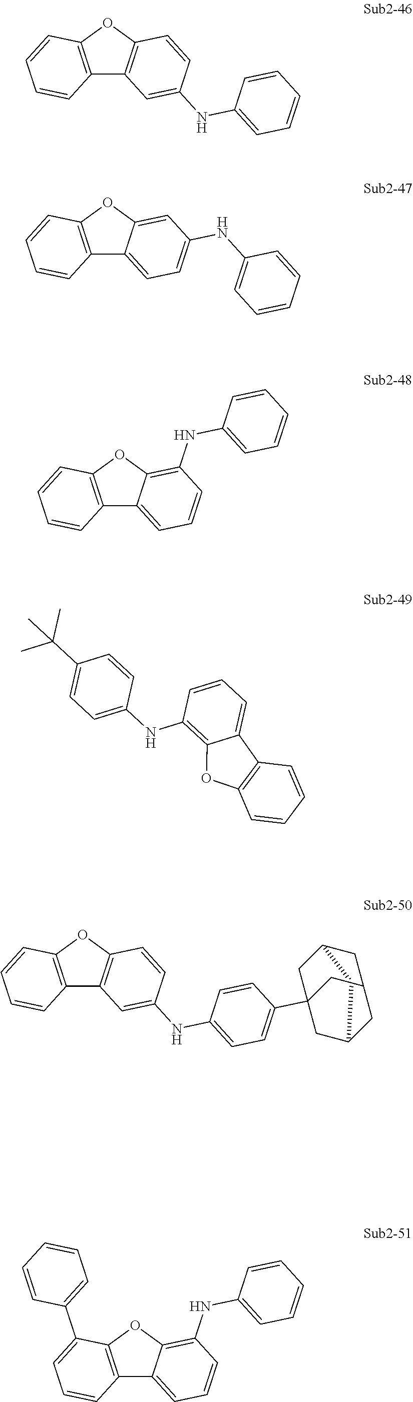 [SMILES: c1ccc(Nc2ccc3oc4ccccc4c3c2)cc1 ; c1ccc(Nc2ccc3c(c2)oc2ccccc23)cc1 ; c1ccc(Nc2cccc3c2oc2ccccc23)cc1 ; CC(C)(C)c1ccc(Nc2cccc3c2oc2ccccc23)cc1 ; c1ccc2c(c1)oc1ccc(Nc3ccc(C45CC6C[C@H](C4)C[C@@H](C6)C5)cc3)cc12 ; c1ccc(Nc2cccc3c2oc2c(-c4ccccc4)cccc23)cc1]

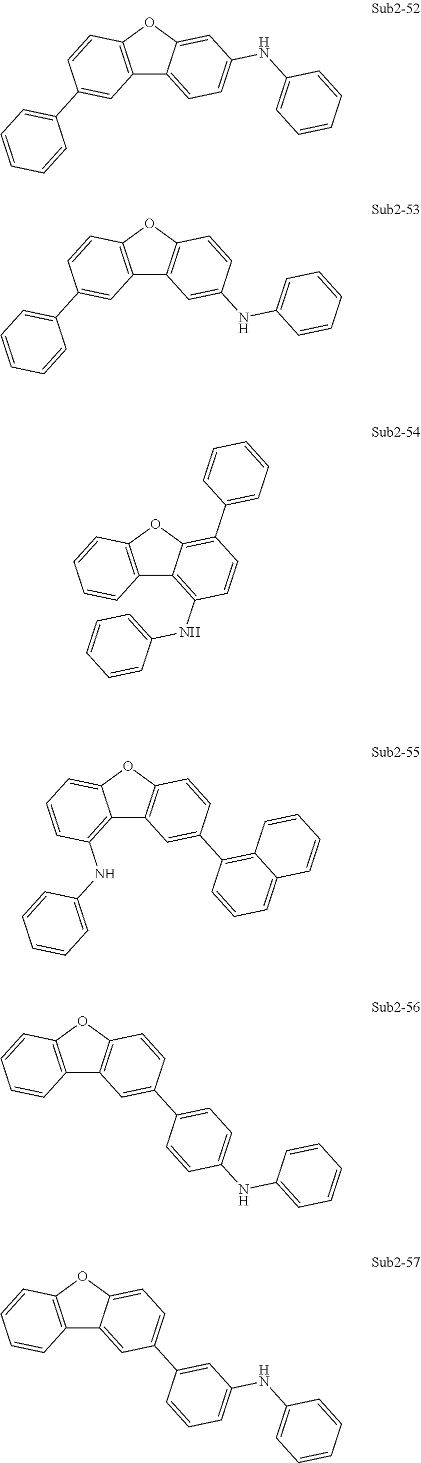 [SMILES: c1ccc(Nc2ccc3c(c2)oc2ccc(-c4ccccc4)cc23)cc1 ; c1ccc(Nc2ccc3oc4ccc(-c5ccccc5)cc4c3c2)cc1 ; c1ccc(Nc2ccc(-c3ccccc3)c3oc4ccccc4c23)cc1 ; c1ccc(Nc2cccc3oc4ccc(-c5cccc6ccccc56)cc4c23)cc1 ; c1ccc(Nc2ccc(-c3ccc4oc5ccccc5c4c3)cc2)cc1 ; c1ccc(Nc2cccc(-c3ccc4oc5ccccc5c4c3)c2)cc1]

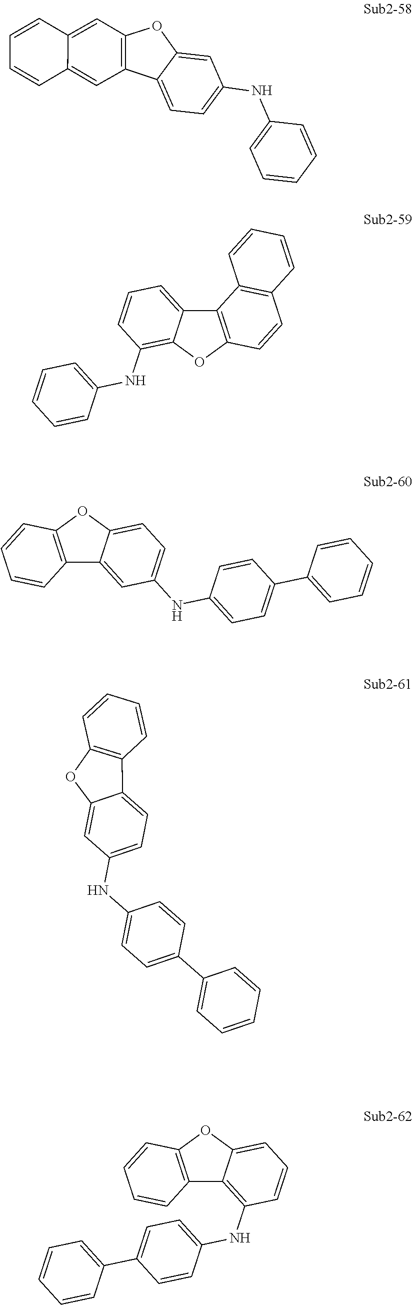 [SMILES: c1ccc(Nc2ccc3c(c2)oc2cc4ccccc4cc23)cc1 ; c1ccc(Nc2cccc3c2oc2ccc4ccccc4c23)cc1 ; c1ccc(-c2ccc(Nc3ccc4oc5ccccc5c4c3)cc2)cc1 ; c1ccc(-c2ccc(Nc3ccc4c(c3)oc3ccccc34)cc2)cc1 ; c1ccc(-c2ccc(Nc3cccc4oc5ccccc5c34)cc2)cc1]

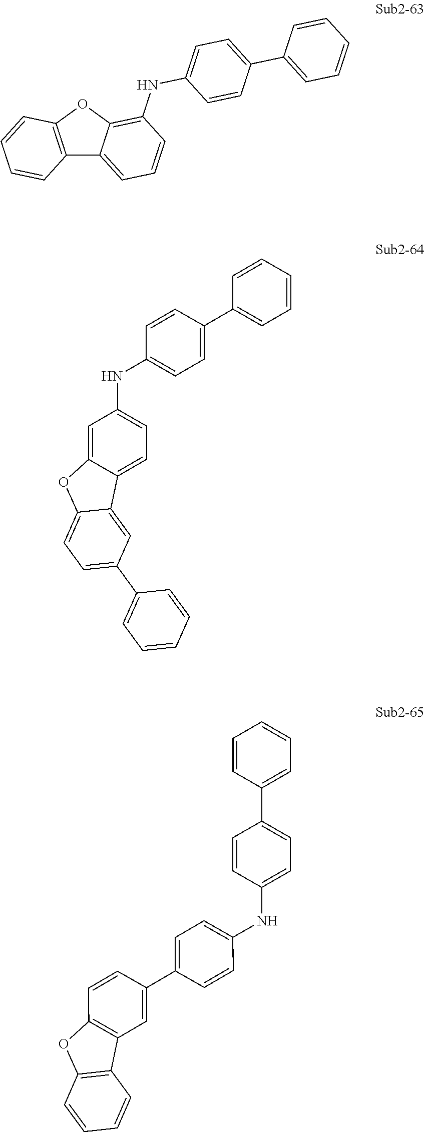 [SMILES: c1ccc(-c2ccc(Nc3cccc4c3oc3ccccc34)cc2)cc1 ; c1ccc(-c2ccc(Nc3ccc4c(c3)oc3ccc(-c5ccccc5)cc34)cc2)cc1 ; c1ccc(-c2ccc(Nc3ccc(-c4ccc5oc6ccccc6c5c4)cc3)cc2)cc1]

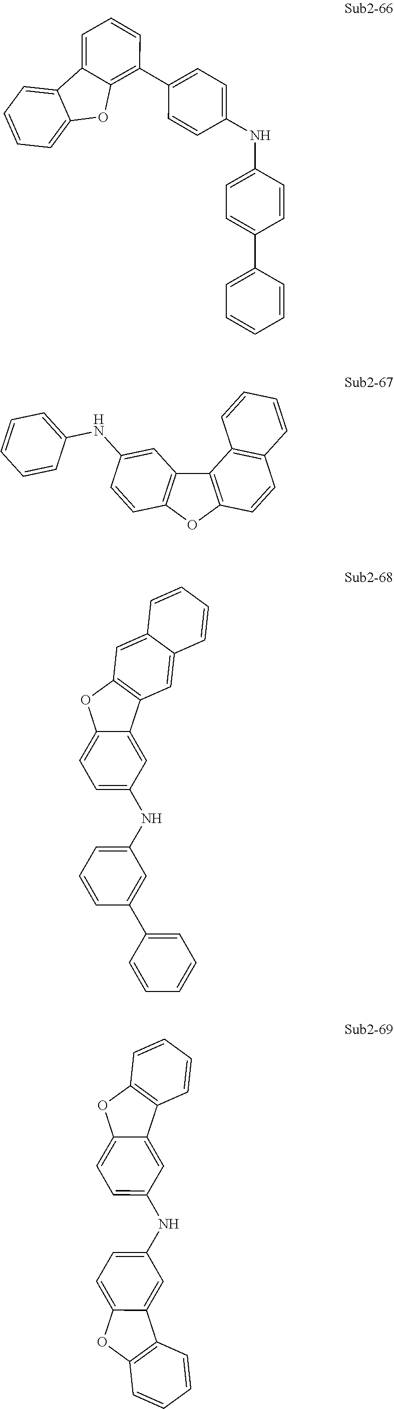 [SMILES: c1ccc(-c2ccc(Nc3ccc(-c4cccc5c4oc4ccccc45)cc3)cc2)cc1 ; c1ccc(Nc2ccc3oc4ccc5ccccc5c4c3c2)cc1 ; c1ccc(-c2cccc(Nc3ccc4oc5cc6ccccc6cc5c4c3)c2)cc1 ; c1ccc2c(c1)oc1ccc(Nc3ccc4oc5ccccc5c4c3)cc12]

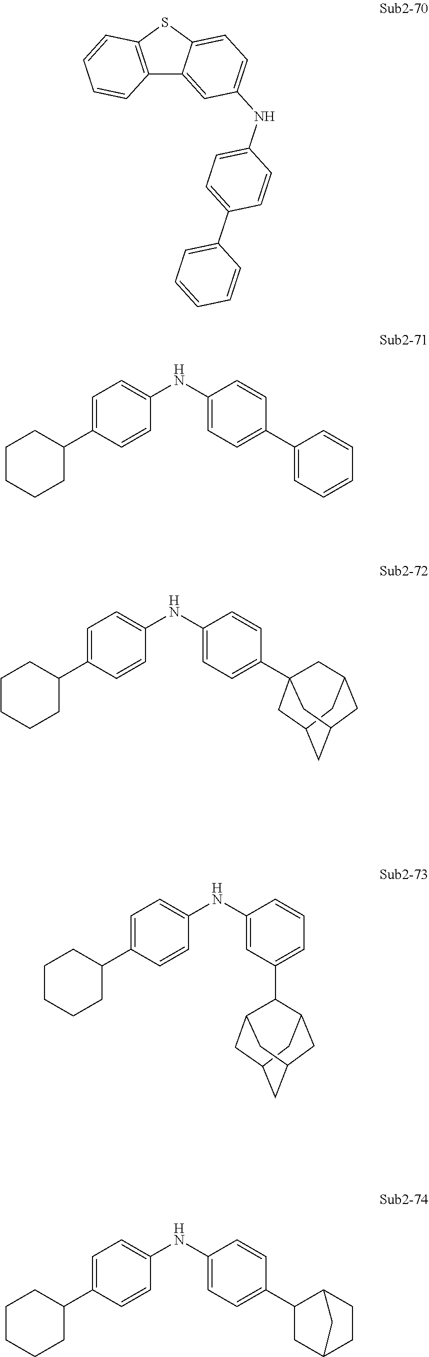 [SMILES: c1ccc(-c2ccc(Nc3ccc4sc5ccccc5c4c3)cc2)cc1 ; c1ccc(-c2ccc(Nc3ccc(C4CCCCC4)cc3)cc2)cc1 ; c1cc(C2CCCCC2)ccc1Nc1ccc(C23CC4CC(CC(C4)C2)C3)cc1 ; c1cc(Nc2ccc(C3CCCCC3)cc2)cc(C2C3CC4CC(C3)CC2C4)c1 ; c1cc(C2CCCCC2)ccc1Nc1ccc(C2CC3CCC2C3)cc1]

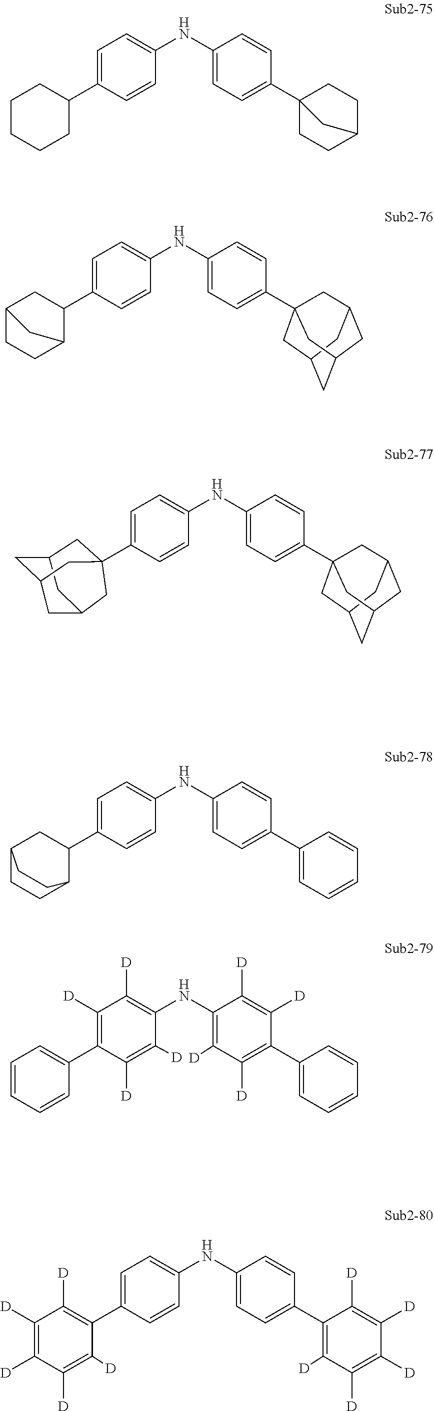 [SMILES: c1cc(C2CCCCC2)ccc1Nc1ccc(C23CCC(CC2)C3)cc1 ; c1cc(C2CC3CCC2C3)ccc1Nc1ccc(C23CC4CC(CC(C4)C2)C3)cc1 ; c1cc(C23CC4CC(CC(C4)C2)C3)ccc1Nc1ccc(C23CC4CC(CC(C4)C2)C3)cc1 ; c1ccc(-c2ccc(Nc3ccc(C4CC5CCC4CC5)cc3)cc2)cc1 ; [2H]c1c([2H])c(-c2ccccc2)c([2H])c([2H])c1Nc1c([2H])c([2H])c(-c2ccccc2)c([2H])c1[2H] ; [2H]c1c([2H])c([2H])c(-c2ccc(Nc3ccc(-c4c([2H])c([2H])c([2H])c([2H])c4[2H])cc3)cc2)c([2H])c1[2H]]

TABLE 2

| Compound | FD-MS | Compound | FD-MS |
|---|---|---|---|
| Sub2-1 | m/z = 169.09(C₁₂H₁₁N = 169.23) | Sub2-2 | m/z = 179.15(C₁₂HD₁₀N = 179.29) |
| Sub2-3 | m/z = 241.15(C₁₆H₁₉NO = 241.33) | Sub2-4 | m/z = 353.14(C₂₄H₁₉NO₂ = 353.42) |
| Sub2-5 | m/z = 281.21(C₂₀H₂₇N = 281.44) | Sub2-6 | m/z = 205.07(C₁₂H₉F₂N = 205.21) |
| Sub2-7 | m/z = 219.1(C₁₆H₁₃N = 219.29) | Sub2-8 | m/z = 269.12(C₂₀H₁₅N = 269.35) |
| Sub2-9 | m/z = 269.12(C₂₀H₁₅N = 269.35) | Sub2-10 | m/z = 269.12(C₂₀H₁₅N = 269.35) |
| Sub2-11 | m/z = 245.12(C₁₈H₁₅N = 245.33) | Sub2-12 | m/z = 321.15(C₂₄H₁₉N = 321.42) |
| Sub2-13 | m/z = 339.26(C₂₄HD₁₈N = 339.53) | Sub2-14 | m/z = 321.15(C₂₄H₁₉N = 321.42) |
| Sub2-15 | m/z = 295.14(C₂₂H₁₇N = 295.39) | Sub2-16 | m/z = 295.14(C₂₂H₁₇N = 295.39) |
| Sub2-17 | m/z = 371.17(C₂₈H₂₁N = 371.48) | Sub2-18 | m/z = 371.17(C₂₈H₂₁N = 371.48) |
| Sub2-19 | m/z = 421.18(C₃₂H₂₃N = 421.54) | Sub2-20 | m/z = 371.17(C₂₈H₂₁N = 371.48) |
| Sub2-21 | m/z = 421.18(C₃₂H₂₃N = 421.54) | Sub2-22 | m/z = 473.21(C₃₆H₂₇N = 473.62) |
| Sub2-23 | m/z = 361.18(C₂₇H₂₃N = 361.49) | Sub2-24 | m/z = 483.2(C₃₇H₂₅N = 483.61) |
| Sub2-25 | m/z = 361.18(C₂₇H₂₃N = 361.49) | Sub2-26 | m/z = 275.08(C₁₈H₁₃NS = 275.37) |
| Sub2-27 | m/z = 275.08(C₁₈H₁₃NS = 275.37) | Sub2-28 | m/z = 275.08(C₁₈H₁₃NS = 275.37) |
| Sub2-29 | m/z = 275.08(C₁₈H₁₃NS = 275.37) | Sub2-30 | m/z = 331.14(C₂₂H₂₁NS = 331.48) |
| Sub2-31 | m/z = 331.14(C₂₂H₂₁NS = 331.48) | Sub2-32 | m/z = 351.11(C₂₄H₁₇NS = 351.47) |
| Sub2-33 | m/z = 351.11(C₂₄H₁₇NS = 351.47) | Sub2-34 | m/z = 351.11(C₂₄H₁₇NS = 351.47) |
| Sub2-35 | m/z = 351.11(C₂₄H₁₇NS = 351.47) | Sub2-36 | m/z = 351.11(C₂₄H₁₇NS = 351.47) |
| Sub2-37 | m/z = 401.12(C₂₈H₁₉NS = 401.53) | Sub2-38 | m/z = 325.09(C₂₂H₁₅NS = 325.43) |
| Sub2-39 | m/z = 351.11(C₂₄H₁₇NS = 351.47) | Sub2-40 | m/z = 351.11(C₂₄H₁₇NS = 351.47) |
| Sub2-41 | m/z = 351.11(C₂₄H₁₇NS = 351.47) | Sub2-42 | m/z = 351.11(C₂₄H₁₇NS = 351.47) |
| Sub2-43 | m/z = 325.09(C₂₂H₁₅NS = 325.43) | Sub2-44 | m/z = 325.09(C₂₂H₁₅NS = 325.43) |
| Sub2-45 | m/z = 259.1(C₁₈H₁₃NO = 259.31) | Sub2-46 | m/z = 259.1(C₁₈H₁₃NO = 259.31) |
| Sub2-47 | m/z = 259.1(C₁₈H₁₃NO = 259.31) | Sub2-48 | m/z = 259.1(C₁₈H₁₃NO = 259.31) |
| Sub2-49 | m/z = 315.16(C₂₂H₂₁NO = 315.42) | Sub2-50 | m/z = 393.21(C₂₈H₂₇NO = 393.53) |
| Sub2-51 | m/z = 335.13(C₂₄H₁₇NO = 335.41) | Sub2-52 | m/z = 335.13(C₂₄H₁₇NO = 335.41) |
| Sub2-53 | m/z = 335.13(C₂₄H₁₇NO = 335.41) | Sub2-54 | m/z = 335.13(C₂₄H₁₇NO = 335.41) |
| Sub2-55 | m/z = 385.15(C₂₈H₁₉NO = 385.47) | Sub2-56 | m/z = 335.13(C₂₄H₁₇NO = 335.41) |
| Sub2-57 | m/z = 335.13(C₂₄H₁₇NO = 335.41) | Sub2-58 | m/z = 309.12(C₂₂H₁₅NO = 309.37) |
| Sub2-59 | m/z = 309.12(C₂₂H₁₅NO = 309.37) | Sub2-60 | m/z = 335.13(C₂₄H₁₇NO = 335.41) |
| Sub2-61 | m/z = 335.13(C₂₄H₁₇NO = 335.41) | Sub2-62 | m/z = 335.13(C₂₄H₁₇NO = 335.41) |
| Sub2-63 | m/z = 335.13(C₂₄H₁₇NO = 335.41) | Sub2-64 | m/z = 411.16(C₃₀H₂₁NO = 411.5) |
| Sub2-65 | m/z = 411.16(C₃₀H₂₁NO = 411.5) | Sub2-66 | m/z = 411.16(C₃₀H₂₁NO = 411.5) |
| Sub2-67 | m/z = 309.12(C₂₂H₁₅NO = 309.37) | Sub2-68 | m/z = 385.15(C₂₈H₁₉NO = 385.47) |
| Sub2-69 | m/z = 349.11(C₂₄H₁₅NO₂ = 349.39) | Sub2-70 | m/z = 351.11(C₂₄H₁₇NS = 351.47) |
| Sub2-71 | m/z = 327.2(C₂₄H₂₅N = 327.47) | Sub2-72 | m/z = 385.28(C₂₈H₃₅N = 385.6) |
| Sub2-73 | m/z = 385.28(C₂₈H₃₅N = 385.6) | Sub2-74 | m/z = 345.25(C₂₅H₃₁N = 345.53) |
| Sub2-75 | m/z = 345.25(C₂₅H₃₁N = 345.53) | Sub2-76 | m/z = 397.28(C₂₉H₃₅N = 397.61) |
| Sub2-77 | m/z = 437.31(C₃₂H₃₉N = 437.67) | Sub2-78 | m/z = 353.21(C₂₆H₂₇N = 353.51) |
| Sub2-79 | m/z = 329.20(C₂₄H₁₁D₈N = 329.47) | Sub2-80 | m/z = 331.21(C₂₄H₉D₁₀N = 331.48) |

### Synthesis Example of Final Compound

### 1. Synthesis Example of P1-1

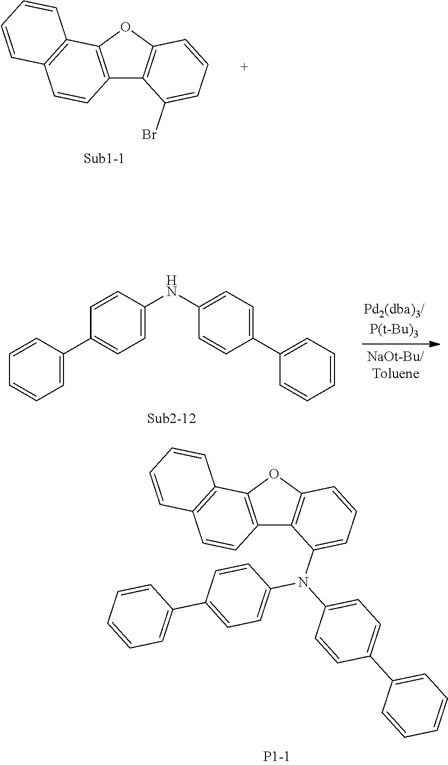

Sub1-1 (5.0 g, 16.8 mmol), Sub2-12 (5.4 g, 16.8 mmol), Pd₂(dba)₃ (0.46 g, 0.50 mmol), P(t-Bu)₃ (0.20 g, 1.01 mmol), NaOt-Bu (3.2 g, 33.7 mmol) and toluene (84 mL) were put into a round bottom flask, and the reaction was carried out at 60° C. When the reaction was completed, the reaction product was extracted with CH₂Cl₂ and water, and then an organic layer was dried with MgSO₄ and concentrated. Then, the concentrate was separated through a silica gel column and recrystallized to obtain 6.8 g (yield: 75%) of the product.

### 2. Synthesis Example of P1-8

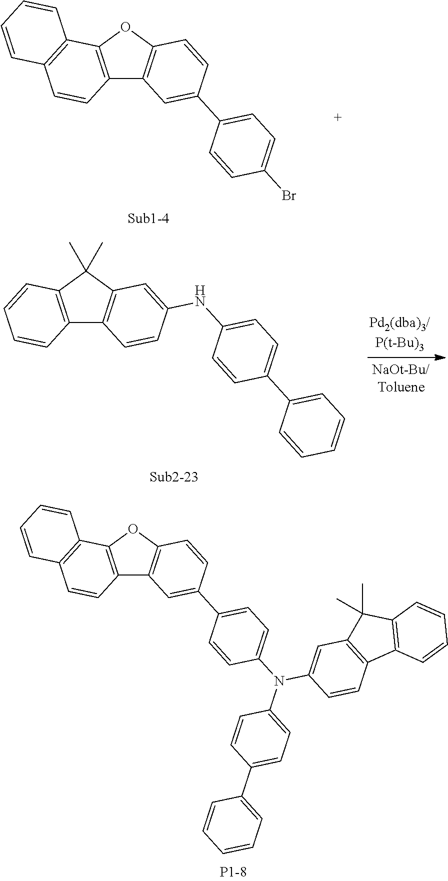

Sub1-4 (5.0 g, 13.4 mmol), Sub2-23 (4.8 g, 13.4 mmol), Pd₂(dba)₃ (0.37 g, 0.40 mmol), P(t-Bu)₃ (0.16 g, 0.80 mmol), NaOt-Bu (2.6 g, 26.8 mmol), Toluene (67 mL) were putted into a round bottom flask, and then the synthesis was carried out in the same manner as in the synthesis method of P1-1 to obtain 6.8 g (yield: 78%) of the product.

### 3. Synthesis Example of P1-12

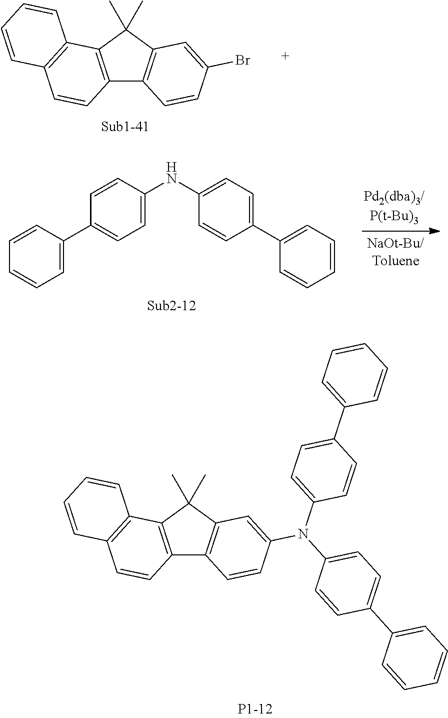 [SMILES: CC1(C)c2cc(Br)ccc2-c2ccc3ccccc3c21 ; c1ccc(-c2ccc(Nc3ccc(-c4ccccc4)cc3)cc2)cc1 ; CC1(C)c2cc(N(c3ccc(-c4ccccc4)cc3)c3ccc(-c4ccccc4)cc3)ccc2-c2ccc3ccccc3c21]

Sub1-41 (5.0 g, 15.5 mmol), Sub2-12 (5.0 g, 15.5 mmol), Pd₂(dba)₃ (0.42 g, 0.46 mmol), P(t-Bu)₃ (0.19 g, 0.93 mmol), NaOt-Bu (3.0 g, 30.9 mmol) and toluene (77 mL) were putted into a round bottom flask, and then the synthesis was carried out in the same manner as in the synthesis method of P1-1 to obtain 6.5 g (yield: 74%) of the product.

### 4. Synthesis Example of P1-22

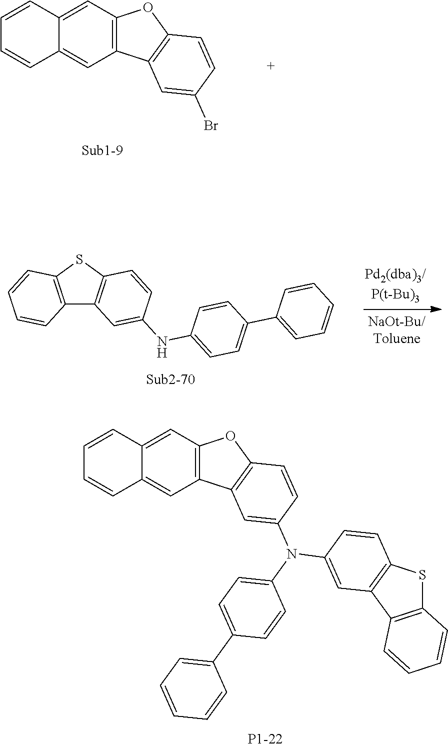 [SMILES: Brc1ccc2oc3cc4ccccc4cc3c2c1 ; c1ccc(-c2ccc(Nc3ccc4sc5ccccc5c4c3)cc2)cc1 ; c1ccc(-c2ccc(N(c3ccc4oc5cc6ccccc6cc5c4c3)c3ccc4sc5ccccc5c4c3)cc2)cc1]

Sub1-9 (5.0 g, 16.8 mmol), Sub2-70 (5.9 g, 16.8 mmol), Pd₂(dba)₃ (0.46 g, 0.50 mmol), P(t-Bu)₃ (0.20 g, 1.01 mmol), NaOt-Bu (3.2 g, 33.7 mmol) and toluene (84 mL) were putted into a round bottom flask, and then the synthesis was carried out in the same manner as in the synthesis method of P1-1 to obtain 7.5 g (yield: 79%) of the product.

### 5. Synthesis Example of P1-24

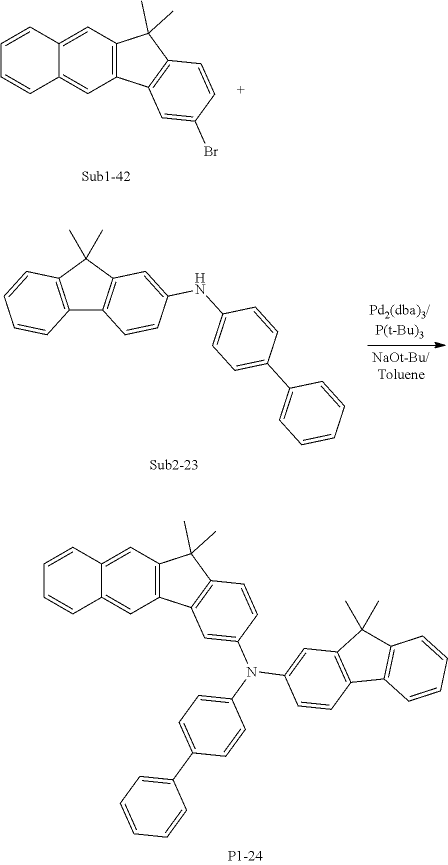 [SMILES: CC1(C)c2ccc(Br)cc2-c2cc3ccccc3cc21 ; CC1(C)c2ccccc2-c2ccc(Nc3ccc(-c4ccccc4)cc3)cc21 ; CC1(C)c2ccccc2-c2ccc(N(c3ccc(-c4ccccc4)cc3)c3ccc4c(c3)-c3cc5ccccc5cc3C4(C)C)cc21]

Sub1-42 (5.0 g, 15.5 mmol), Sub2-23 (5.6 g, 15.5 mmol), Pd₂(dba)₃ (0.42 g, 0.46 mmol), P(t-Bu)₃ (0.19 g, 0.93 mmol), NaOt-Bu (3.0 g, 30.9 mmol) and toluene (77 mL) were putted into a round bottom flask, and then the synthesis was carried out in the same manner as in the synthesis method of P1-1 to obtain 7.2 g (yield: 77%) of the product.

### 6. Synthesis Example of P1-36

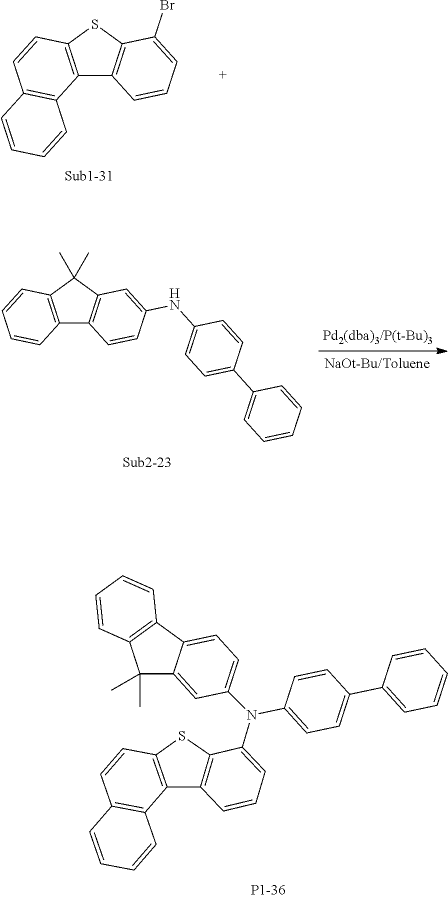

Sub1-31 (2.7 g, 8.6 mmol), Sub2-23 (3.1 g, 8.6 mmol), Pd₂(dba)₃ (0.24 g, 0.26 mmol), P(t-Bu)₃ (0.10 g, 0.52 mmol), NaOt-Bu (1.7 g, 17.2 mmol) and toluene (43 mL) were putted into a round bottom flask, and then the synthesis was carried out in the same manner as in the synthesis method of P1-1 to obtain 3.7 g (yield: 73%) of the product.

### 7. Synthesis Example of P1-51

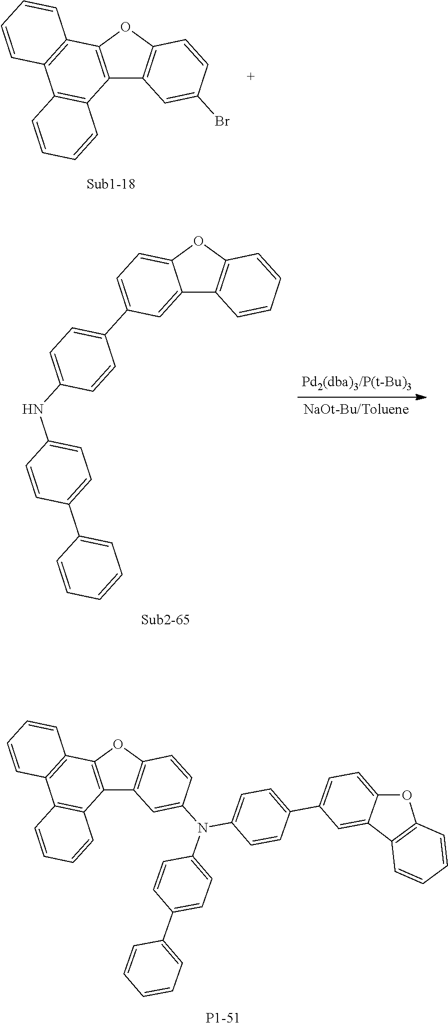 [SMILES: Brc1ccc2oc3c4ccccc4c4ccccc4c3c2c1 ; c1ccc(-c2ccc(Nc3ccc(-c4ccc5oc6ccccc6c5c4)cc3)cc2)cc1 ; c1ccc(-c2ccc(N(c3ccc(-c4ccc5oc6ccccc6c5c4)cc3)c3ccc4oc5c6ccccc6c6ccccc6c5c4c3)cc2)cc1]

Sub1-18 (5.0 g, 14.4 mmol), Sub2-65 (5.9 g, 14.4 mmol), Pd₂(dba)₃ (0.40 g, 0.43 mmol), P(t-Bu)₃ (0.17 g, 0.86 mmol), NaOt-Bu (2.8 g, 28.8 mmol) and toluene (72 mL) were putted into a round bottom flask, and then the synthesis was carried out in the same manner as in the synthesis method of P1-1 to obtain 7.2 g (yield: 74%) of the product.

### 8. Synthesis Example of P1-56

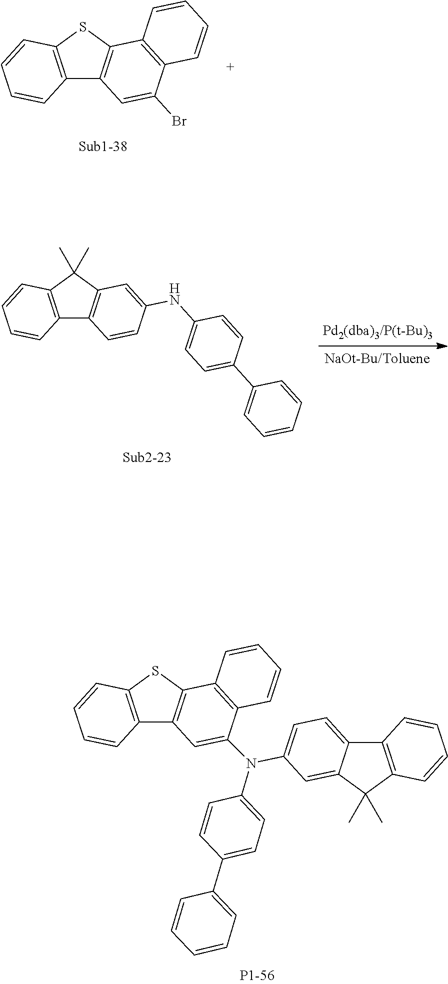

Sub1-38 (5.0 g, 16.0 mmol), Sub2-23 (5.8 g, 16.0 mmol), Pd₂(dba)₃ (0.44 g, 0.48 mmol), P(t-Bu)₃ (0.19 g, 0.96 mmol), NaOt-Bu (3.1 g, 31.9 mmol) and toluene (80 mL) were putted into a round bottom flask, and then the synthesis was carried out in the same manner as in the synthesis method of P1-1 to obtain 6.4 g (yield: 68%) of the product.

### 9. Synthesis Example of P1-63

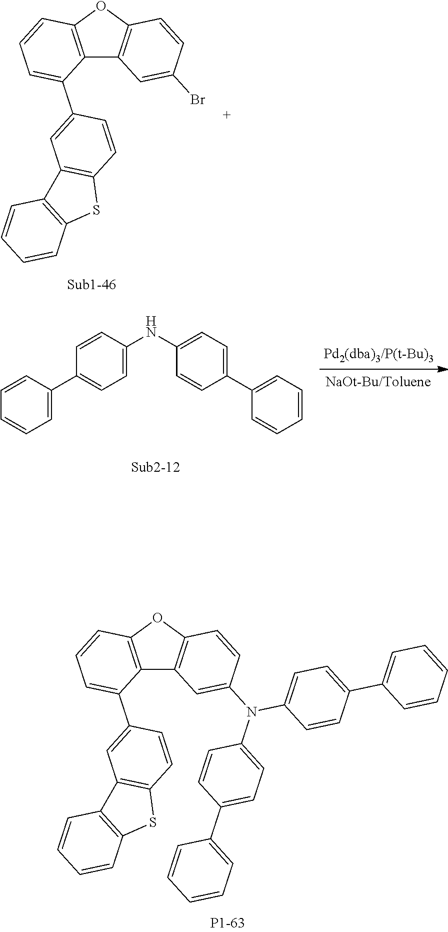 [SMILES: Brc1ccc2oc3cccc(-c4ccc5sc6ccccc6c5c4)c3c2c1 ; c1ccc(-c2ccc(Nc3ccc(-c4ccccc4)cc3)cc2)cc1 ; c1ccc(-c2ccc(N(c3ccc(-c4ccccc4)cc3)c3ccc4oc5cccc(-c6ccc7sc8ccccc8c7c6)c5c4c3)cc2)cc1]

Sub1-46 (5.0 g, 11.6 mmol), Sub2-12 (3.7 g, 11.6 mmol), Pd₂(dba)₃ (0.32 g, 0.35 mmol), P(t-Bu)₃ (0.14 g, 0.70 mmol), NaOt-Bu (2.2 g, 23.3 mmol) and toluene (58 mL) were putted into a round bottom flask, and then the synthesis was carried out in the same manner as in the synthesis method of P1-1 to obtain 5.6 g (yield: 72%) of the product.

### 10. Synthesis Example of P1-70

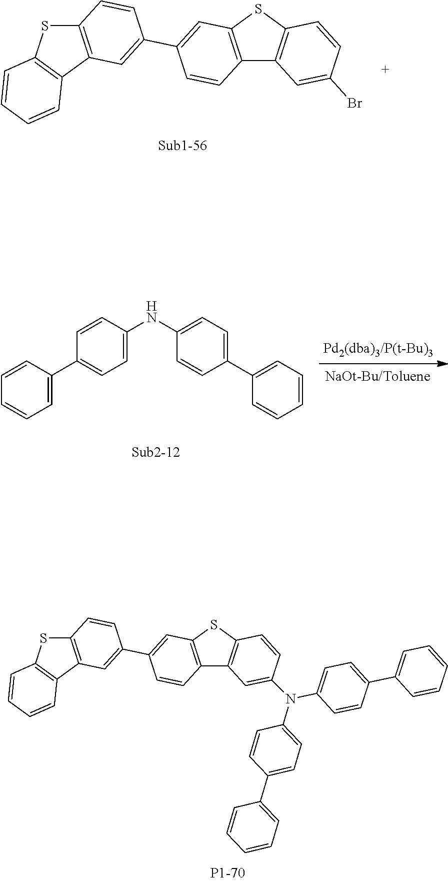

Sub1-56 (5.0 g, 11.2 mmol), Sub2-12 (3.6 g, 11.2 mmol), Pd₂(dba)₃ (0.31 g, 0.34 mmol), P(t-Bu)₃ (0.14 g, 0.67 mmol), NaOt-Bu (2.2 g, 22.5 mmol) and toluene (56 mL) were putted into a round bottom flask, and then the synthesis was carried out in the same manner as in the synthesis method of P1-1 to obtain 5.9 g (yield: 76%) of the product.

### 11. Synthesis Example of P1-73

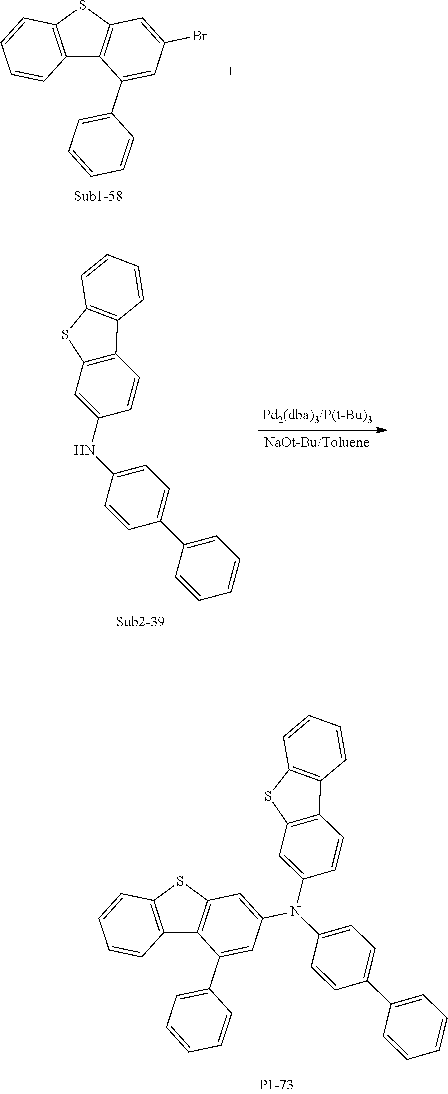 [SMILES: Brc1cc(-c2ccccc2)c2c(c1)sc1ccccc12 ; c1ccc(-c2ccc(Nc3ccc4c(c3)sc3ccccc34)cc2)cc1 ; c1ccc(-c2ccc(N(c3ccc4c(c3)sc3ccccc34)c3cc(-c4ccccc4)c4c(c3)sc3ccccc34)cc2)cc1]

Sub1-58 (5.0 g, 14.7 mmol), Sub2-39 (5.2 g, 14.7 mmol), Pd₂(dba)₃ (0.40 g, 0.44 mmol), P(t-Bu)₃ (0.18 g, 0.88 mmol), NaOt-Bu (2.8 g, 29.5 mmol) and toluene (74 mL) were putted into a round bottom flask, and then the synthesis was carried out in the same manner as in the synthesis method of P1-1 to obtain 6.5 g (yield: 72%) of the product.

### 12. Synthesis Example of P1-75

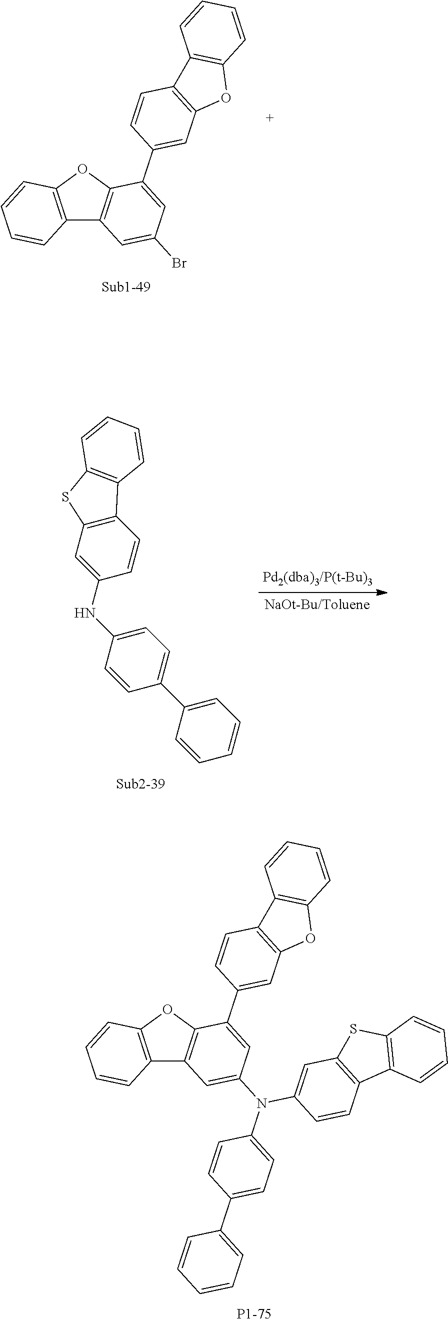 [SMILES: Brc1cc(-c2ccc3c(c2)oc2ccccc23)c2oc3ccccc3c2c1 ; c1ccc(-c2ccc(Nc3ccc4c(c3)sc3ccccc34)cc2)cc1 ; c1ccc(-c2ccc(N(c3ccc4c(c3)sc3ccccc34)c3cc(-c4ccc5c(c4)oc4ccccc45)c4oc5ccccc5c4c3)cc2)cc1]

Sub1-49 (5.0 g, 12.1 mmol), Sub2-39 (4.3 g, 12.1 mmol), Pd₂(dba)₃ (0.33 g, 0.36 mmol), P(t-Bu)₃ (0.15 g, 0.73 mmol), NaOt-Bu (2.3 g, 24.2 mmol) and toluene (60 mL) were putted into a round bottom flask, and then the synthesis was carried out in the same manner as in the synthesis method of P1-1 to obtain 5.9 g (yield: 71%) of the product.

### 13. Synthesis Example of P1-90

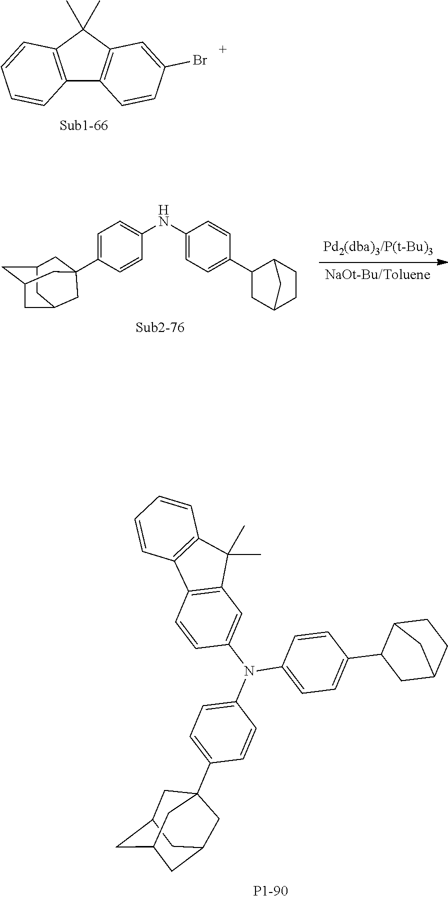 [SMILES: CC1(C)c2ccccc2-c2ccc(Br)cc21 ; c1cc(C2CC3CCC2C3)ccc1Nc1ccc(C23CC4CC(CC(C4)C2)C3)cc1 ; CC1(C)c2ccccc2-c2ccc(N(c3ccc(C4CC5CCC4C5)cc3)c3ccc(C45CC6CC(CC(C6)C4)C5)cc3)cc21]

Sub1-66 (5.0 g, 18.3 mmol), Sub2-76 (6.7 g, 18.3 mmol), Pd₂(dba)₃ (0.50 g, 0.55 mmol), P(t-Bu)₃ (0.22 g, 1.10 mmol), NaOt-Bu (3.5 g, 36.6 mmol) and toluene (92 mL) were putted into a round bottom flask, and then the synthesis was carried out in the same manner as in the synthesis method of P1-1 to obtain 7.3 g (yield: 68%) of the product.

FD-MS values of the compounds P1-1 to P1-92 of the present invention synthesized by the above synthesis method are shown in Table 3 below.

TABLE 3

| Compound | FD-MS | Compound | FD-MS |
|---|---|---|---|
| P1-1 | m/z = 537.21(C₄₀H₂₇NO = 537.66) | P1-2 | m/z = 553.19(C₄₀H₂₇NS = 553.72) |
| P1-3 | m/z = 551.19(C₄₀H₂₅NO₂ = 551.65) | P1-4 | m/z = 567.17(C₄₀H₂₅NOS = 567.71) |
| P1-5 | m/z = 689.27(C₅₂H₃₅NO = 689.86) | P1-6 | m/z = 477.16(C₃₄H₂₃NS = 477.63) |
| P1-7 | m/z = 491.13(C₃₄H₂₁NOS = 491.61) | P1-8 | m/z = 653.27(C₄₉H₃₅NO = 653.83) |
| P1-9 | m/z = 587.22(C₄₄H₂₉NO = 587.72) | P1-10 | m/z = 643.2(C₄₆H₂₉NOS = 643.8) |
| P1-11 | m/z = 567.17(C₄₀H₂₅NOS = 567.71) | P1-12 | m/z = 563.26(C₄₃H₃₃N = 563.74) |
| P1-13 | m/z = 567.17(C₄₀H₂₅NOS = 567.71) | P1-14 | m/z = 537.21(C₄₀H₂₇NO = 537.66) |
| P1-15 | m/z = 593.22(C₄₃H₃₁NS = 593.79) | P1-16 | m/z = 663.26(C₅₀H₃₃NO = 663.82) |
| P1-17 | m/z = 569.2(C₄₀H₂₇NO₃ = 569.66) | P1-18 | m/z = 527.17(C₃₈H₂₅NS = 527.69) |
| P1-19 | m/z = 567.17(C₄₀H₂₅NOS = 567.71) | P1-20 | m/z = 551.19(C₄₀H₂₅NO₂ = 551.65) |
| P1-21 | m/z = 497.27(C₃₆H₃₅NO = 497.68) | P1-22 | m/z = 567.17(C₄₀H₂₅NOS = 567.71) |
| P1-23 | m/z = 567.17(C₄₀H₂₅NOS = 567.71) | P1-24 | m/z = 603.29(C₄₆H₃₇N = 603.81) |
| P1-25 | m/z = 555.32(C₄₀H₉D₁₈NO = 555.77) | P1-26 | m/z = 551.19(C₄₀H₂₅NO₂ = 551.65) |
| P1-27 | m/z = 567.17(C₄₀H₂₅NOS = 567.71) | P1-28 | m/z = 603.29(C₄₆H₃₇N = 603.81) |
| P1-29 | m/z = 395.21(C₂₈H₉D₁₀NO = 395.53) | P1-30 | m/z = 643.2(C₄₆H₂₉NOS = 643.8) |
| P1-31 | m/z = 587.22(C₄₄H₂₉NO = 587.72) | P1-32 | m/z = 485.18(C₃₆H₂₃NO = 485.59) |
| P1-33 | m/z = 553.19(C₄₀H₂₇NS = 553.72) | P1-34 | m/z = 601.2(C₄₄H₂₇NO₂ = 601.71) |
| P1-35 | m/z = 421.13(C₂₈H₁₇F₂NO = 421.45) | P1-36 | m/z = 593.22(C₄₃H₃₁NS = 593.79) |
| P1-37 | m/z = 725.31(C₅₆H₃₉N = 725.94) | P1-38 | m/z = 525.17(C₃₈H₂₃NO₂ = 525.61) |
| P1-39 | m/z = 659.17(C₄₆H₂₉NS₂ = 659.87) | P1-40 | m/z = 567.17(C₄₀H₂₅NOS = 567.71) |
| P1-41 | m/z = 541.15(C₃₈H₂₃NOS = 541.67) | P1-42 | m/z = 567.17(C₄₀H₂₅NOS = 567.71) |
| P1-43 | m/z = 485.18(C₃₆H₂₃NO = 485.59) | P1-44 | m/z = 613.24(C₄₆H₃₁NO = 613.76) |
| P1-45 | m/z = 603.2(C₄₄H₂₉NS = 603.78) | P1-46 | m/z = 587.22(C₄₄H₂₉NO = 587.72) |
| P1-47 | m/z = 627.26(C₄₇H₃₃NO = 627.79) | P1-48 | m/z = 769.24(C₅₆H₃₅NOS = 769.96) |
| P1-49 | m/z = 587.22(C₄₄H₂₉NO = 587.72) | P1-50 | m/z = 703.23(C₅₂H₃₃NS = 703.9) |
| P1-51 | m/z = 677.24(C₅₀H₃₁NO₂ = 677.8) | P1-52 | m/z = 541.15(C₃₈H₂₃NOS = 541.67) |
| P1-53 | m/z = 461.18(C₃₄H₂₃NO = 461.56) | P1-54 | m/z = 553.19(C₄₀H₂₇NS = 553.72) |
| P1-55 | m/z = 551.19(C₄₀H₂₅NO₂ = 551.65) | P1-56 | m/z = 593.22(C₄₃H₃₁NS = 593.79) |
| P1-57 | m/z = 537.21(C₄₀H₂₇NO = 537.66) | P1-58 | m/z = 643.2(C₄₆H₂₉NOS = 643.8) |
| P1-59 | m/z = 567.17(C₄₀H₂₅NOS = 567.71) | P1-60 | m/z = 629.22(C₄₆H₃₁NS = 629.82) |
| P1-61 | m/z = 563.22(C₄₂H₂₉NO = 563.7) | P1-62 | m/z = 685.19(C₄₈H₃₁NS₂ = 685.9) |
| P1-63 | m/z = 669.21(C₄₈H₃₁NOS = 669.84) | P1-64 | m/z = 683.19(C₄₈H₂₉NO₂S = 683.83) |
| P1-65 | m/z = 749.18(C₅₂H₃₁NOS₂ = 749.95) | P1-66 | m/z = 667.2(C₄₈H₂₉NOS = 667.83) |
| P1-67 | m/z = 709.19(C₅₀H₃₁NS₂ = 709.93) | P1-68 | m/z = 735.21(C₅₂H₃₃NS₂ = 735.96) |
| P1-69 | m/z = 517.15(C₃₆H₂₃NOS = 517.65) | P1-70 | m/z = 685.19(C₄₈H₃₁NS₂ = 685.9) |
| P1-71 | m/z = 695.26(C₅₁H₃₇NS = 695.92) | P1-72 | m/z = 709.24(C₅₁H₃₅NOS = 709.91) |
| P1-73 | m/z = 609.16(C₄₂H₂₇NS₂ = 609.81) | P1-74 | m/z = 699.17(C₄₈H₂₉NOS₂ = 699.89) |
| P1-75 | m/z = 683.19(C₄₈H₂₉NO₂S = 683.83) | P1-76 | m/z = 699.17(C₄₈H₂₉NOS₂ = 699.89) |
| P1-77 | m/z = 771.22(C₅₅H₃₃NO₂S = 771.93) | P1-78 | m/z = 623.32(C₄₆H₄₁NO = 623.84) |
| P1-79 | m/z = 669.21(C₄₈H₃₁NOS = 669.84) | P1-80 | m/z = 847.25(C₆₁H₃₇NO₂S = 848.03) |
| P1-81 | m/z = 709.24(C₅₁H₃₅NOS = 709.91) | P1-82 | m/z = 519.29(C₃₉H₃₇N = 519.73) |
| P1-83 | m/z = 643.32(C₄₉H₄₁N = 643.87) | P1-84 | m/z = 641.31(C₄₉H₃₉N = 641.86) |
| P1-85 | m/z = 577.37(C₄₃H₄₇N = 577.86) | P1-86 | m/z = 577.37(C₄₃H₄₇N = 577.86) |
| P1-87 | m/z = 537.34(C₄₀H₄₃N = 537.79) | P1-88 | m/z = 613.37(C₄₆H₄₇N = 613.89) |
| P1-89 | m/z = 577.37(C₄₃H₄₇N = 577.86) | P1-90 | m/z = 589.37(C₄₄H₄₇N = 589.87) |
| P1-91 | m/z = 629.4(C₄₇H₅₁N = 629.93) | P1-92 | m/z = 545.31(C₄₁H₃₉N = 545.77) |

### Synthesis Example 2

### Synthesis Example of Formula 2

The compound represented by Formula 2 according to the present invention can be synthesized by reaction route of the following Reaction Scheme 4, but is not limited thereto.

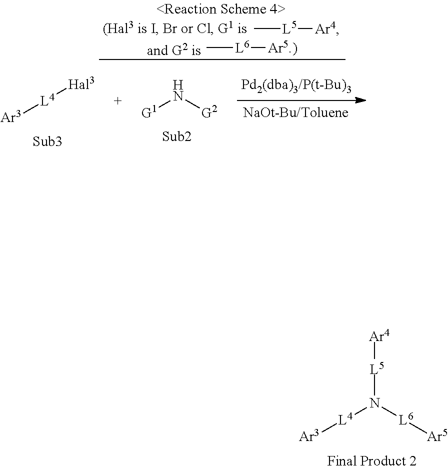

### Example Compounds of Sub3

Compounds belonging to Sub 3 may be, but not limited to, the following compounds, and Table 4 shows FD-MS (Field Desorption-Mass Spectrometry) values of the following compounds.

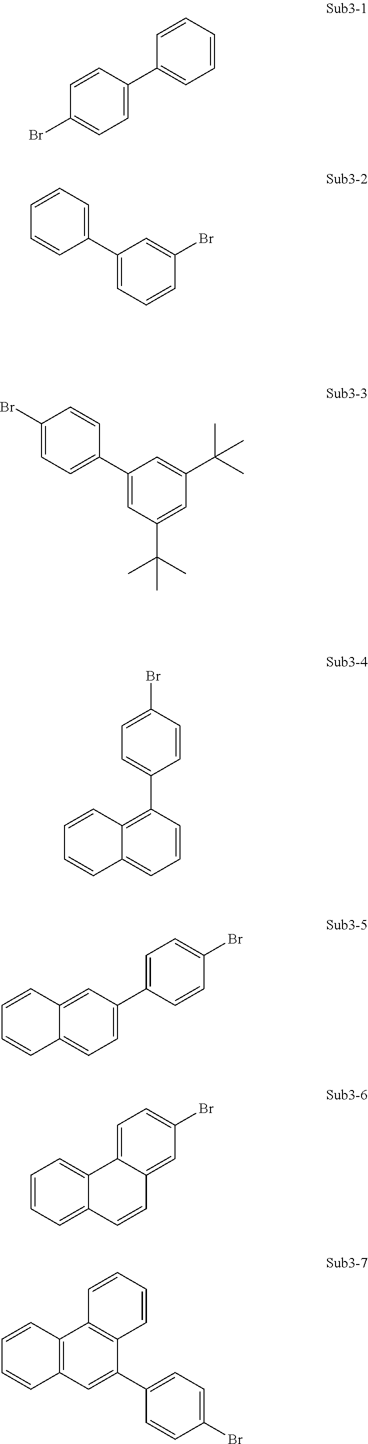

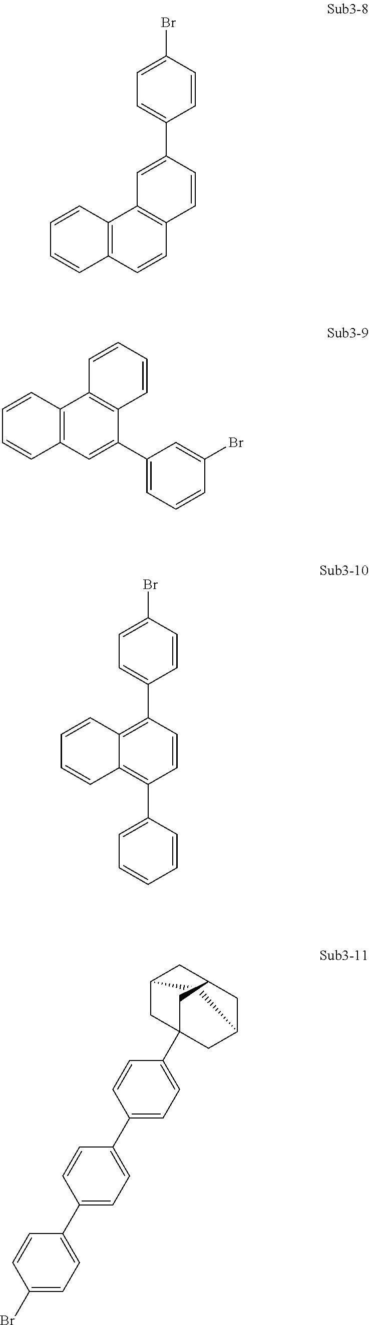 [SMILES: Brc1ccc(-c2ccc3ccc4ccccc4c3c2)cc1 ; Brc1cccc(-c2cc3ccccc3c3ccccc23)c1 ; Brc1ccc(-c2ccc(-c3ccccc3)c3ccccc23)cc1 ; Brc1ccc(-c2ccc(-c3ccc(C45C[C@H]6C[C@@H](C4)C[C@@H](C5)C6)cc3)cc2)cc1]

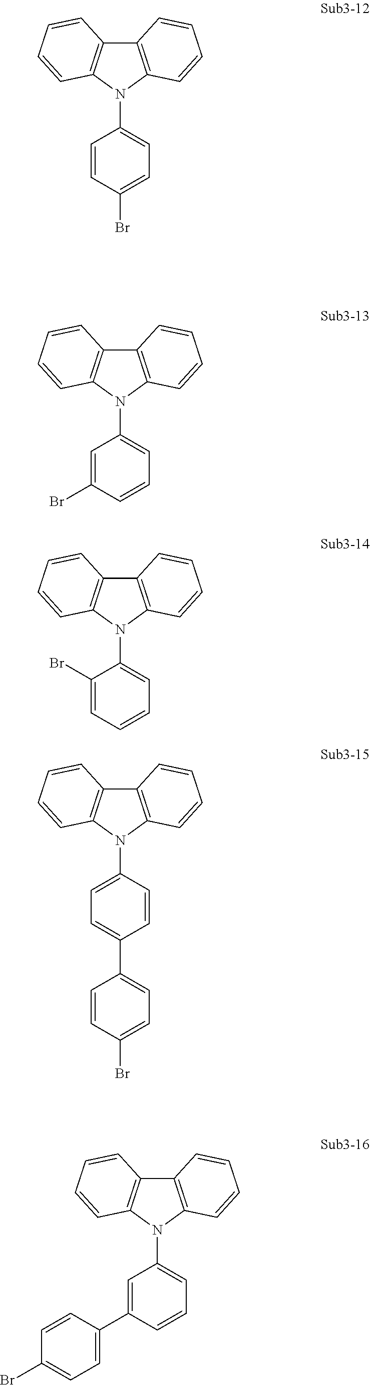 [SMILES: Brc1ccc(-n2c3ccccc3c3ccccc32)cc1 ; Brc1cccc(-n2c3ccccc3c3ccccc32)c1 ; Brc1ccccc1-n1c2ccccc2c2ccccc21 ; Brc1ccc(-c2ccc(-n3c4ccccc4c4ccccc43)cc2)cc1 ; Brc1ccc(-c2cccc(-n3c4ccccc4c4ccccc43)c2)cc1]

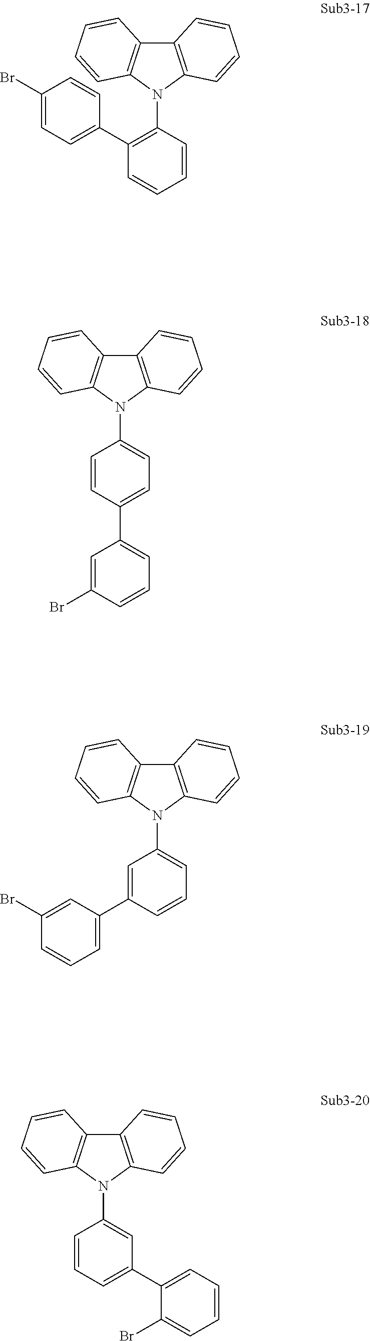 [SMILES: Brc1ccc(-c2ccccc2-n2c3ccccc3c3ccccc32)cc1 ; Brc1cccc(-c2ccc(-n3c4ccccc4c4ccccc43)cc2)c1 ; Brc1cccc(-c2cccc(-n3c4ccccc4c4ccccc43)c2)c1 ; Brc1ccccc1-c1cccc(-n2c3ccccc3c3ccccc32)c1]

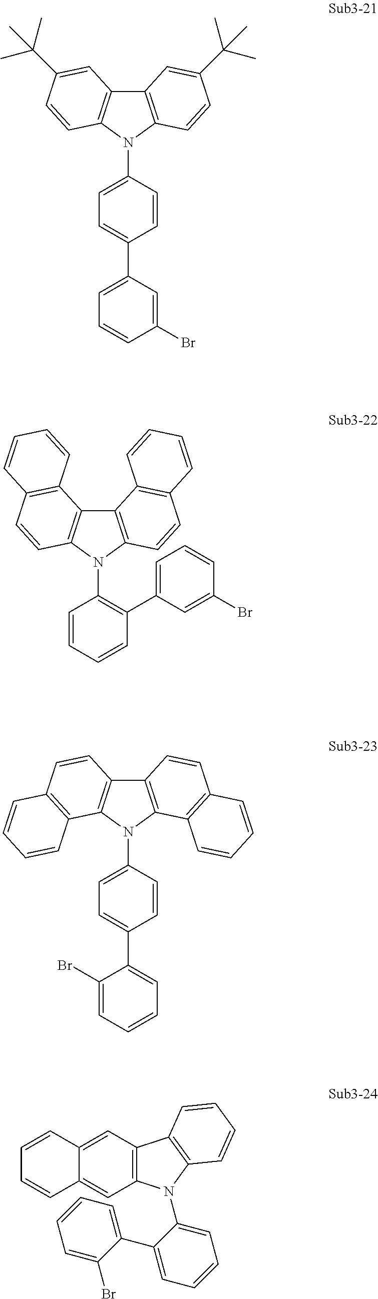 [SMILES: CC(C)(C)c1ccc2c(c1)c1cc(C(C)(C)C)ccc1n2-c1ccc(-c2cccc(Br)c2)cc1 ; Brc1cccc(-c2ccccc2-n2c3ccc4ccccc4c3c3c4ccccc4ccc32)c1 ; Brc1ccccc1-c1ccc(-n2c3c4ccccc4ccc3c3ccc4ccccc4c32)cc1 ; Brc1ccccc1-c1ccccc1-n1c2ccccc2c2cc3ccccc3cc21]

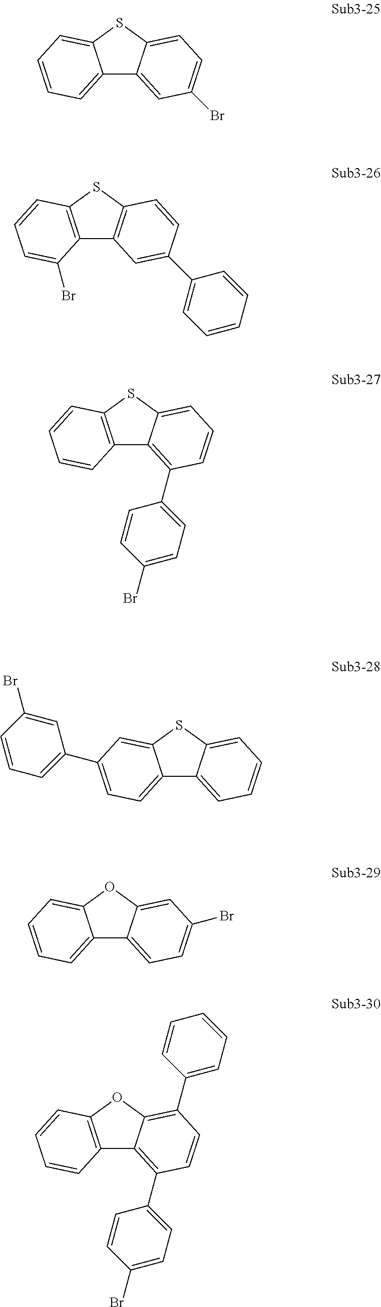 [SMILES: Brc1ccc2sc3ccccc3c2c1 ; Brc1cccc2sc3ccc(-c4ccccc4)cc3c12 ; Brc1ccc(-c2cccc3sc4ccccc4c23)cc1 ; Brc1cccc(-c2ccc3c(c2)sc2ccccc23)c1 ; Brc1ccc2c(c1)oc1ccccc12 ; Brc1ccc(-c2ccc(-c3ccccc3)c3oc4ccccc4c23)cc1]

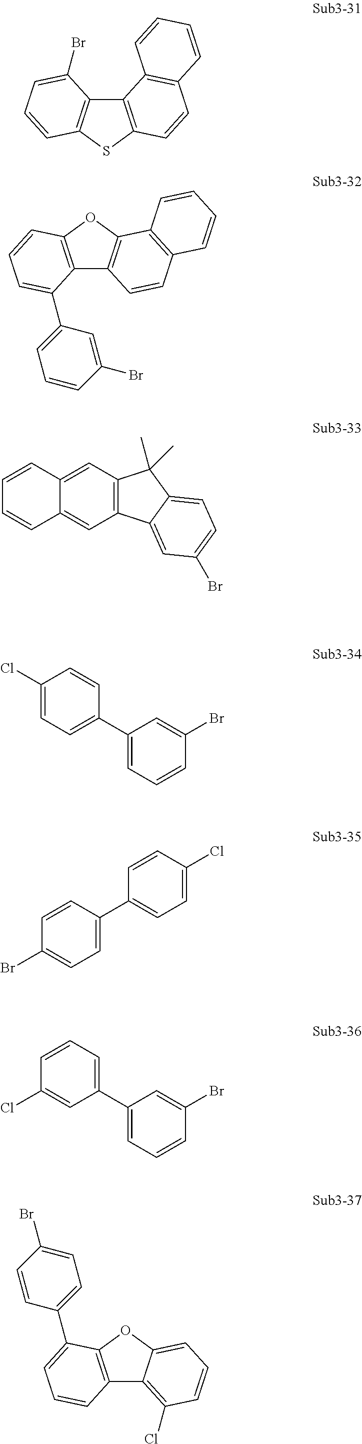

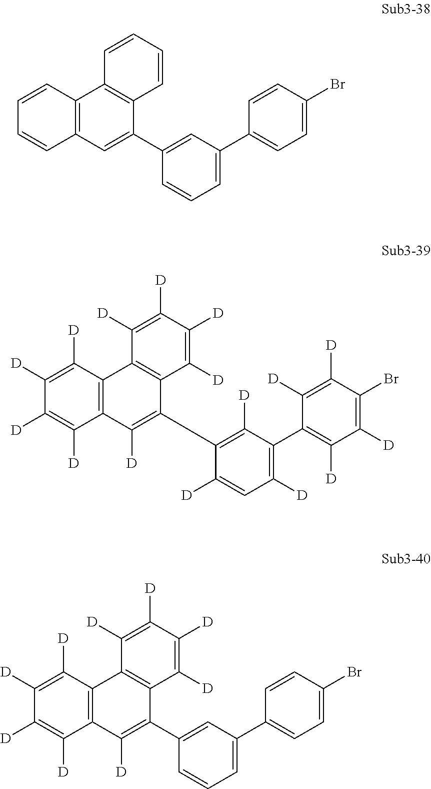 [SMILES: Brc1ccc(-c2cccc(-c3cc4ccccc4c4ccccc34)c2)cc1 ; [2H]c1cc([2H])c(-c2c([2H])c3c([2H])c([2H])c([2H])c([2H])c3c3c([2H])c([2H])c([2H])c([2H])c23)c([2H])c1-c1c([2H])c([2H])c(Br)c([2H])c1[2H] ; [2H]c1c([2H])c([2H])c2c(c1[2H])c([2H])c(-c1cccc(-c3ccc(Br)cc3)c1)c1c([2H])c([2H])c([2H])c([2H])c12]

TABLE 4

| Compound | FD-MS | Compound | FD-MS |
|---|---|---|---|
| Sub3-1 | m/z = 231.99(C₁₂H₉Br = 233.11) | Sub3-2 | m/z = 231.99(C₁₂H₉Br = 233.11) |
| Sub3-3 | m/z = 344.11(C₂₀H₂₅Br = 345.32) | Sub3-4 | m/z = 282(C₁₆H₁₁Br = 283.17) |
| Sub3-5 | m/z = 282(C₁₆H₁₁Br = 283.17) | Sub3-6 | m/z = 255.99(C₁₄H₉Br = 257.13) |
| Sub3-7 | m/z = 332.02(C₂₀H₁₃Br = 333.23) | Sub3-8 | m/z = 332.02(C₂₀H₁₃Br = 333.23) |
| Sub3-9 | m/z = 332.02(C₂₀H₁₃Br = 333.23) | Sub3-10 | m/z = 358.04(C₂₂H₁₅Br = 359.27) |
| Sub3-11 | m/z = 442.13(C₂₈H₂₇Br = 443.43) | Sub3-12 | m/z = 321.02(C₁₈H₁₂BrN = 322.21) |
| Sub3-13 | m/z = 321.02(C₁₈H₁₂BrN = 322.21) | Sub3-14 | m/z = 321.02(C₁₈H₁₂BrN = 322.21) |
| Sub3-15 | m/z = 397.05(C₂₄H₁₆BrN = 398.3) | Sub3-16 | m/z = 397.05(C₂₄H₁₆BrN = 398.3) |
| Sub3-17 | m/z = 397.05(C₂₄H₁₆BrN = 398.3) | Sub3-18 | m/z = 397.05(C₂₄H₁₆BrN = 398.3) |
| Sub3-19 | m/z = 397.05(C₂₄H₁₆BrN = 398.3) | Sub3-20 | m/z = 397.05(C₂₄H₁₆BrN = 398.3) |
| Sub3-21 | m/z = 509.17(C₃₂H₃₂BrN = 510.52) | Sub3-22 | m/z = 497.08(C₃₂H₂₀BrN = 498.42) |
| Sub3-23 | m/z = 497.08(C₃₂H₂₀BrN = 498.42) | Sub3-24 | m/z = 447.06(C₂₈H₁₈BrN = 448.36) |
| Sub3-25 | m/z = 261.95(C₁₂H₇BrS = 263.15) | Sub3-26 | m/z = 337.98(C₁₈H₁₁BrS = 339.25) |
| Sub3-27 | m/z = 337.98(C₁₈H₁₁BrS = 339.25) | Sub3-28 | m/z = 337.98(C₁₈H₁₁BrS = 339.25) |
| Sub3-29 | m/z = 245.97(C₁₂H₇BrO = 247.09) | Sub3-30 | m/z = 398.03(C₂₄H₁₅BrO = 399.29) |
| Sub3-31 | m/z = 295.98(C₁₆H₉BrO = 297.15) | Sub3-32 | m/z = 372.01(C₂₂H₁₃BrO = 373.25) |
| Sub3-33 | m/z = 322.04(C₁₉H₁₅Br = 323.23) | Sub3-34 | m/z = 265.95(C₁₂H₈BrCl = 267.55) |
| Sub3-35 | m/z = 265.95(C₁₂H₈BrCl = 267.55) | Sub3-36 | m/z = 265.95(C₁₂H₈BrCl = 267.55) |
| Sub3-37 | m/z = 355.96(C₁₈H₁₀BrClO = 357.63) | Sub3-38 | m/z = 408.05(C₂₆H₁₇Br = 409.33) |
| Sub3-39 | m/z = 424.15(C₂₆HD₁₆Br = 425.42) | Sub3-40 | m/z = 417.11(C₂₆H₈D₉Br = 418.38) |

### Synthesis Example of Final Compound

### 1. Synthesis Example of P2-1

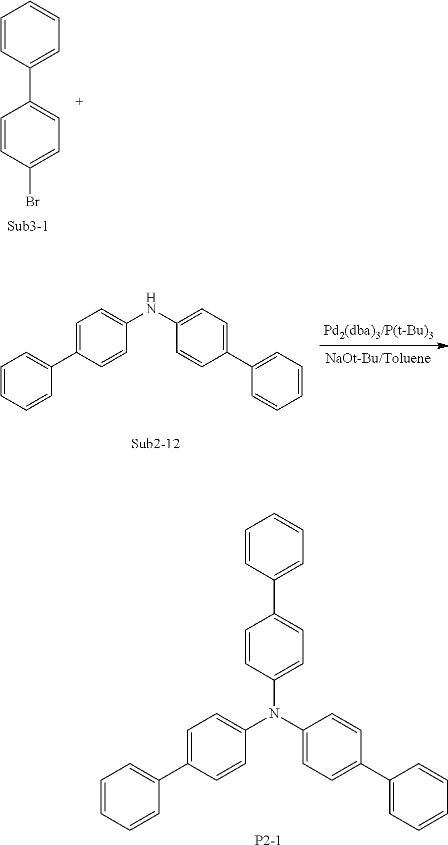 [SMILES: Brc1ccc(-c2ccccc2)cc1 ; c1ccc(-c2ccc(Nc3ccc(-c4ccccc4)cc3)cc2)cc1 ; c1ccc(-c2ccc(N(c3ccc(-c4ccccc4)cc3)c3ccc(-c4ccccc4)cc3)cc2)cc1 ; "P2-1"]

Sub3-1 (5.0 g, 21.6 mmol), Sub2-12 (5.0 g, 21.6 mmol), Pd₂(dba)₃ (0.59 g, 0.65 mmol), P(t-BU)₃ (0.26 g, 1.29 mmol), NaOt-Bu (4.1 g, 43.1 mmol) and toluene (108 mL) were put into a round bottom flask, and the reaction was carried out at 80° C. When the reaction was completed, the reaction product was extracted with CH₂Cl₂ and water, and then an organic layer was dried with MgSO₄ and concentrated. Then, the concentrate was separated through a silica gel column and recrystallized to obtain 8.1 g (yield: 79%) of the product.

### 2. Synthesis Example of P2-6

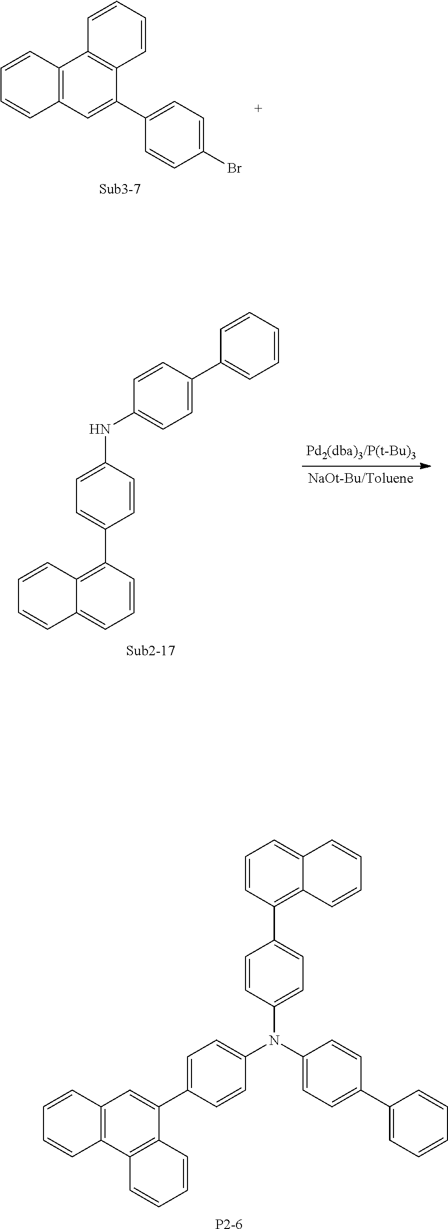 [SMILES: Brc1ccc(-c2cc3ccccc3c3ccccc23)cc1 ; "Sub3-7" ; c1ccc(-c2ccc(Nc3ccc(-c4cccc5ccccc45)cc3)cc2)cc1 ; c1ccc(-c2ccc(N(c3ccc(-c4cccc5ccccc45)cc3)c3ccc(-c4cc5ccccc5c5ccccc45)cc3)cc2)cc1 ; "P2-6"]

Sub3-7 (5.0 g, 15.0 mmol), Sub2-17 (5.6 g, 15.0 mmol), Pd₂(dba)₃ (0.41 g, 0.45 mmol), P(t-Bu)₃ (0.18 g, 0.90 mmol), NaOt-Bu (2.9 g, 30.0 mmol) and toluene (75 mL) were putted into a round bottom flask, and then the synthesis was carried out in the same manner as in the synthesis method of P2-1 to obtain 7.2 g (yield: 77%) of the product.

### 3. Synthesis Example of P2-17

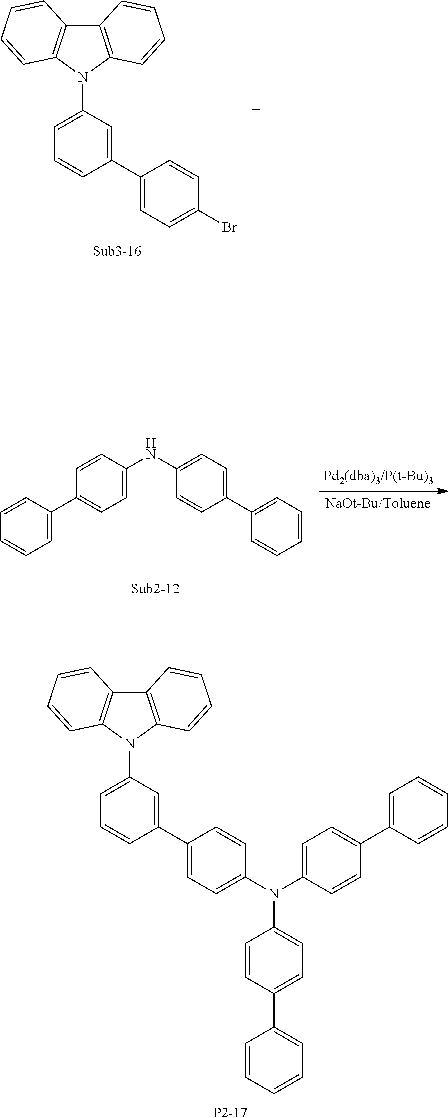

Sub3-16 (5.0 g, 12.6 mmol), Sub2-12 (4.0 g, 12.6 mmol), Pd₂(dba)₃ (0.34 g, 0.38 mmol), P(t-Bu)₃ (0.15 g, 0.75 mmol), NaOt-Bu (2.4 g, 25.1 mmol) and toluene (63 mL) were putted into a round bottom flask, and then the synthesis was carried out in the same manner as in the synthesis method of P2-1 to obtain 6.3 g (yield: 78%) of the product.

### 4. Synthesis Example of P2-29

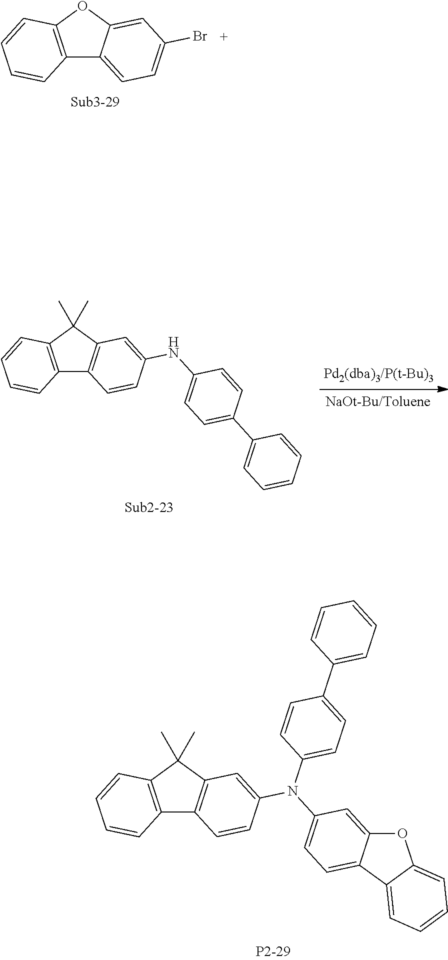 [SMILES: Brc1ccc2c(c1)oc1ccccc12 ; CC1(C)c2ccccc2-c2ccc(Nc3ccc(-c4ccccc4)cc3)cc21 ; CC1(C)c2ccccc2-c2ccc(N(c3ccc(-c4ccccc4)cc3)c3ccc4c(c3)oc3ccccc34)cc21]

Sub3-29 (5.0 g, 20.2 mmol), Sub2-23 (7.3 g, 20.2 mmol), Pd₂(dba)₃ (0.56 g, 0.61 mmol), P(t-Bu)₃ (0.25 g, 1.21 mmol), NaOt-Bu (3.9 g, 40.5 mmol) and toluene (100 mL) were putted into a round bottom flask, and then the synthesis was carried out in the same manner as in the synthesis method of P2-1 to obtain 7.7 g (yield: 72%) of the product.

### 5. Synthesis Example of P2-40

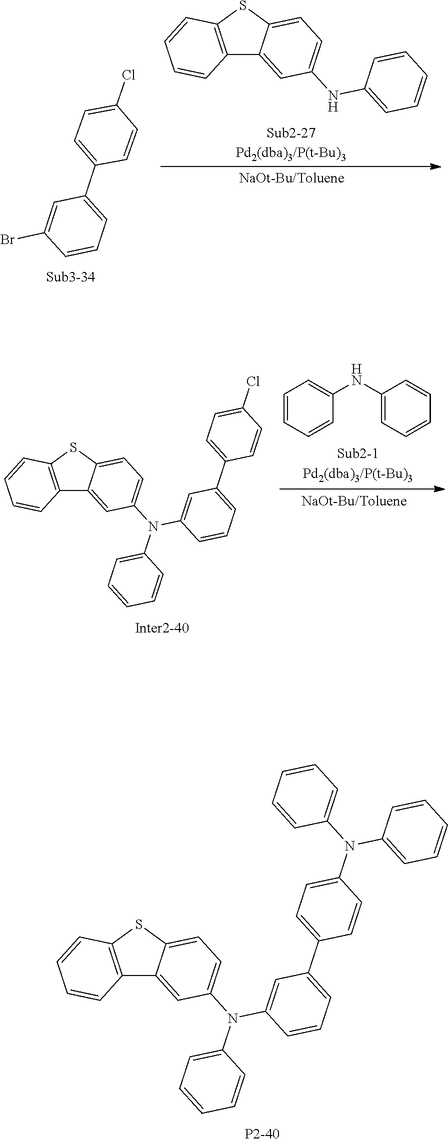

### (1) Synthesis of Inter2-40

Sub3-34 (5.0 g, 13.6 mmol), Sub2-27 (3.7 g, 13.6 mmol), Pd₂(dba)₃ (0.37 g, 0.41 mmol), P(t-Bu)₃ (0.17 g, 0.82 mmol), NaOt-Bu (2.6 g, 27.2 mmol) and toluene (68 mL) were put into a round bottom flask, and the reaction was carried out at 60° C. When the reaction was completed, the reaction product was extracted with CH₂Cl₂ and water, and then an organic layer was dried with MgSO₄ and concentrated. Then, the concentrate was separated through a silica gel column and recrystallized to obtain 4.9 g (yield: 78%) of the product.

### (2) Synthesis of P2-40

Inter2-40 (4.9 g, 10.6 mmol), Sub2-1 (1.8 g, 10.6 mmol), Pd₂(dba)₃ (0.29 g, 0.32 mmol), P(t-Bu)₃ (0.13 g, 0.64 mmol), NaOt-Bu (2.0 g, 21.2 mmol) and toluene (53 mL) were put into a round bottom flask, and the reaction was carried out at 80° C. When the reaction was completed, the reaction product was extracted with CH₂Cl₂ and water, and then an organic layer was dried with MgSO₄ and concentrated. Then, the concentrate was separated through a silica gel column and recrystallized to obtain 4.8 g (yield: 76%) of the product.

### 6. Synthesis Example of P2-43

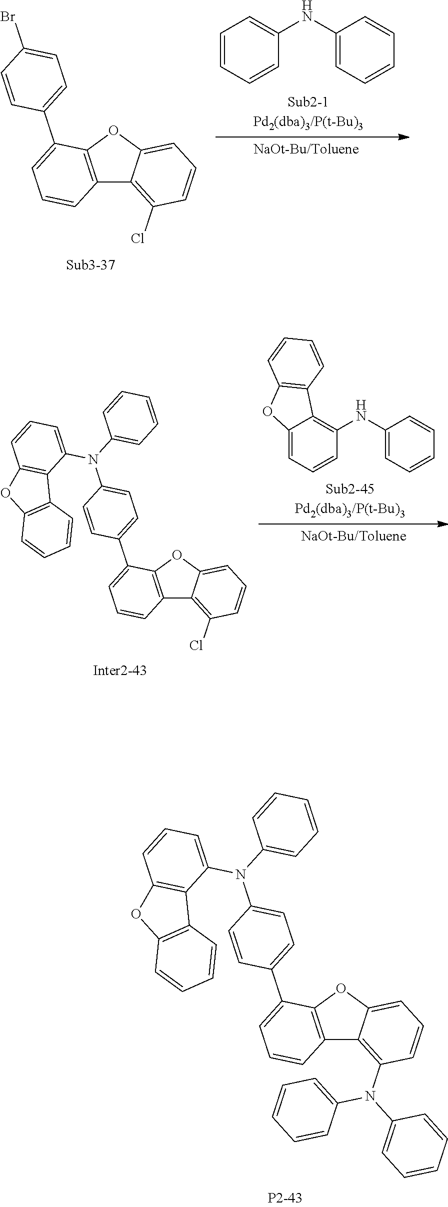 [SMILES: Clc1cccc2oc3c(-c4ccc(Br)cc4)cccc3c12 ; c1ccc(Nc2ccccc2)cc1 ; Clc1cccc2oc3c(-c4ccc(N(c5ccccc5)c5cccc6oc7ccccc7c56)cc4)cccc3c12 ; c1ccc(Nc2cccc3oc4ccccc4c23)cc1 ; c1ccc(N(c2ccc(-c3cccc4c3oc3cccc(N(c5ccccc5)c5ccccc5)c34)cc2)c2cccc3oc4ccccc4c23)cc1]

### (1) Synthesis of Inter2-43

Sub3-37 (5.0 g, 14.0 mmol), Sub2-1 (2.4 g, 14.0 mmol), Pd₂(dba)₃ (0.38 g, 0.42 mmol), P(t-Bu)₃ (0.17 g, 0.84 mmol), NaOt-Bu (2.7 g, 28.0 mmol) and toluene (70 mL) were putted into a round bottom flask, and then the synthesis was carried out in the same manner as in the synthesis method of Inter2-40 to obtain 5.9 g (yield: 79%) of the product.

### (2) Synthesis of P2-43

Inter2-43 (5.9 g, 11.0 mmol), Sub2-45 (2.9 g, 11.0 mmol), Pd₂(dba)₃ (0.13 g, 0.66 mmol), P(t-Bu)₃ (0.13 g, 0.66 mmol), NaOt-Bu (2.1 g, 22.1 mmol) and toluene (55 mL) were putted into a round bottom flask, and then the synthesis was carried out in the same manner as in the synthesis method of P2-40 to obtain 5.2 g (yield: 71%) of the product.

### 7. Synthesis Example of P2-44

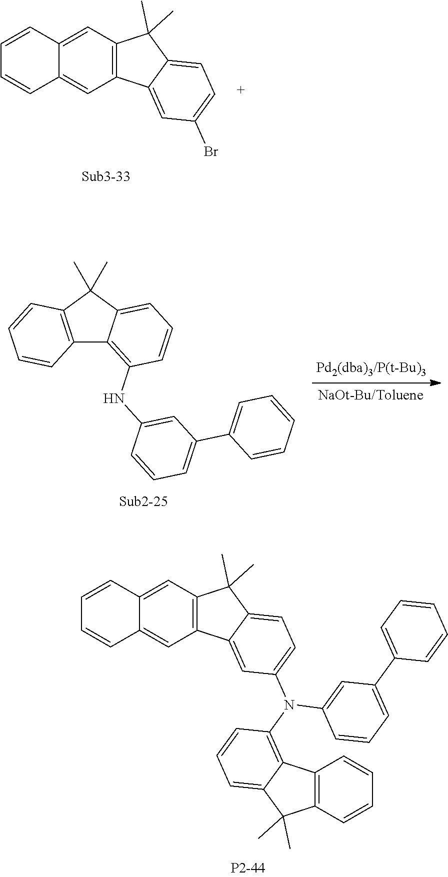 [SMILES: CC1(C)c2ccc(Br)cc2-c2cc3ccccc3cc21 ; CC1(C)c2ccccc2-c2c(Nc3cccc(-c4ccccc4)c3)cccc21 ; CC1(C)c2ccc(N(c3cccc(-c4ccccc4)c3)c3cccc4c3-c3ccccc3C4(C)C)cc2-c2cc3ccccc3cc21]

Sub3-33 (5.0 g, 15.5 mmol), Sub2-25 (5.6 g, 15.5 mmol), Pd₂(dba)₃ (0.42 g, 0.46 mmol), P(t-Bu)₃ (0.19 g, 0.93 mmol), NaOt-Bu (3.0 g, 30.9 mmol) and toluene (77 mL) were putted into a round bottom flask, and then the synthesis was carried out in the same manner as in the synthesis method of P2-1 to obtain 6.7 g (yield: 72%) of the product.

FD-MS values of the compounds P2-1 to P2-56 of the present invention synthesized by the above synthesis method are shown in Table 5 below.

TABLE 5

| Compound | FD-MS | Compound | FD-MS |
|---|---|---|---|
| P2-1 | m/z = 473.21(C₃₆H₂₇N = 473.62) | P2-2 | m/z = 473.21(C₃₆H₂₇N = 473.62) |
| P2-3 | m/z = 573.25(C₄₄H₃₁N = 573.74) | P2-4 | m/z = 573.25(C₄₄H₃₁N = 573.74) |
| P2-5 | m/z = 497.21(C₃₈H₂₇N = 497.64) | P2-6 | m/z = 623.26(C₄₈H₃₃N = 623.8) |
| P2-7 | m/z = 573.25(C₄₄H₃₁N = 573.74) | P2-8 | m/z = 623.26(C₄₈H₃₃N = 623.8) |
| P2-9 | m/z = 491.33(C₃₆H₉D₁₈N = 491.73) | P2-10 | m/z = 649.28(C₅₀H₃₅N = 649.84) |
| P2-11 | m/z = 683.36(C₅₂H₄₅N = 683.94) | P2-12 | m/z = 585.34(C₄₄H₄₃N = 585.84) |
| P2-13 | m/z = 562.24(C₄₂H₃₀N₂ = 562.72) | P2-14 | m/z = 602.27(C₄₅H₃₄N₂ = 602.78) |
| P2-15 | m/z = 562.24(C₄₂H₃₀N₂ = 562.72) | P2-16 | m/z = 638.27(C₄₈H₃₄N₂ = 638.81) |
| P2-17 | m/z = 638.27(C₄₈H₃₄N₂ = 638.81) | P2-18 | m/z = 678.3(C₅₁H₃₈N₂ = 678.88) |
| P2-19 | m/z = 652.25(C₄₈H₃₂N₂O = 652.8) | P2-20 | m/z = 790.33(C₆₀H₄₂N₂ = 791.01) |
| P2-21 | m/z = 788.32(C₆₀H₄₀N₂ = 788.99) | P2-22 | m/z = 712.29(C₅₄H₃₆N₂ = 712.9) |
| P2-23 | m/z = 738.3(C₅₆H₃₈N₂ = 738.93) | P2-24 | m/z = 688.29(C₅₂H₃₆N₂ = 688.87) |
| P2-25 | m/z = 594.23(C₄₂H₃₀N₂O₂ = 594.71) | P2-26 | m/z = 668.23(C₄₈H₃₂N₂S = 668.86) |
| P2-27 | m/z = 750.4(C₅₆H₅₀N₂ = 751.03) | P2-28 | m/z = 496.27(C₃₆H₁₆D₁₀N₂ = 496.68) |
| P2-29 | m/z = 527.22(C₃₉H₂₉NO = 527.67) | P2-30 | m/z = 689.27(C₅₂H₃₅NO = 689.86) |
| P2-31 | m/z = 619.23(C₄₅H₃₃NS = 619.83) | P2-32 | m/z = 669.21(C₄₈H₃₁NOS = 669.84) |
| P2-33 | m/z = 643.2(C₄₆H₂₉NOS = 643.8) | P2-34 | m/z = 627.22(C₄₆H₂₉NO₂ = 627.74) |
| P2-35 | m/z = 583.14(C₄₀H₂₅NS₂ = 583.77) | P2-36 | m/z = 665.22(C₄₉H₃₁NS = 665.85) |
| P2-37 | m/z = 792.35(C₆₀H₄₄N₂ = 793.03) | P2-38 | m/z = 594.21(C₄₂H₃₀N₂S = 594.78) |
| P2-39 | m/z = 654.27(C₄₈H₃₄N₂O = 654.81) | P2-40 | m/z = 594.21(C₄₂H₃₀N₂S = 594.78) |
| P2-41 | m/z = 578.24(C₄₂H₃₀N₂O = 578.72) | P2-42 | m/z = 710.28(C₅₁H₃₈N₂S = 710.94) |
| P2-43 | m/z = 668.25(C₄₈H₃₂N₂O₂ = 668.8) | P2-44 | m/z = 603.29(C₄₆H₃₇N = 603.81) |
| P2-45 | m/z = 603.26(C₄₅H₃₃NO = 603.77) | P2-46 | m/z = 757.24(C₅₅H₃₅NOS = 757.95) |
| P2-47 | m/z = 607.16(C₄₂H₂₅NO₂S = 607.73) | P2-48 | m/z = 833.28(C₆₁H₃₉NOS = 834.05) |
| P2-49 | m/z = 833.28(C₆₁H₃₉NOS = 834.05) | P2-50 | m/z = 649.28(C₅₀H₃₅N = 649.84) |
| P2-51 | m/z = 684.22(C₄₈H₃₂N₂OS = 684.86) | P2-52 | m/z = 683.49(C₅₀HD₃₄N = 684.04) |
| P2-53 | m/z = 658.33(C₅₀H₂₆D₉N = 658.89) | P2-54 | m/z = 699.29(C₅₄H₃₇N = 699.9) |
| P2-55 | m/z = 657.33(C₅₀H₂₇D₈N = 657.89) | P2-56 | m/z = 659.34(C₅₀H₂₅D₁₀N = 659.9) |

### Fabrication and Evaluation of Organic Electric Element

### [Test Example 1] Red Organic Electroluminescent Element (Emission-Auxiliary Layer)

After vacuum-depositing 4,4′,4″-tris[2-naphthyl(phenyl)amino]triphenylamine (hereinafter abbreviated as “2-TNATA”) on an ITO layer (anode) formed on a glass substrate to form a hole injection layer of 70 nm thickness, a hole transport layer of 70 nm thickness was formed by vacuum-depositing N,N′-bis(1-naphthalenyl)-N,N′-bis-phenyl-(1,1′-biphenyl)-4,4′-diamine (hereinafter abbreviated as “NPB”) on the hole injection layer.

Compound P1-1 of the present invention was vacuum deposited to a thickness of 70 nm on the hole transport layer to form a first light-emitting auxiliary layer, and then compound P2-3 of the present invention was vacuum deposited to a thickness of 5 nm on the first light-emitting auxiliary layer to form a second light emitting auxiliary layer.

Next, 4,4-N,N′-dicarbazole-biphenyl (hereinafter abbreviated as “CBP”) as a host material and bis-(1-phenyl isoquinolyl)iridium(III)acetylacetonate (hereinafter abbreviated as “(piq)₂Ir(acac)”) as a dopant material in a weight ratio of 95:5 were deposited on the second light-emitting auxiliary layer to form a light-emitting layer of 40 nm thickness.

Next, (1,1′-bisphenyl-4-olato)bis(2-methyl-8-quinolinolato)aluminum (hereinafter abbreviated as “BAlq”) was vacuum-deposited to form a hole blocking layer of 5 nm thickness on the light-emitting layer, and bis(10-hydroxybenzo[h]quinolinato)beryllium (hereinafter abbreviated as “BeBq₂”) was vacuum-deposited to form a an electron transport layer of 30 nm thickness on the hole blocking layer.

Thereafter, LiF was deposited to form an electron injection layer of 0.2 nm thickness on the electron transport layer, and then Al was deposited to form a cathode of 150 nm thickness on the electron injection layer.

### [Test Example 2] to [Test Example 64]

The organic electroluminescent elements were fabricated in the same manner as described in Example 1 except that the compounds of the present invention described in the following Table 6 were used as materials of a first light-emitting auxiliary layer and a second light emitting auxiliary layer.

### [Comparative Example 1] to [Comparative Example 17]

The organic electroluminescent elements were fabricated in the same manner as described in Example 1 except that a single light-emitting auxiliary layer was formed using a single material listed in Table 6 below.

### Comparative Example 18

The organic electroluminescent elements were fabricated in the same manner as described in Example 1 except that the following comparative compound A was used as material of a first light-emitting auxiliary layer, and the compound P1-1 of the present invention was used as material of a second light-emitting auxiliary layer as shown in Table 6 below.

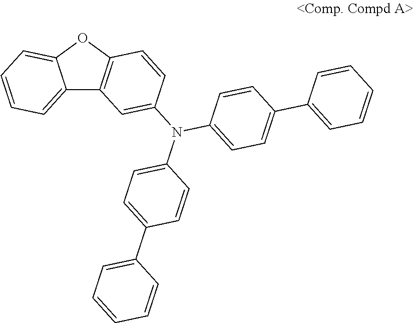 [SMILES: c1ccc(-c2ccc(N(c3ccc(-c4ccccc4)cc3)c3ccc4oc5ccccc5c4c3)cc2)cc1]

A forward bias DC voltage was applied to the electroluminescent elements manufactured in Test Examples 1 to 64 and Comparative Examples 1 to 18, and electroluminescence (EL) characteristics were measured with Photo Research's PR-650 and lifetime (T95) was measured with a lifetime measuring device manufactured by Mc Science company at 2500 cd/m² standard luminance. The measurement results are shown in Table 6 below.

TABLE 6

| | | | | Current | | | |
|---|---|---|---|---|---|---|---|
| | | | Voltage | Density | Brightness | Efficiency | Lifetime |
| | EAL 1 | EAL 2 | (V) | (mA/cm²) | (cd/m²) | (cd/A) | T(95) |
| comp. Ex(1) | Com. (P1-1) | | 5.3 | 12.6 | 2500.0 | 19.9 | 93.4 |
| comp. Ex(2) | Com. (P1-4) | | 5.5 | 12.8 | 2500.0 | 19.6 | 94.6 |
| comp. Ex(3) | Com. (P1-7) | | 5.4 | 12.8 | 2500.0 | 19.5 | 91.2 |
| comp. Ex(4) | Com. (P1-22) | | 5.4 | 13.0 | 2500.0 | 19.3 | 80.4 |
| comp. Ex(5) | Com. (P1-24) | | 5.3 | 12.8 | 2500.0 | 19.6 | 90.5 |
| comp. Ex(6) | Com. (P1-28) | | 5.4 | 13.1 | 2500.0 | 19.1 | 89.2 |
| comp. Ex(7) | Com. (P1-40) | | 5.3 | 12.8 | 2500.0 | 19.5 | 94.5 |
| comp. Ex(8) | Com. (P1-42) | | 5.4 | 13.0 | 2500.0 | 19.2 | 92.2 |
| comp. Ex(9) | Com. (P1-56) | | 5.4 | 13.4 | 2500.0 | 18.6 | 87.3 |
| comp. Ex(10) | Com. (P1-61) | | 5.4 | 12.7 | 2500.0 | 19.7 | 98.9 |
| comp. Ex(11) | Com. (P1-62) | | 5.3 | 13.2 | 2500.0 | 18.9 | 79.6 |
| comp. Ex(12) | Com. (P1-75) | | 5.4 | 13.8 | 2500.0 | 18.1 | 88.7 |
| comp. Ex(13) | Com. (P2-3) | | 5.6 | 13.4 | 2500.0 | 18.6 | 93.2 |
| comp. Ex(14) | Com. (P2-17) | | 5.5 | 12.7 | 2500.0 | 19.7 | 103.3 |
| comp. Ex(15) | Com. (P2-29) | | 5.5 | 14.2 | 2500.0 | 17.6 | 86.3 |
| comp. Ex(16) | Com. (P2-43) | | 5.4 | 12.4 | 2500.0 | 20.2 | 101.4 |
| comp. Ex(17) | Com. (P2-44) | | 5.6 | 14.9 | 2500.0 | 16.8 | 83.2 |
| comp. Ex(18) | Comp. compdA | Com. (P1-1) | 5.3 | 12.2 | 2500.0 | 20.5 | 104.5 |
| Test Ex(1) | Com. (P1-1) | Com. (P2-3) | 4.8 | 9.6 | 2500.0 | 26.1 | 120.3 |
| Test Ex(2) | | Com. (P2-17) | 4.8 | 9.1 | 2500.0 | 27.6 | 132.6 |
| Test Ex(3) | | Com. (P2-29) | 4.8 | 10.6 | 2500.0 | 23.7 | 117.7 |
| Test Ex(4) | | Com. (P2-43) | 4.8 | 8.8 | 2500.0 | 28.5 | 126.7 |
| Test Ex(5) | | Com. (P2-44) | 4.9 | 10.0 | 2500.0 | 24.9 | 115.7 |
| Test Ex(6) | Com. (P1-4) | Com. (P2-3) | 5.1 | 9.8 | 2500.0 | 25.5 | 120.4 |
| Test Ex(7) | | Com. (P2-17) | 5.1 | 9.2 | 2500.0 | 27.3 | 131.5 |
| Test Ex(8) | | Com. (P2-29) | 5.2 | 10.7 | 2500.0 | 23.4 | 117.3 |
| Test Ex(9) | | Com. (P2-43) | 5.1 | 9.0 | 2500.0 | 27.9 | 126.1 |
| Test Ex(10) | | Com. (P2-44) | 5.1 | 10.2 | 2500.0 | 24.5 | 114.7 |
| Test Ex(11) | Com. (P1-7) | Com. (P2-3) | 4.9 | 9.4 | 2500.0 | 26.6 | 121.9 |
| Test Ex(12) | | Com. (P2-17) | 4.9 | 8.8 | 2500.0 | 28.4 | 132.9 |
| Test Ex(13) | Com. (P1-7) | Com. (P2-29) | 5.0 | 10.3 | 2500.0 | 24.3 | 118.7 |
| Test Ex(14) | | Com. (P2-43) | 4.9 | 8.7 | 2500.0 | 28.9 | 127.9 |
| Test Ex(15) | | Com. (P2-44) | 4.9 | 9.9 | 2500.0 | 25.3 | 116.4 |
| Test Ex(16) | Com. (P1-22) | Com. (P2-3) | 4.9 | 9.1 | 2500.0 | 27.5 | 127.2 |
| Test Ex(17) | | Com. (P2-17) | 4.9 | 8.5 | 2500.0 | 29.4 | 138.4 |
| Test Ex(18) | | Com. (P2-29) | 4.9 | 9.9 | 2500.0 | 25.2 | 123.1 |
| Test Ex(19) | | Com. (P2-43) | 4.9 | 8.3 | 2500.0 | 30.1 | 133.3 |
| Test Ex(20) | | Com. (P2-44) | 4.9 | 9.5 | 2500.0 | 26.4 | 120.0 |
| Test Ex(21) | Com. (P1-24) | Com. (P2-3) | 4.8 | 10.0 | 2500.0 | 25.0 | 117.3 |
| Test Ex(22) | | Com. (P2-17) | 4.8 | 9.4 | 2500.0 | 26.5 | 129.5 |
| Test Ex(23) | | Com. (P2-29) | 4.9 | 11.0 | 2500.0 | 22.7 | 114.6 |
| Test Ex(24) | | Com. (P2-43) | 4.8 | 9.2 | 2500.0 | 27.3 | 123.5 |
| Test Ex(25) | | Com. (P2-44) | 4.8 | 10.5 | 2500.0 | 23.9 | 112.5 |
| Test Ex(26) | Com. (P1-28) | Com. (P2-3) | 4.9 | 10.0 | 2500.0 | 24.9 | 116.7 |
| Test Ex(27) | | Com. (P2-17) | 4.9 | 9.5 | 2500.0 | 26.3 | 128.0 |
| Test Ex(28) | | Com. (P2-29) | 5.0 | 11.1 | 2500.0 | 22.4 | 113.9 |
| Test Ex(29) | | Com. (P2-43) | 4.9 | 9.2 | 2500.0 | 27.0 | 123.0 |
| Test Ex(30) | | Com. (P2-44) | 4.9 | 10.5 | 2500.0 | 23.7 | 112.3 |
| Test Ex(31) | Com. (P1-40) | Com. (P2-3) | 4.8 | 9.1 | 2500.0 | 27.4 | 123.5 |
| Test Ex(32) | | Com. (P2-17) | 4.8 | 8.6 | 2500.0 | 29.2 | 135.5 |
| Test Ex(33) | | Com. (P2-29) | 4.8 | 10.1 | 2500.0 | 24.7 | 120.9 |
| Test Ex(34) | | Com. (P2-43) | 4.8 | 8.4 | 2500.0 | 29.9 | 129.3 |
| Test Ex(35) | | Com. (P2-44) | 4.8 | 9.5 | 2500.0 | 26.2 | 118.3 |
| Test Ex(36) | Com. (P1-42) | Com. (P2-3) | 4.9 | 9.3 | 2500.0 | 27.0 | 122.8 |
| Test Ex(37) | | Com. (P2-17) | 4.9 | 8.7 | 2500.0 | 28.8 | 134.6 |
| Test Ex(38) | | Com. (P2-29) | 4.9 | 10.2 | 2500.0 | 24.6 | 119.3 |
| Test Ex(39) | | Com. (P2-43) | 4.9 | 8.5 | 2500.0 | 29.4 | 128.8 |
| Test Ex(40) | | Com. (P2-44) | 4.9 | 9.7 | 2500.0 | 25.8 | 117.5 |
| Test Ex(41) | Com. (P1-56) | Com. (P2-3) | 4.9 | 9.9 | 2500.0 | 25.3 | 119.9 |
| Test Ex(42) | | Com. (P2-17) | 4.9 | 9.3 | 2500.0 | 27.0 | 131.0 |
| Test Ex(43) | Com. (P1-56) | Com. (P2-29) | 5.0 | 10.8 | 2500.0 | 23.0 | 116.8 |
| Test Ex(44) | | Com. (P2-43) | 4.9 | 9.0 | 2500.0 | 27.8 | 124.8 |
| Test Ex(45) | | Com. (P2-44) | 4.9 | 10.3 | 2500.0 | 24.3 | 114.3 |
| Test Ex(46) | Com. (P1-61) | Com. (P2-3) | 4.9 | 9.5 | 2500.0 | 26.4 | 120.8 |
| Test Ex(47) | | Com. (P2-17) | 4.9 | 8.9 | 2500.0 | 28.1 | 133.4 |
| Test Ex(48) | | Com. (P2-29) | 5.0 | 10.4 | 2500.0 | 24.0 | 118.1 |
| Test Ex(49) | | Com. (P2-43) | 4.9 | 8.7 | 2500.0 | 28.9 | 127.5 |
| Test Ex(50) | | Com. (P2-44) | 5.0 | 9.9 | 2500.0 | 25.4 | 115.5 |
| Test Ex(51) | Com. (P1-62) | Com. (P2-3) | 4.7 | 8.8 | 2500.0 | 28.6 | 124.2 |
| Test Ex(52) | | Com. (P2-17) | 4.7 | 8.2 | 2500.0 | 30.5 | 136.4 |
| Test Ex(53) | | Com. (P2-29) | 4.8 | 9.6 | 2500.0 | 26.0 | 121.1 |
| Test Ex(54) | | Com. (P2-43) | 4.7 | 8.0 | 2500.0 | 31.2 | 131.2 |
| Test Ex(55) | | Com. (P2-44) | 4.7 | 9.2 | 2500.0 | 27.3 | 118.8 |
| Test Ex(56) | Com. (P1-75) | Com. (P2-3) | 4.9 | 9.1 | 2500.0 | 27.6 | 123.1 |
| Test Ex(57) | | Com. (P2-17) | 4.9 | 8.6 | 2500.0 | 29.2 | 133.6 |
| Test Ex(58) | | Com. (P2-29) | 5.0 | 10.1 | 2500.0 | 24.8 | 118.9 |
| Test Ex(59) | | Com. (P2-43) | 4.9 | 8.3 | 2500.0 | 30.0 | 128.3 |
| Test Ex(60) | | Com. (P2-44) | 4.9 | 9.6 | 2500.0 | 26.1 | 117.3 |
| Test Ex(61) | Com. (P1-90) | Com. (P2-17) | 4.9 | 8.1 | 2500.0 | 30.9 | 133.4 |
| Test Ex(62) | | Com. (P2-43) | 4.9 | 7.9 | 2500.0 | 31.6 | 127.7 |
| Test Ex(63) | | Com. (P2-53) | 4.9 | 8.3 | 2500.0 | 30.3 | 135.6 |
| Test Ex(64) | | Com. (P2-54) | 4.9 | 8.3 | 2500.0 | 30.1 | 129.1 |

From Table 6, it can be seen that in case of Comparative example 18 and Test examples of the present invention in which a plurality of light emitting auxiliary layers were formed, rather than Comparative Example 1 to Comparative Example 17 in which the light-emitting auxiliary layer was formed as a single layer using a single material, the organic electric element characteristics are improved. In particular, according to embodiments of the present invention, the driving voltage of the organic electric element can be significantly lowered, and the luminous efficiency and lifespan can be significantly improved.

The light-emitting auxiliary layer must well receive holes from the hole transport layer, must well transmit holes to the host, and must well block electrons from passing from the host. However, it is not easy to select a material that satisfies all of these required properties when forming a single light-emitting auxiliary layer with one material since the properties (hole mobility, energy level, etc.) of the compounds forming each layer are different.

When forming a plurality of light-emitting auxiliary layers with the compound of the present invention, it is easy to improve the overall element performance since the above required characteristics can be more easily satisfied.

In Comparative Example 18, two light-emitting auxiliary layers were formed using different materials, but the characteristics of element were significantly superior according to the example of the present invention.

There is a difference in that Comparative compound A has a structure in which dibenzothiophene is substituted with a diarylamine group, whereas the compound of the present invention has a structure in which the benzene ring of dibenzothiophene or dibenzofuran is necessarily substituted with a substituent other than hydrogen or is condensed with another ring.

It appears that the packing density is increased, the driving voltage is lowered, and the refractive index and thermal stability are increased when the compound of the present invention is used as material of a first light-emitting auxiliary layer, thereby improving the efficiency and lifespan of the element.

It appears that the driving voltage of the element varies depending on the material forming a first light-emitting auxiliary layer, and the efficiency and lifespan of the element vary depending on the material forming a second light-emitting auxiliary layer.

In order to confirm these characteristics, the hole mobility according to HOD (Hole Only Device) was measured for the compounds in Table 7. Table 7 shows the hole mobility of HOD (Hole Only Device) in an organic electric element that manufactured by depositing in the following order: ITO layer (anode)/HAT-CN 5 nm/comparative compound A or compound of the present invention 300 nm/HAT-CN 1 nm/Al (cathode) 100 nm.

TABLE 7

| | hole mobility |
|---|---|
| Compound | (cm/V•S) |
| Comp. compd A | 4.2 × 10⁻⁵ |
| P1-1 | 1.1 × 10⁻³ |
| P1-4 | 5.1 × 10⁻⁵ |
| P1-7 | 5.9 × 10⁻⁴ |
| P1-22 | 9.7 × 10⁻⁴ |
| P1-24 | 1.5 × 10⁻³ |
| P1-28 | 9.1 × 10⁻⁴ |
| P1-40 | 2.1 × 10⁻³ |
| P1-42 | 7.1 × 10⁻⁴ |
| P1-56 | 5.5 × 10⁻⁴ |
| P1-61 | 8.2 × 10⁻⁴ |
| P1-62 | 1.4 × 10⁻³ |
| P1-75 | 5.9 × 10⁻⁴ |
| P1-90 | 7.9 × 10⁻⁴ |

Looking at Table 7 above, it can be seen that the hole mobility of the compound of the present invention is faster than that of comparative compound A.

Referring to Table 6 above, it can be seen that the driving voltage is lower when the compound of the present invention is used as material for a first light-emitting auxiliary layer, comparing to when comparative compound A is used (Comparative Example 18). Therefore, it can be seen that the driving voltage can be lowered by forming a first light-emitting auxiliary layer with a material with high hole mobility.

However, the efficiency and lifespan of a device cannot be improved simply by using a material with high hole mobility, and the characteristics of the compound, such as the difference in energy level from the light-emitting layer, affect the overall performance of the device.

Therefore, the present invention manufactured an element employing a second light-emitting auxiliary layer in order to compensate for this problem, and DFT method (B3LYP/6-31g(D)) of the Gaussian program was used to confirm the energy level characteristics of a second light-emitting auxiliary layer. HOMO, LUMO and T1 values are shown in Table 8 below.

TABLE 8

| Compound | P2-3 | P2-17 | P2-29 | P2-43 | P2-44 |
|---|---|---|---|---|---|
| G.HOMO | −5.001 | −5.018 | −4.832 | −5.004 | −4.978 |
| G.LUMO | −1.106 | −0.871 | −1.064 | −1.087 | −1.378 |
| G.T1 | 2.570 | 2.726 | 2.648 | 2.778 | 2.511 |

Referring to Table 6 and Table 8, it can be seen that the HOMO value of the material of a second light-emitting auxiliary layer affects the efficiency of an element, the LUMO value affects the lifespan of an element, and the T1 value affects the efficiency and lifespan.

It appears that when a compound with a low HOMO value is used as the material for a second light-emitting auxiliary layer, the hole injection from the second light-emitting auxiliary layer to the host can be smoothly performed, thereby improving the efficiency of an element, when a compound with a high LUMO value is used, it can effectively block electrons coming from the host, thereby improving the lifespan of an element, and when a compound with a high T1 value is used, it can effectively block triplet electrons coming from the dopant, thereby improving both efficiency and lifespan.

### [Test Example 65] to [Test Example 89] Green Organic Electroluminescent Element (Emission-Auxiliary Layer)

The organic electroluminescent elements were fabricated in the same manner as described in Example 1 except that the compounds in Table 9 below were used as materials for first and second light-emitting auxiliary layer, and the first light-emitting auxiliary layer was formed to a thickness of 30 nm, the second light-emitting auxiliary layer was formed to a thickness of 5 nm, and tris(2-phenylpyridine)-iridium (hereinafter referred to as Ir(ppy)₃) was used as dopant.

### [Comparative Example 19] to [Comparative Example 28]

The organic electroluminescent elements were fabricated in the same manner as described in Example 65 except that a single light-emitting auxiliary layer was formed using a single material listed in Table 9 below.

### Comparative Example 29

The organic electroluminescent elements were fabricated in the same manner as described in Example 65 except that the following comparative compound A was used as material of a first light-emitting auxiliary layer, and the compound P1-1 of the present invention was used as material of a second light-emitting auxiliary layer as shown in Table 9 below.

A forward bias DC voltage was applied to the electroluminescent elements manufactured in Test Examples 65 to 89 and Comparative Examples 19 to 29, and electroluminescence (EL) characteristics were measured with Photo Research's PR-650 and lifetime (T95) was measured with a lifetime measuring device manufactured by Mc Science company at 5000 cd/m² standard luminance. The measurement results are shown in Table 9 below.

TABLE 9

| | | | | Current | | | |
|---|---|---|---|---|---|---|---|
| | | | Voltage | Density | Brightness | Efficiency | Lifetime |
| | EAL 1 | EAL 2 | (V) | (m/cm²) | (cd/m²) | (cd/A) | T(95) |
| comp. Ex(19) | Com. (P1-77) | | 5.3 | 22.0 | 5000.0 | 22.7 | 93.5 |
| comp. Ex(20) | Com. (P1-78) | | 5.4 | 21.2 | 5000.0 | 23.6 | 92.6 |
| comp. Ex(21) | Com. (P1-79) | | 5.5 | 22.4 | 5000.0 | 22.3 | 94.6 |
| comp. Ex(22) | Com. (P1-80) | | 5.3 | 21.6 | 5000.0 | 23.1 | 94.1 |
| comp. Ex(23) | Com. (P1-81) | | 5.4 | 22.8 | 5000.0 | 21.9 | 93.3 |
| comp. Ex(24) | Com. (P2-29) | | 5.5 | 23.7 | 5000.0 | 21.1 | 91.2 |
| comp. Ex(25) | Com. (P2-45) | | 5.5 | 21.4 | 5000.0 | 23.4 | 97.3 |
| comp. Ex(26) | Com. (P2-47) | | 5.5 | 20.3 | 5000.0 | 24.6 | 98.9 |
| comp. Ex(27) | Com. (P2-48) | | 5.4 | 19.4 | 5000.0 | 25.8 | 98.5 |
| comp. Ex(28) | Com. (P2-49) | | 5.4 | 19.7 | 5000.0 | 25.4 | 97.6 |
| comp. Ex(29) | Comp. compdA | Com. (P1-1) | 5.2 | 14.2 | 5000.0 | 35.2 | 115.6 |
| Test Ex(65) | Com.(P1-77) | Com. (P2-29) | 4.7 | 11.4 | 5000.0 | 44.0 | 139.0 |
| Test Ex(66) | | Com. (P2-45) | 4.7 | 10.0 | 5000.0 | 50.1 | 154.4 |
| Test Ex(67) | | Com. (P2-47) | 4.6 | 9.6 | 5000.0 | 52.2 | 166.0 |
| Test Ex(68) | | Com. (P2-48) | 4.7 | 9.4 | 5000.0 | 53.2 | 161.4 |
| Test Ex(69) | | Com. (P2-49) | 4.7 | 9.8 | 5000.0 | 51.1 | 144.6 |
| Test Ex(70) | Com. (P1-78) | Com. (P2-29) | 4.9 | 11.1 | 5000.0 | 45.2 | 133.1 |
| Test Ex(71) | | Com. (P2-45) | 4.9 | 9.8 | 5000.0 | 51.0 | 150.3 |
| Test Ex(72) | | Com. (P2-47) | 4.9 | 9.4 | 5000.0 | 53.2 | 159.4 |
| Test Ex(73) | | Com. (P2-48) | 4.9 | 9.2 | 5000.0 | 54.1 | 153.6 |
| Test Ex(74) | | Com. (P2-49) | 4.9 | 9.6 | 5000.0 | 51.9 | 139.4 |
| Test Ex(75) | Com. (P1-79) | Com. (P2-29) | 5.1 | 11.4 | 5000.0 | 43.9 | 144.4 |
| Test Ex(76) | | Com. (P2-45) | 5.1 | 10.1 | 5000.0 | 49.5 | 162.4 |
| Test Ex(77) | | Com. (P2-47) | 5.0 | 9.7 | 5000.0 | 51.8 | 172.7 |
| Test Ex(78) | | Com. (P2-48) | 5.1 | 9.5 | 5000.0 | 52.9 | 167.3 |
| Test Ex(79) | | Com. (P2-49) | 5.1 | 9.9 | 5000.0 | 50.4 | 151.0 |
| Test Ex(80) | Com. (P1-80) | Com. (P2-29) | 4.8 | 11.2 | 5000.0 | 44.5 | 141.9 |
| Test Ex(81) | | Com. (P2-45) | 4.8 | 9.9 | 5000.0 | 50.5 | 157.5 |
| Test Ex(82) | | Com. (P2-47) | 4.7 | 9.5 | 5000.0 | 52.4 | 170.0 |
| Test Ex(83) | | Com. (P2-48) | 4.8 | 9.4 | 5000.0 | 53.2 | 164.6 |
| Test Ex(84) | | Com. (P2-49) | 4.8 | 9.7 | 5000.0 | 51.4 | 149.0 |
| Test Ex(85) | Com. (P1-81) | Com. (P2-29) | 5.0 | 11.5 | 5000.0 | 43.5 | 135.8 |
| Test Ex(86) | | Com. (P2-45) | 5.0 | 10.1 | 5000.0 | 49.3 | 152.5 |
| Test Ex(87) | | Com. (P2-47) | 5.0 | 9.8 | 5000.0 | 51.0 | 162.5 |
| Test Ex(88) | | Com. (P2-48) | 5.0 | 9.6 | 5000.0 | 52.2 | 157.6 |
| Test Ex(89) | | Com. (P2-49) | 5.0 | 10.0 | 5000.0 | 50.2 | 142.6 |

From Table 9, it can be seen that the characteristics of an element are improved when a plurality of light emitting auxiliary layers are formed compared to the case where a light-emitting auxiliary layer is formed as a single layer using a single material (Comparative Example 19 to Comparative Example 28).

As explained in the red organic electric element discussed above, it appears that the characteristics of an element are improved when a plurality of light-emitting auxiliary layers are formed since a first light-emitting auxiliary layer affects the driving voltage of an element, and a second light-emitting auxiliary layer affects the efficiency and lifespan of an element.

To confirm this, the hole mobility of Comparative Compound A and the compound of the present invention was measured, and hole mobility was measured under the same conditions as in Table 7. The measurement results are shown in Table 10 below.

TABLE 10

| | hole mobility |
|---|---|
| Compound | (cm/V•S) |
| Comp. compd A | 4.2 × 10⁻⁵ |
| P1-77 | 1.1 × 10⁻³ |
| P1-78 | 6.4 × 10⁻⁴ |
| P1-79 | 1.8 × 10⁻⁴ |
| P1-80 | 9.7 × 10⁻⁴ |
| P1-81 | 3.2 × 10⁻⁴ |

Looking at Tables 9 and 10, as described in the previous red organic electroluminescent device, it can be seen that when a compound with high hole mobility is used as material for a first light-emitting auxiliary layer, the driving voltage of an element is reduced. That is, when comparing Comparative Compound A and the compound of the present invention, it can be seen that the hole mobility of the compound of the present invention is noticeably higher than that of comparative compound A, and it can be confirmed that the driving voltage of an element is significantly reduced when the compound of the present invention is used as material for a first light-emitting auxiliary layer.

In addition, the DFT method (B3LYP/6-31g(D)) of the Gaussian program was used to confirm the energy level characteristics of a second light-emitting auxiliary layer, and the measured data are shown in Table 11 below.

TABLE 11

| Compound | P2-29 | P2-45 | P2-47 | P2-48 | P2-49 |
|---|---|---|---|---|---|
| G.T1 | 2.648 | 2.711 | 2.818 | 2.830 | 2.717 |

Looking at Table 9 and Table 11, it appears that triplet electrons may be prevented from transferring from the dopant when T1 of a second light-emitting auxiliary layer is high, which can affect efficiency and lifespan. In particular, it can be seen that compounds with a high T1 of 2.7 or more show high efficiency and long lifespan since the T1 of the green dopant is formed to be high.

In conclusion, it appears that a first light-emitting auxiliary layer performs the role of hole transport, and a second light-emitting auxiliary layer performs the role of injecting holes into the dopant or host and blocking electrons from the host. It can be seen that when a plurality of light-emitting auxiliary layers are formed as in the present invention, appropriate interactions can occur in each layer and maximizing the synergy effect between compounds, as a result, the characteristics of the element are greatly improved compared to when a single light-emitting auxiliary layer is formed.

Although the exemplary embodiments of the present invention have been described for illustrative purposes, those skilled in the art to which the present invention pertains will be capable of various modifications without departing from the essential characteristics of the present invention. Accordingly, the embodiments disclosed in this specification are for illustrative purposes rather than limiting the present invention, and the scope of the present invention is not limited by these embodiments. The scope of the present invention shall be construed on the basis of the accompanying claims, and it shall be construed that all of the technical arts included within the scope equivalent to the claims belong to the present invention.

1: An organic electric element comprising:
a first electrode;
a second electrode; and
an organic material layer between the first electrode and the second electrode,
wherein the organic material layer comprises a light-emitting layer, a hole transport layer between the first electrode and the light-emitting layer, and a plurality of light-emitting auxiliary layers between the hole transport layer and the light-emitting layer,
the plurality of light-emitting auxiliary layers comprise a first light-emitting auxiliary layer adjacent to the hole transport layer and a second light-emitting auxiliary layer adjacent to the light-emitting layer, and
the first light-emitting auxiliary layer comprises a compound represented by the following Formula 1 and the second light-emitting auxiliary layer comprises a compound represented by the following Formula 2: 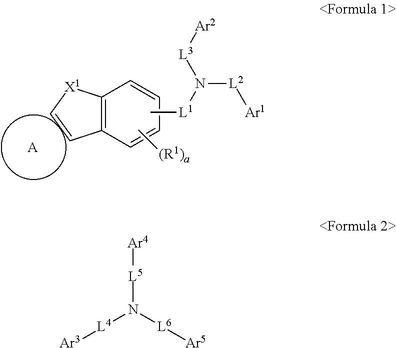
wherein:
A ring is a C₆-C₆₀ aromatic hydrocarbon ring group, and may be substituted with the same or different R,
X¹ is O, S or C(R′)(R″),
Ar¹ to Ar⁵ are each independently selected from the group consisting of a C₆-C₆₀ aryl group, a fluorenyl group, a C₂-C₆₀ heterocyclic group containing at least one heteroatom of O, N, S, Si and P, and a C₃-C₆₀ aliphatic ring group,
L¹ to L⁶ are each independently selected from the group consisting of a single bond, a C₆-C₆₀ arylene group, a fluorenylene group, a C₂-C₆₀ heterocyclic group containing at least one heteroatom of O, N, S, Si and P, and a C₃-C₆₀ aliphatic ring group,
R¹, R, R′ and R″ are each independently selected from the group consisting of hydrogen, deuterium, halogen, a cyano group, a nitro group, a C₆-C₆₀ aryl group, a fluorenyl group, a C₂-C₆₀ heterocyclic group containing at least one heteroatom of O, N, S, Si and P, a C₃-C₆₀ aliphatic ring group, a C₁-C₂₀ alkyl group, a C₂-C₂₀ alkenyl group, a C₂-C₂₀ alkynyl group, a C₁-C₂₀ alkoxyl group, and a C₆-C₂₀ aryloxy group, and adjacent R¹s may be bonded to each other to form a ring, and R′ and R″ may be bonded to each other to form a ring,
a is an integer of 1 to 3, and when a is an integer of 2 or more, each of R¹s is the same as or different from each other,
with the proviso that when A ring is a C₆ aromatic hydrocarbon ring group, i) the A ring is substituted with R that is a substituent other than hydrogen, ii) R¹ is a substituent other than hydrogen, iii) adjacent R¹s form a ring, or iv) at least one of Ar¹ and Ar² is a C₃-C₆₀ aliphatic ring group when X¹ is C(R′)(R″),
the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, and the ring formed by adjacent groups may be each optionally substituted with one or more substituents selected from the group consisting of deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and -L′-N(Rₐ)(R_{b}),
L′ is selected from the group consisting of a single bond, a C₆-C₃₀ arylene group, a fluorenylene group, a C₂-C₃₀ heterocyclic group containing at least one heteroatom of O, N, S, Si and P, and a C₃-C₃₀ aliphatic ring group, and
Rₐ and R_{b} are each independently selected from the group consisting of a C₆-C₃₀ aryl group, a fluorenyl group, a C₂-C₃₀ heterocyclic group containing at least one heteroatom of O, N, S, Si and P, and a C₃-C₃₀ aliphatic ring group.

2: The organic electric element of claim 1, wherein A ring of Formula 1 is one of the following Formulas A-1 to A-3: 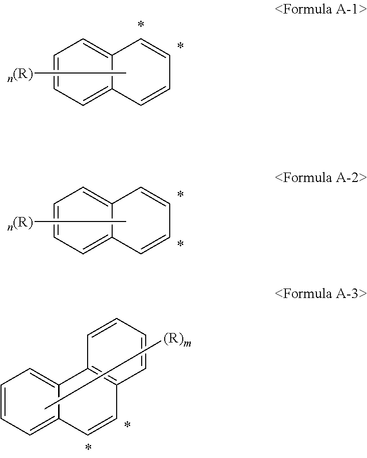
wherein, R is the same as defined in claim 1, n is an integer of 0 to 6, m is an integer of 0 to 8, and when each of these is an integer of 2 or more, each of R is the same as or different from each other, and adjacent R may be bonded to each other to form a ring.

3: The organic electric element of claim 1, wherein Formula 1 is represented by Formula 1-5 or Formula 1-6: 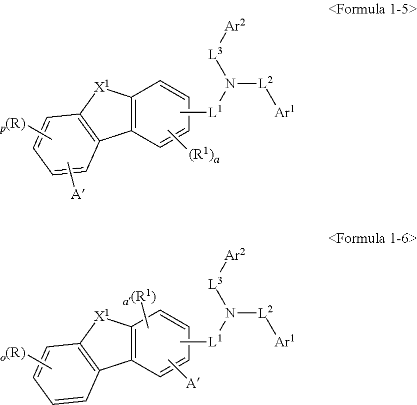
wherein X¹, R, R¹, L¹-L³, Ar¹, Ar², a are the same as defined in claim 1,
A′ is selected from the group consisting of a C₁-C₂₀ alkyl group, a C₂-C₂₀ alkenyl group, a C₆-C₆₀ aryl group, a fluorenyl group, a C₂-C₆₀ heterocyclic group comprising at least one heteroatom selected from the group consisting of O, N, S, Si and P, and a C₃-C₆₀ aliphatic ring group, and
p is an integer of 0 to 3, a′ is an integer of 0 to 2, o is an integer of 0 to 4, and when each of these is an integer of 2 or more, each of R, each of R¹ are the same as or different from each other, and adjacent groups may be bonded to each other to form a ring.

4: The organic electric element of claim 1, wherein Formula 1 is represented by Formula 1-14: 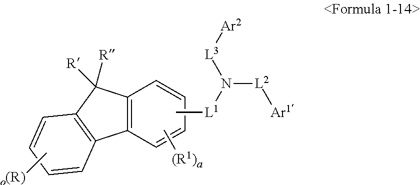
wherein R, R¹, R′, R″, L¹-L³, Ar², a are the same as defined in claim 1, o is an integer of 0 to 4, and when o is an integer of 2 or more, adjacent groups may be bonded to each other to form a ring, and Ar^{1′} is a C₃-C₆₀ aliphatic ring group.

5: The organic electric element of claim 1, wherein Formula 1 is represented by one of Formula 1-15 to Formula 1-17: 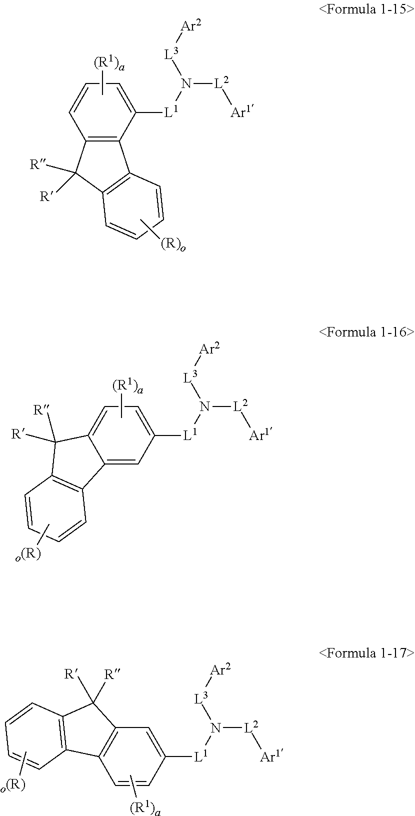
wherein R, R¹, R′, R″, L¹-L³, Ar², a are the same as defined in claim 1, o is an integer of 0 to 4, and when o is an integer of 2 or more, adjacent groups may be bonded to each other to form a ring, and Ar^{1′} is C₃-C₆₀ is a C₃-C₆₀ aliphatic ring group.

6: The organic electric element of claim 1, wherein Ar¹ in Formula 1 is the following Formula a: 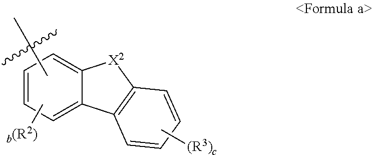
Wherein:
X² is O, S or C(R_{c})(R_{d}),
R², R³, R_{c} and R_{d} are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, and a C₃-C₃₀ aliphatic ring group, and adjacent groups may be bonded to each other to form a ring, and R_{c} and R_{d} may be bonded to each other to form a ring, and
b is an integer of 0 to 3, c is an integer of 0 to 4, and when each of these is an integer of 2 or more, each of R², each of R³ are the same as or different from each other.

7: The organic electric element of claim 1, wherein Ar³ in Formula 2 is represented by one of the following Formulas b to d: 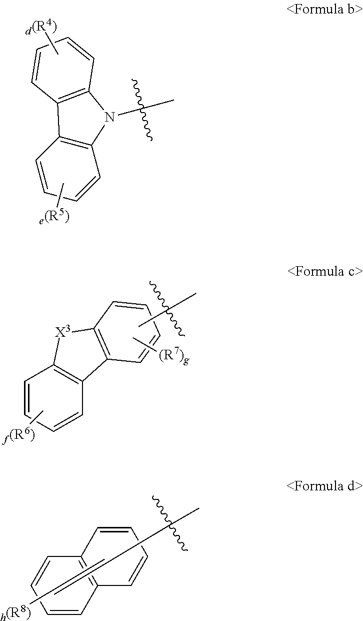
wherein:
X³ is O or S,
R⁴ to R⁸ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and -L′-N(Rₐ)(R_{b}), and adjacent groups may be bonded to each other to form a ring,
d, e and f are each an integer of 0 to 4, g is an integer of 0 to 3, h is an integer of 0 to 7, and when each of these is an integer of 2 or more, each of R⁴, each of R⁵, each of R⁶, each of R⁷, each of R⁸ are the same as or different from each other, and
L′, Rₐ and R_{b} are the same as defined in claim 1.

8: The organic electric element of claim 1, wherein the above Formula 2 is represented by the following Formula 2-1: 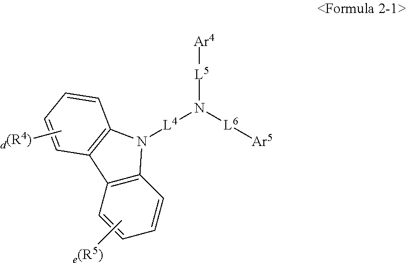
wherein L⁴ to L⁶, Ar⁴ and Ar⁵ are the same as defined in claim 1,
R⁴ and R⁵ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and -L′-N(Rₐ)(R_{b}), and adjacent groups may be bonded to each other to form a ring,
d and e are each an integer of 0 to 4, and when each of these is an integer of 2 or more, each of R⁴, each of R⁵ are the same as or different from each other, and
L′, Rₐ and R_{b} are the same as defined in claim 1.

9: The organic electric element of claim 1, wherein at least one of the L¹ to L⁶ is one of the following Formula L-1 to Formula L-12: 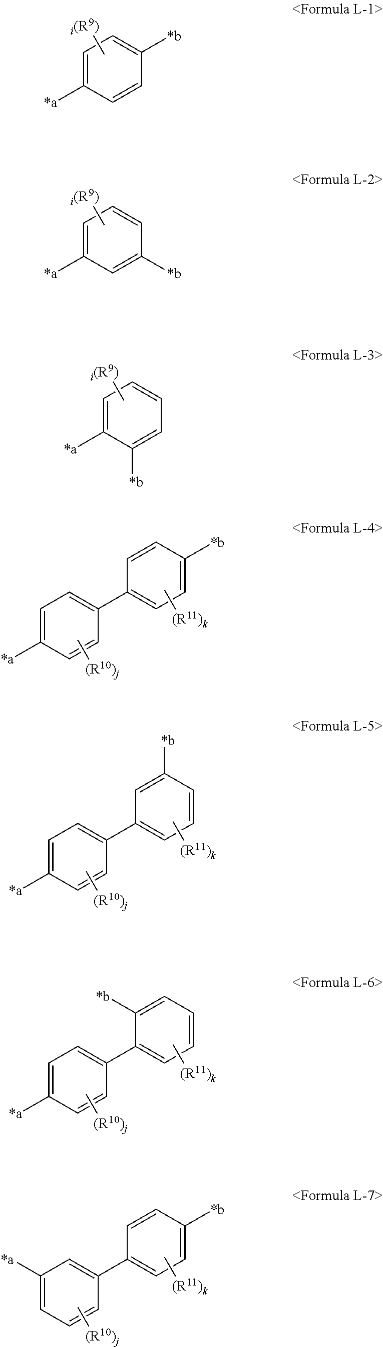 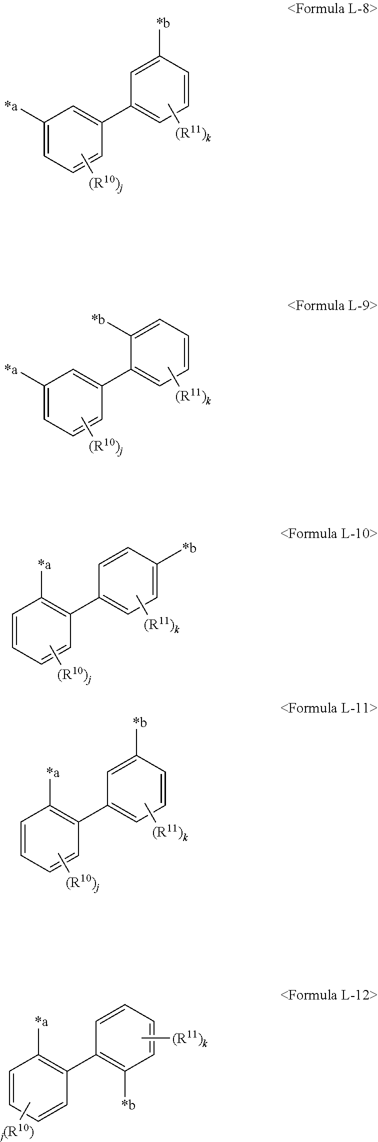
wherein:
R⁹ to R¹¹ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and -L′-N(Rₐ)(R_{b}), and adjacent groups may be bonded to each other to form a ring,
i, j and k are each an integer of 0 to 4, and when each of these is an integer of 2 or more, each of R⁹, each of R¹⁰, each of R¹¹ are the same as or different from each other, and
when L¹ is one of Formula L-1 to Formula L-12, *a represents the position bonded to the nitrogen of the amine group, *b represents the position bonded to the benzene ring to which R¹ is bonded, and when at least one of L² to L⁶ is one of Formula L-1 to Formula L-12, *a represents the position bonded to the nitrogen of the amine group, *b represents the position bonded to Ar¹ to Ar⁵, and
L′, Rₐ and R_{b} are the same as defined in claim 1.

10: The organic electric element of claim 1, wherein compound represented by Formula 1 is one of the following compounds:

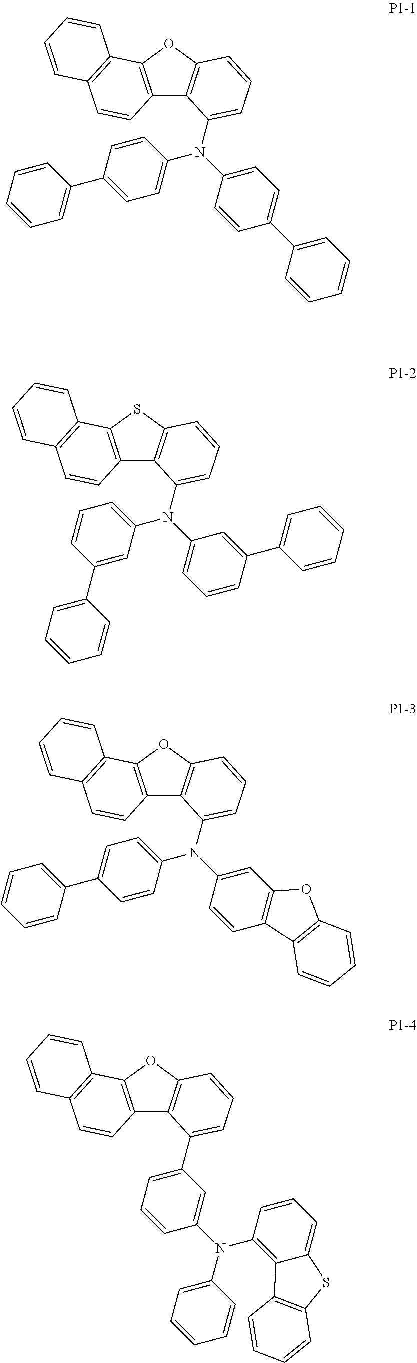 [SMILES: c1ccc(-c2ccc(N(c3ccc(-c4ccccc4)cc3)c3cccc4oc5c6ccccc6ccc5c34)cc2)cc1 ; c1ccc(-c2cccc(N(c3cccc(-c4ccccc4)c3)c3cccc4sc5c6ccccc6ccc5c34)c2)cc1 ; c1ccc(-c2ccc(N(c3ccc4c(c3)oc3ccccc34)c3cccc4oc5c6ccccc6ccc5c34)cc2)cc1 ; c1ccc(N(c2cccc(-c3cccc4oc5c6ccccc6ccc5c34)c2)c2cccc3sc4ccccc4c23)cc1]

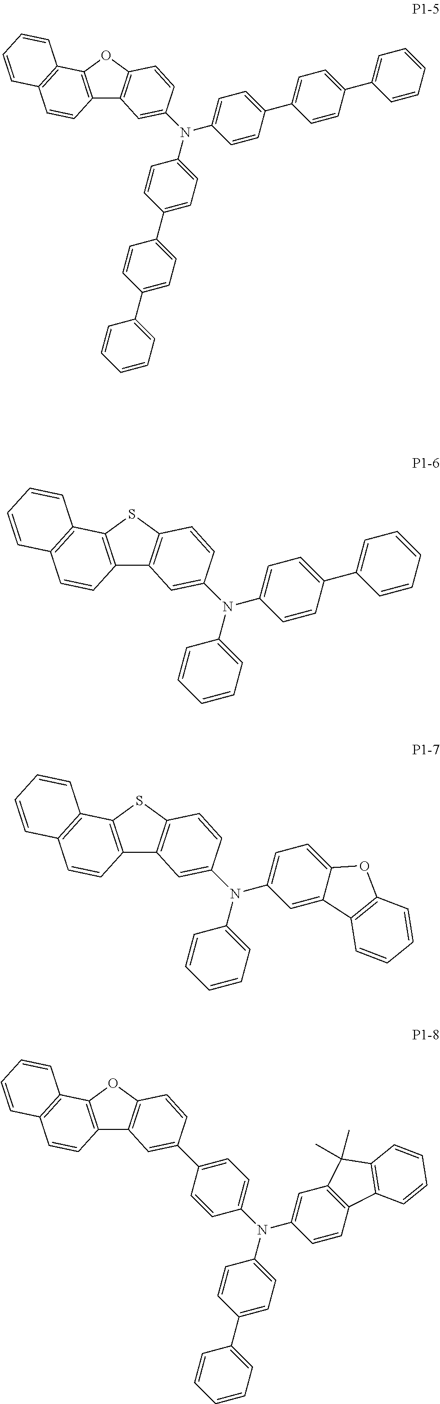 [SMILES: c1ccc(-c2ccc(-c3ccc(N(c4ccc(-c5ccc(-c6ccccc6)cc5)cc4)c4ccc5oc6c7ccccc7ccc6c5c4)cc3)cc2)cc1 ; c1ccc(-c2ccc(N(c3ccccc3)c3ccc4sc5c6ccccc6ccc5c4c3)cc2)cc1 ; c1ccc(N(c2ccc3oc4ccccc4c3c2)c2ccc3sc4c5ccccc5ccc4c3c2)cc1 ; CC1(C)c2ccccc2-c2ccc(N(c3ccc(-c4ccccc4)cc3)c3ccc(-c4ccc5oc6c7ccccc7ccc6c5c4)cc3)cc21]

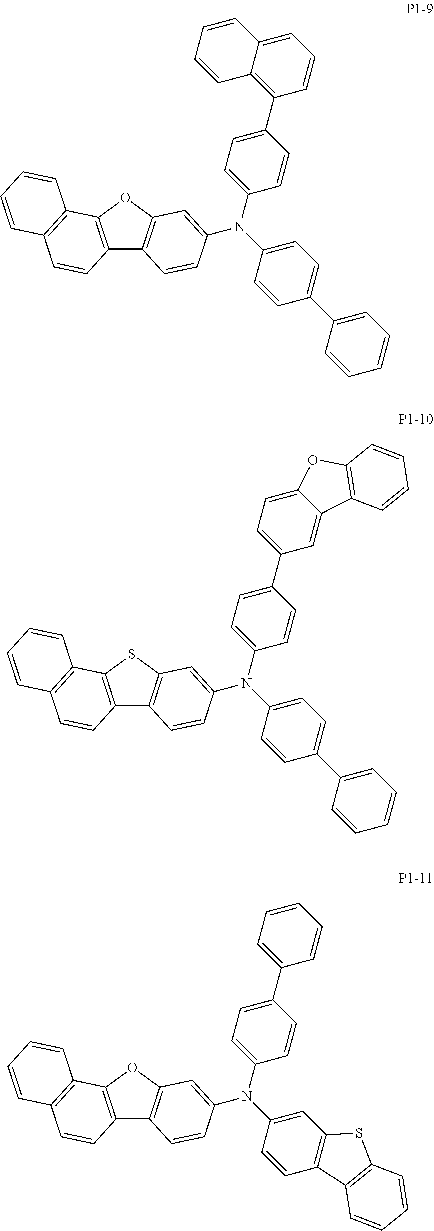 [SMILES: c1ccc(-c2ccc(N(c3ccc(-c4cccc5ccccc45)cc3)c3ccc4c(c3)oc3c5ccccc5ccc43)cc2)cc1 ; c1ccc(-c2ccc(N(c3ccc(-c4ccc5oc6ccccc6c5c4)cc3)c3ccc4c(c3)sc3c5ccccc5ccc43)cc2)cc1 ; c1ccc(-c2ccc(N(c3ccc4c(c3)oc3c5ccccc5ccc43)c3ccc4c(c3)sc3ccccc34)cc2)cc1]

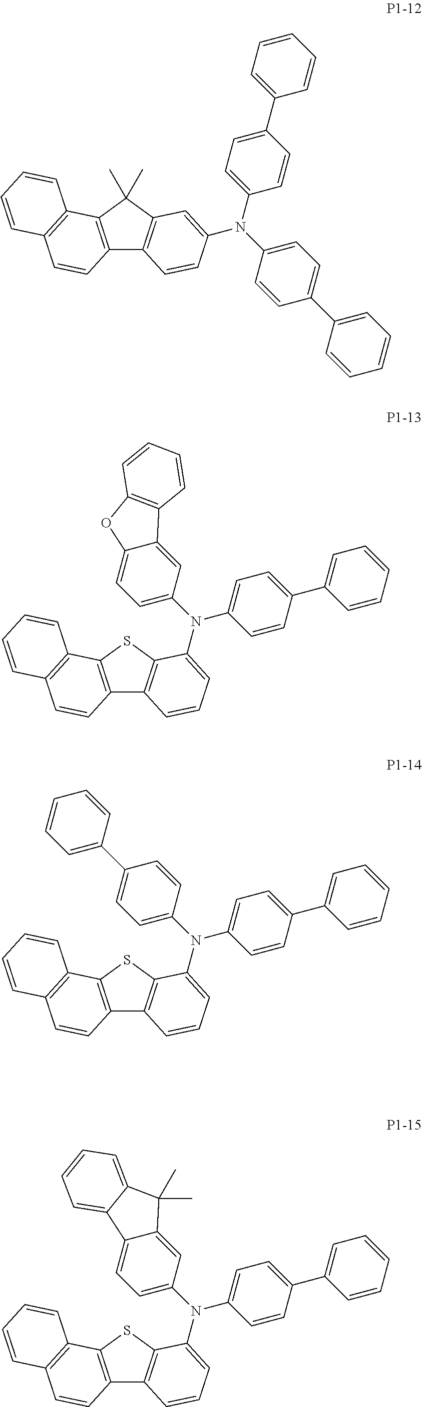 [SMILES: CC1(C)c2cc(N(c3ccc(-c4ccccc4)cc3)c3ccc(-c4ccccc4)cc3)ccc2-c2ccc3ccccc3c21 ; c1ccc(-c2ccc(N(c3ccc4oc5ccccc5c4c3)c3cccc4c3sc3c5ccccc5ccc43)cc2)cc1 ; c1ccc(-c2ccc(N(c3ccc(-c4ccccc4)cc3)c3cccc4c3sc3c5ccccc5ccc43)cc2)cc1 ; CC1(C)c2ccccc2-c2ccc(N(c3ccc(-c4ccccc4)cc3)c3cccc4c3sc3c5ccccc5ccc43)cc21]

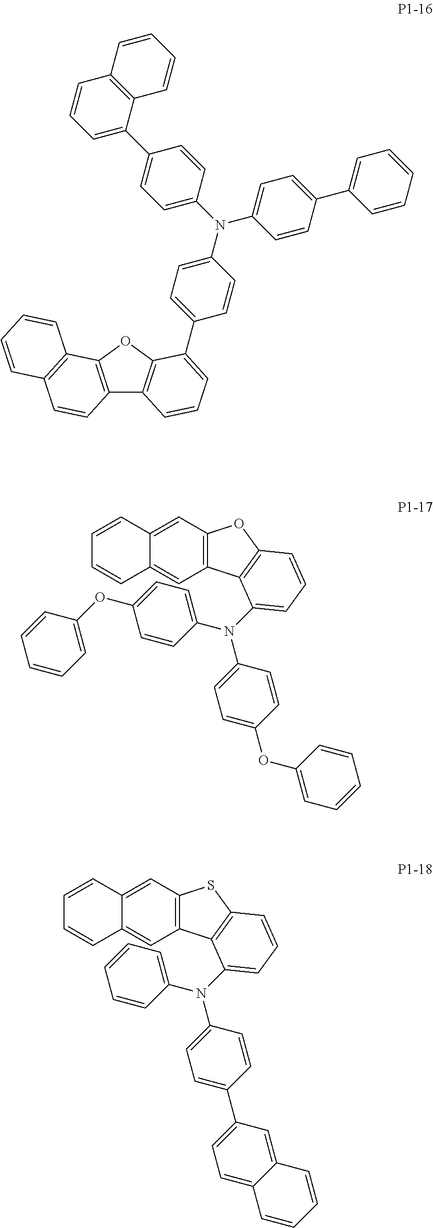 [SMILES: c1ccc(-c2ccc(N(c3ccc(-c4cccc5ccccc45)cc3)c3ccc(-c4cccc5c4oc4c6ccccc6ccc54)cc3)cc2)cc1 ; c1ccc(Oc2ccc(N(c3ccc(Oc4ccccc4)cc3)c3cccc4oc5cc6ccccc6cc5c34)cc2)cc1 ; c1ccc(N(c2ccc(-c3ccc4ccccc4c3)cc2)c2cccc3sc4cc5ccccc5cc4c23)cc1]

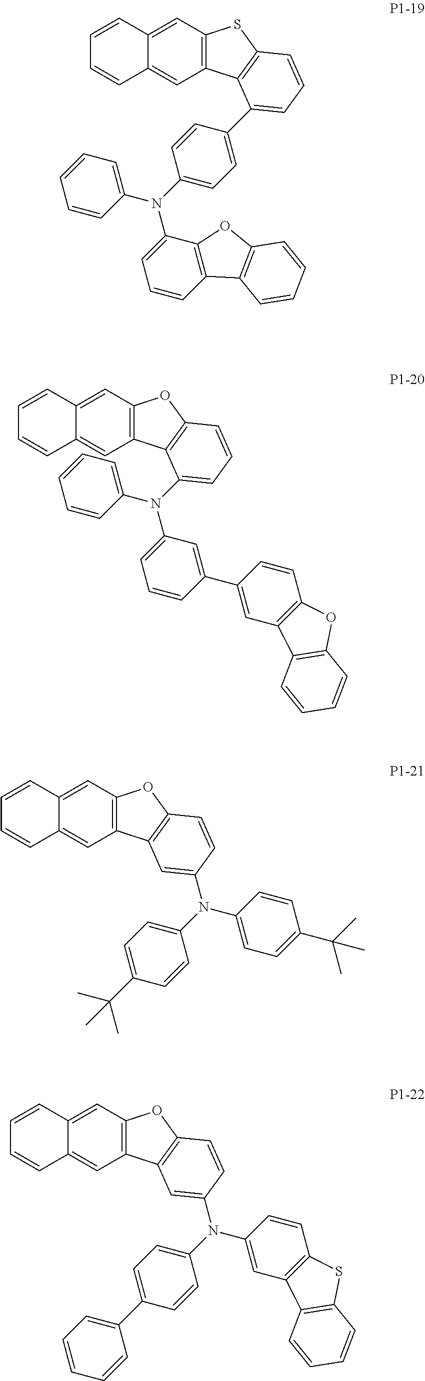 [SMILES: c1ccc(N(c2ccc(-c3cccc4sc5cc6ccccc6cc5c34)cc2)c2cccc3c2oc2ccccc23)cc1 ; c1ccc(N(c2cccc(-c3ccc4oc5ccccc5c4c3)c2)c2cccc3oc4cc5ccccc5cc4c23)cc1 ; CC(C)(C)c1ccc(N(c2ccc(C(C)(C)C)cc2)c2ccc3oc4cc5ccccc5cc4c3c2)cc1 ; c1ccc(-c2ccc(N(c3ccc4oc5cc6ccccc6cc5c4c3)c3ccc4sc5ccccc5c4c3)cc2)cc1]

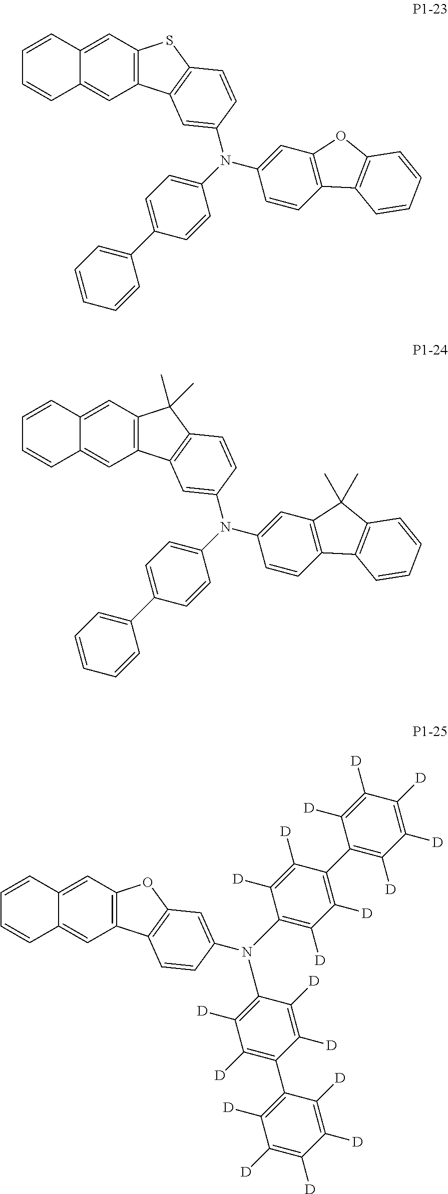 [SMILES: c1ccc(-c2ccc(N(c3ccc4c(c3)oc3ccccc34)c3ccc4sc5cc6ccccc6cc5c4c3)cc2)cc1 ; CC1(C)c2ccccc2-c2ccc(N(c3ccc(-c4ccccc4)cc3)c3ccc4c(c3)-c3cc5ccccc5cc3C4(C)C)cc21 ; [2H]c1c([2H])c([2H])c(-c2c([2H])c([2H])c(N(c3ccc4c(c3)oc3cc5ccccc5cc34)c3c([2H])c([2H])c(-c4c([2H])c([2H])c([2H])c([2H])c4[2H])c([2H])c3[2H])c([2H])c2[2H])c([2H])c1[2H]]

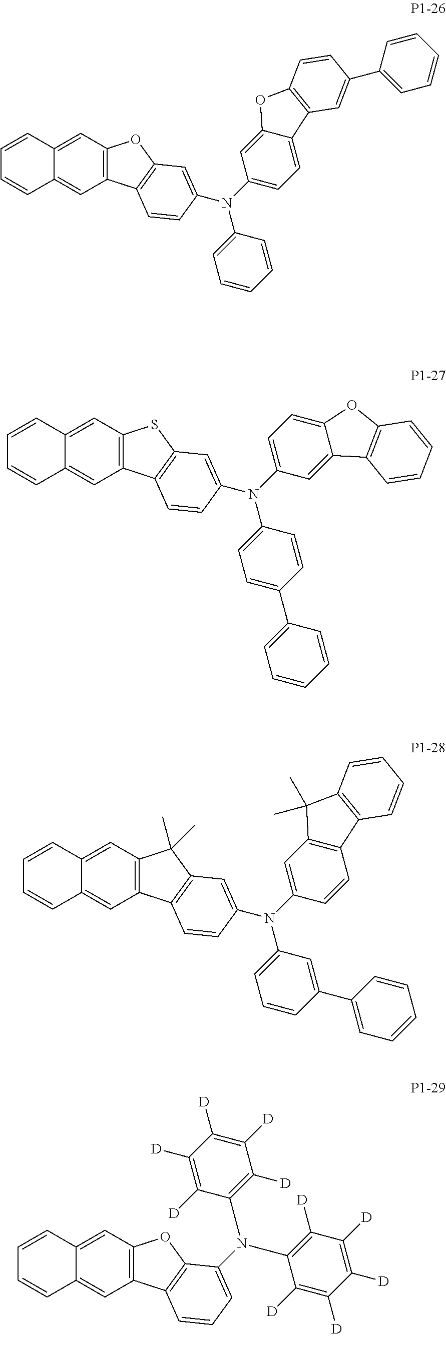

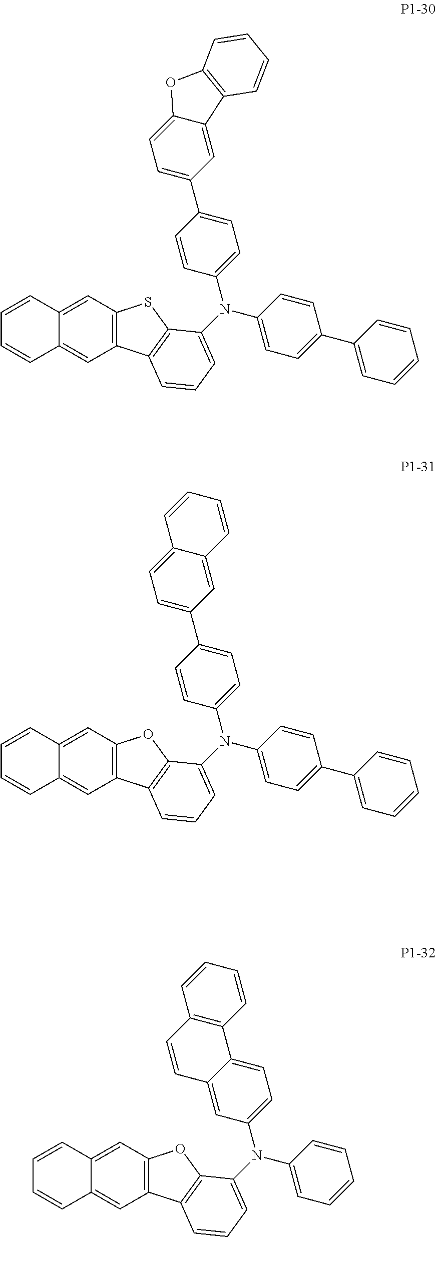

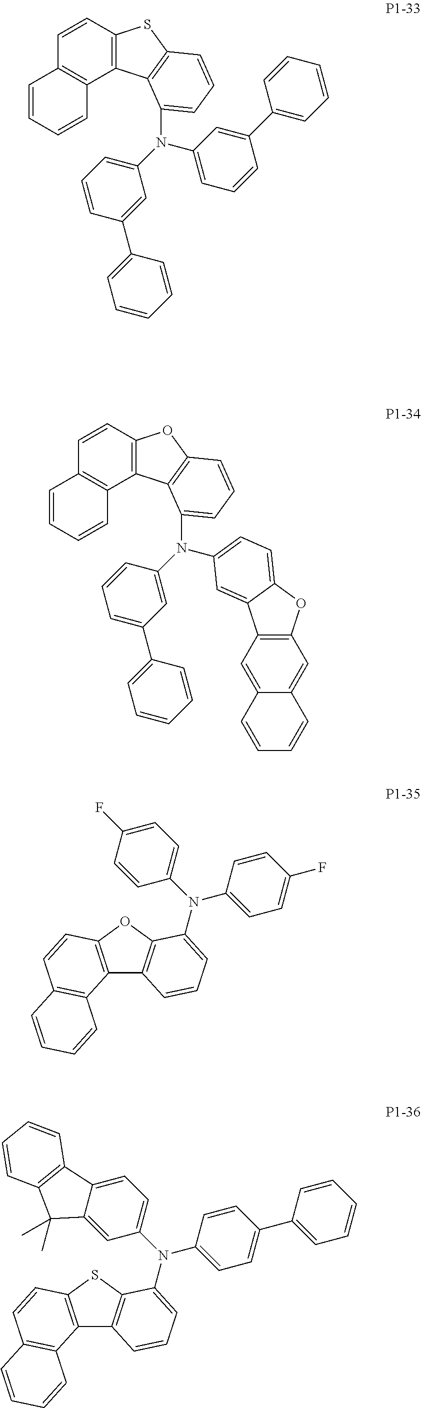

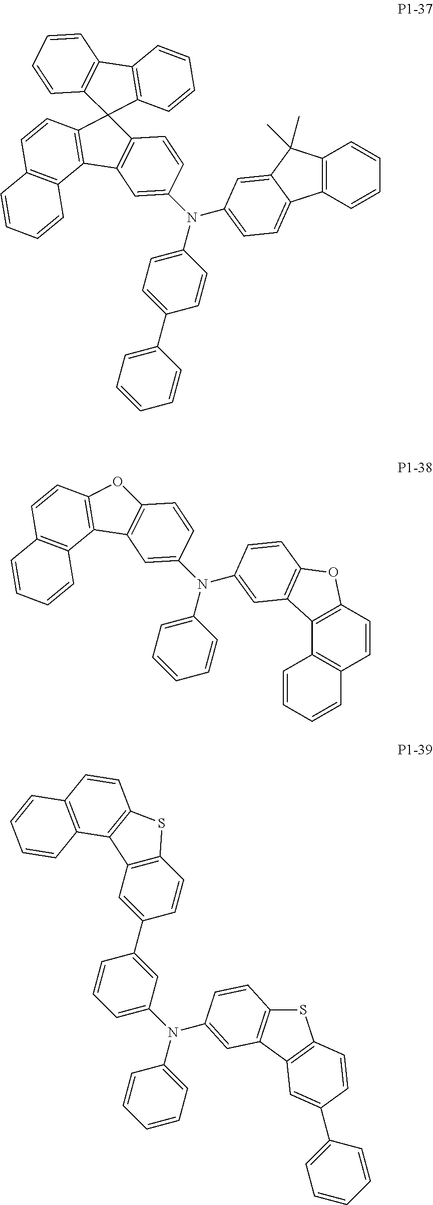 [SMILES: CC1(C)c2ccccc2-c2ccc(N(c3ccc(-c4ccccc4)cc3)c3ccc4c(c3)-c3c(ccc5ccccc35)C43c4ccccc4-c4ccccc43)cc21 ; c1ccc(N(c2ccc3oc4ccc5ccccc5c4c3c2)c2ccc3oc4ccc5ccccc5c4c3c2)cc1 ; c1ccc(-c2ccc3sc4ccc(N(c5ccccc5)c5cccc(-c6ccc7sc8ccc9ccccc9c8c7c6)c5)cc4c3c2)cc1]

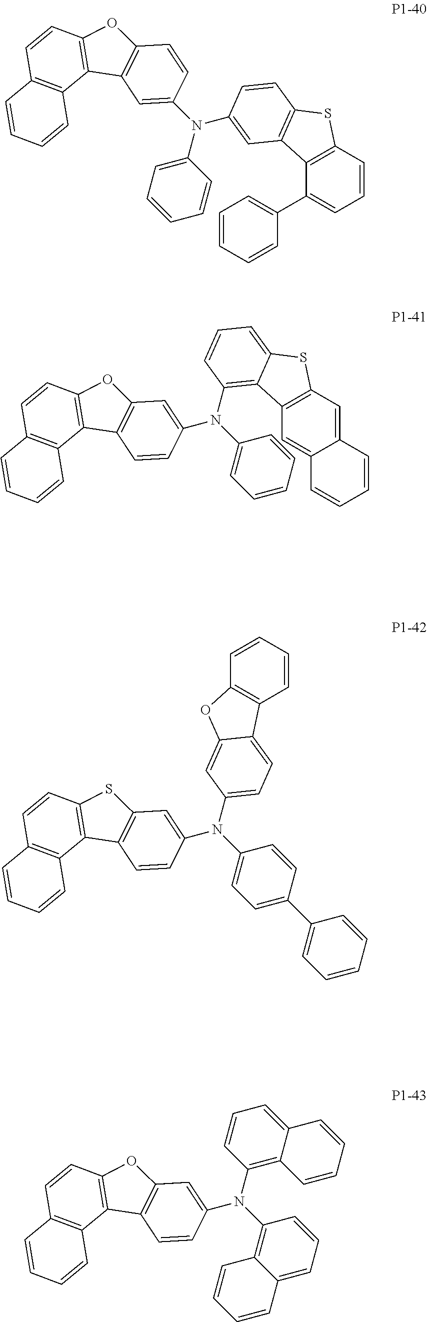 [SMILES: c1ccc(-c2cccc3sc4ccc(N(c5ccccc5)c5ccc6oc7ccc8ccccc8c7c6c5)cc4c23)cc1 ; c1ccc(N(c2ccc3c(c2)oc2ccc4ccccc4c23)c2cccc3sc4cc5ccccc5cc4c23)cc1 ; c1ccc(-c2ccc(N(c3ccc4c(c3)oc3ccccc34)c3ccc4c(c3)sc3ccc5ccccc5c34)cc2)cc1 ; c1ccc2c(N(c3ccc4c(c3)oc3ccc5ccccc5c34)c3cccc4ccccc34)cccc2c1]

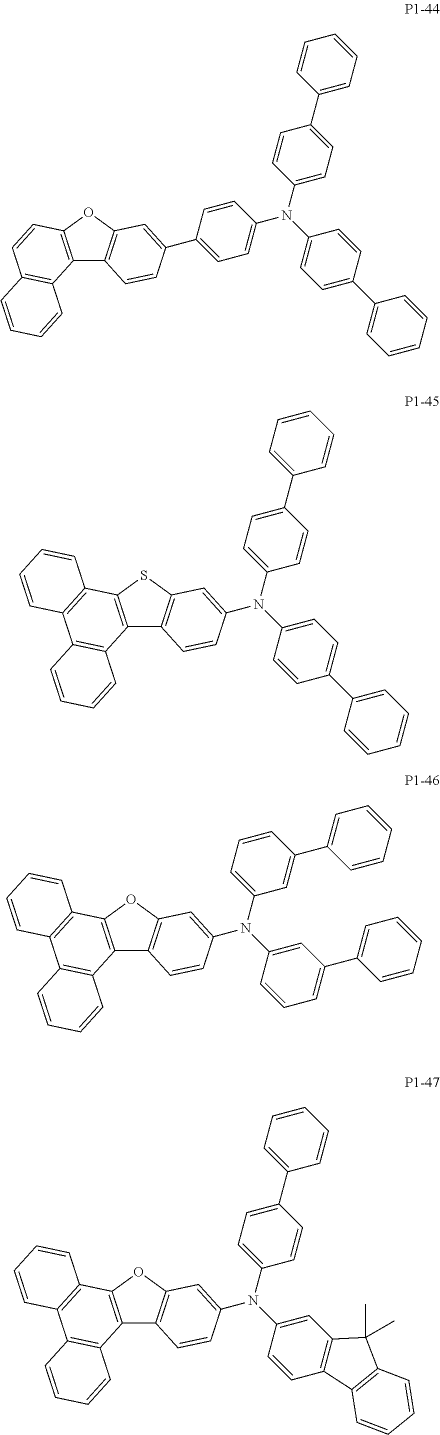 [SMILES: c1ccc(-c2ccc(N(c3ccc(-c4ccccc4)cc3)c3ccc(-c4ccc5c(c4)oc4ccc6ccccc6c45)cc3)cc2)cc1 ; c1ccc(-c2ccc(N(c3ccc(-c4ccccc4)cc3)c3ccc4c(c3)sc3c5ccccc5c5ccccc5c43)cc2)cc1 ; c1ccc(-c2cccc(N(c3cccc(-c4ccccc4)c3)c3ccc4c(c3)oc3c5ccccc5c5ccccc5c43)c2)cc1 ; CC1(C)c2ccccc2-c2ccc(N(c3ccc(-c4ccccc4)cc3)c3ccc4c(c3)oc3c5ccccc5c5ccccc5c43)cc21]

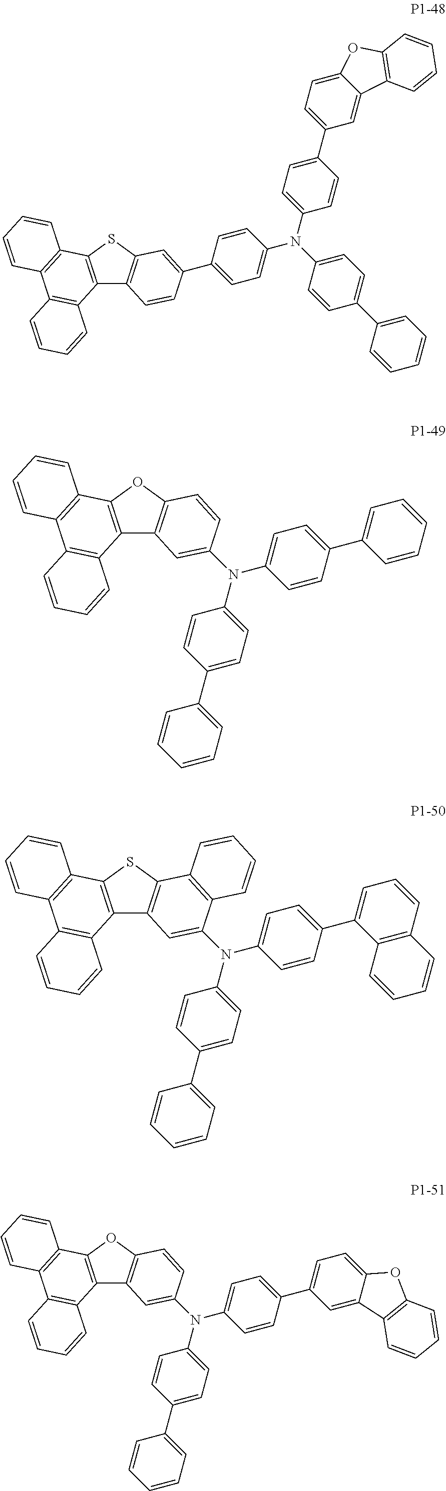 [SMILES: c1ccc(-c2ccc(N(c3ccc(-c4ccc5c(c4)sc4c6ccccc6c6ccccc6c54)cc3)c3ccc(-c4ccc5oc6ccccc6c5c4)cc3)cc2)cc1 ; c1ccc(-c2ccc(N(c3ccc(-c4ccccc4)cc3)c3ccc4oc5c6ccccc6c6ccccc6c5c4c3)cc2)cc1 ; c1ccc(-c2ccc(N(c3ccc(-c4cccc5ccccc45)cc3)c3cc4c(sc5c6ccccc6c6ccccc6c45)c4ccccc34)cc2)cc1 ; c1ccc(-c2ccc(N(c3ccc(-c4ccc5oc6ccccc6c5c4)cc3)c3ccc4oc5c6ccccc6c6ccccc6c5c4c3)cc2)cc1]

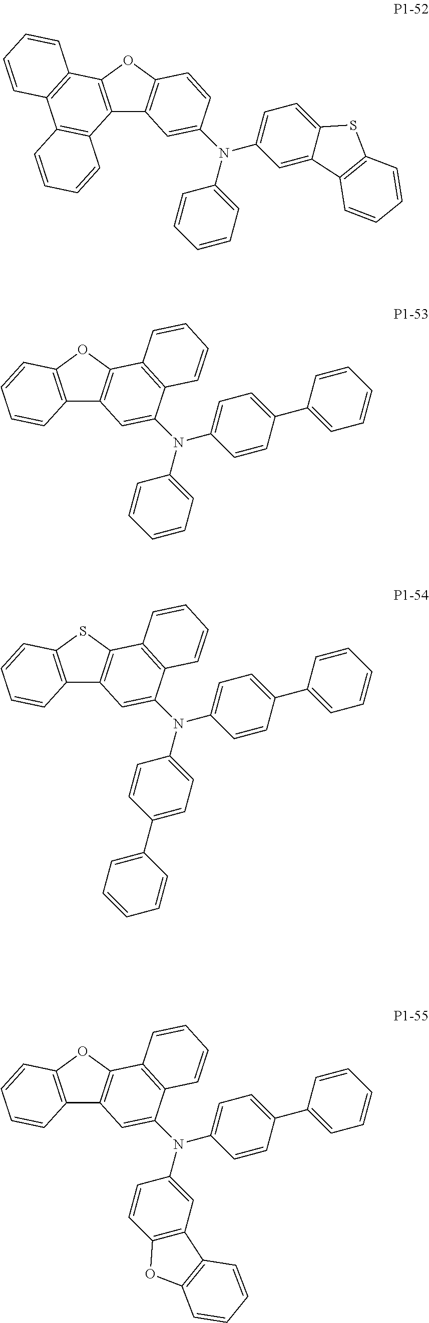 [SMILES: c1ccc(N(c2ccc3sc4ccccc4c3c2)c2ccc3oc4c5ccccc5c5ccccc5c4c3c2)cc1 ; c1ccc(-c2ccc(N(c3ccccc3)c3cc4c5ccccc5oc4c4ccccc34)cc2)cc1 ; c1ccc(-c2ccc(N(c3ccc(-c4ccccc4)cc3)c3cc4c5ccccc5sc4c4ccccc34)cc2)cc1 ; c1ccc(-c2ccc(N(c3ccc4oc5ccccc5c4c3)c3cc4c5ccccc5oc4c4ccccc34)cc2)cc1]

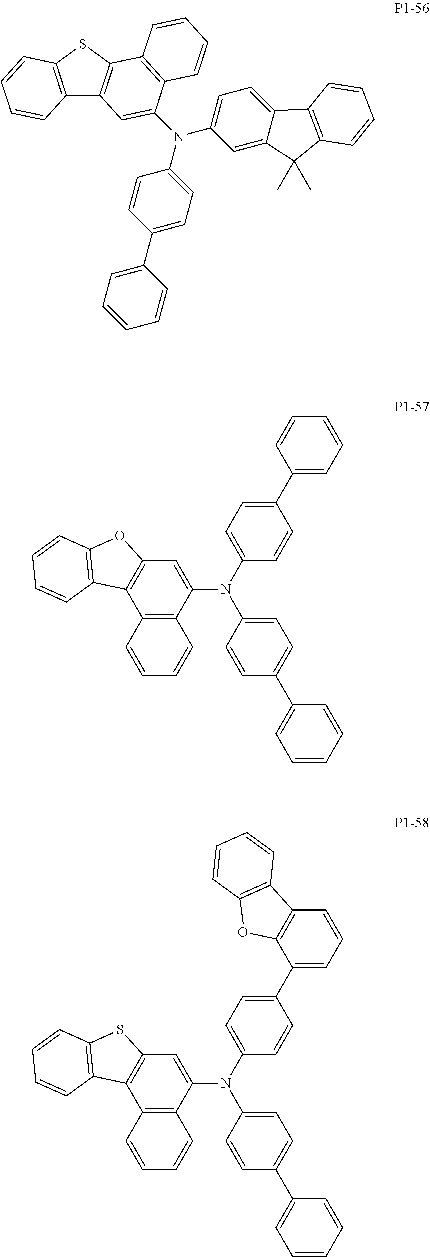 [SMILES: CC1(C)c2ccccc2-c2ccc(N(c3ccc(-c4ccccc4)cc3)c3cc4c5ccccc5sc4c4ccccc34)cc21 ; c1ccc(-c2ccc(N(c3ccc(-c4ccccc4)cc3)c3cc4oc5ccccc5c4c4ccccc34)cc2)cc1 ; c1ccc(-c2ccc(N(c3ccc(-c4cccc5c4oc4ccccc45)cc3)c3cc4sc5ccccc5c4c4ccccc34)cc2)cc1]

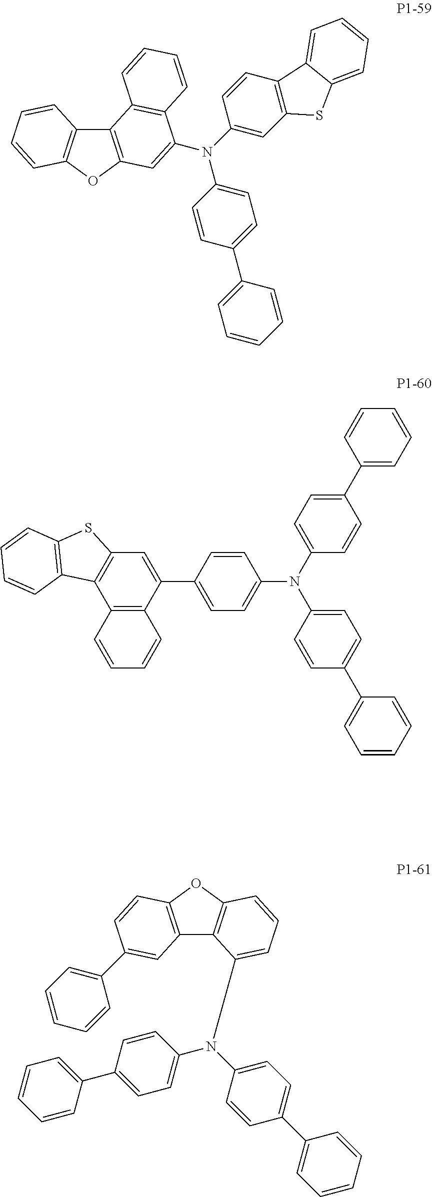 [SMILES: c1ccc(-c2ccc(N(c3ccc4c(c3)sc3ccccc34)c3cc4oc5ccccc5c4c4ccccc34)cc2)cc1 ; c1ccc(-c2ccc(N(c3ccc(-c4ccccc4)cc3)c3ccc(-c4cc5sc6ccccc6c5c5ccccc45)cc3)cc2)cc1 ; c1ccc(-c2ccc(N(c3ccc(-c4ccccc4)cc3)c3cccc4oc5ccc(-c6ccccc6)cc5c34)cc2)cc1]

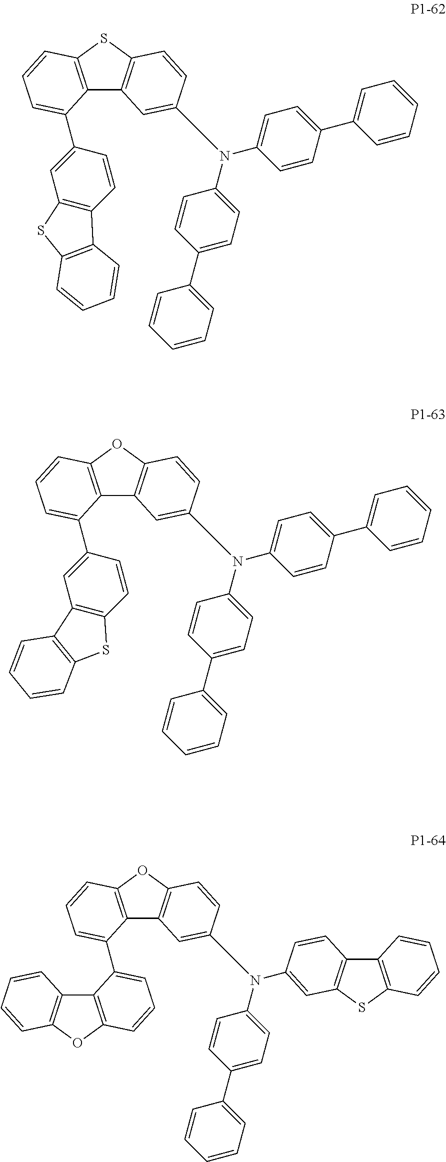 [SMILES: c1ccc(-c2ccc(N(c3ccc(-c4ccccc4)cc3)c3ccc4sc5cccc(-c6ccc7c(c6)sc6ccccc67)c5c4c3)cc2)cc1 ; c1ccc(-c2ccc(N(c3ccc(-c4ccccc4)cc3)c3ccc4oc5cccc(-c6ccc7sc8ccccc8c7c6)c5c4c3)cc2)cc1 ; c1ccc(-c2ccc(N(c3ccc4c(c3)sc3ccccc34)c3ccc4oc5cccc(-c6cccc7oc8ccccc8c67)c5c4c3)cc2)cc1]

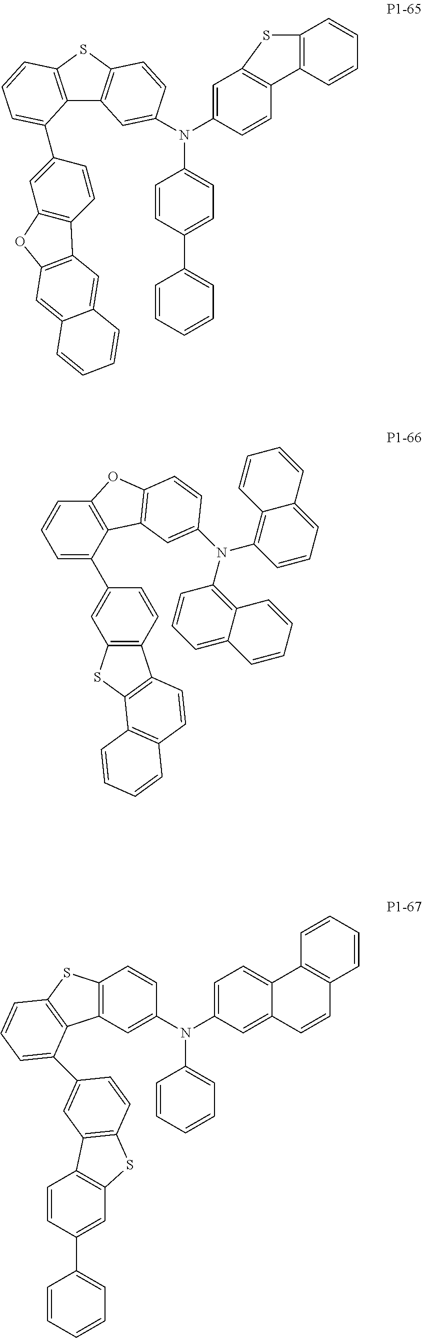 [SMILES: c1ccc(-c2ccc(N(c3ccc4c(c3)sc3ccccc34)c3ccc4sc5cccc(-c6ccc7c(c6)oc6cc8ccccc8cc67)c5c4c3)cc2)cc1 ; c1ccc2c(N(c3ccc4oc5cccc(-c6ccc7c(c6)sc6c8ccccc8ccc76)c5c4c3)c3cccc4ccccc34)cccc2c1 ; c1ccc(-c2ccc3c(c2)sc2ccc(-c4cccc5sc6ccc(N(c7ccccc7)c7ccc8c(ccc9ccccc98)c7)cc6c45)cc23)cc1]

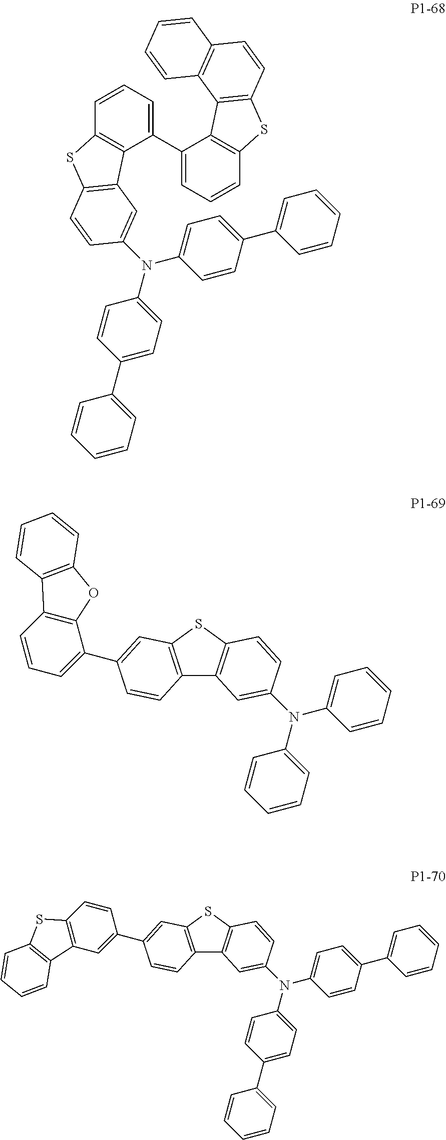 [SMILES: c1ccc(-c2ccc(N(c3ccc(-c4ccccc4)cc3)c3ccc4sc5cccc(-c6cccc7sc8ccc9ccccc9c8c67)c5c4c3)cc2)cc1 ; c1ccc(N(c2ccccc2)c2ccc3sc4cc(-c5cccc6c5oc5ccccc56)ccc4c3c2)cc1 ; c1ccc(-c2ccc(N(c3ccc(-c4ccccc4)cc3)c3ccc4sc5cc(-c6ccc7sc8ccccc8c7c6)ccc5c4c3)cc2)cc1]

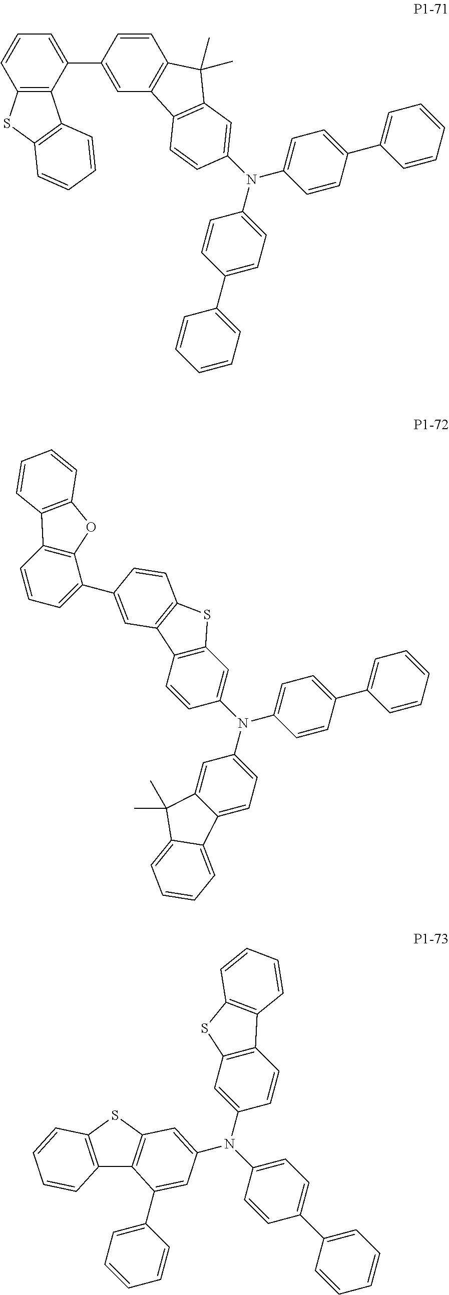 [SMILES: CC1(C)c2ccc(-c3cccc4sc5ccccc5c34)cc2-c2ccc(N(c3ccc(-c4ccccc4)cc3)c3ccc(-c4ccccc4)cc3)cc21 ; CC1(C)c2ccccc2-c2ccc(N(c3ccc(-c4ccccc4)cc3)c3ccc4c(c3)sc3ccc(-c5cccc6c5oc5ccccc56)cc34)cc21 ; c1ccc(-c2ccc(N(c3ccc4c(c3)sc3ccccc34)c3cc(-c4ccccc4)c4c(c3)sc3ccccc34)cc2)cc1]

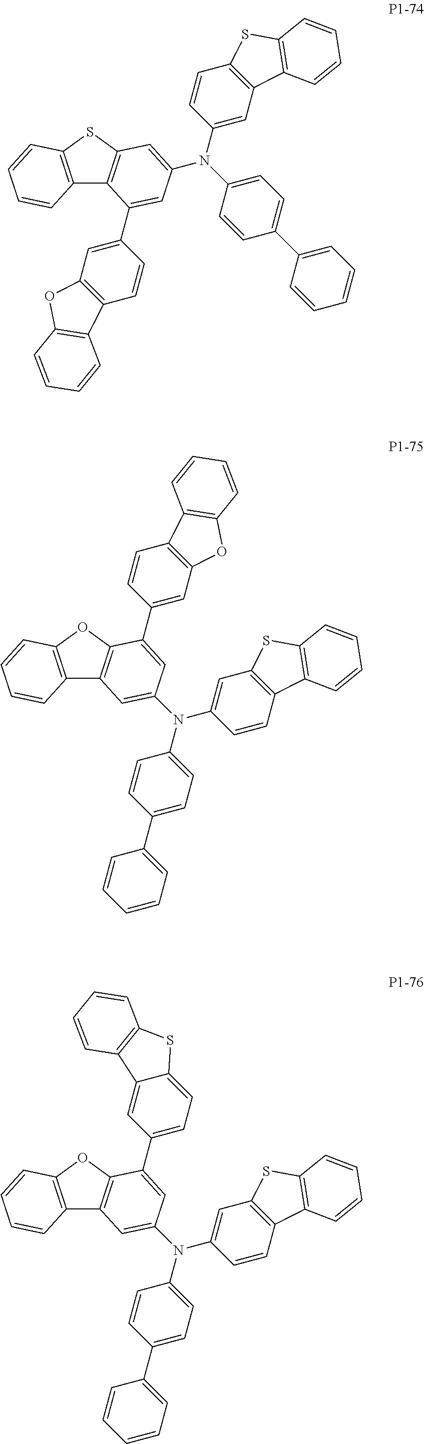 [SMILES: c1ccc(-c2ccc(N(c3cc(-c4ccc5c(c4)oc4ccccc45)c4c(c3)sc3ccccc34)c3ccc4sc5ccccc5c4c3)cc2)cc1 ; c1ccc(-c2ccc(N(c3ccc4c(c3)sc3ccccc34)c3cc(-c4ccc5c(c4)oc4ccccc45)c4oc5ccccc5c4c3)cc2)cc1 ; c1ccc(-c2ccc(N(c3ccc4c(c3)sc3ccccc34)c3cc(-c4ccc5sc6ccccc6c5c4)c4oc5ccccc5c4c3)cc2)cc1]

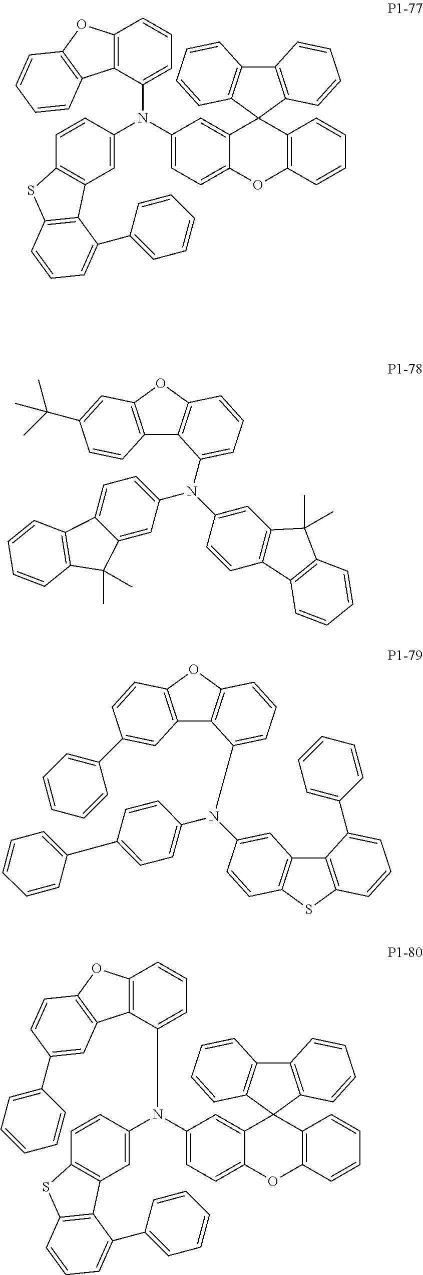 [SMILES: c1ccc(-c2cccc3sc4ccc(N(c5ccc6c(c5)C5(c7ccccc7O6)c6ccccc6-c6ccccc65)c5cccc6oc7ccccc7c56)cc4c23)cc1 ; CC(C)(C)c1ccc2c(c1)oc1cccc(N(c3ccc4c(c3)C(C)(C)c3ccccc3-4)c3ccc4c(c3)C(C)(C)c3ccccc3-4)c12 ; c1ccc(-c2ccc(N(c3ccc4sc5cccc(-c6ccccc6)c5c4c3)c3cccc4oc5ccc(-c6ccccc6)cc5c34)cc2)cc1 ; c1ccc(-c2ccc3oc4cccc(N(c5ccc6c(c5)C5(c7ccccc7O6)c6ccccc6-c6ccccc65)c5ccc6sc7cccc(-c8ccccc8)c7c6c5)c4c3c2)cc1]

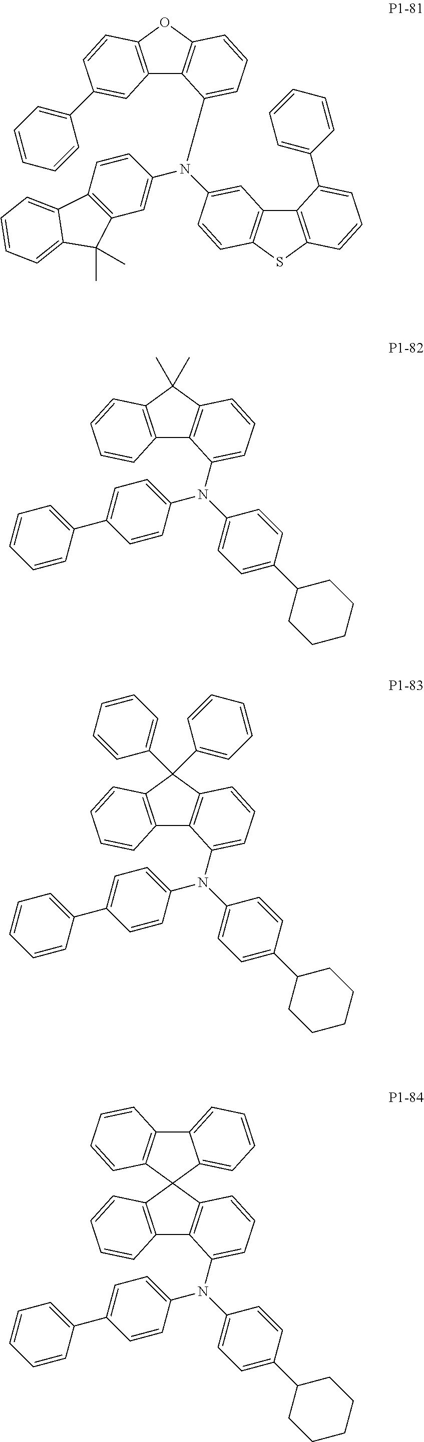 [SMILES: CC1(C)c2ccccc2-c2ccc(N(c3ccc4sc5cccc(-c6ccccc6)c5c4c3)c3cccc4oc5ccc(-c6ccccc6)cc5c34)cc21 ; CC1(C)c2ccccc2-c2c(N(c3ccc(-c4ccccc4)cc3)c3ccc(C4CCCCC4)cc3)cccc21 ; c1ccc(-c2ccc(N(c3ccc(C4CCCCC4)cc3)c3cccc4c3-c3ccccc3C4(c3ccccc3)c3ccccc3)cc2)cc1 ; c1ccc(-c2ccc(N(c3ccc(C4CCCCC4)cc3)c3cccc4c3-c3ccccc3C43c4ccccc4-c4ccccc43)cc2)cc1]

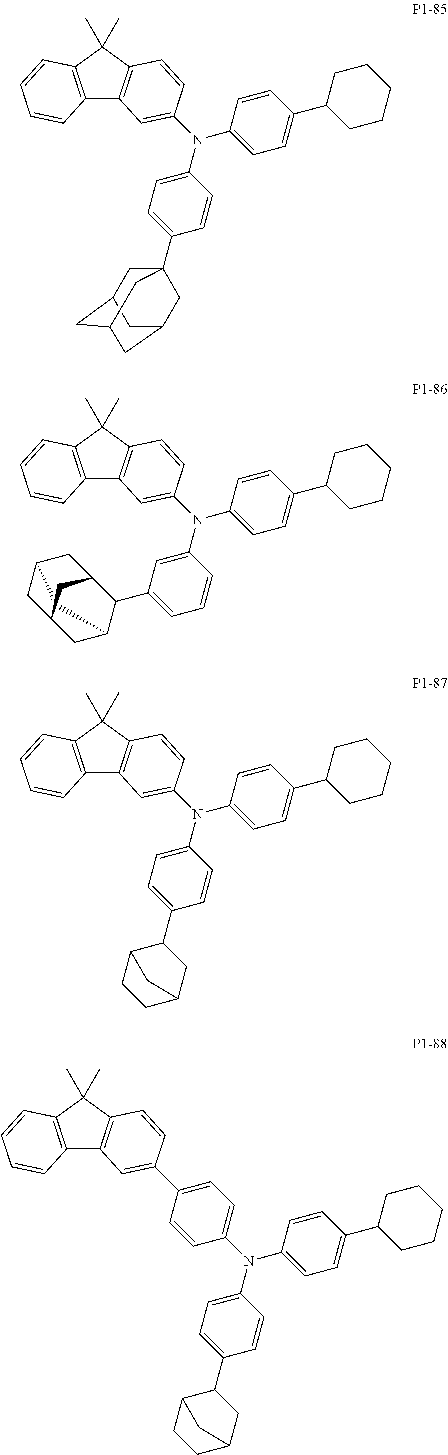

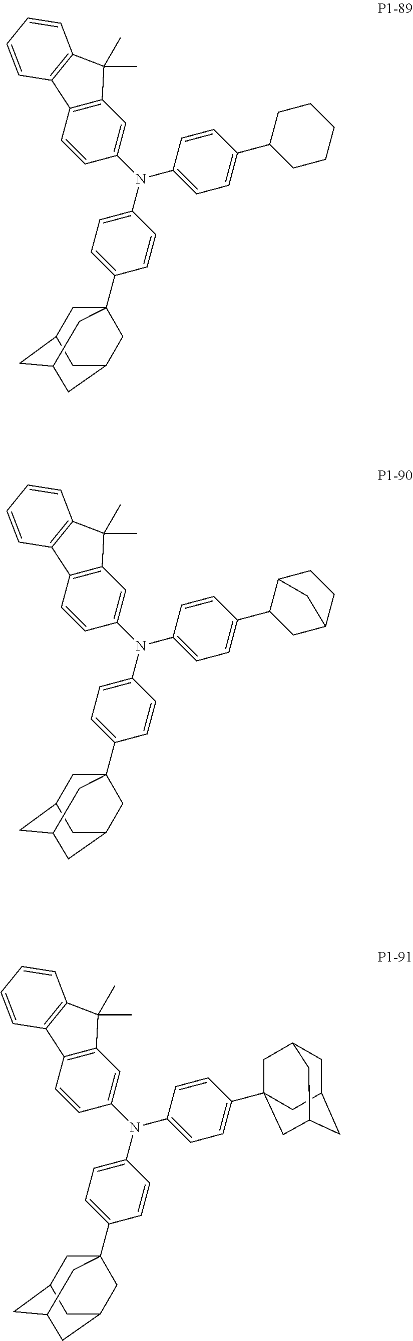 [SMILES: CC1(C)c2ccccc2-c2ccc(N(c3ccc(C4CCCCC4)cc3)c3ccc(C45CC6CC(CC(C6)C4)C5)cc3)cc21 ; CC1(C)c2ccccc2-c2ccc(N(c3ccc(C4CC5CCC4C5)cc3)c3ccc(C45CC6CC(CC(C6)C4)C5)cc3)cc21 ; CC1(C)c2ccccc2-c2ccc(N(c3ccc(C45CC6CC(CC(C6)C4)C5)cc3)c3ccc(C45CC6CC(CC(C6)C4)C5)cc3)cc21]

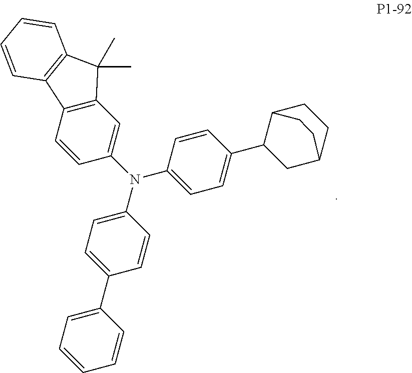 [SMILES: CC1(C)c2ccccc2-c2ccc(N(c3ccc(-c4ccccc4)cc3)c3ccc(C4CC5CCC4CC5)cc3)cc21]

11: The organic electric element of claim 1, wherein compound represented by Formula 2 is one of the following compounds:

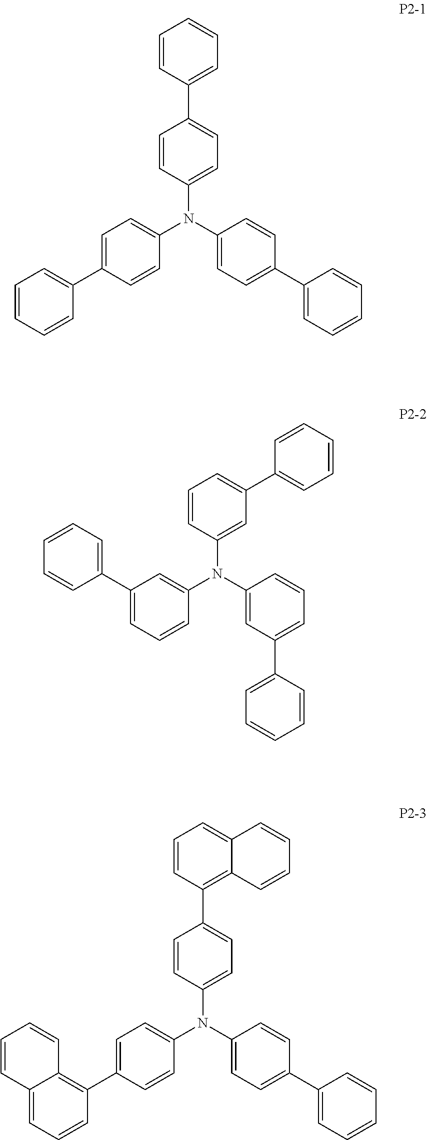 [SMILES: c1ccc(-c2ccc(N(c3ccc(-c4ccccc4)cc3)c3ccc(-c4ccccc4)cc3)cc2)cc1 ; c1ccc(-c2cccc(N(c3cccc(-c4ccccc4)c3)c3cccc(-c4ccccc4)c3)c2)cc1 ; c1ccc(-c2ccc(N(c3ccc(-c4cccc5ccccc45)cc3)c3ccc(-c4cccc5ccccc45)cc3)cc2)cc1]

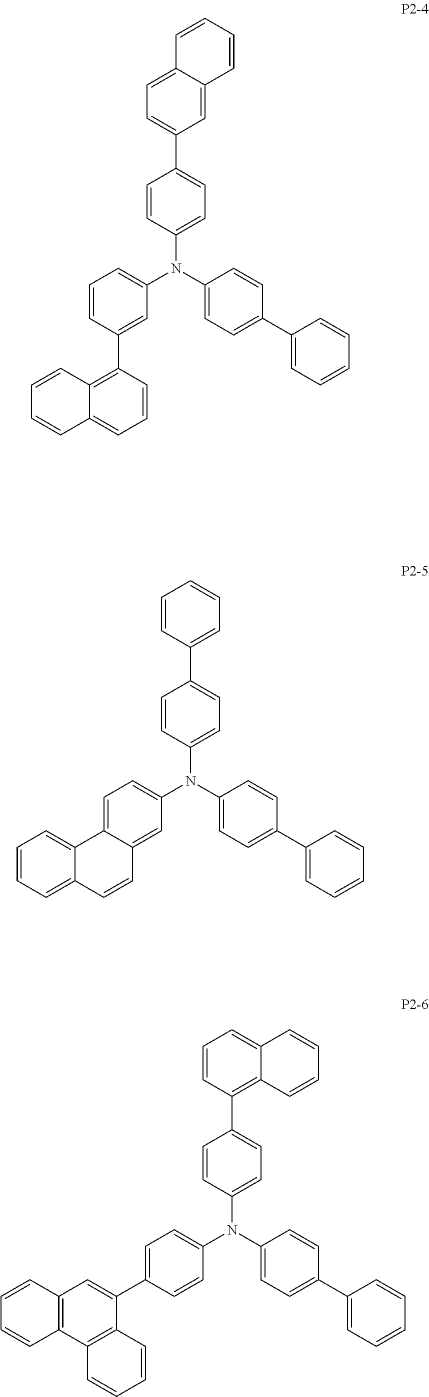 [SMILES: c1ccc(-c2ccc(N(c3ccc(-c4ccc5ccccc5c4)cc3)c3cccc(-c4cccc5ccccc45)c3)cc2)cc1 ; c1ccc(-c2ccc(N(c3ccc(-c4ccccc4)cc3)c3ccc4c(ccc5ccccc54)c3)cc2)cc1 ; c1ccc(-c2ccc(N(c3ccc(-c4cccc5ccccc45)cc3)c3ccc(-c4cc5ccccc5c5ccccc45)cc3)cc2)cc1]

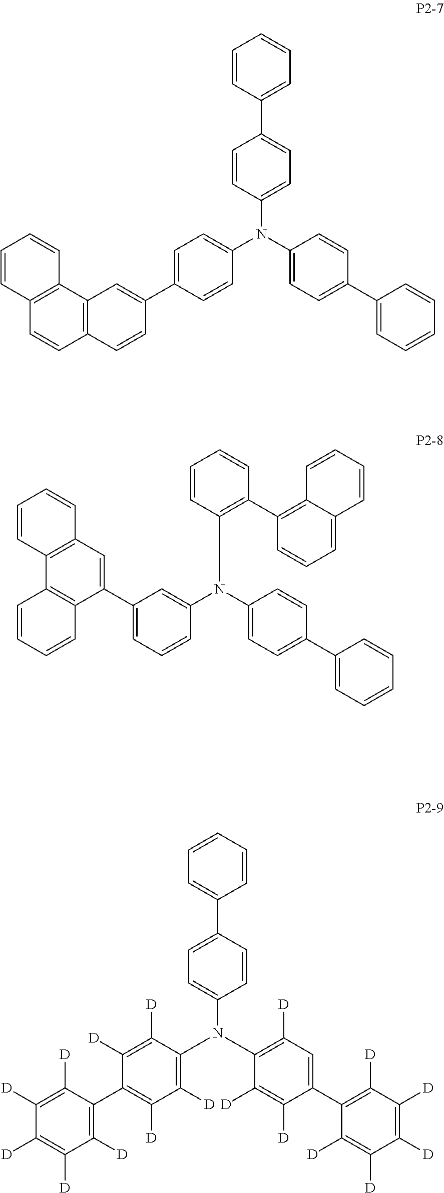 [SMILES: c1ccc(-c2ccc(N(c3ccc(-c4ccccc4)cc3)c3ccc(-c4ccc5ccc6ccccc6c5c4)cc3)cc2)cc1 ; c1ccc(-c2ccc(N(c3cccc(-c4cc5ccccc5c5ccccc45)c3)c3ccccc3-c3cccc4ccccc34)cc2)cc1 ; [2H]c1cc(-c2c([2H])c([2H])c([2H])c([2H])c2[2H])c([2H])c([2H])c1N(c1ccc(-c2ccccc2)cc1)c1c([2H])c([2H])c(-c2c([2H])c([2H])c([2H])c([2H])c2[2H])c([2H])c1[2H]]

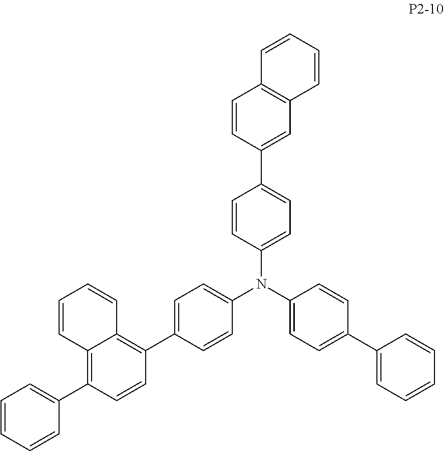 [SMILES: c1ccc(-c2ccc(N(c3ccc(-c4ccc5ccccc5c4)cc3)c3ccc(-c4ccc(-c5ccccc5)c5ccccc45)cc3)cc2)cc1]

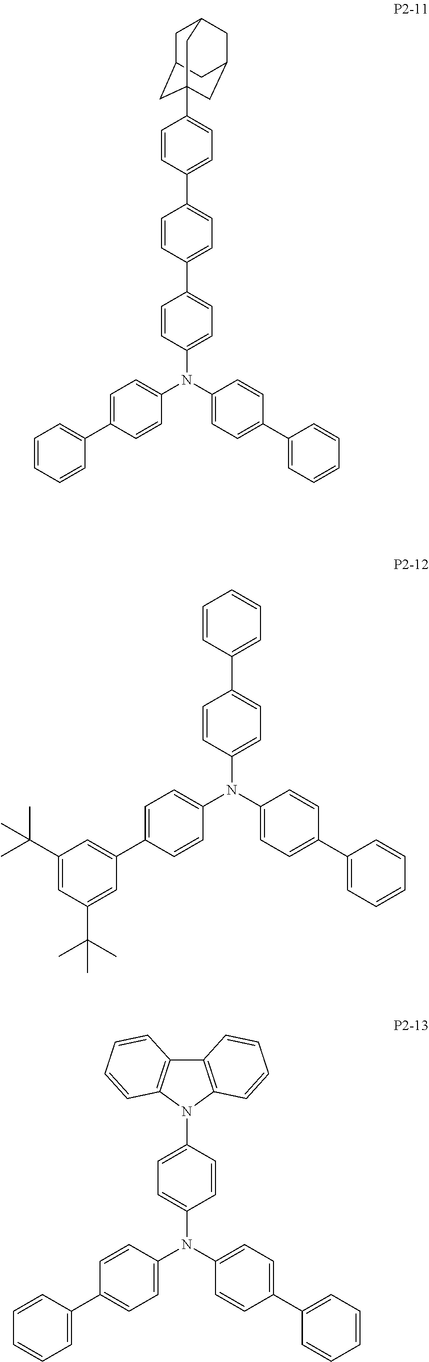 [SMILES: c1ccc(-c2ccc(N(c3ccc(-c4ccccc4)cc3)c3ccc(-c4ccc(-c5ccc(C67CC8CC(CC(C8)C6)C7)cc5)cc4)cc3)cc2)cc1 ; CC(C)(C)c1cc(-c2ccc(N(c3ccc(-c4ccccc4)cc3)c3ccc(-c4ccccc4)cc3)cc2)cc(C(C)(C)C)c1 ; c1ccc(-c2ccc(N(c3ccc(-c4ccccc4)cc3)c3ccc(-n4c5ccccc5c5ccccc54)cc3)cc2)cc1]

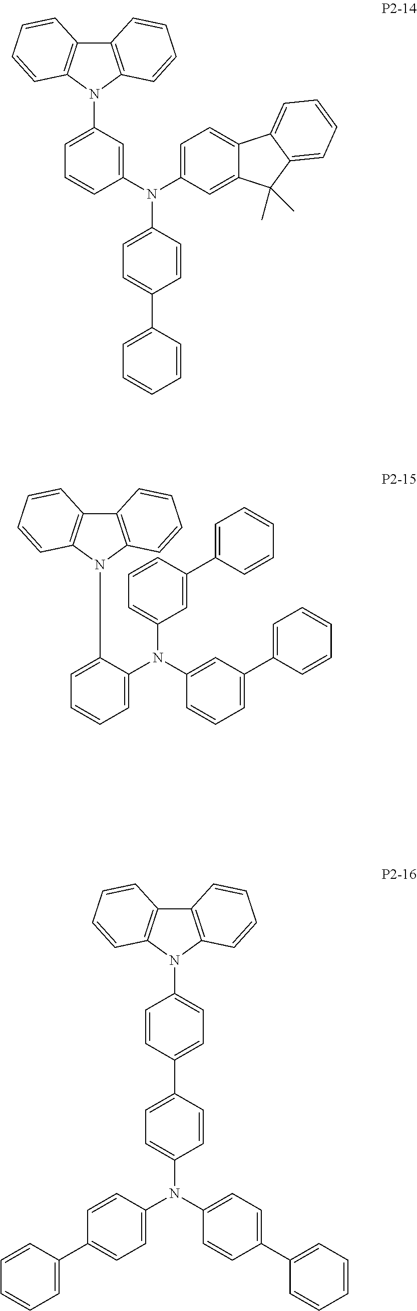 [SMILES: CC1(C)c2ccccc2-c2ccc(N(c3ccc(-c4ccccc4)cc3)c3cccc(-n4c5ccccc5c5ccccc54)c3)cc21 ; c1ccc(-c2cccc(N(c3cccc(-c4ccccc4)c3)c3ccccc3-n3c4ccccc4c4ccccc43)c2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

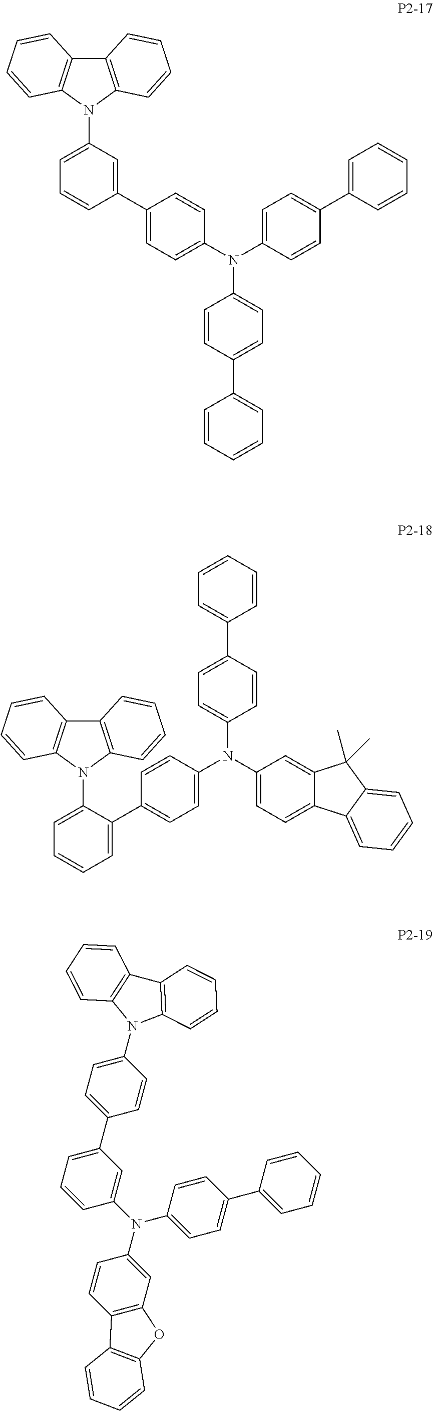 [SMILES: c1ccc(-c2ccc(N(c3ccc(-c4ccccc4)cc3)c3ccc(-c4cccc(-n5c6ccccc6c6ccccc65)c4)cc3)cc2)cc1 ; CC1(C)c2ccccc2-c2ccc(N(c3ccc(-c4ccccc4)cc3)c3ccc(-c4ccccc4-n4c5ccccc5c5ccccc54)cc3)cc21 ; c1ccc(-c2ccc(N(c3cccc(-c4ccc(-n5c6ccccc6c6ccccc65)cc4)c3)c3ccc4c(c3)oc3ccccc34)cc2)cc1]

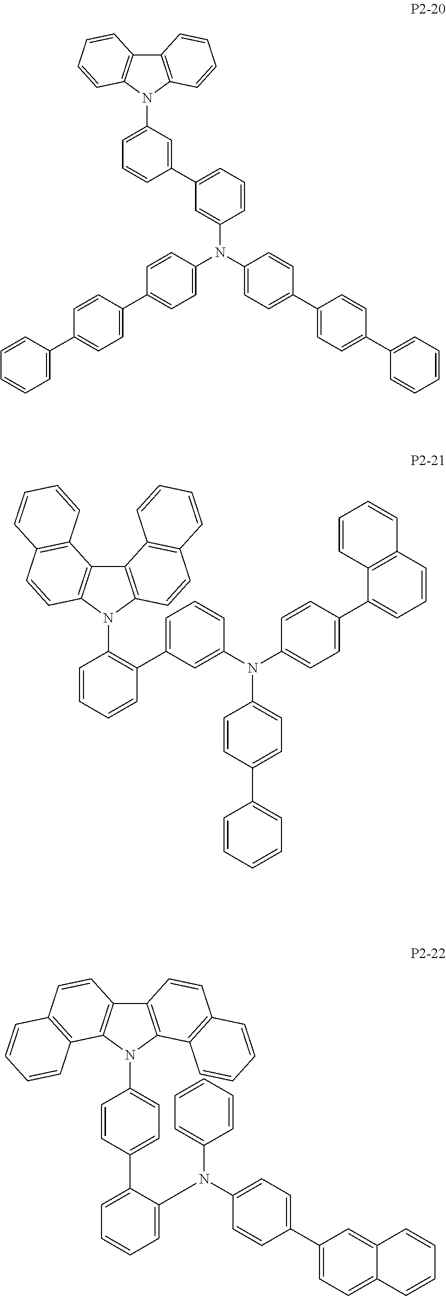 [SMILES: c1ccc(-c2ccc(-c3ccc(N(c4ccc(-c5ccc(-c6ccccc6)cc5)cc4)c4cccc(-c5cccc(-n6c7ccccc7c7ccccc76)c5)c4)cc3)cc2)cc1 ; c1ccc(-c2ccc(N(c3ccc(-c4cccc5ccccc45)cc3)c3cccc(-c4ccccc4-n4c5ccc6ccccc6c5c5c6ccccc6ccc54)c3)cc2)cc1 ; c1ccc(N(c2ccc(-c3ccc4ccccc4c3)cc2)c2ccccc2-c2ccc(-n3c4c5ccccc5ccc4c4ccc5ccccc5c43)cc2)cc1]

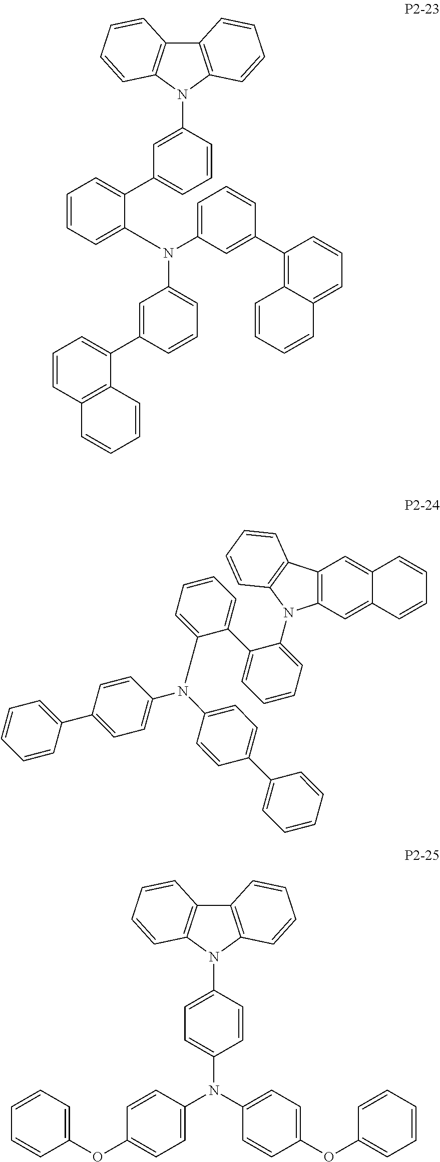 [SMILES: c1cc(-c2cccc3ccccc23)cc(N(c2cccc(-c3cccc4ccccc34)c2)c2ccccc2-c2cccc(-n3c4ccccc4c4ccccc43)c2)c1 ; c1ccc(-c2ccc(N(c3ccc(-c4ccccc4)cc3)c3ccccc3-c3ccccc3-n3c4ccccc4c4cc5ccccc5cc43)cc2)cc1 ; c1ccc(Oc2ccc(N(c3ccc(Oc4ccccc4)cc3)c3ccc(-n4c5ccccc5c5ccccc54)cc3)cc2)cc1]

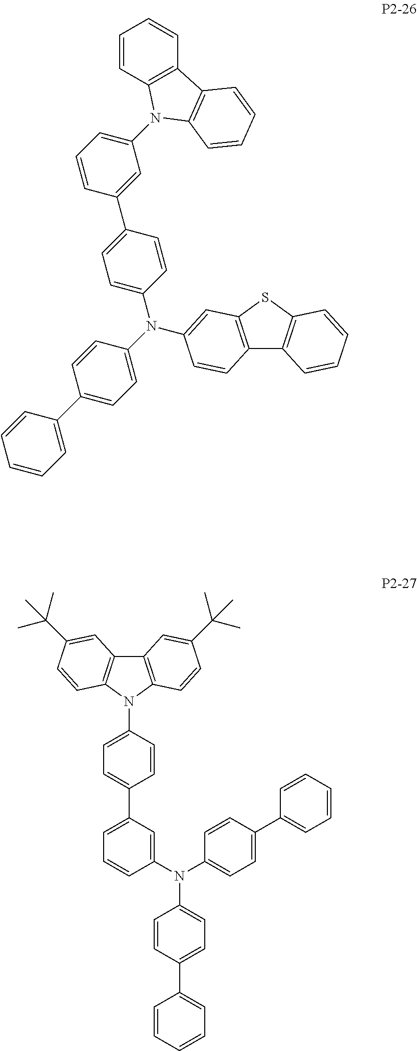 [SMILES: c1ccc(-c2ccc(N(c3ccc(-c4cccc(-n5c6ccccc6c6ccccc65)c4)cc3)c3ccc4c(c3)sc3ccccc34)cc2)cc1 ; CC(C)(C)c1ccc2c(c1)c1cc(C(C)(C)C)ccc1n2-c1ccc(-c2cccc(N(c3ccc(-c4ccccc4)cc3)c3ccc(-c4ccccc4)cc3)c2)cc1]

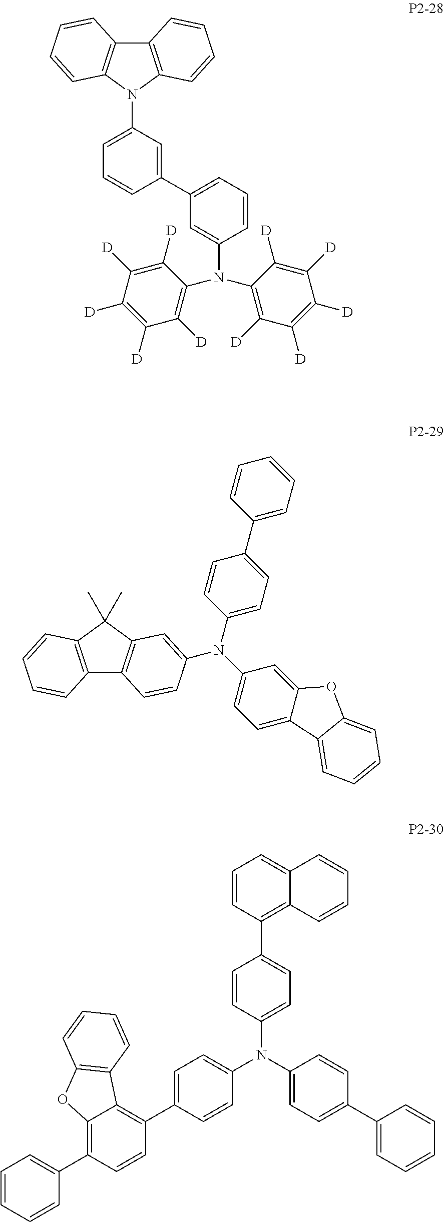 [SMILES: [2H]c1c([2H])c([2H])c(N(c2cccc(-c3cccc(-n4c5ccccc5c5ccccc54)c3)c2)c2c([2H])c([2H])c([2H])c([2H])c2[2H])c([2H])c1[2H] ; CC1(C)c2ccccc2-c2ccc(N(c3ccc(-c4ccccc4)cc3)c3ccc4c(c3)oc3ccccc34)cc21 ; c1ccc(-c2ccc(N(c3ccc(-c4cccc5ccccc45)cc3)c3ccc(-c4ccc(-c5ccccc5)c5oc6ccccc6c45)cc3)cc2)cc1]

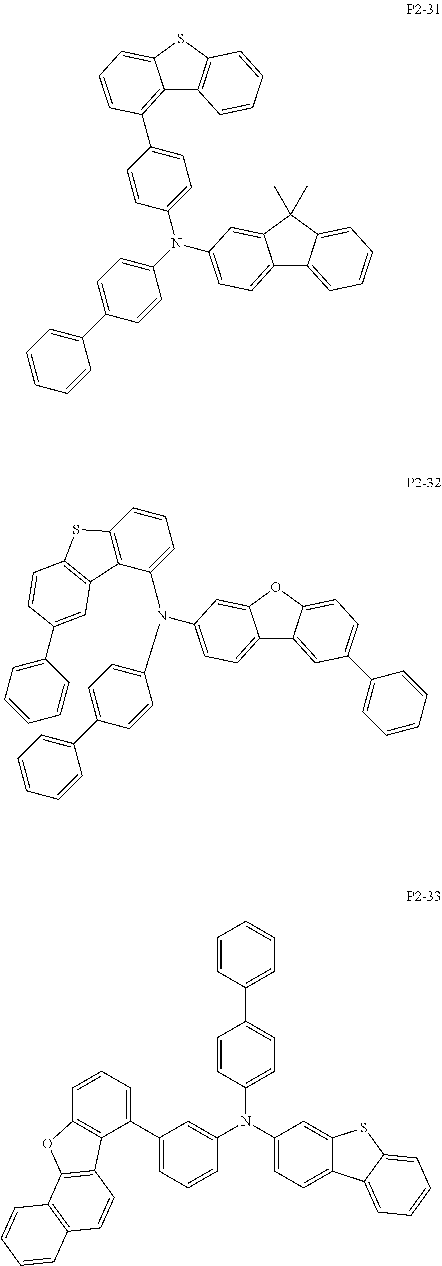 [SMILES: CC1(C)c2ccccc2-c2ccc(N(c3ccc(-c4ccccc4)cc3)c3ccc(-c4cccc5sc6ccccc6c45)cc3)cc21 ; c1ccc(-c2ccc(N(c3ccc4c(c3)oc3ccc(-c5ccccc5)cc34)c3cccc4sc5ccc(-c6ccccc6)cc5c34)cc2)cc1 ; c1ccc(-c2ccc(N(c3cccc(-c4cccc5oc6c7ccccc7ccc6c45)c3)c3ccc4c(c3)sc3ccccc34)cc2)cc1]

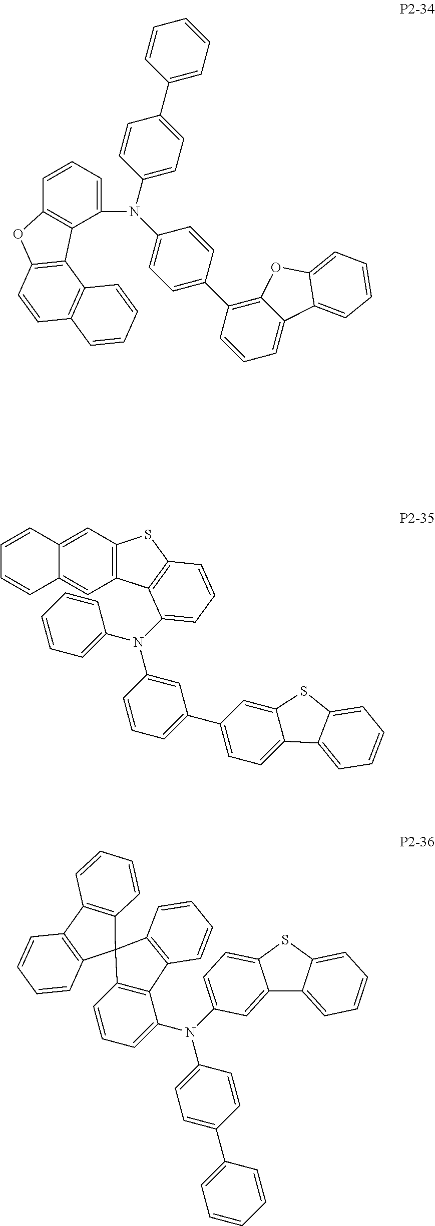 [SMILES: c1ccc(-c2ccc(N(c3ccc(-c4cccc5c4oc4ccccc45)cc3)c3cccc4oc5ccc6ccccc6c5c34)cc2)cc1 ; c1ccc(N(c2cccc(-c3ccc4c(c3)sc3ccccc34)c2)c2cccc3sc4cc5ccccc5cc4c23)cc1 ; c1ccc(-c2ccc(N(c3ccc4sc5ccccc5c4c3)c3cccc4c3-c3ccccc3C43c4ccccc4-c4ccccc43)cc2)cc1]

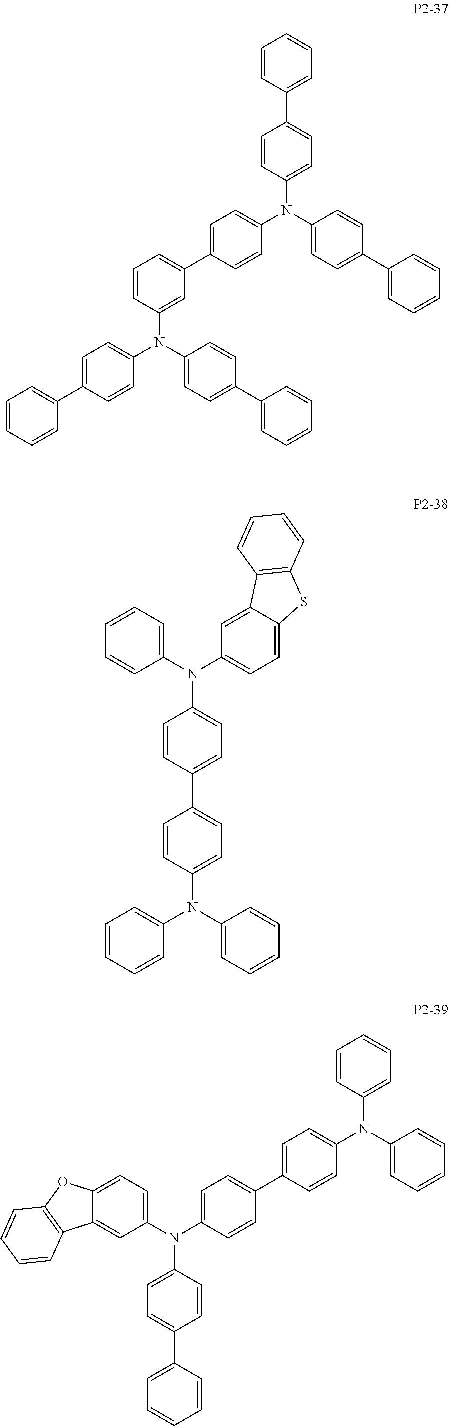 [SMILES: c1ccc(-c2ccc(N(c3ccc(-c4ccccc4)cc3)c3ccc(-c4cccc(N(c5ccc(-c6ccccc6)cc5)c5ccc(-c6ccccc6)cc5)c4)cc3)cc2)cc1 ; c1ccc(N(c2ccccc2)c2ccc(-c3ccc(N(c4ccccc4)c4ccc5sc6ccccc6c5c4)cc3)cc2)cc1 ; c1ccc(-c2ccc(N(c3ccc(-c4ccc(N(c5ccccc5)c5ccccc5)cc4)cc3)c3ccc4oc5ccccc5c4c3)cc2)cc1]

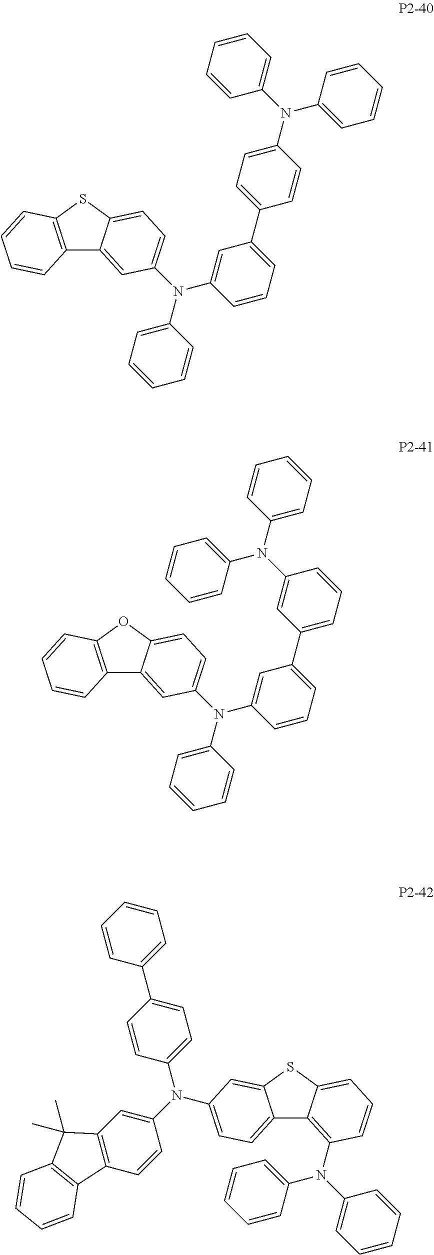 [SMILES: c1ccc(N(c2ccccc2)c2ccc(-c3cccc(N(c4ccccc4)c4ccc5sc6ccccc6c5c4)c3)cc2)cc1 ; c1ccc(N(c2ccccc2)c2cccc(-c3cccc(N(c4ccccc4)c4ccc5oc6ccccc6c5c4)c3)c2)cc1 ; CC1(C)c2ccccc2-c2ccc(N(c3ccc(-c4ccccc4)cc3)c3ccc4c(c3)sc3cccc(N(c5ccccc5)c5ccccc5)c34)cc21]

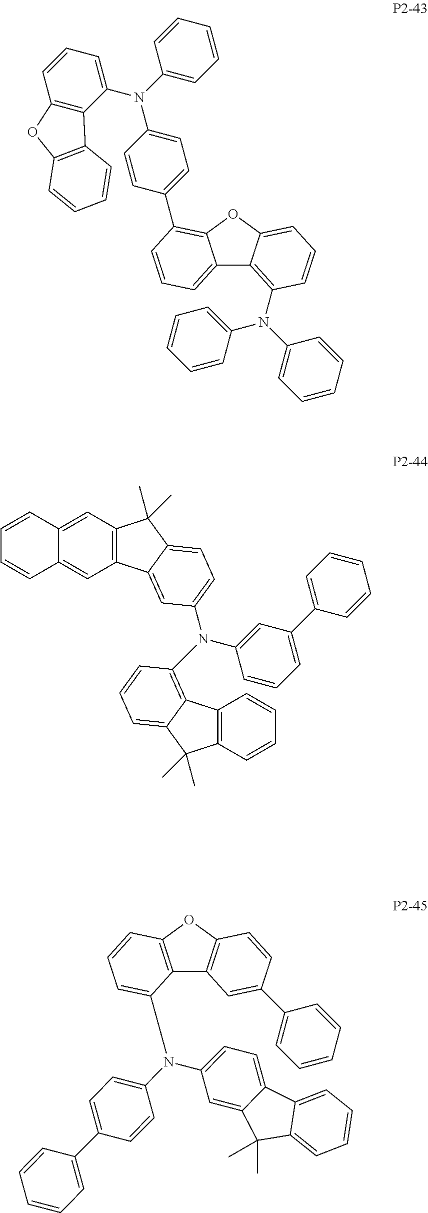 [SMILES: c1ccc(N(c2ccc(-c3cccc4c3oc3cccc(N(c5ccccc5)c5ccccc5)c34)cc2)c2cccc3oc4ccccc4c23)cc1 ; CC1(C)c2ccc(N(c3cccc(-c4ccccc4)c3)c3cccc4c3-c3ccccc3C4(C)C)cc2-c2cc3ccccc3cc21 ; CC1(C)c2ccccc2-c2ccc(N(c3ccc(-c4ccccc4)cc3)c3cccc4oc5ccc(-c6ccccc6)cc5c34)cc21]

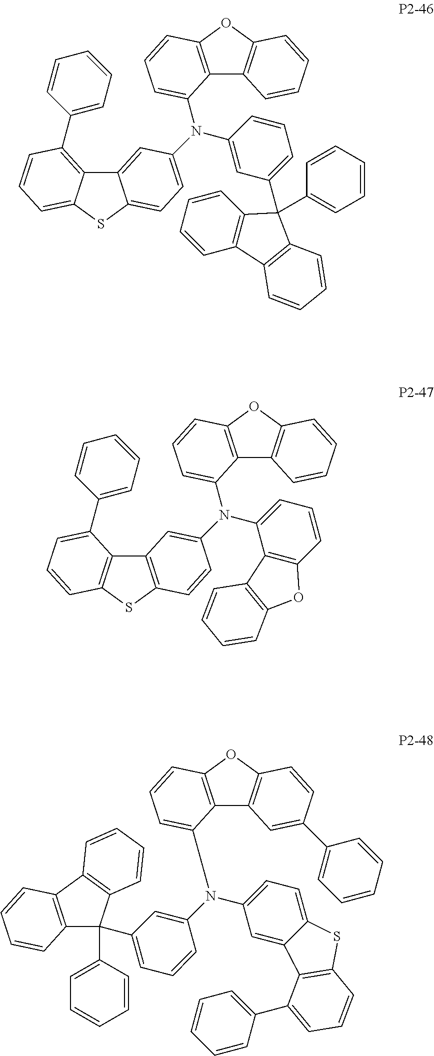 [SMILES: c1ccc(-c2cccc3sc4ccc(N(c5cccc(C6(c7ccccc7)c7ccccc7-c7ccccc76)c5)c5cccc6oc7ccccc7c56)cc4c23)cc1 ; c1ccc(-c2cccc3sc4ccc(N(c5cccc6oc7ccccc7c56)c5cccc6oc7ccccc7c56)cc4c23)cc1 ; c1ccc(-c2ccc3oc4cccc(N(c5cccc(C6(c7ccccc7)c7ccccc7-c7ccccc76)c5)c5ccc6sc7cccc(-c8ccccc8)c7c6c5)c4c3c2)cc1]

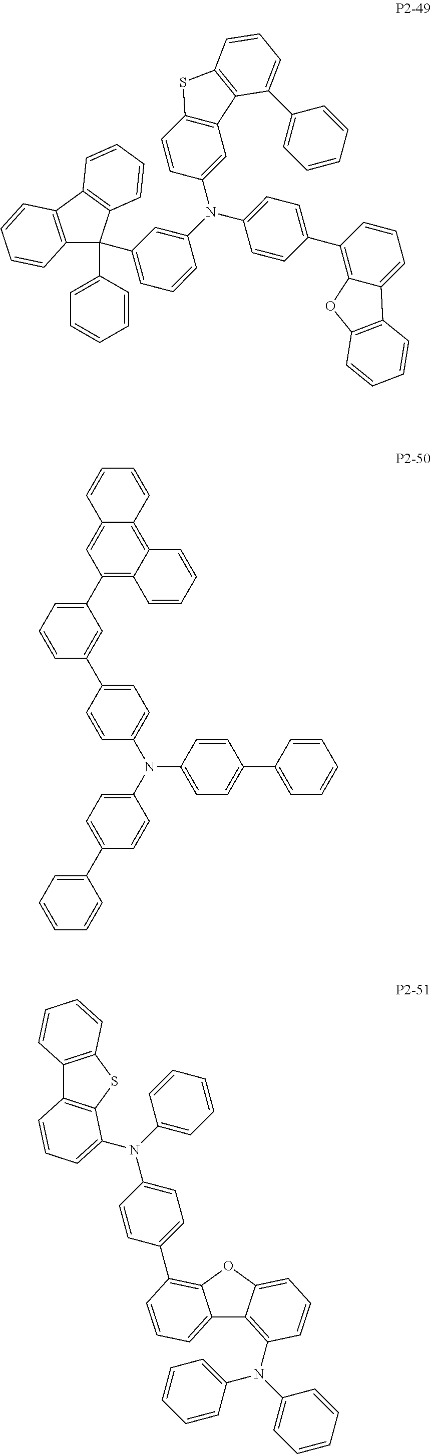 [SMILES: c1ccc(-c2cccc3sc4ccc(N(c5ccc(-c6cccc7c6oc6ccccc67)cc5)c5cccc(C6(c7ccccc7)c7ccccc7-c7ccccc76)c5)cc4c23)cc1 ; c1ccc(-c2ccc(N(c3ccc(-c4ccccc4)cc3)c3ccc(-c4cccc(-c5cc6ccccc6c6ccccc56)c4)cc3)cc2)cc1 ; c1ccc(N(c2ccc(-c3cccc4c3oc3cccc(N(c5ccccc5)c5ccccc5)c34)cc2)c2cccc3c2sc2ccccc23)cc1]

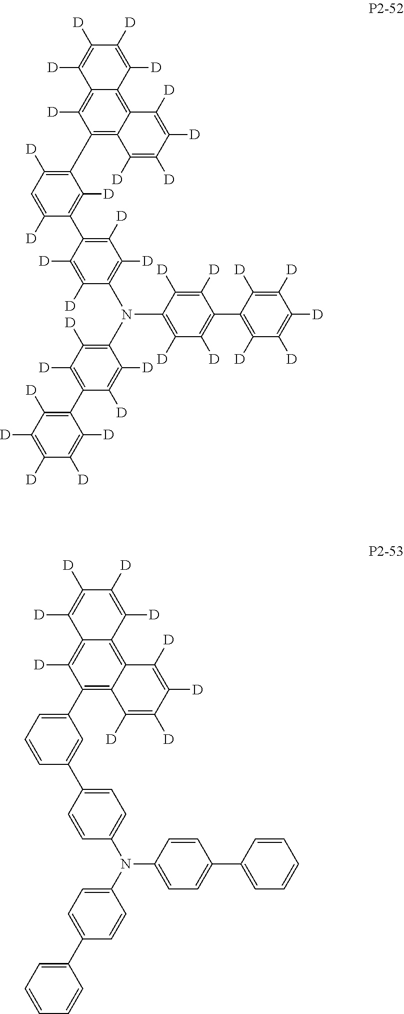 [SMILES: [2H]c1cc([2H])c(-c2c([2H])c3c([2H])c([2H])c([2H])c([2H])c3c3c([2H])c([2H])c([2H])c([2H])c23)c([2H])c1-c1c([2H])c([2H])c(N(c2c([2H])c([2H])c(-c3c([2H])c([2H])c([2H])c([2H])c3[2H])c([2H])c2[2H])c2c([2H])c([2H])c(-c3c([2H])c([2H])c([2H])c([2H])c3[2H])c([2H])c2[2H])c([2H])c1[2H] ; [2H]c1c([2H])c([2H])c2c(c1[2H])c([2H])c(-c1cccc(-c3ccc(N(c4ccc(-c5ccccc5)cc4)c4ccc(-c5ccccc5)cc4)cc3)c1)c1c([2H])c([2H])c([2H])c([2H])c12]

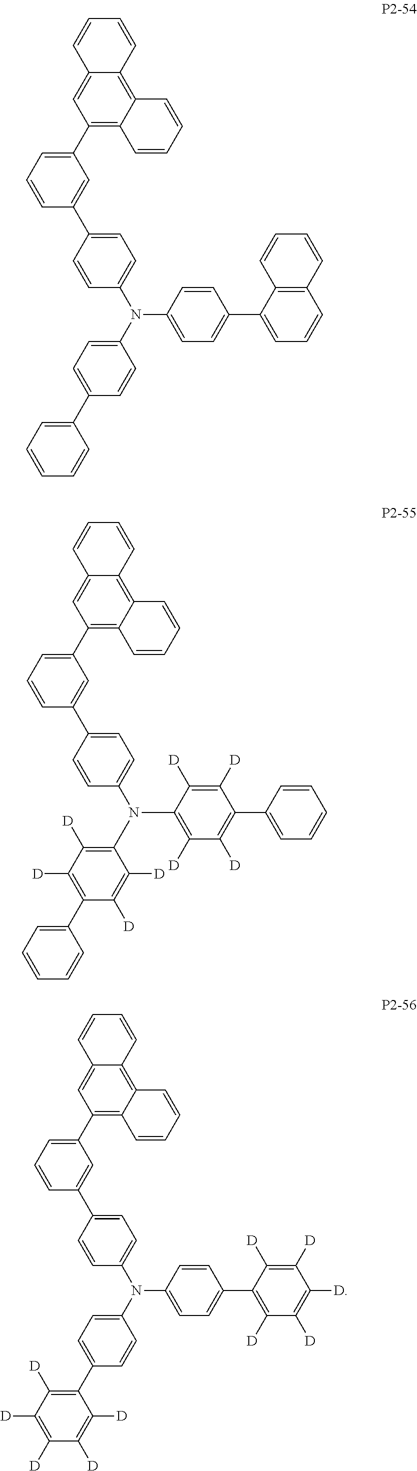

12: The organic electric element of claim 1, wherein the first light-emitting auxiliary layer has a thickness of 25 to 900 Å, and the second light-emitting auxiliary layer has a thickness of 10 to 300 Å.

13: The organic electric element of claim 1, wherein the hole mobility of the compound represented by Formula 1 in the first light-emitting auxiliary layer is 5.1×10⁻⁵ to 1.3×10⁻³ cm/V-S.

14: The organic electric element of claim 1, wherein T₁ energy level of the compound represented by Formula 2 in the second light-emitting auxiliary layer is 2.3 to 3.0.

15: The organic electric element of claim 1, wherein the organic electric element further comprises a layer for improving luminous efficiency, and the layer for improving luminous efficiency is formed on one side of both sides of the anode or the cathode, wherein the one side is not facing the organic material layer.

16: The organic electric element of claim 1, wherein the organic material layer includes two or more stacks comprising a hole transport layer, a light-emitting layer, a light-emitting auxiliary layer and an electron transport layer sequentially formed on the first electrode.

17: The organic electric element of claim 16, wherein the organic material layer further includes a charge generation layer formed between the two or more stacks.

18: An electronic device including a display device and a control unit for driving the display device, wherein the display device includes the organic electric element of claim 1.

19: The electronic device of claim 18, wherein the organic electric element is selected from the group consisting of an organic electroluminescent element, an organic solar cell, an organic photo conductor, an organic transistor, an element for monochromatic illumination and a quantum dot display.
